(19) United States
(12) Patent Application Publication
(10) Pub. No.: US 2016/0147147 A1
(43) Pub. Date: May 26, 2016

(54) PATTERN FORMING METHOD, ACTINIC RAY SENSITIVE OR RADIATION SENSITIVE RESIN COMPOSITION, RESIST FILM, METHOD FOR MANUFACTURING ELECTRONIC DEVICE USING SAME, AND ELECTRONIC DEVICE

(71) Applicant: FUJIFILM Corporation, Tokyo (JP)

(72) Inventors: Shuji HIRANO, Haibara-gun (JP); Hiroo TAKIZAWA, Haibara-gun (JP)

(73) Assignee: FUJIFILM Corporation, Tokyo (JP)

(21) Appl. No.: 15/008,945

(22) Filed: Jan. 28, 2016

Related U.S. Application Data
(63) Continuation of application No. PCT/JP2014/067442, filed on Jun. 30, 2014.

(30) Foreign Application Priority Data
Aug. 2, 2013 (JP) 2013-161903

(51) Int. Cl. G03F 7/038; G03F 7/30

(52) U.S. Cl. CPC G03F 7/038; G03F 7/30

(57) ABSTRACT

There are provided a pattern forming method which satisfies high sensitivity, high resolving power at the time of isolated line pattern formation, a good pattern shape, and high dry etching resistance at the same time, an actinic ray sensitive or radiation sensitive resin composition and a resist film which are provided thereto, a method for manufacturing an electronic device using these, and an electronic device by using a pattern forming method including step (1) of forming a film using the actinic ray sensitive or radiation sensitive resin composition containing a resin (Ab) having a repeating unit represented by the specific General Formula (Ab1), step (2) of exposing the film, and step (4) of performing development using a developer including an organic solvent after exposing and of forming a negative type pattern, in this order.

### CROSS REFERENCE TO RELATED APPLICATION

This is a continuation of International Application No. PCT/JP2014/067442 filed on Jun. 30, 2014, and claims priority from Japanese Patent Application No. 2013-161903 filed on Aug. 2, 2013, the entire disclosures of which are incorporated herein by reference.

### BACKGROUND OF THE INVENTION

1. Field of the Invention

The present invention relates to a pattern forming method using a developer including an organic solvent, which is suitably used in an ultra microlithography process in manufacturing an ultra LSI or a high-capacity microchip or other photofabrication processes, an actinic ray sensitive or radiation sensitive resin composition, a resist film, a method for manufacturing an electronic device using these, and an electronic device. In more detail, the present invention relates to a pattern forming method using a developer including an organic solvent, which can be suitably used in fine processing of a semiconductor element using an electron beam or EUV light (wavelength: around 13 nm), an actinic ray sensitive or radiation sensitive resin composition, a resist film, a method for manufacturing an electronic device using these, and an electronic device.

2. Description of the Related Art

In the related art, fine processing by lithography using a photoresist composition has been performed in the manufacturing process of semiconductor devices such as IC and LSI. In recent years, with higher integration of integrated circuits, ultra fine patterns have been required to be formed in a sub-micron region or a quarter-micron region. Accordingly, exposure wavelengths tend to be shortened, for example, from g-line to i-line, and to a KrF excimer laser light. Furthermore, at present, lithography using an electron beam, X-rays, or EUV light, in addition to the excimer laser light, is also being developed.

Lithography using an electron beam, X-rays, or EUV light is positioned as a next generation or next after next generation pattern forming technology, and a resist composition having high sensitivity and high-resolution is desired.

In particular, for shortening the wafer processing time, sensitivity improvement is a very important issue, but when trying to improve sensitivity, the pattern shape or the resolving power represented by the limit resolution line width decreases, and therefore, development of a resist composition which satisfies these properties at the same time has been strongly desired.

In general, there are two types of the actinic ray sensitive or radiation sensitive resin composition, that is, a “positive type” in which a pattern is formed by solubilizing the exposed portion with respect to an alkali developer by exposure to radiation using a resin poorly soluble or insoluble in the alkali developer, and a “negative type” in which a pattern is formed by poorly solubilizing or insolubilizing the exposed portion with respect to an alkali developer by exposure to radiation using a resin soluble in the alkali developer.

As the actinic ray sensitive or radiation sensitive resin composition suitable for a lithography process using an electron beam, X-rays, or EUV light, from the viewpoint of high sensitivity, a chemical amplification positive resist composition using mainly an acid catalytic reaction has been considered, and a chemical amplification positive resist composition consisting of a resin which is insoluble or poorly soluble in an alkali developer, and has properties of becoming soluble in an alkali developer by the action of an acid, as a main component, and an acid generator is effectively used (for example, refer to JP2013-100471A, JP2013-100472A, and JP2013-100473A).

On the other hand, in the manufacture of a semiconductor element or the like, formation of patterns having various shapes such as a line, a trench, and a hole is required. To meet the requirement for formation of patterns having various shapes, development of not only a positive type actinic ray sensitive or radiation sensitive resin composition but also a negative type actinic ray sensitive or radiation sensitive resin composition has also been performed.

In formation of an ultra fine pattern, further reduction in resolving power decrease and further improvement of the pattern shape have been demanded.

To solve this problem, a method of developing an acid decomposable resin using a developer other than an alkali developer has also been proposed (for example, refer to JP2013-68675A and JP2011-221513A).

### SUMMARY OF THE INVENTION

However, in the above-described pattern forming method, further improvement of sensitivity, resolving power at the time of isolated line pattern formation, a pattern shape, and dry etching resistance has been demanded, and thus, a pattern forming method which satisfies these characteristics at the same time at a higher level has been demanded.

In consideration of the above problems, objects of the present invention are to solve the problems in performance improvement techniques in fine processing of a semiconductor element, and to provide a pattern forming method which satisfies high sensitivity, high resolving power at the time of isolated line pattern formation, a good pattern shape, and high dry etching resistance at the same time, an actinic ray sensitive or radiation sensitive resin composition, a resist film, a method for manufacturing an electronic device using these, and an electronic device.

That is, the present invention is as follows.

[1]

A pattern forming method including Step (1) of forming a film using an actinic ray sensitive or radiation sensitive resin composition containing a resin (Ab) having a repeating unit represented by the following General Formula (Ab1), Step (2) of exposing the film, and Step (4) of performing development using a developer including an organic solvent after exposing and of forming a negative type pattern, in this order.

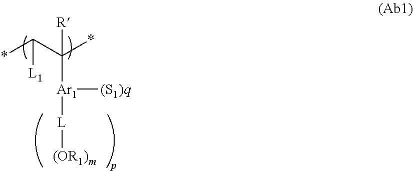

In General Formula (Ab1), R′ represents a hydrogen atom, an alkyl group, or a halogen atom.

L₁ represents a hydrogen atom or an alkyl group, and L₁ and Ar₁ may be connected to each other to form a ring, and in this case, L₁ represents an alkylene group.

Ar₁ represents a (p+q+1) valent aromatic ring group.

L represents an (m+1) valent connecting group.

S₁ represents an organic group,

OR₁ represents a group which generates an alcoholic hydroxyl group by being decomposed due to the action of an acid.

In a case where a plurality of S₁'s, L's, and R₁'s are present, the plurality of S₁'s, the plurality of L's, or the plurality of R₁'s may be the same or different, respectively, and the plurality of R₁'s may be bonded to each other to form a ring.

m represents an integer of 1 or greater.

p represents an integer of 1 or greater, and q represents an integer of 0 or greater.

[2]

The pattern forming method according to [1], in which the repeating unit represented by General Formula (Ab1) is a repeating unit represented by the following General Formula (Ab1-1).

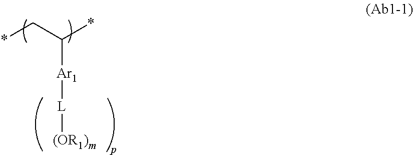

In General Formula (Ab1-1), Ar₁ represents a (p+1) valent aromatic ring group.

L represents an (m+1) valent connecting group.

OR₁ represents a group which generates an alcoholic hydroxyl group by being decomposed due to the action of an acid.

In a case where a plurality of L's and R₁'s are present, the plurality of L's and the plurality of R₁'s may be the same or different, respectively, and the plurality of R₁'s may be bonded to each other to form a ring.

m represents an integer of 1 or greater.

p represents an integer of 1 or greater.

[3]

The pattern forming method according to [2], in which the repeating unit represented by General Formula (Ab1-1) is a repeating unit represented by the following General Formula (Ab1-1-1).

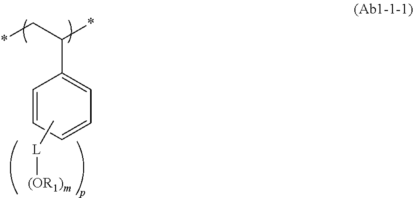

In General Formula (Ab1-1-1), L represents an (m+1) valent connecting group.

OR₁ represents a group which generates an alcoholic hydroxyl group by being decomposed due to the action of an acid.

In a case where a plurality of L's and R₁'s are present, the plurality of L's and the plurality of R₁'s may be the same or different, respectively, and the plurality of R₁'s may be bonded to each other to form a ring.

m represents an integer of 1 or greater.

p represents an integer of 1 or greater.

[4]

The pattern forming method according to any one of [1] to [3], in which the resin (Ab) further has a repeating unit represented by the following General Formula (A).

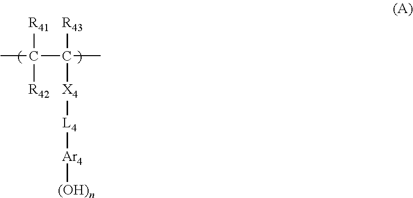

In General Formula (A), each of R₄₁, R₄₂, and R₄₃ independently represents a hydrogen atom, an alkyl group, a halogen atom, a cyano group, or an alkoxycarbonyl group. Here, R₄₂ may be bonded to An₄ or X₄ to form a ring, and R₄₂ in this case represents a single bond or an alkylene group.

X₄ represents a single bond, an alkylene group, —COO—, or —CONR₆₄—. Here, R₆₄ represents a hydrogen atom or an alkyl group.

L₄ represents a single bond, —COO—, or an alkylene group.

Ar₄ represents an (n+1) valent aromatic ring group, and, in the case of being bonded to R₄₂ to form a ring, Ar₄ represents an (n+2) valent aromatic ring group.

n represents an integer of 1 to 4.

[5]

The pattern forming method according to [4], in which the repeating unit represented by General Formula (A) is a repeating unit represented by the following General Formula (A1) or (A2).

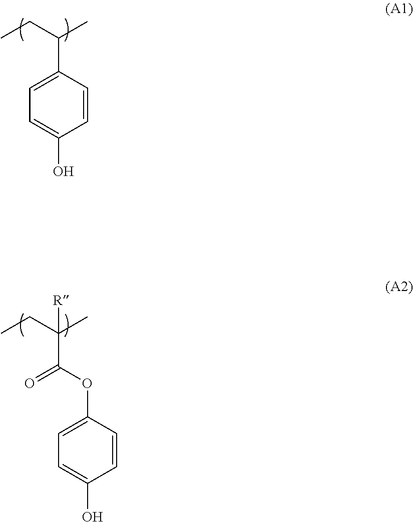

In General Formula (A2), R″ represents a hydrogen atom or a methyl group. [6]

The pattern forming method according to any one of [1] to [5], in which the exposure in Step (2) is exposure by an electron beam or extreme ultraviolet rays.

[7]

The pattern forming method according to any one of [1] to [6], in which the actinic ray sensitive or radiation sensitive resin composition further includes a compound that generates an acid by irradiation with actinic ray or radiation.

[8]

The pattern forming method according to any one of [1] to [7], in which the resin (Ab) is a resin having a repeating unit represented by the following General Formula (4).

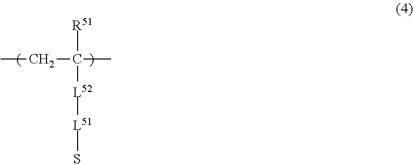

In General Formula (4), R⁵¹ represents a hydrogen atom or a methyl group. L⁵¹ represents a single bond or a divalent connecting group. L⁵² represents a divalent connecting group. S represents a structural portion that generates an acid on a side chain by being decomposed by irradiation with actinic ray or radiation.

[9]

An actinic ray sensitive or radiation sensitive resin composition which is supplied to the pattern forming method according to any one of [1] to [8].

[10]

A resist film which is formed of the actinic ray sensitive or radiation sensitive resin composition according to [9].

[11]

A method for manufacturing an electronic device including the pattern forming method according to any one of [1] to [8].

[12]

An electronic device manufactured by the method for manufacturing an electronic device according to [11].

According to the present invention, a pattern forming method which satisfies high sensitivity, high resolving power at the time of isolated line pattern formation, a good pattern shape, and high dry etching resistance at the same time, an actinic ray sensitive or radiation sensitive resin composition, a resist film, a method for manufacturing an electronic device using these, and an electronic device can be provided.

### DESCRIPTION OF THE PREFERRED EMBODIMENTS

Hereinafter, embodiments of the invention will be described in detail.

Regarding the description of a group (atomic group) in the present specification, when the description does not indicate whether a group is substituted or unsubstituted, the description includes both a group having a substituent and a group not having a substituent. For example, “alkyl group” includes not only an alkyl group (an unsubstituted alkyl group) which does not have a substituent but also an alkyl group (a substituted alkyl group) which has a substituent.

The term “actinic ray” or “radiation” in the present specification refers to, for example, a bright line spectrum of a mercury lamp, far-ultraviolet rays represented by an excimer laser, extreme ultraviolet (EUV) rays, X-rays, or an electron beam (EB). The “light” in the present invention refers to actinic ray or radiation.

The term “exposure” in the present invention includes not only the exposure performed using a mercury lamp, far-ultraviolet rays represented by an excimer laser, X-rays, EUV light, and the like, but also drawing performed using particle beams such as an electron beam and an ion beam, unless otherwise specified.

[Pattern Formation Method]

First, a pattern forming method of the present invention will be described.

The pattern forming method of the present invention includes Step (1) of forming a film using an actinic ray sensitive or radiation sensitive resin composition containing a resin (Ab) having a repeating unit represented by the following General Formula (Ab1) (hereinafter, also referred to as “film forming step”), Step (2) of exposing the film (hereinafter, also referred to as “exposure step”), and Step (4) of performing development using a developer including an organic solvent after exposing and of forming a negative type pattern (hereinafter, also referred to as “development step”), in this order.

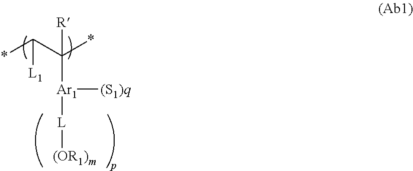

In General Formula (Ab1), R′ represents a hydrogen atom, an alkyl group, or a halogen atom.

L₁ represents a hydrogen atom or an alkyl group, and L₁ and Ar₁ may be connected to each other to form a ring, and in this case, L₁ represents an alkylene group.

Ar₁ represents a (p+q+1) valent aromatic ring group.

L represents an (m+1) valent connecting group.

S₁ represents an organic group,

OR₁ represents a group which generates an alcoholic hydroxyl group by being decomposed due to the action of an acid. In a case where a plurality of S₁'s, L's, and R₁'s are present, the plurality of S₁'s, L's, or R₁'s may be the same or different, respectively, and the plurality of R₁'s may be bonded to each other to form a ring.

m represents an integer of 1 or greater.

p represents an integer of 1 or greater, and q represents an integer of 0 or greater.

According to the pattern forming method of the present invention, a pattern forming method which satisfies high sensitivity, high resolving power at the time of isolated line pattern formation, and a good pattern shape at the same time, an actinic ray sensitive or radiation sensitive resin composition, a resist film, a method for manufacturing an electronic device using these, and an electronic device can be provided. The reason for this is not clear, however, it is thought to be as follows.

The resin (Ab) contained in the actinic ray sensitive or radiation sensitive resin composition used in the pattern forming method of the present invention has an aromatic ring group as Ar₁ in the repeating unit represented by General Formula (Ab1). It is thought that, due to this, in the exposed portion, the aromatic ring emits a sufficient number of secondary electrons, and the reaction in which the resin produces a polar group efficiently proceeds, and thus, sensitivity becomes high.

Since the aromatic ring π-π-interacts with other aromatic rings, the strength of the resist film formed of the actinic ray sensitive or radiation sensitive resin composition used in the present invention is higher compared to the strength of a resist film in which the resin does not have an aromatic ring. It is thought that, due to this, the dry etching resistance is improved.

The repeating unit which generates an alcoholic hydroxyl group produced by decomposition of the repeating unit represented by General Formula (Ab1) due to the action of an acid has lower affinity for a developer containing an organic solvent, for example, compared to a repeating unit having a phenolic hydroxyl group. Accordingly, it is thought that the dissolution rate of the exposed portion with respect to the developer can be sufficiently reduced, and thus, the pattern shape is improved. In general, in an isolated line pattern, pattern collapse is likely to occur and high resolution is less likely to be obtained, but according to the invention, as described above, the dissolution rate of the exposed portion with respect to the developer is sufficiently low, and the exposed portion containing a resin having the repeating unit represented by General Formula (Ab1) having an aromatic ring has high adhesion to a substrate. It is thought that, due to this, pattern collapse is less likely to occur, and, in particular, this contributes to improvement of resolution of the isolated line pattern.

(1) Film Forming Step

The present invention also relates to a resist film which is formed of the actinic ray sensitive or radiation sensitive resin composition described above.

More specifically, a resist film can be formed by dissolving the respective components described below of the actinic ray sensitive or radiation sensitive resin composition in a solvent, by filtering using a filter, as necessary, and by applying the resultant product to a support (substrate). As the filter, a filter made of polytetrafluoroethylene, made of polyethylene, or made of nylon, preferably having a pore size of 0.5 μm or less, more preferably having a pore size of 0.2 μm or less, and still more preferably having a pore size of 0.1 μm or less is preferable.

The composition is applied to a substrate (example: silicon, silicon dioxide coating) which is used in manufacture of precision integrated circuit elements by a suitable coating method such as a spin coater. Thereafter, the resultant product is dried, whereby a photosensitive film is formed. In the step of drying, heating (prebake) is preferably performed.

Although the film thickness is not particularly limited, the film thickness is preferably within a range of 10 nm to 500 nm, more preferably within a range of 10 nm to 200 nm, and still more preferably within a range of 10 nm to 100 nm. In a case where the actinic ray sensitive or radiation sensitive resin composition is applied by using a spinner, the rotation speed is typically 500 rpm to 3000 rpm, preferably 800 rpm to 2000 rpm, and more preferably 1000 rpm to 1500 rpm.

The heating (prebake) temperature is preferably 60° C. to 200° C., more preferably 80° C. to 150° C., and still more preferably 90° C. to 140° C.

Although the heating (prebake) time is not particularly limited, the heating (prebake) time is preferably 30 seconds to 300 seconds, more preferably 30 seconds to 180 seconds, and still more preferably 30 seconds to 90 seconds.

The heating can be typically performed by means provided in an exposure developing device, or may be performed using a hot plate or the like.

A commercially available inorganic or organic antireflection film can be used, as necessary. An antireflection film can also be further applied to the lower layer of the actinic ray sensitive or radiation sensitive resin composition and used. As the antireflection film, any type of an inorganic film type such as titanium, titanium dioxide, titanium nitride, chromium oxide, carbon, or amorphous silicon, and an organic film type formed of a light absorber and a polymer material can be used. In addition, as the organic antireflection film, a commercially available organic antireflection film such as DUV30 series or DUV-40 series manufactured by Brewer Science, Inc., or AR-2, AR-3, or AR-5 manufactured by Shipley Company, L.L.C. can also be used.

(2) Exposure Step

Exposure is performed by actinic ray or radiation. Examples of the actinic ray or the radiation include infrared light, visible light, ultraviolet light, far-ultraviolet light, X-rays, extreme ultraviolet rays (hereinafter, also referred to as “EUV light”), an electron beam (hereinafter, also referred to as “EB”). The actinic ray or the radiation, for example, more preferably has a wavelength of 250 nm or less, in particular, 220 nm or less. Examples of the actinic ray or the radiation include a KrF excimer laser (248 nm), an ArF excimer laser (193 nm), an F₂ excimer laser (157 nm), X-rays, extreme ultraviolet rays, and an electron beam. Preferable examples of the actinic ray or the radiation include a KrF excimer laser, an electron beam, X-rays, and EUV light. The actinic ray or the radiation is more preferably an electron beam, X-rays, or EUV light, and still more preferably an electron beam or EUV light.

(3) Baking Step

After exposure, baking (heating) is preferably performed before development is performed.

The heating temperature is preferably 60° C. to 150° C., more preferably 80° C. to 150° C., and still more preferably 90° C. to 140° C.

Although the heating time is not particularly limited, the heating time is preferably 30 seconds to 300 seconds, more preferably 30 seconds to 180 seconds, and still more preferably 30 seconds to 90 seconds.

The heating can be typically performed by means provided in an exposure developing device, or may be performed using a hot plate or the like.

The reaction of an exposed portion is promoted by baking, and the sensitivity or the pattern profile is improved. In addition, a heating step (Post Bake) is also preferably included after a rinsing step. The heating temperature and the heating time are as described above. By baking, the developer and the rinse liquid remaining between the patterns and in the patterns are removed.

(4) Development Step

In the present invention, development is performed by using a developer including an organic solvent.

Developer

The vapor pressure (total vapor pressure in the case of a mixed solvent) of the developer is preferably 5 kPa or lower, more preferably 3 kPa or lower, and particularly preferably 2 kPa or lower, at 20° C. It is thought that when the vapor pressure of the organic solvent is 5 kPa or lower, evaporation of the developer on the substrate or in a development cup is suppressed, the temperature evenness in the wafer surface is improved, and as a result, the dimensional evenness in the wafer surface is improved.

As the organic solvent used in the developer, various organic solvents are widely used, and, for example, solvents such as an ester-based solvent, a ketone-based solvent, an alcohol-based solvent, an amide-based solvent, an ether-based solvent, and a hydrocarbon-based solvent can be used.

In the present invention, the ester-based solvent refers to a solvent having an ester group in the molecule, the ketone-based solvent refers to a solvent having a ketone group in the molecule, the alcohol-based solvent refers to a solvent having an alcoholic hydroxyl group in the molecule, the amide-based solvent refers to a solvent having an amide group in the molecule, and the ether-based solvent refers to a solvent having an ether bond in the molecule. Among these, a solvent having a plurality types of functional groups described above in one molecule may also be present, but, in this case, it is assumed that the solvent also corresponds to any solvent type including the functional group which the solvent has. For example, it is assumed that diethylene glycol monomethyl ether also corresponds to any of the alcohol-based solvent, or the ether-based solvent, in the above classification. In addition, the hydrocarbon-based solvent is a hydrocarbon solvent having no substituent.

In particular, a developer containing at least one type of solvent selected from a ketone-based solvent, an ester-based solvent, an alcohol-based solvent, and an ether-based solvent is preferable.

Examples of the ester-based solvent can include methyl acetate, ethyl acetate, butyl acetate, pentyl acetate, isopropyl acetate, amyl acetate, isoamyl acetate, ethyl methoxyacetate, ethyl ethoxyacetate, propylene glycol monomethyl ether acetate (PGMEA; also referred to as 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate.

Examples of the ketone-based solvent can include 1-octanone, 2-octanone, 1-nonanone, 2-nonanone, acetone, 2-heptanone, 4-heptanone, 1-hexanone, 2-hexanone, diisobutyl ketone, cyclohexanone, methyl cyclohexanone, phenyl acetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, and γ-butyrolactone.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, and 3-methoxy-1-butanol, glycol-based solvents such as ethylene glycol, diethylene glycol, and triethylene glycol, and glycol ether-based solvents containing a hydroxyl group, such as ethylene glycol monomethyl ether, propylene glycol monomethyl ether (PGME; also referred to as 1-methoxy-2-propanol), diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, and propylene glycol monophenyl ether. Among these, glycol ether-based solvents are preferably used.

Examples of the ether-based solvent include glycol ether-based solvents having no hydroxyl group such as propylene glycol dimethyl ether, propylene glycol diethyl ether, diethylene glycol dimethyl ether, and diethylene glycol diethyl ether, aromatic ether solvents such as anisole and phenetole, dioxane, tetrahydrofuran, tetrahydropyran, perfluoro-2-butyltetrahydrofuran, perfluorotetrahydrofuran, and 1,4-dioxane, in addition to the glycol ether-based solvents containing a hydroxyl group. A glycol ether-based solvent or an aromatic ether solvent such as anisole is preferably used.

As the amide-based solvent, for example, N-methyl-2-pyrrolidone, N,N-dimethylacetamide, N,N-dimethylformamide, hexamethylphosphoric triamide, or 1,3-dimethyl-2-imidazolidinone can be used.

Examples of the hydrocarbon-based solvent include aliphatic hydrocarbon-based solvents such as pentane, hexane, octane, decane, 2,2,4-trimethylpentane, 2,2,3-trimethylhexane, perfluorohexane, and perfluoroheptane, and aromatic hydrocarbon-based solvents such as toluene, xylene, ethyl benzene, propyl benzene, 1-methylpropyl benzene, 2-methylpropyl benzene, dimethyl benzene, diethyl benzene, ethylmethyl benzene, trimethyl benzene, ethyldimethyl benzene, and dipropyl benzene. Among these, aromatic hydrocarbon-based solvents are preferable.

A plurality of the solvents described above may be used in combination, or the solvent may be used in combination with a solvent other than the solvents described above or water. Here, in order to exhibit the effects of the present invention, the water content of the entirety of the developer is preferably less than 10% by mass, and the developer more preferably substantially does not contain water.

The concentration of the organic solvent (sum total content in a case where a plurality of solvents are mixed together) in the developer is preferably 50% by mass or greater, more preferably 70% by mass or greater, and still more preferably 90% by mass or greater. A case where the developer is formed of substantially only an organic solvent is particularly preferable. Moreover, a case where the developer is formed of substantially only an organic solvent includes a case where trace amounts of surfactant, antioxidant, stabilizer, or anti-foaming agent are contained.

Among the above-described solvents, the developer more preferably contains one or more types selected from the group consisting of butyl acetate, pentyl acetate, isopentyl acetate, propylene glycol monomethyl ether acetate, 2-heptanone, and anisole.

As the organic solvent used as the developer, an ester-based solvent can also be suitably exemplified.

As the ester-based solvent, a solvent represented by General Formula (S1) described below or a solvent represented by General Formula (S2) described below is more preferably used, the solvent represented by General Formula (S1) is still more preferably used, an alkyl acetate is particularly preferably used, and butyl acetate, pentyl acetate, or isopentyl acetate is most preferably used.

R—C(═O)—O—R′ General Formula (S1)

In General Formula (S1), each of R and R′ independently represents a hydrogen atom, an alkyl group, a cycloalkyl group, an alkoxyl group, an alkoxycarbonyl group, a carboxyl group, a hydroxyl group, a cyano group, or a halogen atom. R and R′ may be bonded to each other to form a ring.

Each of the alkyl group, the alkoxyl group, and the alkoxycarbonyl group represented by each of R and R′ preferably has 1 to 15 carbon atoms, and the cycloalkyl group represented by each of R and R′ preferably has 3 to 15 carbon atoms.

Each of R and R′ is preferably a hydrogen atom or an alkyl group, and the alkyl group, the cycloalkyl group, the alkoxyl group, and the alkoxycarbonyl group represented by each of R and R′, and a ring formed by bonding of R and R′ to each other may be substituted with a hydroxyl group, a group including a carbonyl group (for example, an acyl group, an aldehyde group, or an alkoxycarbonyl group), or a cyano group.

Examples of the solvent represented by General Formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, and ethyl 2-hydroxy propionate.

Among these, a solvent in which R and R′ are unsubstituted alkyl groups is preferable.

As the solvent represented by General Formula (S1), an alkyl acetate is preferable, and butyl acetate, pentyl acetate, or isopentyl acetate is more preferable.

The solvent represented by General Formula (S1) may be used in combination with one or more other types of organic solvents. The solvent used in combination in this case is not particularly limited as long as it can be mixed in without being separating from the solvent represented by General Formula (S1), the solvents represented by General Formula (S1) may be used in combination with each other, or a solvent represented by General Formula (S1) may be used by being mixed with a solvent selected from other ester-based solvents, ketone-based solvents, alcohol-based solvents, amide-based solvents, ether-based solvents, and hydrocarbon-based solvents. One or more solvents can be used in combination, but one solvent is preferably used in combination in order to obtain a stable performance. The mixing ratio between the solvent represented by General Formula (S1) and a solvent used in combination in a case where one solvent is used in combination by being mixed is typically 20:80 to 99:1, preferably 50:50 to 97:3, more preferably 60:40 to 95:5, and most preferably 60:40 to 90:10, in terms of a mass ratio.

R″—C(═O)—O—R′″—O—R″″ General Formula (S2)

In General Formula (S2), each of R″ and R′″ independently represents a hydrogen atom, an alkyl group, a cycloalkyl group, an alkoxyl group, an alkoxycarbonyl group, a carboxyl group, a hydroxyl group, a cyano group, or a halogen atom. R″ and R″″ may be bonded to each other to form a ring.

Each of R″ and R″″ is preferably a hydrogen atom or an alkyl group. Each of the alkyl group, the alkoxyl group, and the alkoxycarbonyl group represented by each of R″ and R″″ preferably has 1 to 15 carbon atoms, and the cycloalkyl group represented by each of R″ and R″″ preferably has 3 to 15 carbon atoms.

R′″ represents an alkylene group or a cycloalkylene group. R′″ is preferably an alkylene group. The alkyl group represented by R′″ preferably has 1 to 10 carbon atoms. The cycloalkyl group represented by to R′″ preferably has 3 to 10 carbon atoms.

The alkyl group, the cycloalkyl group, the alkoxyl group, and the alkoxycarbonyl group represented by each of R″ and R″″, the alkylene group and the cycloalkylene group represented by R′″, and a ring formed by bonding of R″ and R″″ to each other may be substituted with a hydroxyl group, a group including a carbonyl group (for example, an acyl group, an aldehyde group, or an alkoxycarbonyl group), or a cyano group.

In General Formula (S2), the alkylene group represented by R′″ may have an ether bond in the alkylene chain.

Examples of the solvent represented by General Formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol monopropyl ether acetate, methyl-3-methoxypropionate, ethyl-3-methoxypropionate, ethyl-3-ethoxypropionate, propyl-3-methoxypropionate, ethyl methoxyacetate, ethyl ethoxyacetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, and 4-methyl-4-methoxypentyl acetate, and propylene glycol monomethyl ether acetate is preferable.

Among these, it is preferable that each of R″ and R″″ is an unsubstituted alkyl group and R′″ is an unsubstituted alkylene group, each of R″ and R″″ is more preferably either a methyl group or an ethyl group, and each of R″ and R″″ is still more preferably a methyl group.

The solvent represented by General Formula (S2) may be used in combination with one or more types of other organic solvents. The solvent used in combination in this case is not particularly limited as long as it can be mixed in without being separating from the solvent represented by General Formula (S2), the solvents represented by General Formula (S2) may be used in combination with each other, or a solvent represented by General Formula (S2) may be used by being mixed with a solvent selected from other ester-based solvents, ketone-based solvents, alcohol-based solvents, amide-based solvents, ether-based solvents, and hydrocarbon-based solvents. One or more solvents can be used in combination, but one solvent is preferably used in combination in order to obtain a stable performance. The mixing ratio between the solvent represented by General Formula (S2) and a solvent in a case where one solvent is used in combination by being mixed is typically 20:80 to 99:1, preferably 50:50 to 97:3, more preferably 60:40 to 95:5, and most preferably 60:40 to 90:10, in terms of a mass ratio.

In addition, as the organic solvent used as a developer, an ether-based solvent can also be suitably exemplified.

As the ether-based solvent which can be suitably used, the ether-based solvents described above are exemplified, and among these, an ether-based solvent including one or more aromatic rings is preferable, a solvent represented by the following General Formula (S3) is more preferable, and anisole is most preferable.

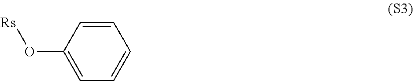

In General Formula (S3), R_{S} represents an alkyl group. An alkyl group having 1 to 4 carbon atoms is preferable, a methyl group or an ethyl group is more preferable, and a methyl group is most preferable.

In the present invention, the water content of the developer is typically 10% by mass or less, preferably 5% by mass or less, more preferably 1% by mass or less, and most preferably substantially no water is contained.

Surfactant

A suitable amount of surfactant can be contained to the developer including an organic solvent, as necessary.

As the surfactant, the same surfactant as that used in the actinic ray sensitive or radiation sensitive resin composition described below can be used.

The amount of the surfactant used is typically 0.001% by mass to 5% by mass, preferably 0.005% by mass to 2% by mass, and more preferably 0.01% by mass to 0.5% by mass, with respect to the total amount of developer.

Basic Compound

The developer including an organic solvent may include a basic compound. Specific examples and preferable examples of the basic compound which can be included in the developer used in the present invention include the same as those of the basic compound which can be included in the actinic ray sensitive or radiation sensitive resin composition.

Developing Method

As the developing method, a method in which a substrate is dipped in a bath filled with a developer for a predetermined period of time (dipping method), a method in which developing is performed by placing a developer on the substrate surface using surface tension and this being held stationary for a predetermined period of time (puddle method), a method in which a developer is sprayed onto a substrate surface (spray method), or a method in which a substrate is spun at a constant rate, and a developer discharge nozzle is then scanned across the substrate at a constant rate while a developer is discharged continuously on the substrate from the nozzle (dynamic dispensing method) can be applied.

In addition, after a step of performing development, while replacing with another solvent, a step of stopping the development may be performed.

The development time is not particularly limited as long as it is a period of time during which the resin of the unexposed portion is sufficiently dissolved, is typically 10 seconds to 300 seconds, and is preferably 20 seconds to 120 seconds. The temperature of the developer is preferably 0° C. to 50° C., and more preferably 15° C. to 35° C.

(5) Rinsing Step

The pattern forming method according to the present invention may include Step (5) of washing using a rinse liquid including an organic solvent after Development Step (4), but preferably does not include the rinsing step from the viewpoint of throughput or amount of rinse liquid used.

Rinse Liquid

The vapor pressure (total vapor pressure in the case of a mixed solvent) of the rinse liquid used after development is preferably 0.05 kPa to 5 kPa, more preferably 0.1 kPa to 5 kPa, and most preferably 0.12 kPa to 3 kPa, at 20° C. When the vapor pressure of the rinse liquid is 0.05 kPa to 5 kPa, the temperature evenness in the wafer surface is improved, swelling due to penetration of the rinse liquid is suppressed, and the dimensional evenness in the wafer surface is improved.

As the rinse liquid, various organic solvents are used, but a rinse liquid containing at least one type of organic solvent selected from a hydrocarbon-based solvent, a ketone-based solvent, an ester-based solvent, an alcohol-based solvent, an amide-based solvent, and an ether-based solvent, or water is preferably used.

More preferably, after development, a step of washing is performed using a rinse liquid including at least one type of organic solvent selected from a ketone-based solvent, an ester-based solvent, an alcohol-based solvent, an amide-based solvent, and a hydrocarbon-based solvent. Still more preferably, after development, a step of washing is performed using a rinse liquid containing an alcohol-based solvent or a hydrocarbon-based solvent.

Particularly preferably, a rinse liquid containing at least one or more types selected from the group consisting of monohydric alcohols and hydrocarbon-based solvents is used.

Here, as the monohydric alcohol used in the rinsing step after the development, linear, branched, or cyclic monohydric alcohols are exemplified, and specifically, 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dithyl-2-hexal, 6-methyl-2-heptanol, 7-methyl-2-octanol, 8-methyl-2-nonal, or 9-methyl-2-decanol can be used, and 1-hexanol, 2-hexanol, 1-pentanol, 3-methyl-1-butanol, 3-methyl-2-pentanol, 3-methyl-3-pentanol, 4-methyl-2-pentanol, or 4-methyl-3-pentanol is preferable, and 1-hexanol or 4-methyl-2-pentanol is most preferable.

Examples of the hydrocarbon-based solvent include aromatic hydrocarbon-based solvents such as toluene and xylene, and aliphatic hydrocarbon-based solvents such as octane and decane.

The rinse liquid more preferably contain one or more types selected from the group consisting of 1-hexanol, 4-methyl-2-pentanol, and decane.

A plurality of the respective components described above may be used in combination, or the respective components may be used in combination with a solvent other than the solvents described above. The solvents described above may be mixed with water, and the water content in the rinse liquid is typically 60% by mass or less, preferably 30% by mass or less, more preferably 10% by mass or less, and most preferably 5% by mass or less. When the water content is 60% by mass or less, good rinsing properties can be obtained.

A suitable amount of a surfactant can also be added to the rinse liquid and used.

As the surfactant, the same surfactant as that used in the actinic ray sensitive or radiation sensitive resin composition described below can be used, and the amount used is typically 0.001% by mass to 5% by mass, preferably 0.005% by mass to 2% by mass, and more preferably 0.01% by mass to 0.5% by mass, with respect to the total amount of rinse liquid.

Rinsing Method

In the rinsing step, the developed wafer is subjected to a washing treatment using the rinse liquid including an organic solvent.

The method of washing treatment is not particularly limited, and, for example, a method in which a rinse liquid is discharged continuously onto a substrate while the substrate is spun at a constant rate (spin discharging method), a method in which a substrate is dipped in a bath filled with a rinse liquid for a predetermined period of time (dipping method), or a method in which a rinse liquid is sprayed onto a substrate surface (spray method) can be suitably used, and among these, it is preferable that a washing treatment is performed by the spin discharging method, and, after washing, a rinse liquid is removed from the substrate by rotating the substrate at a rotation speed of 2000 rpm to 4000 rpm.

Although the rinsing time is not particularly limited, the rinsing time is typically 10 seconds to 300 seconds, 10 seconds to 180 seconds, and most preferably 20 seconds to 120 seconds.

The temperature of the rinse liquid is preferably 0° C. to 50° C., and more preferably 15° C. to 35° C.

After the development treatment or the rinse treatment, a treatment of removing the developer or rinse liquid adhered to the pattern by a supercritical fluid can be performed.

After the development treatment, the rinse treatment, and the treatment by a supercritical fluid, a heat treatment can also be performed to remove the solvent remaining in the pattern. The heating temperature is not particularly limited as long as a good resist pattern is obtained, and is typically 40° C. to 160° C. The heating temperature is preferably 50° C. to 150° C., and most preferably 50° C. to 110° C. The heating time is not particularly limited as long as a good resist pattern is obtained, and is typically 15 seconds to 300 seconds, and is preferably 15 seconds to 180 seconds.

Alkali Development

The pattern forming method of the present invention can further include a step (alkali development step) of forming a resist pattern by performing development using an alkali aqueous solution. Thus, a finer pattern can be formed.

In the present invention, a portion having weak exposure intensity is removed in an organic solvent development step (4), and a portion having strong exposure intensity is also removed by performing the alkali development step. Since pattern formation is performed without dissolving only a region having intermediate exposure intensity by the multiple development process performing development multiple times in this manner, a finer pattern than usual can be formed (the same mechanism as that in paragraph “0077” of JP2008-292975A).

Although the alkali development can be performed either before or after Step (4) of developing using a developer including an organic solvent, the alkali development is more preferably performed before the organic solvent development step (4).

As the alkali developer, for example, alkaline aqueous solutions such as inorganic alkalies including sodium hydroxide, potassium hydroxide, sodium carbonate, sodium silicate, sodium metasilicate, and ammonia water, primary amines including ethylamine and n-propylamine, secondary amines including diethylamine and di-n-butylamine, tertiary amines including triethylamine and methyldiethylamine, alcohol amines including dimethyl ethanolamine and triethanolamine, tetraalkylammonium hydroxides including tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salts including trimethylphenylammonium hydroxide, trimethylbenzylammonium hydroxide, and triethylbenzylammonium hydroxide, and cyclic amines including pyrrole and piperidine can be used. A suitable amount of an alcohol or a surfactant can also be added to the alkaline aqueous solution and used. The alkali concentration of the alkali developer is typically 0.1% by mass to 20% by mass. The pH of the alkali developer is typically 10.0 to 15.0. The alkali concentration and the pH of the alkali developer can be suitably prepared and used. A surfactant or an organic solvent may be added to the alkali developer and used.

After development using an alkali aqueous solution, a rinse treatment can be performed. As the rinse liquid in the rinse treatment, pure water is preferable, and a suitable amount of surfactant can also be added and used.

After the development treatment or the rinse treatment, a heat treatment can also be performed in order to remove water remaining in the pattern.

In addition, by heating, a treatment for removing the remaining developer or rinse liquid can be performed. The heating temperature is not particularly limited as long as a good resist pattern is obtained, and is typically 40° C. to 160° C. The heating temperature is preferably 50° C. to 150° C., and most preferably 50° C. to 110° C. The heating time is not particularly limited as long as a good resist pattern is obtained, and is typically 15 seconds to 300 seconds, and preferably 15 seconds to 180 seconds.

When the film formed of the resist composition according to the present invention is irradiated with actinic ray or radiation, exposure (immersion exposure) may be performed in a state of being filled with liquid (immersion medium) having a higher refractive index than the air between a film and a lens. Thus, the resolution can be increased. Although the immersion medium used is not particularly limited as long as it is liquid having a higher refractive index than air, pure water is preferable.

When the film formed of the resist composition according to the present invention is irradiated with actinic ray or radiation, exposure (immersion exposure) may be performed in a state of being filled with liquid (immersion medium) having a higher refractive index than the air between a film and a lens. Thus, the resolution can be increased. Although the immersion medium used is not particularly limited as long as it is liquid having a higher refractive index than air, pure water is preferable.

Regarding the immersion liquid used when liquid immersion exposure is performed, the description in paragraphs “0059’ and “0060” of JP2013-76991A can be referred to, and the contents thereof are incorporated in the present specification.

A film poorly soluble in an immersion liquid (hereinafter, also referred to as “topcoat”) may be provided between the film formed of the composition of the present invention and the immersion liquid such that the film does not come into contact with the immersion liquid. Functions required for the topcoat are coating suitability to the upper layer portion of a composition film and poor solubility in an immersion liquid. The topcoat is preferably a topcoat which does not mix the composition film, and can be evenly applied to the upper layer of the composition film.

Regarding the topcoat, the description in paragraphs “0061” and “0062” of JP2013-76991A can be referred to, and the contents thereof are incorporated in the present specification.

On the other hand, when EUV exposure or EB exposure is performed, for the purpose of suppression of outgassing, suppression of blob defects, prevention of perpendicularity deterioration due to reverse taper shape improvement, prevention of LWR deterioration due to surface roughness, and the like, a topcoat layer may be formed on the upper layer of a resist film formed of the actinic ray sensitive or radiation sensitive resin composition of the present invention. The topcoat composition used in formation of a topcoat layer will be described below.

The solvent of the topcoat composition in the present invention is preferably water or an organic solvent. Water or an alcohol-based solvent is more preferable.

In a case where the solvent is an organic solvent, the solvent is preferably a solvent which does not dissolve a resist film. As a solvent capable of being used, an alcohol-based solvent, a fluorine-based solvent, or a hydrocarbon-based solvent is preferably used, and an alcohol-based solvent which is nonfluorine-based is more preferably used. As the alcohol-based solvent, a primary alcohol is preferable, and a primary alcohol having 4 to 8 carbon atoms is more preferable, form the viewpoint of coating properties. Although a linear, a branched, or a cyclic alcohol can be used as a primary alcohol having 4 to 8 carbon atoms, a linear or a branched alcohol is preferable. Specific examples thereof include 1-butanol, 1-hexanol, 1-pentanol, and 3-methyl-1-butanol.

In a case where the solvent of the topcoat composition in the present invention is water or an alcohol-based solvent, the solvent preferably contains a water-soluble resin. It is considered that the evenness of solubility in a developer can be enhanced when the solvent contains a water-soluble resin. Examples of preferable water-soluble resins include polyacrylic acid, polymethacrylic acid, polyhydroxystyrene, polyvinyl pyrrolidone, polyvinyl alcohol, polyvinyl ether, polyvinyl acetal, polyacrylic imide, polyethylene glycol, polyethylene oxide, polyethylene imine, polyester polyol, polyether polyol, and polysaccharides. Polyacrylic acid, polymethacrylic acid, polyhydroxystyrene, polyvinyl pyrrolidone, or polyvinyl alcohol is particularly preferable. Moreover, the water-soluble resin is not limited only to a homopolymer, and may be a copolymer. For example, the water-soluble resin may be a copolymer which has a monomer corresponding to the repeating unit of the homopolymer described above and another monomer unit. Specifically, an acrylic acid-methacrylic acid copolymer or an acrylic acid-hydroxystyrene copolymer can also be used in the present invention.

In addition, as the resin for the topcoat composition, a resin having an acidic group described in JP2009-134177A or JP2009-91798A can also be preferably used.

Although the weight average molecular weight of the water-soluble resin is not particularly limited, the weight average molecular weight is preferably 2000 to 1000000, more preferably 5000 to 500000, and particularly preferably 10000 to 100000. Here, the weight average molecular weight of a resin is a molecular weight in terms of polystyrene measured by using GPC (carrier: THF or N-methyl-2-pyrrolidone (NMP)).

Although the pH of the topcoat composition is not particularly limited, the pH is preferably 0 to 10, more preferably 0 to 8, and particularly preferably 1 to 7.

In a case where the solvent of the topcoat composition is an organic solvent, the topcoat composition may contain a hydrophobic resin as the hydrophobic resin (HR) to be described in the section of the actinic ray sensitive or radiation sensitive resin composition. As the hydrophobic resin, the hydrophobic resin described in JP2008-209889A is also preferably used.

The concentration of the resin in the topcoat composition is preferably 0.1% by mass to 10% by mass, more preferably 0.2% by mass to 5% by mass, and particularly preferably 0.3% by mass to 3% by mass.

The topcoat material may include components other than a resin, and the proportion of the resin in the solid content of the topcoat composition is preferably 80% by mass to 100% by mass, more preferably 90% by mass to 100% by mass, and particularly preferably 95% by mass to 100% by mass.

The solid content concentration of the topcoat composition in the present invention is preferably 0.1% by mass to 10% by mass, more preferably 0.2% by mass to 6% by mass, and particularly preferably 0.3% by mass to 5% by mass. When the solid content concentration is within the above range, the topcoat composition can be evenly applied to a resist film.

Examples of components other than resins capable of being added to the topcoat material include a surfactant, a photoacid generator, and a basic compound. Specific examples of the photoacid generator and the basic compound include the same compounds as compounds that generate an acid by irradiation with actinic ray or radiation and the basic compounds described above.

In a case where a surfactant is used, the amount of the surfactant used is preferably 0.0001% by mass to 2% by mass, and more preferably 0.001% by mass to 1% by mass, with respect to the total amount of the topcoat composition.

When a surfactant is added to the topcoat composition, coating properties in a case of applying the topcoat composition can be improved. Examples of the surfactant include nonionic, anionic, cationic, and amphoteric surfactants.

As the nonionic surfactant, Plufarac series manufactured by BASF Corp., ELEBASE series, FINESURF series, or BLAUNON series, manufactured by Aoki Oil Industrial Co., Ltd., Adeka Pluronic P-103 manufactured by Adeka Corporation, EMULGEN series, AMIET series, AMINON PK-02S, EMANON CH-25, or RHEODOL series, manufactured by Kao Chemical Co., SURFLON S-141 manufactured by AGC SEIMI CHEMICAL CO., LTD., NOIGEN series manufactured by Dai-ichi Kogyo Seiyaku Co., Ltd., NEWKALGEN series manufactured by TAKEMOTO OIL & FAT Co., Ltd., DYNOL 604, EnviroGem AD01, OLFINE EXP series, and Surfynol series, manufactured by Nissin Chemical Industry Co., Ltd., FTERGENT 300 manufactured by Ryoko Chemical Co., Ltd., or the like can be used.

As the anionic surfactant, EMAL 20T or POIZ 532A manufactured by Kao Chemical Co., Phosphanol ML-200 manufactured by Toho Chemical Industry Co., Ltd., EMULSOGEN series manufactured by Clariant Japan KK, SURFLON S-111N or SURFLON S-211 manufactured by AGC SEIMI CHEMICAL CO., LTD., PLYSURF series manufactured by Dai-ichi Kogyo Seiyaku Co., Ltd., PIONIN Series manufactured by TAKEMOTO OIL & FAT Co., Ltd., OLFINE PD-201 or Olfine PD-202 manufactured by Nissin Chemical Industry Co., Ltd., AKYPO RLM45 or ECT-3 manufactured by Nihon Surfactant Kogyo K.K., LIPON manufactured by Lion Corporation, or the like can be used.

As the cationic surfactant, ACETAMIN 24, and ACETAMIN 86 manufactured by Kao Chemical Co., or the like can be used.

As the amphoteric surfactant, SURFLON S-131 (manufactured by AGC SEIMI CHEMICAL CO., LTD.), ENADICOL C-40H or Lipomin LA (all manufactured by Kao Chemical Co., Ltd.), or the like can be used.

In addition, there surfactants can also be used in combination.

In the pattern forming method of the present invention, a resist film can be formed on a substrate by using the actinic ray sensitive or radiation sensitive resin composition, and a topcoat layer can be formed on the resist film using the topcoat composition described above. The film thickness of the resist film is preferably 10 nm to 100 nm, and the film thickness of the topcoat layer is preferably 10 nm to 200 nm, more preferably 20 nm to 100 nm, and particularly preferably 40 nm to 80 nm.

As a method of applying the actinic ray sensitive or radiation sensitive resin composition to the substrate, spin coating is preferable, and the rotation speed thereof is preferably 1000 to 3000 rpm.

For example, a resist film is formed by applying the actinic ray sensitive or radiation sensitive resin composition to a substrate (example: silicon/silicon dioxide coating) which is used in manufacture of precision integrated circuit elements by using a suitable coating method such as with a spinner or a coater and drying the resultant product. Moreover, a known antireflection film can also be applied in advance. In addition, the resist film is preferably dried before formation of a topcoat layer.

Next, a topcoat layer can be formed by applying a topcoat composition to the obtained resist film by the same means as that in the resist film forming method and by drying the resultant product.

Development is performed by irradiating a resist film having a topcoat layer on the upper layer with an electron beam (EB), X-rays, or EUV light typically through a mask and by, preferably, baking (heating) the resultant product. Thus, a good pattern can be obtained.

In addition, the present invention also relates to a method for manufacturing an electronic device including the pattern forming method of the present invention described above and an electronic device manufactured by the manufacturing method.

The electronic device of the present invention is suitably mounted on electrical and electronic equipment (home electrical appliances, OA and media-related equipment, optical equipment, communication equipment, or the like).

[Actinic Ray Sensitive or Radiation Sensitive Resin Composition]

The actinic ray sensitive or radiation sensitive resin composition used in the pattern forming method of the present invention will be described below.

The actinic ray sensitive or radiation sensitive resin composition according to the present invention is used in negative type development (development in which, when exposed, solubility is decreased with respect to a developer, the exposed portion remains as a pattern, and the unexposed portion is removed). That is, the actinic ray sensitive or radiation sensitive resin composition according to the present invention can be used as an actinic ray sensitive or radiation sensitive resin composition for organic solvent development used in development using a developer including an organic solvent. Here, “for organic solvent development” means an application to be subjected to a step of developing using a developer including at least an organic solvent.

Thus, the present invention also relates to the actinic ray sensitive or radiation sensitive resin composition which is provided to the pattern forming method according to the present invention described above.

The actinic ray sensitive or radiation sensitive resin composition of the present invention is typically a resist composition, and a negative resist composition (that is, resist composition for organic solvent development) is preferable since particularly significant effects can be obtained. The composition according to the present invention is typically a chemical amplification resist composition.

[1] Resin (Ab) Having Repeating Unit Represented by General Formula (Ab1)

The composition used in the present invention contains a resin (Ab) having a repeating unit represented by the following General Formula (Ab1).

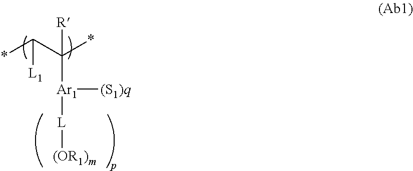

In General Formula (Ab1), R′ represents a hydrogen atom, an alkyl group, or a halogen atom.

L₁ represents a hydrogen atom or an alkyl group, and L₁ and Ar₁ may be connected to each other to form a ring, and in this case, L₁ represents an alkylene group.

Ar₁ represents a (p+q+1) valent aromatic ring group.

L represents an (m+1) valent connecting group.

S₁ represents an organic group,

OR₁ represents a group which generates an alcoholic hydroxyl group by being decomposed due to the action of an acid.

In a case where a plurality of S₁'s, L's, and R₁'s are present, the plurality of S₁'s, L's, or R₁'s may be the same or different, respectively, and the plurality of R₁'s may be bonded to each other to form a ring.

m represents an integer of 1 or greater.

p represents an integer of 1 or greater, and q represents an integer of 0 or greater.

In General Formula (Ab1), the alkyl group represented by R′ is preferably an alkyl group having 1 to 10 carbon atoms, more preferably an alkyl group having 1 to 5 carbon atoms, still more preferably an alkyl group having 1 to 3 carbon atoms, and particularly preferably an alkyl group having 1 or 2 carbon atoms (that is, a methyl group or an ethyl group). Specific examples of the alkyl group represented by R′ can include a methyl group, an ethyl group, an n-propyl group, an isopropyl group, an n-butyl group, an isobutyl group, a sec-butyl group, and a t-butyl group.

The halogen atom represented by R′ is preferably fluorine, bromine, or iodine, and more preferably a fluorine atom.

R′ is preferably a hydrogen atom or an alkyl group, and more preferably a hydrogen atom.

The alkyl group represented by L₁ may have a substituent (preferably, a fluorine atom), is preferably a substituent having 1 to 5 carbon atoms, more preferably a substituent having 1 to 3 carbon atoms, and still more preferably a methyl group.

L₁ is preferably a hydrogen atom or a methyl group, and more preferably a hydrogen atom.

The alkylene group represented by L₁ in a case where L₁ and L are bonded to each other to form a ring is preferably an alkyl group having 1 to 3 carbon atoms, and more preferably an alkyl group having 1 or 2 carbon atoms.

Preferable examples of the (p+q+1) valent aromatic ring represented by Ar₁ can include aromatic ring groups having 6 to 18 carbon atoms (more preferably, 6 to 12 carbon atoms) such as a benzene ring and a naphthalene ring, and aromatic rings including a heteroring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring, and the aromatic ring is more preferably a benzene ring, a biphenyl ring, or a naphthalene ring, and still more preferably a benzene ring.

In a case where m is 1, examples of the (m+1) valent connecting group represented by L include an alkylene group, a divalent aromatic ring group, a cycloalkylene group, —COO-L′-, L′—O—, —O-L′-, —CONH—, and a group formed by combining two or more thereof. Here, L₁′ represents an alkylene group (preferably having 1 to 20 carbon atoms), a cycloalkylene group (preferably having 3 to 20 carbon atoms), a divalent aromatic ring group, or a divalent connecting group obtained by combining an alkylene group and a divalent aromatic ring group.

Preferable examples of the alkylene group represented by L include alkylene groups having 1 to 8 carbon atoms such as a methylene group, an ethylene group, a propylene group, a butylene group, a hexylene group, and an octylene group. The alkylene group more preferably has 1 to 4 carbon atoms, and particularly preferably has 1 or 2 carbon atoms.

The cycloalkylene group represented by L is preferably a cycloalkylene group having 3 to 20 carbon atoms, and examples thereof include a cyclopropylene group, a cyclobutylene group, a cyclopentylene group, a cyclohexylene group, a cycloheptylene group, a cyclooctylene group, a norbornylene group, and an adamantylene group, and an adamantylene group is more preferable.

Preferable examples of the aromatic ring group represented by L can include aromatic ring groups having 6 to 18 carbon atoms (more preferably, 6 to 10 carbon atoms) such as a benzene ring and a naphthalene ring, and aromatic ring groups including a heteroring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring, and the aromatic ring group is particularly preferably a benzene ring group.

In a case where L represents a divalent aromatic ring group, L is connected to (OR₁)ₘ through an alkylene group or a cycloalkylene group. Specific examples and the preferable ranges of the alkylene group and the cycloalkylene group are the same as those for the alkylene group and the cycloalkylene group represented by L described above.

The definitions and the preferable ranges of the alkylene group, the cycloalkylene group, and the divalent aromatic ring group represented by L′ are the same as those for the alkylene group, the cycloalkylene group, and the divalent aromatic ring group represented by L.

The definitions and the preferable ranges of the alkylene group and the divalent aromatic group in a group obtained by combining the alkylene group and the divalent aromatic ring group represented by L′ are the same as those for the alkylene group and the divalent aromatic ring group represented by L described above.

L is preferably a group represented by —COO-L′-, -L′-O—, or —O-L′-.

In a case where m is 2 or greater, examples of the (m+1) valent connecting group represented by L can include a group obtained by excluding an arbitrary (m−1) hydrogen atoms from the divalent connecting group described above.

In the repeating unit represented by General Formula (Ab1), -L-(OR₁)ₘ is preferably a group represented by —La-Lb-(OR₁)ₘ. La represents a single bond or a divalent connecting group, and Lb represents an (m+1) valent hydrocarbon group. In a case where m is 1, Lb preferably represents an alkylene group, a cycloalkylene group, or a group formed by combining two or more thereof, and in a case where m is 2 or greater, Lb preferably represents a group obtained by excluding an arbitrary (m−1) hydrogen atoms from the connecting group described above.

Specific examples and preferable examples of the divalent connecting group represented by La are the same as those for the divalent connecting group represented by L described above.

The alkylene group represented by Lb is the same as that in the alkylene group represented by L described above.

The cycloalkylene group represented by Lb is the same as that in the cycloalkylene group represented by L described above.

In the repeating unit represented by General Formula (Ab1), a plurality of (0120's in -Lb-(OR₁)ₘ are preferably bonded to each other to form a group represented by the following General Formula (Ab1′-a).

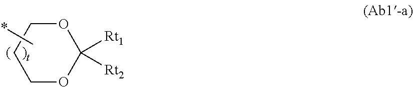

In General Formula (Ab1′-a), * represents a direct bond which is connected to —La— described above.

Each of Rt₁ and Rt₂ independently represents a hydrogen atom or a substituent, and Rt₁ and Rt₂ may be bonded to each other to form a ring.

t represents an integer of 0 to 3.

Each of Rt₁ and Rt₂ preferably represents a hydrogen atom or an alkyl group, and more preferably represents a hydrogen atom or an alkyl group having 1 to 3 carbon atoms. In a case where Rt₁ and Rt₂ are bonded to each other to form a ring, the formed ring may be any one of a polycycle, a monocycle, and a spiro ring, and each of Rt₁ and Rt₂ preferably represents an alkylene group, and more preferably represents an alkylene group having 2 to 5 carbon atoms.

t represents an integer of 0 to 3, and preferably represents 0 or 1.

Specific examples of the group which is represented by —La-Lb-(OR₁)ₘ and formed by bonding of a plurality of (OR₁)'s in Lb-(OR₁)ₘ to each other will be shown below, but the present invention is not limited thereto. * represents a direct bond which is connected to —La— described above.

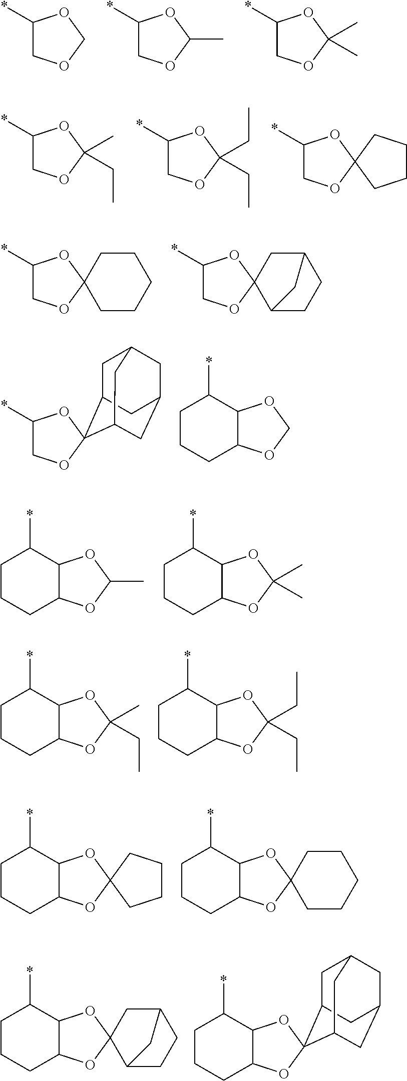

Examples of the organic group represented by S₁ include an alkyl group, an alkoxy group, a cycloalkyl group, an aryl group, an alkynyl group, a carbonyl group, a carbonyloxy group, and an alkenyl group.

Specific examples and preferable examples of the alkyl group as an organic group and the alkyl group included in the alkoxy group are the same as those for the alkyl group represented by L₁ described above.

The cycloalkyl group as an organic group may be monocyclic or polycyclic, and is preferably a cycloalkyl group having 3 to 15 carbon atoms, more preferably a cycloalkyl group having 3 to 10 carbon atoms, and still more preferably a cycloalkyl group having 3 to 6 carbon atoms. Specific examples of the cycloalkyl group can include a cyclopropyl group, a cyclobutyl group, a cyclopentyl group, a cyclohexyl group, a cycloheptyl group, a cyclooctyl group, a decahydronaphthyl group, a cyclodecyl group, a 1-adamantyl group, a 2-adamantyl group, a 1-norbornyl group, and 2-norbornyl group. The cycloalkyl group is preferably a cyclopropyl group, a cyclopentyl group, or a cyclohexyl group.

The aryl group as an organic group is preferably an aryl group having 6 to 15 carbon atoms, more preferably an aryl group having 6 to 12 carbon atoms, and also includes a structure (for example, a biphenyl group or a terphenyl group) in which a plurality of aromatic rings are connected to each other through a single bond. Specific examples of the aryl group include a phenyl group, a naphthyl group, an anthranyl group, a biphenyl group, and a terphenyl group. The aryl group is preferably a phenyl group, a naphthyl group, or a biphenyl group.

As the alkenyl group as an organic group, alkenyl groups having 2 to 5 carbon atoms such as a vinyl group, a propenyl group, and an allyl group can be exemplified.

As the alkynyl group as an organic group, alkynyl groups having 2 to 5 carbon atoms such as an ethynyl group, a propynyl group, and a butynyl group can be exemplified.

S₁ is preferably an alkyl group, an alkoxy group, a carbonyl group, or a carbonyloxy group, and more preferably an alkyl group or an alkoxy group.

OR₁ represents a group which generates an alcoholic hydroxyl group by being decomposed due to the action of an acid.

Here, the alcoholic hydroxyl group is a hydroxyl group bonded to a hydrocarbon group, and is not limited as long as it is a hydroxyl group other than a hydroxyl group directly bonded to an aromatic ring (phenolic hydroxyl group).

The alcoholic hydroxyl group is preferably a hydroxyl group other than a hydroxyl group in an aliphatic alcohol in which the α position carbon (carbon atom to which a hydroxyl group is bonded) is substituted with an electron-withdrawing group (a halogen atom, a cyano group, a nitro group, or the like). The hydroxyl group is preferably a primary alcoholic hydroxyl group (a group in which the carbon atom substituted with a hydroxyl group has two hydrogen atoms separately from the hydroxyl group) or a secondary alcoholic hydroxyl group in which another electron-withdrawing group is not bonded to the carbon atom substituted with a hydroxyl group.

R₁ represents a group leaving due to the action of an acid.

As the group leaving due to the action of an acid, represented by R₁, —C(R₃₆)(R₃₇)(R₃₈), —C(R₃₆)(R₃₇)(OR₃₉), and —C(R₀₁)(R₀₂)(OR₃₉) are also suitably exemplified.

In the formula, each of R₃₆ to R₃₉ independently represents an alkyl group, a cycloalkyl group, an aryl group, an aralkyl group, or an alkenyl group. R₃₆ and R₃₇ may be bonded to each other to form a ring.

In the formula, each of R₀₁ to R₀₂ independently represents a hydrogen atom, an alkyl group, a cycloalkyl group, an aryl group, an aralkyl group, or an alkenyl group.

The acid-decomposable group is preferably a cumyl ester group, an enol ester group, an acetal ester group, or a tertiary alkyl ester group, and more preferably a tertiary alkyl ester group.

In a case where a plurality of R₁'s are present, the plurality of R₁'s may be bonded to each other to form a monocycle, a polycycle, or a spiro ring.

The group represented by OR₁ in the group represented by General Formula (Ab1) is preferably a repeating unit represented by the following General Formula (Ab1′).

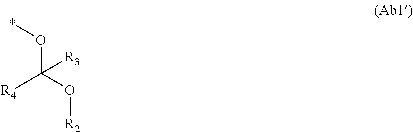

R₄ represents a hydrogen atom or a monovalent substituent.

R₂ represents a monovalent substituent. R₄ and R₂ may be bonded to each other to form a ring.

R₃ represents a substituent.

* represents a direct bond which is connected to L in the repeating unit represented by General Formula (Ab1) described above.

The monovalent substituent represented by R₄ is preferably a group represented by *—C(R₁₁₁)(R₁₁₂)(R₁₁₃). * represents a direct bond which is connected to a carbon atom in the repeating unit represented by General Formula (Ab1′). Each of R₁₁₁ to R₁₁₃ independently represents a hydrogen atom, an alkyl group, a cycloalkyl group, an aryl group, an aralkyl group, or a heterocyclic group. At least two of R₁₁₁ to R₁₁₃ may be connected to each other to form a ring.

The alkyl group represented by each of R₁₁₁ to R₁₁₃ is preferably an alkyl group having 1 to 15 carbon atoms, more preferably an alkyl group having 1 to 10 carbon atoms, and still more preferably an alkyl group having 1 to 6 carbon atoms. Specific examples of the alkyl group represented by each of R₁₁₁ to R₁₁₃ can include a methyl group, an ethyl group, a propyl group, an isopropyl group, an n-butyl group, a sec-butyl group, a t-butyl group, a neopentyl group, a hexyl group, a 2-ethylhexyl group, an octyl group, and a dodecyl group, and the alkyl group represented by each of R₁₁₁ to R₁₁₃ is preferably a methyl group, an ethyl group, a propyl group, an isopropyl group, or a t-butyl group.

Each of at least two of R₁₁₁ to R₁₁₃ independently represents an alkyl group, a cycloalkyl group, an aryl group, an aralkyl group, or a heterocyclic group, and all of R₁₁₁ to R₁₁₃ preferably represent alkyl groups, cycloalkyl groups, aryl groups, aralkyl groups, or heterocyclic groups.

The cycloalkyl group represented by each of R₁₁₁ to R₁₁₃ may be monocyclic or polycyclic, and is preferably a cycloalkyl group having 3 to 15 carbon atoms, more preferably a cycloalkyl group having 3 to 10 carbon atoms, and still more preferably a cycloalkyl group having 3 to 6 carbon atoms. Specific examples of the cycloalkyl group represented by each of R₁₁₁ to R₁₁₃ can include a cyclopropyl group, a cyclobutyl group, a cyclopentyl group, a cyclohexyl group, a cycloheptyl group, a cyclooctyl group, a decahydronaphthyl group, a cyclodecyl group, a 1-adamantyl group, a 2-adamantyl group, a 1-norbornyl group, and 2-norbornyl group. The cycloalkyl group represented by each of R₁₁₁ to R₁₁₃ is preferably a cyclopropyl group, a cyclopentyl group, or a cyclohexyl group.

The aryl group represented by each of R₁₁₁ to R₁₁₃ is preferably an aryl group having 6 to 15 carbon atoms, more preferably an aryl group having 6 to 12 carbon atoms, and also includes a structure (for example, a biphenyl group or a terphenyl group) in which a plurality of aromatic rings are connected to each other through a single bond. Specific examples of the aryl group represented by each of R₁₁₁ to R₁₁₃ include a phenyl group, a naphthyl group, an anthranyl group, a biphenyl group, and a terphenyl group. The aryl group represented by each of R₁₁₁ to R₁₁₃ is preferably a phenyl group, a naphthyl group, or a biphenyl group.

The aralkyl group represented by each of R₁₁₁ to R₁₁₃ is preferably an aralkyl group having 6 to 20 carbon atoms, and more preferably an aralkyl group having 7 to 12 carbon atoms. Specific examples of the aralkyl group represented by each of R₁₁₁ to R₁₁₃ include a benzyl group, a phenethyl group, a naphthylmethyl group, and a naphthylethyl group.

The heterocyclic group represented by each of R₁₁₁ to R₁₁₃ is preferably a heterocyclic group having 6 to 20 carbon atoms, and more preferably a heterocyclic group having 6 to 12 carbon atoms. Specific examples of the heterocyclic group represented by each of R₁₁₁ to R₁₁₃ include a pyridyl group, a pyrazyl group, a tetrahydrofuranyl group, a tetrahydropyranyl group, a tetrahydrothiophene group, a piperidyl group, a piperazyl group, a furanyl group, a pyranyl group, and a chromanyl group.

The alkyl group, the cycloalkyl group, the aryl group, the aralkyl group, and the heterocyclic group represented by each of R₁₁₁ to R₁₁₃ may further have a substituent.

Examples of the substituent which the alkyl group represented by each of R₁₁₁ to R₁₁₃ can further have include a cycloalkyl group, an aryl group, an amino group, an amide group, a ureido group, a urethane group, a hydroxy group, a carboxy group, a halogen atom, an alkoxy group, an aralkyloxy group, a thioether group, an acyl group, an acyloxy group, an alkoxycarbonyl group, a cyano group, and a nitro group. The substituents may be bonded to each other to form a ring, and examples of the ring when the substituents are bonded to each other to form a ring include a cycloalkyl group having 3 to 10 carbon atoms and a phenyl group.

Examples of the substituent which the cycloalkyl group represented by each of R₁₁₁ to R₁₁₃ can further have include alkyl groups and the respective groups described above as the specific examples of the substituent which the alkyl group can further have.

Moreover, each of the alkyl group and the substituent which the cycloalkyl group can further have preferably has 1 to 8 carbon atoms.

Examples of the substituent which the aryl group, the aralkyl group, or the heterocyclic group represented by each of R₁₁₁ to R₁₁₃ can further have include a nitro group, a halogen atom such as a fluorine atom, a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

In a case where at least two of R₁₁₁ to R₁₁₃ are bonded to each other to form a ring, examples of the formed ring include a tetrahydropyran ring, a cyclopentane ring, a cyclohexane ring, an adamantane ring, a norbornene ring, and a norbornane ring. These rings may have substituents, and examples of the substituents which the rings can have include alkyl groups and the respective groups described above as the specific examples of the substituent which the alkyl group can further have.

In a case where all of R₁₁₁ to R₁₁₃ are bonded to each other to form a ring, examples of the formed ring include an adamantane ring, a norbornane ring, a norbornene ring, a bicyclo[2,2,2]octane ring, and a bicyclo[3,1,1]heptane ring. Among these, an adamantane ring is particularly preferable. These may have substituents, and examples of the substituents which the rings can have include alkyl groups and the respective groups described above as the specific examples of the substituent which the alkyl group can further have.

Specific examples of R₄ will be shown below, but the present invention is not limited thereto. In the following specific examples, * represents a direct bond which is connected to a carbon atom.

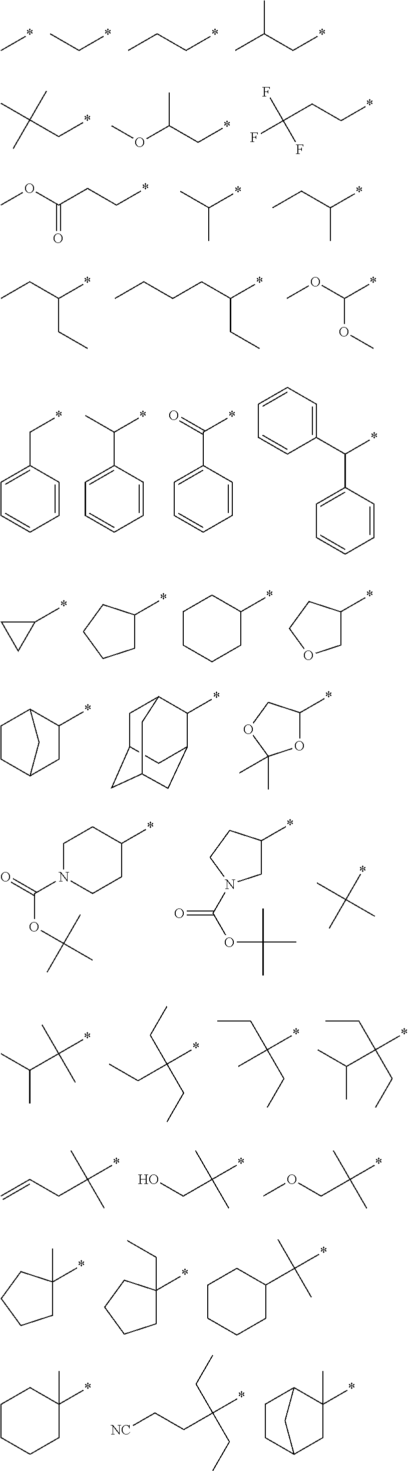

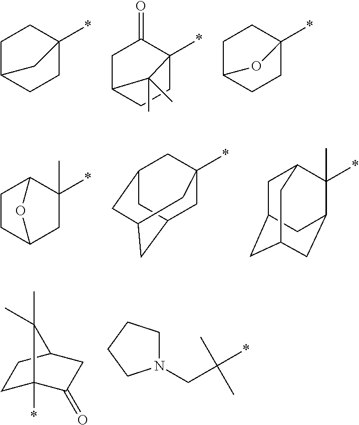

The monovalent substituent represented by R₂ is preferably a group represented by *-M-Q. * represents a direct bond which is connected to an oxygen atom in General Formula (Ab1′). M represents a single bond or a divalent connecting group. Q represents an alkyl group, a cycloalkyl group, an aryl group, or a heterocyclic group.

The divalent connecting group represented by M is, for example, an alkylene group (preferably an alkylene group having 1 to 8 carbon atoms, for example, a methylene group, an ethylene group, a propylene group, a butylene group, a hexylene group, or an octylene group), a cycloalkylene group (preferably a cycloalkylene group having 3 to 15 carbon atoms, for example, a cyclopentylene group or a cyclohexylene group), —S—, —O—, —CO—, —CS—, —SO₂—, —N(R₀)—, or a combination of two or more of the same, and the divalent connecting group preferably has 20 or less carbon atoms in total. Here, R₀ is a hydrogen atom or an alkyl group (for example, an alkyl group having 1 to 8 carbon atoms, specifically a methyl group, an ethyl group, a propyl group, an n-butyl group, a sec-butyl group, a hexyl group, an octyl group, or the like).

M is preferably a single bond, an alkylene group, or a divalent connecting group including a combination of an alkylene group with at least one of —O—, —CO—, —CS—, and —N(R₀)—, and more preferably a single bond, an alkylene group, or a divalent connecting group including a combination of an alkylene group with —O—. Here, R₀ has the same meaning as R₀ described above.

M may further have a substituent, and the substituent which M can have is the same as substituents which the alkyl group represented by each of R₁₁₁ to R₁₁₃ described above can have.

Specific examples and preferable examples of the alkyl group represented by Q include the same as those described as the alkyl group represented by each of R₁₁₁ to R₁₁₃ described above.

The cycloalkyl group represented by Q may be monocyclic or polycyclic. The cycloalkyl group preferably has 3 to 10 carbon atoms. Examples of the cycloalkyl group include a cyclopropyl group, a cyclobutyl group, a cyclopentyl group, a cyclohexyl group, a cycloheptyl group, a cyclooctyl group, a 1-adamantyl group, a 2-adamantyl group, a 1-norbornyl group, a 2-norbornyl group, a bornyl group, an isobornyl group, a 4-tetracyclo[6.2.1.1^{3,6}0.0^{2,7}]dodecyl group, an 8-tricyclo[5.2.1.0^{2,6}]decyl group, and a 2-bicyclo[2.2.1]heptyl group. Among these, a cyclopentyl group, a cyclohexyl group, a 2-adamantyl group, an 8-tricyclo[5.2.1.0^{2,6}]decyl group, or a 2-bicyclo[2.2.1]heptyl group is preferable.

Specific examples and preferable examples of the aryl group represented by Q include the same as those described as the aryl group represented by each of R₁₁₁ to R₁₁₃ described above.

Specific examples and preferable examples of the heterocyclic group represented by Q include the same as those described as the heterocyclic group represented by each of R₁₁₁ to R₁₁₃ described above.

Each of the alkyl group, the cycloalkyl group, the aryl group, and the heterocyclic group represented by Q may have a substituent, and examples thereof include an alkyl group, a cycloalkyl group, a cyano group, a halogen atom, a hydroxyl group, an alkoxy group, a carboxyl group, and an alkoxycarbonyl group.

R₂ is preferably an alkyl group, an alkyl group substituted with a cycloalkyl group, a cycloalkyl group, an aralkyl group, an aryloxyalkyl group, or a heterocyclic group, and more preferably an alkyl group or a cycloalkyl group. Specific examples and preferable examples of the alkyl group represented by R₂, the cycloalkyl group in “the cycloalkyl group” and “the alkyl group substituted with a cycloalkyl group” represented by R₂, and the aryl group in “the aralkyl group (arylalkyl group)” and “the aryloxyalkyl group” as the group represented by R₂ include the same as those described as the alkyl group, the cycloalkyl group, and the aryl group, represented by Q, respectively.

Specific examples and preferable examples of the alkyl portion in “the alkyl group substituted with a cycloalkyl group”, “the aralkyl group (arylalkyl group)”, and “the aryloxyalkyl group”, represented by R₂ include the same as those described as the alkylene group represented by M, respectively.

Specific examples and preferable examples of the heterocyclic group represented by R₂ include the same as those described as the heterocyclic group represented by Q.

Specific examples of the substituent represented by R₂ include a methyl group, an ethyl group, an isopropyl group, a cyclopentyl group, a cyclohexyl group, a cyclohexylethyl group, a 2-adamantyl group, an 8-tricyclo[5.2.1.0^{2,6}]decyl group, a 2-bicyclo[2.2.1]heptyl group, a benzyl group, a 2-phenethyl group, and a 2-phenoxyethylene group.

Specific examples of R₂ will be shown below, but the present invention is not limited thereto.

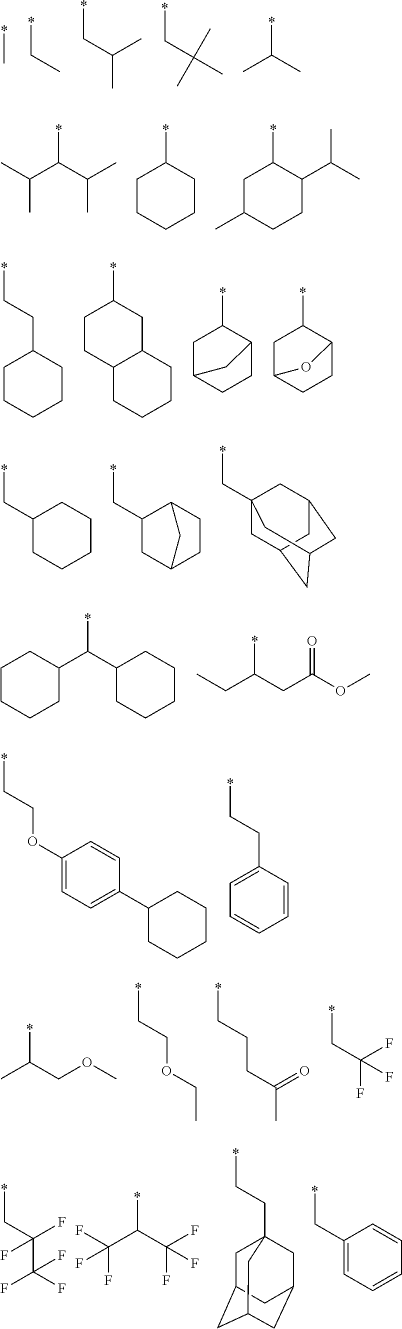

R₄ and R₂ may be bonded to each other to form a ring, and the ring formed by bonding of R₄ and R₂ to each other is preferably an oxygen-containing heterocycle. The oxygen-containing heterocycle may be a monocycle, a polycycle, or a spiro ring, preferably has a monocyclic oxygen-containing heterocyclic structure, and the number of carbon atoms is preferably 3 to 10, and more preferably 4 or 5.

In addition, as described above, in a case where M is a divalent connecting group, Q may be bonded to M to form a ring through a single bond or another connecting group. As the another connecting group, an alkylene group (preferably, an alkylene group having 1 to 3 carbon atoms) is exemplified, and the formed ring is preferably a 5- or 6-membered ring.

R₃ preferably represents a hydrogen atom, an alkyl group, or a cycloalkyl group, and specific examples and preferable examples of the alkyl group and the cycloalkyl group represented by R₃ include the same as those described as the alkyl group and the cycloalkyl group represented by Q described above.

R₃ is more preferably a hydrogen atom or an alkyl group, still more preferably a hydrogen atom or a methyl group, and particularly preferably a hydrogen atom.

The group represented by General Formula (Ab1′) is preferably a group represented by any one of the following (Ab1′-0), (Ab1′-Me), (Ab1′-1), (Ab1′-2), (Ab1′-3), and (Ab1′-c).

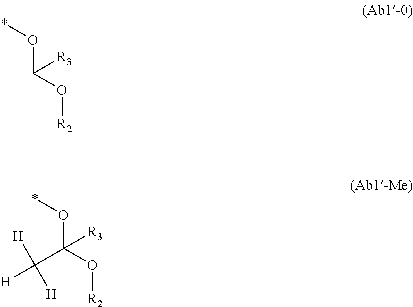

In General Formulas (Ab′1-0) and (Ab1′-Me), each of *, R₂, and R₃ has the same meaning as that in General Formula (Ab1′) described above, and specific examples and preferable examples thereof are also the same.

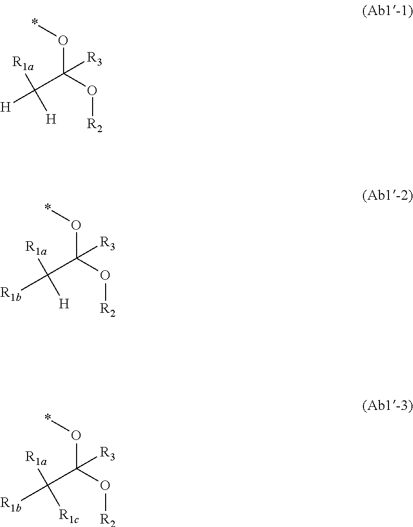

In General Formulas (Ab′1-1), (Ab′1-2), and (Ab1′-3), each of *, R₂, and R₃ has the same meaning as that in General Formula (Ab1′) described above, and specific examples and preferable examples thereof are also the same.

R₁ₐ represents a substituent, and more preferably represents an alkyl group (preferably an alkyl group having 1 to 15 carbon atoms, more preferably an alkyl group having 1 to 10 carbon atoms, and still more preferably an alkyl group having 1 to 6 carbon atoms).

In General Formulas (Ab1′-2) and (Ab1′-3), R_{1b} represents a substituent, and more preferably represents an alkyl group (preferably an alkyl group having 1 to 15 carbon atoms, more preferably an alkyl group having 1 to 10 carbon atoms, and still more preferably an alkyl group having 1 to 6 carbon atoms).

In General Formula (Ab1′-3), R_{1c} represents a substituent, and more preferably represents an alkyl group (preferably an alkyl group having 1 to 15 carbon atoms, more preferably an alkyl group having 1 to 10 carbon atoms, and still more preferably an alkyl group having 1 to 6 carbon atoms).

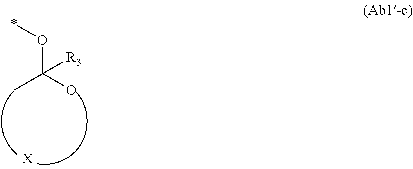

In General Formula (Ab1′-c), each of R₃ and * has the same meaning as that in General Formula (Ab1′), and specific examples and preferable examples thereof are also the same.

X represents an alkylene group, an ether group, or a carbonyl group, preferably represents an alkylene group, preferably has 2 to 7 carbon atoms, and more preferably has 3 to 5 carbon atoms. The alkylene group may be substituted, and as the substituent, an alkyl group is exemplified, and the alkyl group preferably has 3 to 5 carbon atoms, and in a case where the alkylene group is substituted with a plurality of substituents, the substituents may be bonded to each other to form a ring.

Specific examples of a group represented by General Formula (Ab1′-c) will be shown below, but the present invention is not limited thereto. Each of R₃ and * has the same meaning as that in General Formula (Ab1′-c) described above.

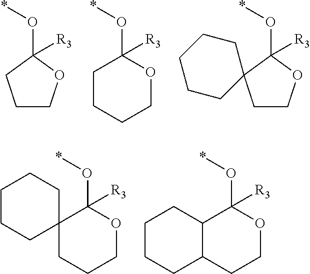

The group represented by General Formula (Ab1′) is preferably a group represented by any one of General Formulas (Ab1′-0), (Ab1′-Me), (Ab1′-1), (Ab1′-2), (Ab1′-3), and (Ab1′-c), more preferably a group represented by any one of General Formulas (Ab1′-0), (Ab1′-Me), (Ab1′-1), (Ab1′-3), and (Ab1′-c), and most preferably a group represented by any one of General Formulas (Ab1′-1), (Ab1′-3), and (Ab1′-c).

OR₁ in the repeating unit represented by General Formula (Ab1) is also preferably a group represented by the following General Formula (Ab1′-b).

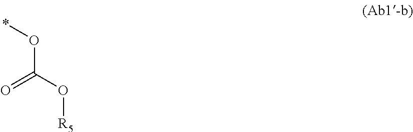

In General Formula (Ab1′-b), * has the same meaning as that in General Formula (Ab1′) described above.

R₅ represents a substituent, and preferably represents an alkyl group.

The alkyl group is preferably an alkyl group having 1 to 6 carbon atoms, and examples thereof can include a methyl group, an ethyl group, a propyl group, an isopropyl group, an n-butyl group, a sec-butyl group, a t-butyl group, a t-amyl group, a neopentyl group, a hexyl group, a 2-ethylhexyl group, an octyl group, and a dodecyl group, and a t-butyl group or a t-amyl group is preferable.

m represents an integer of 1 or greater, preferably represents an integer of 1 to 4, and more preferably represents 1 or 2. p represents an integer of 1 or greater, preferably represents 1 or 2, and more preferably represents 1. q represents an integer of 0 or greater, preferably represents 0 or 1, and more preferably represents 0.

The repeating unit represented by General Formula (Ab1) is preferably a repeating unit represented by the following General Formula (Ab1-1).

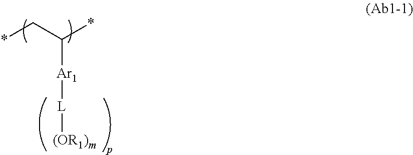

In General Formula (Ab1-1), Ar₁ represents a (p+1) valent aromatic ring group.

L represents an (m+1) valent connecting group.

OR₁ represents a group which generates an alcoholic hydroxyl group by being decomposed due to the action of an acid.

In a case where a plurality of L's and R₁'s are present, the plurality of L's and the plurality of R₁'s may be the same or different, respectively, and the plurality of R₁'s may be bonded to each other to form a ring.

m represents an integer of 1 or greater.

p represents an integer of 1 or greater.

Each of Ar₁, L, R₁, a ring formed by bonding of a plurality of R₁'s to each other, m, and p has the same meaning as that in General Formula (Ab1), and specific examples and preferable examples thereof are also the same.

The repeating unit represented by General Formula (Ab1-1) is more preferably a repeating unit represented by the following General Formula (Ab1-1-1).

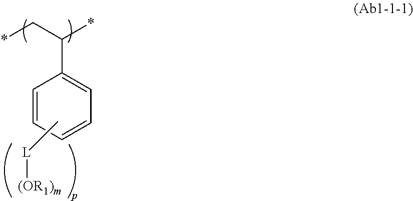

In General Formula (Ab1-1-1), L represents an (m+1) valent connecting group.

OR₁ represents a group which generates an alcoholic hydroxyl group by being decomposed due to the action of an acid.

In a case where a plurality of L's and R₁'s are present, the plurality of L's and the plurality of R₁'s may be the same or different, respectively, and the plurality of R₁'s may be bonded to each other to form a ring.

m represents an integer of 1 or greater.

p represents an integer of 1 or greater.

Each of L, R₁, a ring formed by bonding of a plurality of R₁'s to each other, m, and p has the same meaning as that in General Formula (Ab1), and specific examples and preferable examples thereof are also the same.

L is preferably connected to a meta position or the para position, and more preferably connected to the para position of the benzene ring, with respect to the main chain in General Formula (Ab1-1-1).

Each group described above may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), and the substituent preferably has 8 or less carbon atoms.

The repeating unit represented by General Formula (Ab1) may be used alone or in combination of two or more types thereof, and the content of the repeating unit represented by General Formula (Ab1) is preferably 10 mol % to 90 mol %, more preferably 30 mol % to 80 mol %, and still more preferably 50 mol % to 70 mol %, with respect to the entirety of repeating units constituting the resin (Ab).

Specific examples of the repeating unit represented by General Formula (Ab1) will be described below, but the present invention is not limited thereto.

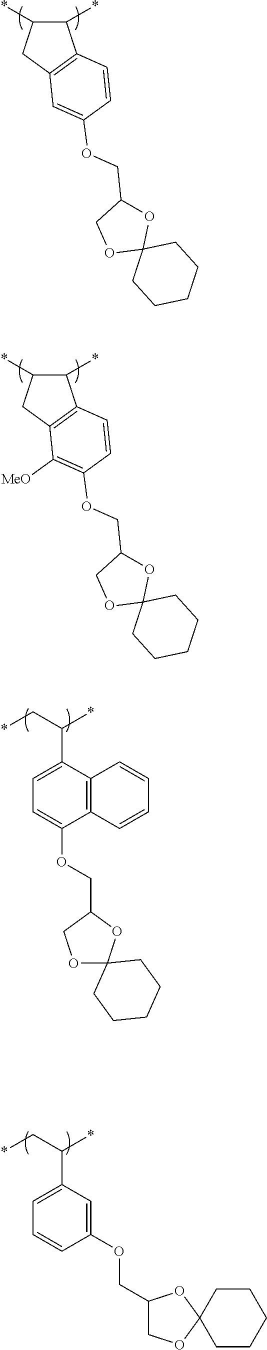

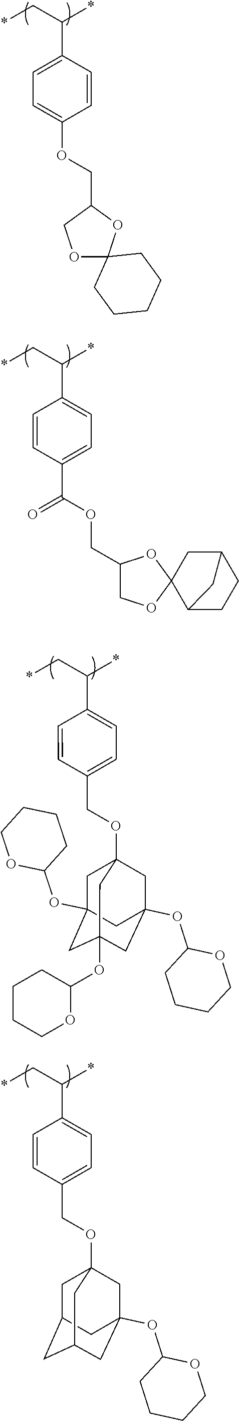

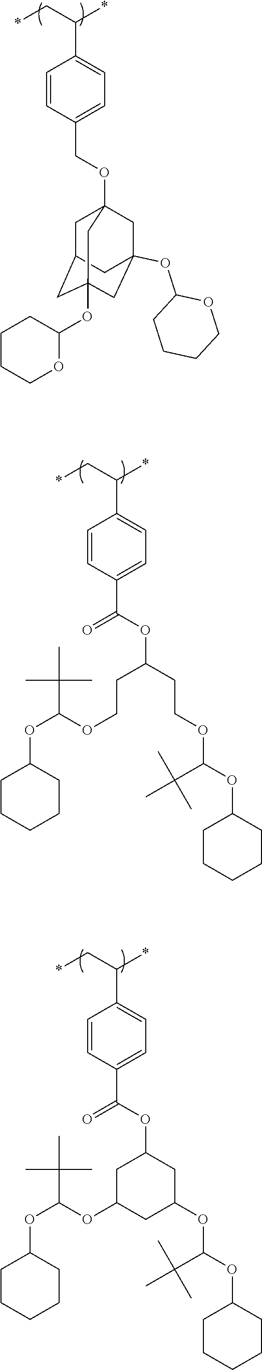

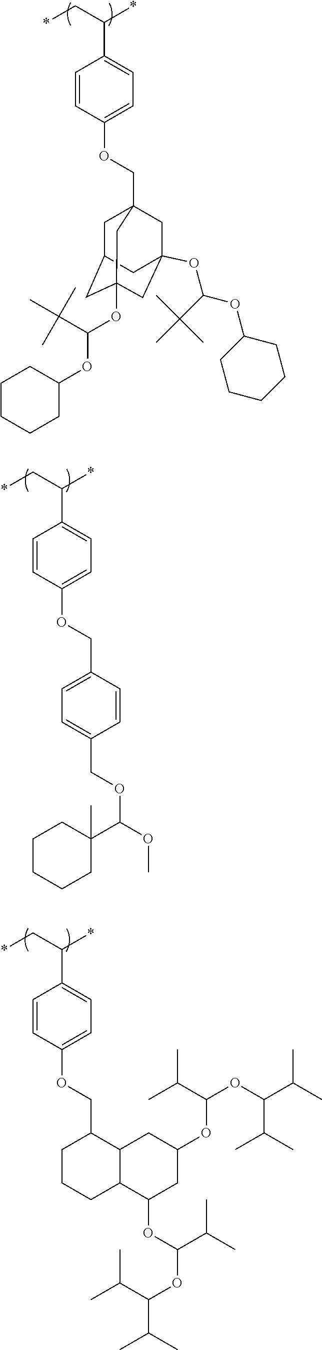

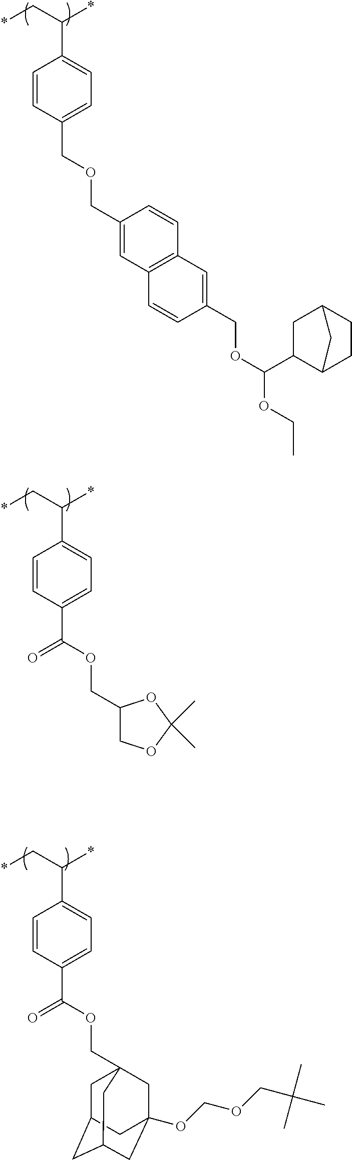

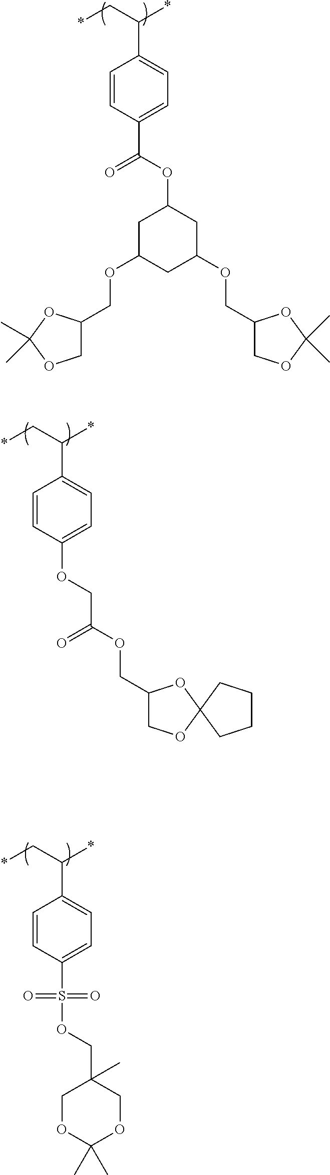

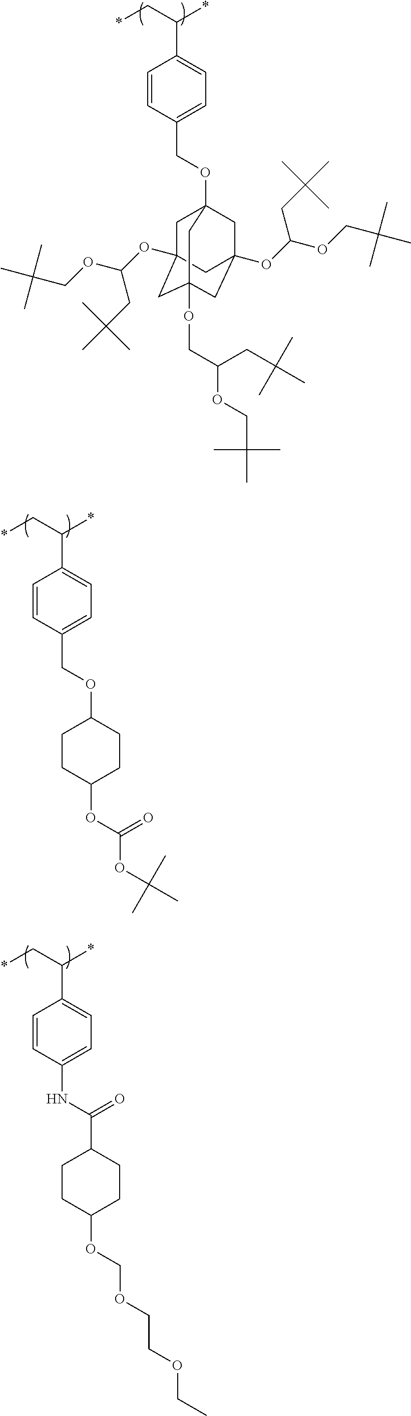

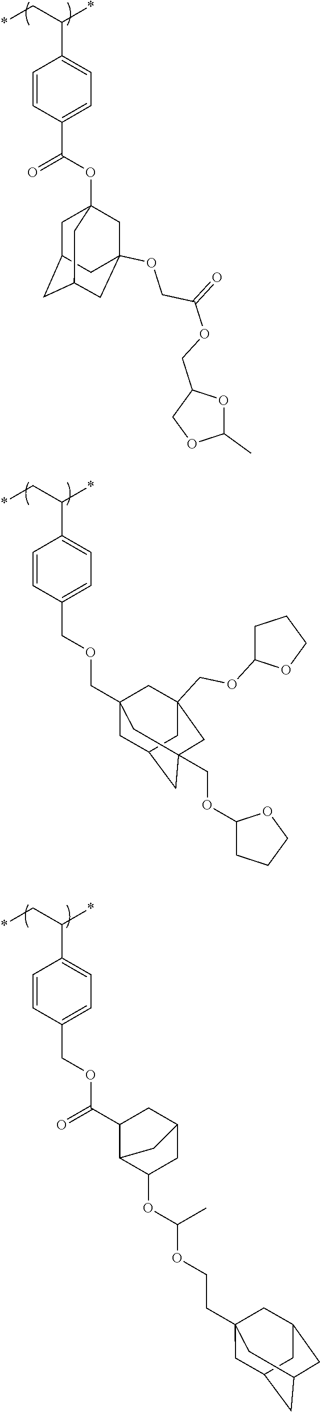

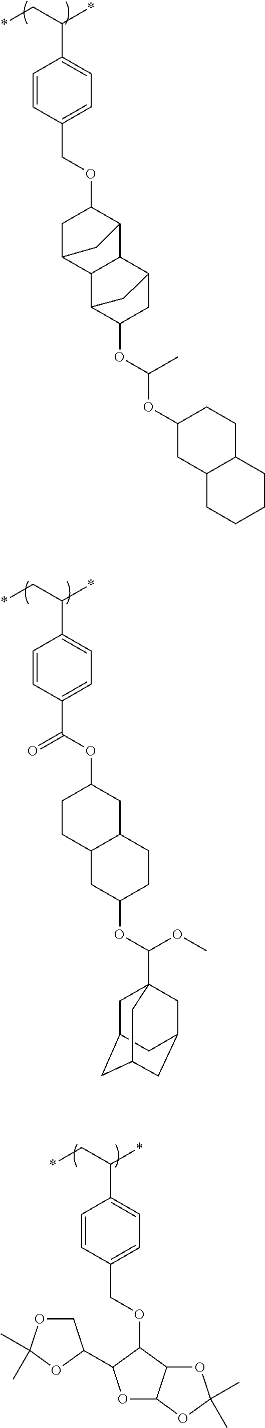

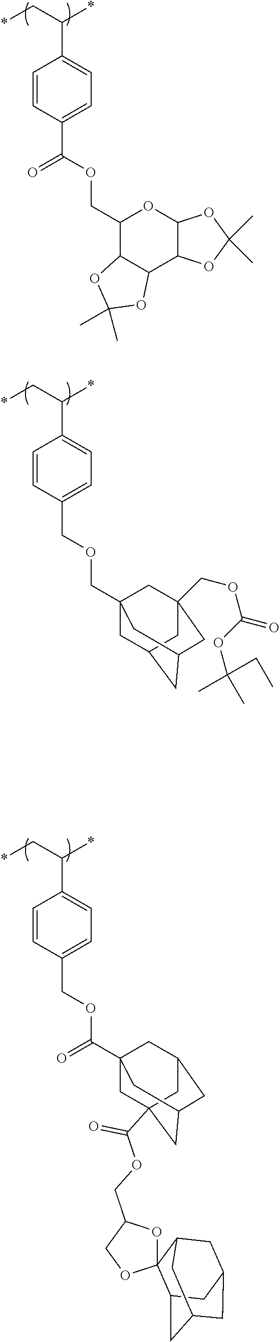

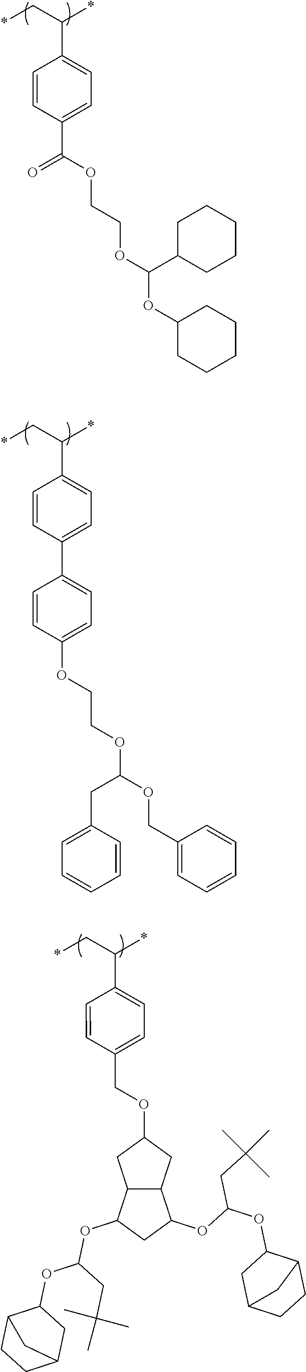

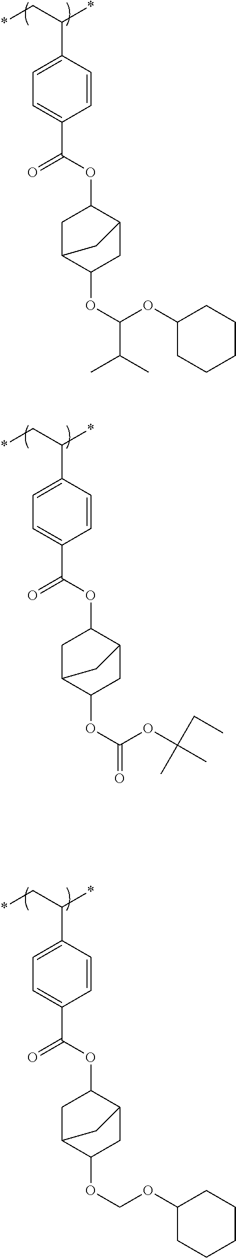

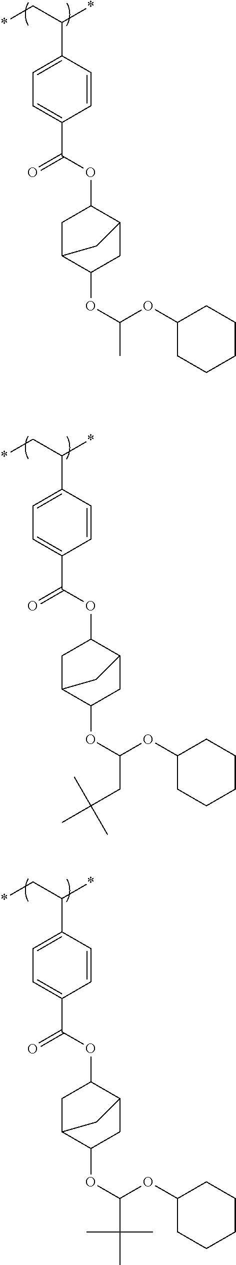

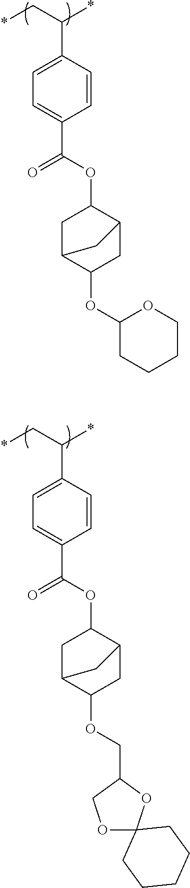

The resin (Ab) of the present invention may further include a repeating unit represented by the following General Formula (4).

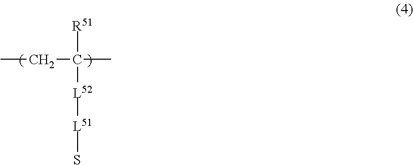

R⁵¹ represents a hydrogen atom or a methyl group. L⁵¹ represents a single bond or a divalent connecting group. L⁵² represents a divalent connecting group. S represents a structural portion that generates an acid on a side chain by being decomposed by irradiation with actinic ray or radiation.

As described above, R⁵¹ represents a hydrogen atom or a methyl group, and more preferably represents a hydrogen atom.

Examples of the divalent connecting group represented by each of L⁵¹ and L⁵² include an alkylene group, a cycloalkylene group, an arylene group, —O—, —SO₂—, —CO—, —N(R)—, —S—, —CS—, and a combination of two or more types thereof, and the group preferably has 20 or less carbon atoms in total. Here, R represents an aryl group, an alkyl group, or a cycloalkyl group.

The divalent connecting group represented by L⁵² is preferably an arylene group, and the arylene group may have a substituent, and preferable examples thereof can include an arylene group having 6 to 18 carbon atoms (more preferably 6 to 10 carbon atoms) such as a phenylene group, a tolylene group, or a naphthylene group.

In a case where the resin (Ab) includes the repeating unit represented by General Formula (4), for example, at least one of resolution, roughness characteristics, and EL (exposure latitude) is further improved.

Preferable examples of the alkylene group represented by each of L⁵¹ and L⁵² include alkylene groups having 1 to 12 carbon atoms such as a methylene group, an ethylene group, a propylene group, a butylene group, a hexylene group, an octylene group, and a dodecanylene group.

Preferable examples of the cycloalkylene group represented by each of L⁵¹ and L⁵² include cycloalkylene groups having 5 to 8 carbon atoms such as a cyclopentylene group and a cyclohexylene group.

Preferable examples of the arylene group represented by each of L⁵¹ and L⁵² include arylene groups having 6 to 14 carbon atoms such as a phenylene group and a naphthylene group.

These alkylene groups, cycloalkylene groups, and arylene groups may further have a substituent. Examples of the substituent include an alkyl group, a cycloalkyl group, an aryl group, an amino group, an amide group, a ureido group, a urethane group, a hydroxy group, a carboxy group, a halogen atom, an alkoxy group, a thioether group, an acyl group, an acyloxy group, an alkoxycarbonyl group, a cyano group, and a nitro group.

S represents a structural portion that generates an acid on a side chain by being decomposed by irradiation with actinic ray or radiation. S is preferably a structural portion that generates an acid anion on a side chain of the resin by being decomposed by irradiation with actinic ray or radiation, more preferably a structural portion having a known compound that generates an acid by light, used in a photoinitiator of cationic photopolymerization, a photoinitiator of radical photopolymerization, a photodecolorant of dyes, a photodiscoloring agent, or a microresist, and the structural portion is more preferably an ionic structural portion.

S is more preferably an ionic structural portion including a sulfonium salt or an iodonium salt. More specifically, S is preferably a group represented by the following General Formula (PZI) or (PZII).

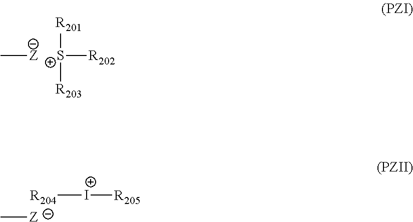

In General Formula (ZI), each of R₂₀₁ to R₂₀₃ independently represents an organic group.

The organic group represented by each of R₂₀₁ to R₂₀₃ generally has 1 to 30 carbon atoms, and preferably has 1 to 20 carbon atoms.

Two of R₂₀₁ to R₂₀₃ may be bonded to each other to form a ring structure, and an oxygen atom, a sulfur atom, an ester bond, an amide bond, or a carbonyl group may be included in the ring. Examples of the group that two of R₂₀₁ to R₂₀₃ form by bonding to each other can include an alkylene group (for example, a butylene group, and a pentylene group). It is preferable to use a group in which a ring structure is formed by bonding of two of R₂₀₁ to R₂₀₃ to each other since it is expected that the exposure machine can be prevented from being contaminated with decomposition products during exposure.

Z⁻ represents an acid anion generated by being decomposed by irradiation with actinic ray or radiation, and is preferably a non-nucleophilic anion. Examples of the non-nucleophilic anion include a sulfonate anion, a carboxylate anion, a sulfonylimide anion, a bis(alkylsulfonyl)imide anion, and a tris(alkylsulfonyl)methyl anion.

The non-nucleophilic anion is an anion with a very low ability for causing a nucleophilic reaction, and is an anion which can suppress temporal decomposition caused by an intra-molecular nucleophilic reaction. Thus, the temporal stability of the resin is improved, and the temporal stability of the composition is also improved.

Examples of the organic group represented by each of R₂₀₁ to R₂₀₃ include an aryl group, an alkyl group, a cycloalkyl group, a cycloalkenyl group, and an indolyl group. Here, in the cycloalkyl group and the cycloalkenyl group, at least one of the carbon atoms forming a ring may be a carbonyl carbon.

At least one of R₂₀₁ to R₂₀₃ is preferably an aryl group, and all of three are more preferably aryl groups.

The aryl group represented by each of R₂₀₁, R₂₀₂, and R₂₀₃ is preferably a phenyl group or a naphthyl group, and more preferably a phenyl group.

Preferable examples of the alkyl group, the cycloalkyl group, and the cycloalkenyl group represented by each of R₂₀₁, R₂₀₂, and R₂₀₃ can include a linear or branched alkyl group (for example, a methyl group, an ethyl group, a propyl group, a butyl group, or a pentyl group) having 1 to 10 carbon atoms, a cycloalkyl group (for example, a cyclopentyl group, a cyclohexyl group, or a norbornyl group) having 3 to 10 carbon atoms, and a cycloalkenyl group (for example, a pentadienyl group or a cyclohexenyl group) having 3 to 10 carbon atoms.

The organic group such as the aryl group, the alkyl group, the cycloalkyl group, the cycloalkenyl group, or the indolyl group, represented by each of R₂₀₁, R₂₀₂, and R₂₀₃ may further have a substituent. Examples of the substituent include a nitro group, a halogen atom such as a fluorine atom, a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an arylthio group (preferably having 6 to 14 carbon atoms), a hydroxyalkyl group (preferably having 1 to 15 carbon atoms), an alkylcarbonyl group (preferably having 2 to 15 carbon atoms), a cycloalkylcarbonyl group (preferably having 4 to 15 carbon atoms), an arylcarbonyl group (preferably having 7 to 14 carbon atoms), a cycloalkenyloxy group (preferably having 3 to 15 carbon atoms), and a cycloalkenylalkyl group (preferably having 4 to 20 carbon atoms), but the present invention is not limited thereto.

In the cycloalkyl group and the cycloalkenyl group as the substituent that each group of R₂₀₁, R₂₀₂, and R₂₀₃ may have, at least one of the carbon atoms forming a ring may be a carbonyl carbon.

The substituent that each group of R₂₀₁, R₂₀₂, and R₂₀₃ may have may further have a substituent, and examples of such a substituent can include the same substituents as those in the above-described examples of the substituent that each group of R₂₀₁, R₂₀₂, and R₂₀₃ may have, and an alkyl group or a cycloalkyl group is preferable.

Examples of preferable structures in a case where at least one of R₂₀₁ to R₂₀₃ is not an aryl group can include cationic structures of compounds exemplified in paragraphs “0046” and “0047” of JP2004-233661A, paragraphs “0040” to “0046” of JP2003-35948A, and exemplified as Formulas (I-1) to (I-70) in US2003/0224288A, and compounds exemplified as Formulas (IA-1) to (IA-54) and Formulas (IB-1) to (IB-24) in US2003/0077540A.

In General Formula (PZII), each of R₂₀₄ and R₂₀₅ independently represents an aryl group, an alkyl group, or a cycloalkyl group. The aryl group, the alkyl group, and the cycloalkyl group are the same as the aryl groups described as the aryl group, the alkyl group, and the cycloalkyl group represented by each of R₂₀₁ to R₂₀₃ in the compound (PZI) described above.

The aryl group represented by R₂₀₄ or R₂₀₅ may be an aryl group having a heterocyclic structure which includes an oxygen atom, a nitrogen atom, or a sulfur atom. Examples of the aryl group having a heterocyclic structure include a pyrrole residue (a group formed when pyrrole loses one hydrogen atom), a furan residue (a group formed when furan loses one hydrogen atom), a thiophene residue (a group formed when thiophene loses one hydrogen atom), an indole residue (a group formed when indole loses one hydrogen atom), a benzofuran residue (a group formed when benzofuran loses one hydrogen atom), and a benzothiophene residue (a group formed when benzothiophene loses one hydrogen atom).

The aryl group, the alkyl group, and the cycloalkyl group represented by R₂₀₄ or R₂₀₅ may have a substituent. Examples of the substituent include substituents that the aryl group, the alkyl group, and the cycloalkyl group represented by each of R₂₀₁ to R₂₀₃ in the compound (PZI) described above may have.

Z⁻ represents an acid anion generated by being decomposed by irradiation with actinic ray or radiation, and is preferably a non-nucleophilic anion, and can include the same as Z⁻ in General Formula (PZI).

Specific preferable examples of S will be described below, but the present invention is not particularly limited thereto. Moreover, the symbol * represents a direct bond to L⁴¹.

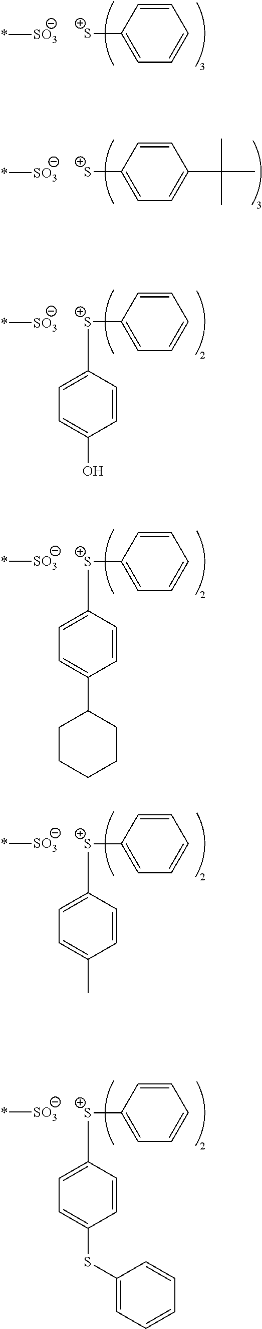

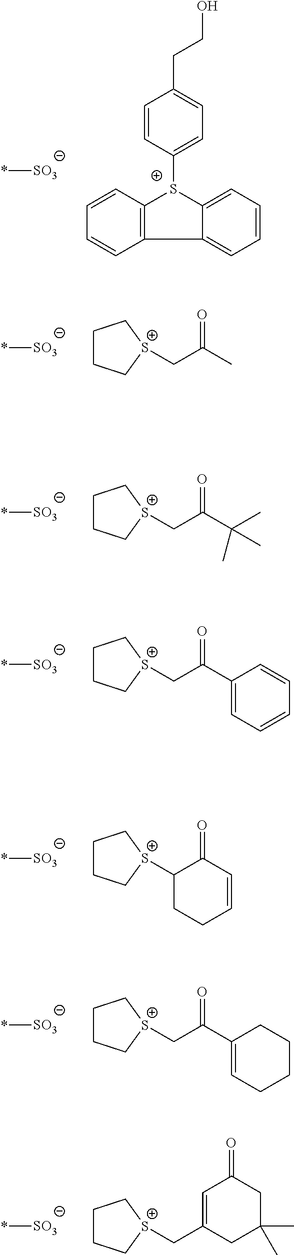

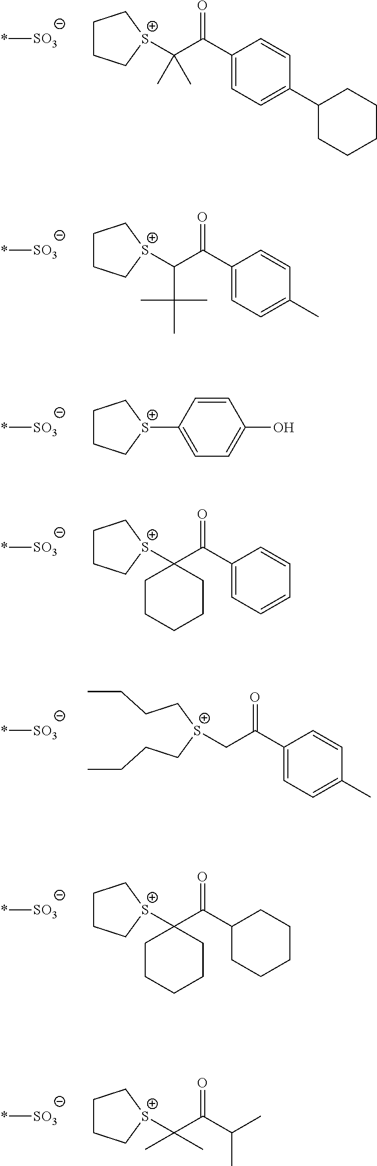

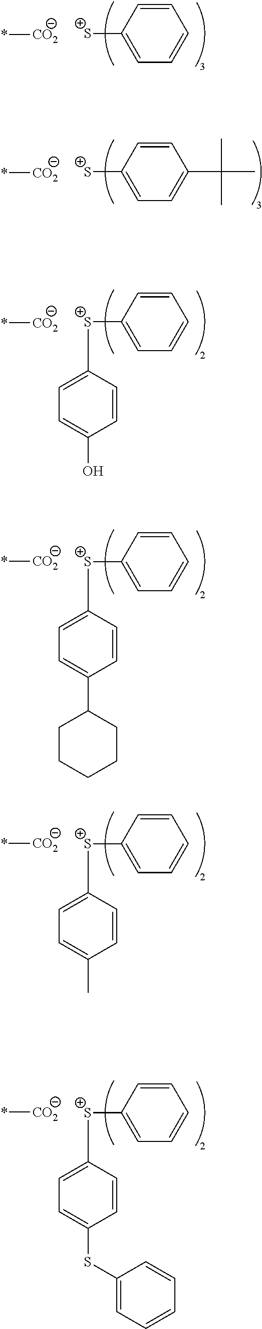

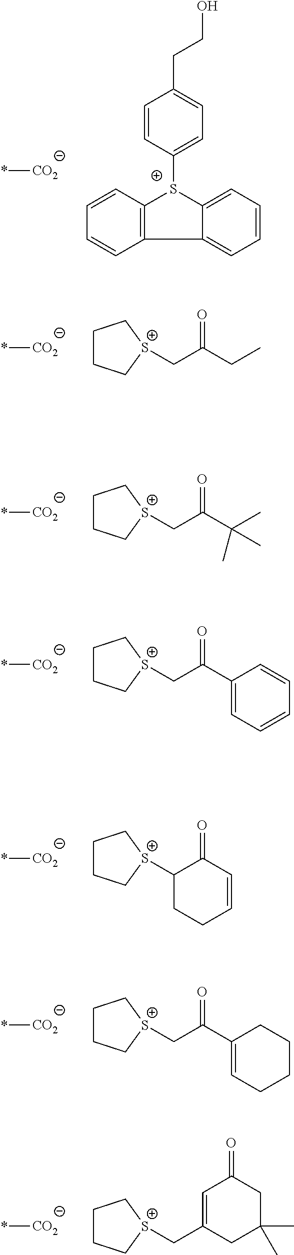

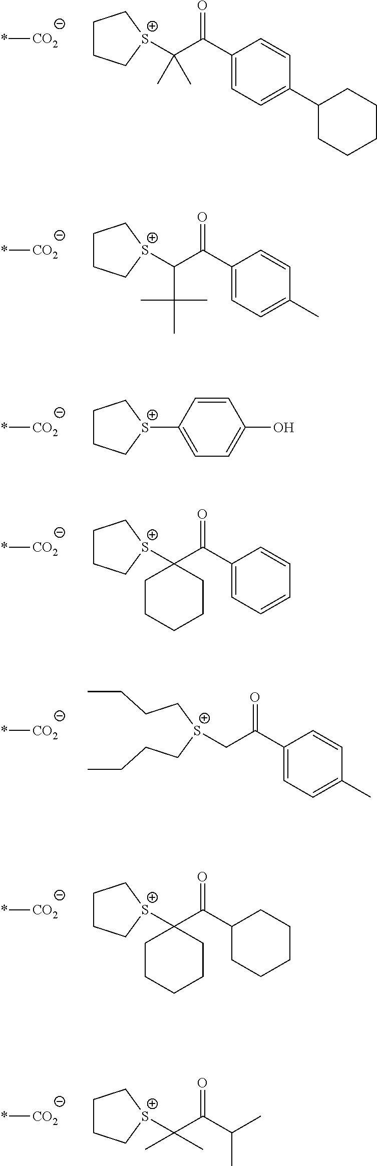

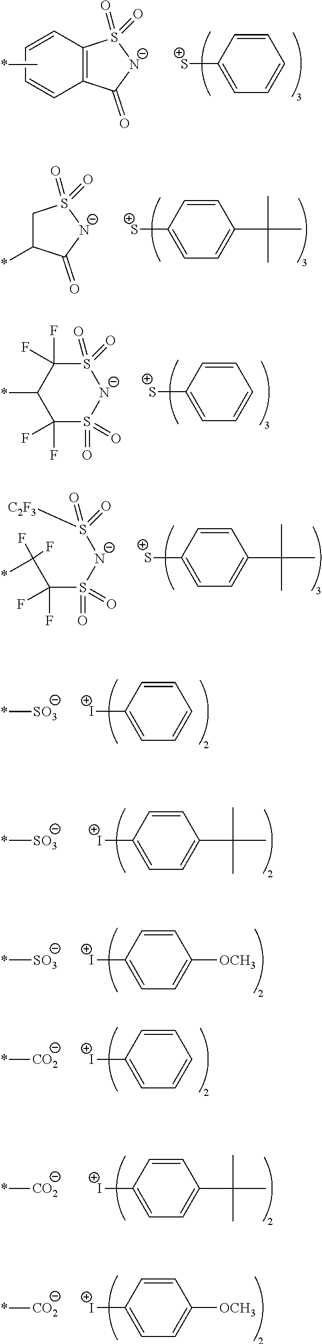

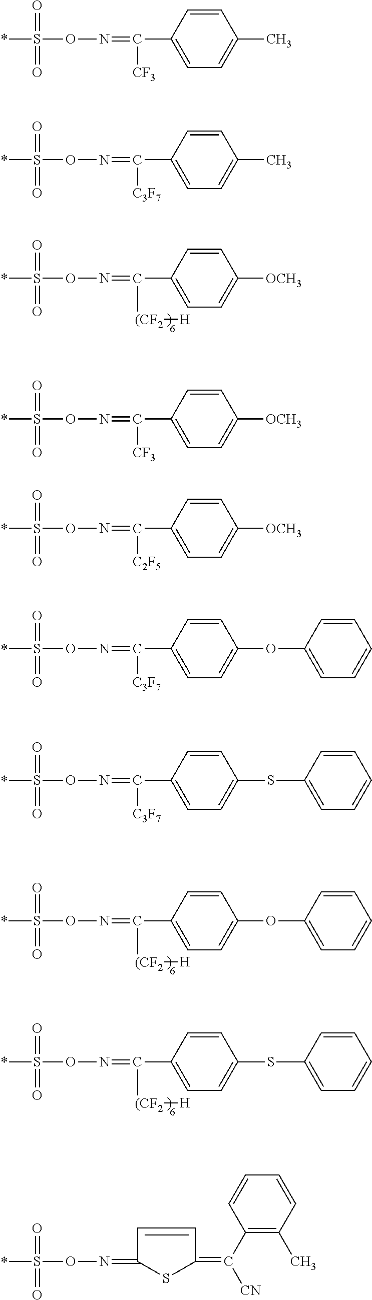

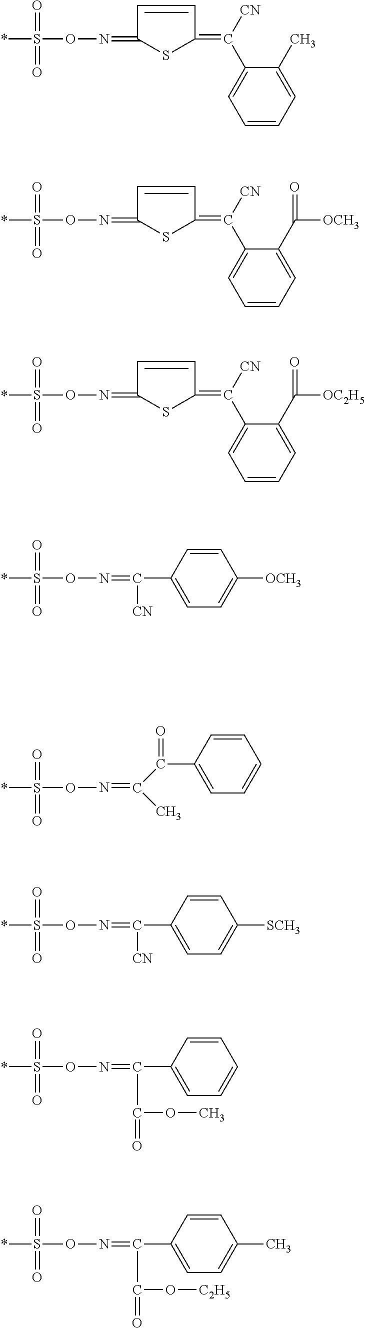

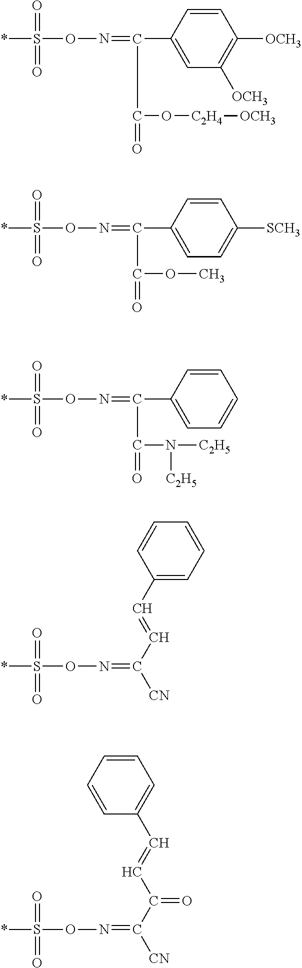

The portion corresponding to (-L⁴¹-S) of the repeating unit represented by General Formula (4) is more preferably represented by the following General Formula (6).

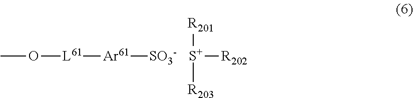

In the formula, L⁶¹ represents a divalent connecting group, and Ar⁶¹ represents an arylene group. Each of R₂₀₁, R₂₀₂, and R₂₀₃ has the same meaning as R₂₀₁, R₂₀₂, and R₂₀₃ in General Formula (PZI).

Examples of the divalent connecting group represented by L⁶¹ include an alkylene group, a cycloalkylene group, —O—, —SO₂—, —CO—, —N(R)—, —S—, —CS—, and a combination thereof. Here, R has the same meaning as R in L⁴¹ of General Formula (4). The divalent connecting group represented by L⁶¹ preferably has 1 to 15 carbon atoms in total, and more preferably has 1 to 10 carbon atoms in total.

The alkylene group and the cycloalkylene group represented by L⁶¹ are the same as the alkylene group and the cycloalkylene group represented by L⁴¹ of General Formula (4), and preferable examples thereof are also the same.

A preferable group represented by L⁶¹ is a carbonyl group, a methylene group, *—CO—(CH₂)ₙ—O—, *—CO—(CH₂)ₙ—O—CO—, *—(CH₂)ₙ—COO—, *—(CH₂)ₙ—CONR—, or *—CO—(CH₂)ₙ—NR—, and particularly preferably a carbonyl group, *—CH₂—COO—, *—CO—CH₂—O—, *—CO—CH₂—O—CO—, *—CH₂—CONR—, or *—CO—CH₂—NR—. Here, n represents an integer of 1 to 10. n is preferably an integer of 1 to 6, is more preferably an integer of 1 to 3, and most preferably is 1. In addition, * represents a connecting portion of a main chain, that is, a connecting portion to an O atom in the formula.

Ar⁶¹ represents an arylene group and may have a substituent. Examples of the substituent which Ar⁶¹ may have include an alkyl group (preferably having 1 to 8 carbon atoms, and more preferably having 1 to 4 carbon atoms), an alkoxy group (preferably having 1 to 8 carbon atoms, and more preferably having 1 to 4 carbon atoms), and a halogen atom (preferably a fluorine atom, a chlorine atom, a bromine atom, or an iodine atom, and more preferably a fluorine atom). The aromatic ring represented by Ar⁶¹ may be an aromatic hydrocarbon ring (for example, a benzene ring or a naphthalene ring), or an aromatic heterocycle (for example, a quinoline ring), and the aromatic ring preferably has 6 to 18 carbon atoms, and more preferably has 6 to 12 carbon atoms.

Ar⁶¹ is preferably an unsubstituted arylene group or an arylene group substituted with an alkyl group or a fluorine atom, and more preferably a phenylene group or a naphthylene group.

Specific examples and preferable examples of R₂₀₁, R₂₀₂, and R₂₀₃ include the same as those described as R₂₀₁, R₂₀₂, and R₂₀₃ in General Formula (PZI).

A method of synthesizing a monomer corresponding to the repeating unit represented by General Formula (4) is not particularly limited. In a case of an onium structure, examples of the method include a method that synthesizes the monomer by exchanging an acid anion having a polymerizable unsaturated bond corresponding to the repeating unit and a halide of a known onium salt.

More specifically, a metal ion salt (for example, a sodium ion, a potassium ion, or the like) or an ammonium salt (ammonium, triethylammonium salt, or the like) of an acid having a polymerizable unsaturated bond corresponding to the repeating unit and an onium salt having a halogen ion (a chloride ion, a bromide ion, an iodide ion, or the like) are stirred in the presence of water or methanol to cause an anion exchange reaction, followed by liquid separation and washing by using an organic solvent such as dichloromethane, chloroform, ethyl acetate, methyl isobutyl ketone, or tetrahydroxyfuran and water, whereby a target monomer corresponding to the repeating unit represented by General Formula (4) can be synthesized.

In addition, the monomer can also be synthesized by a method in which stirring is performed in the presence of an organic solvent capable of being separated from water, such as dichloromethane, chloroform, ethyl acetate, methyl isobutyl ketone, or tetrahydroxyfuran, and water to cause an anion exchange reaction, followed by liquid separation and washing by using water.

The repeating unit represented by General Formula (4) can also be synthesized by introducing an acid anion portion to a side chain by a polymerization reaction and introducing an onium salt by salt exchange.

Specific examples of the repeating unit represented by General Formula (4) will be described below, but the present invention is not limited thereto.

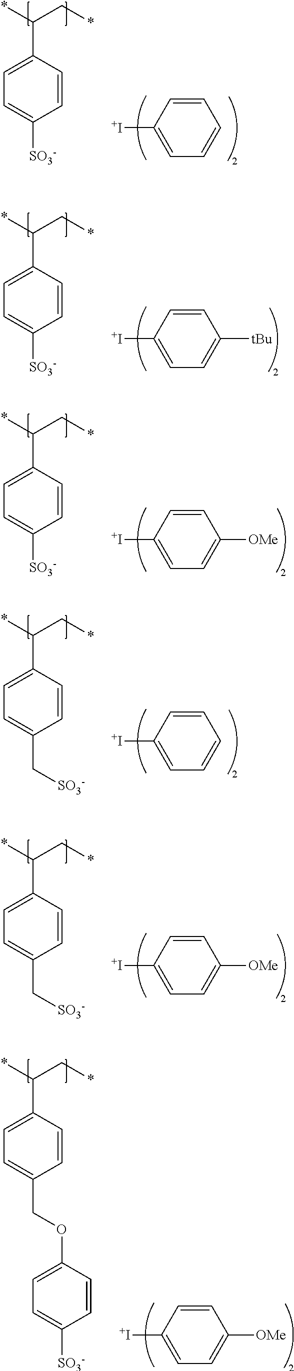

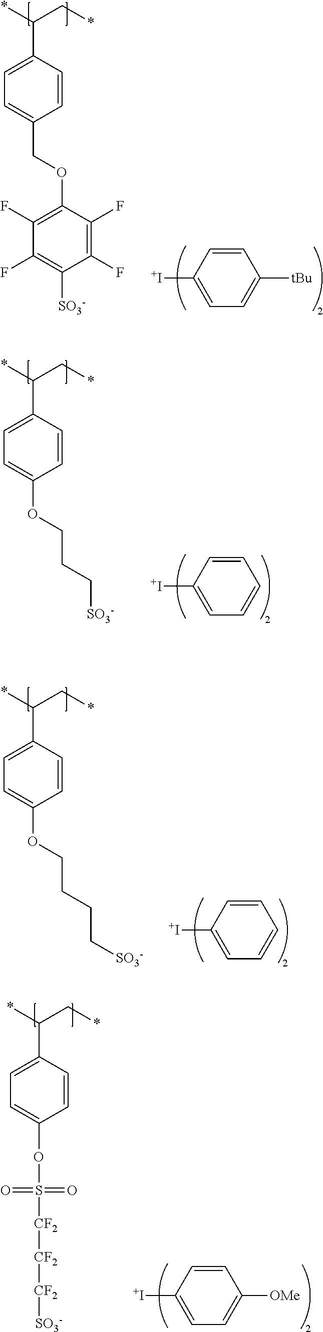

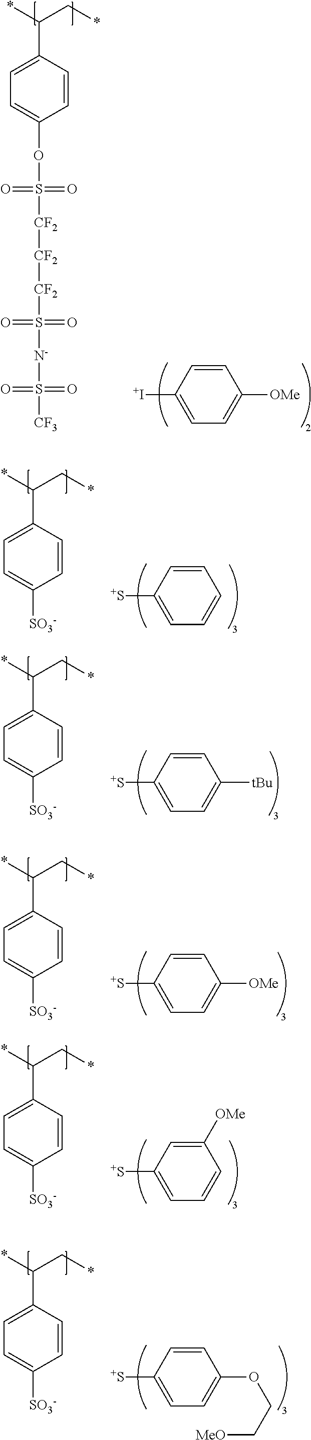

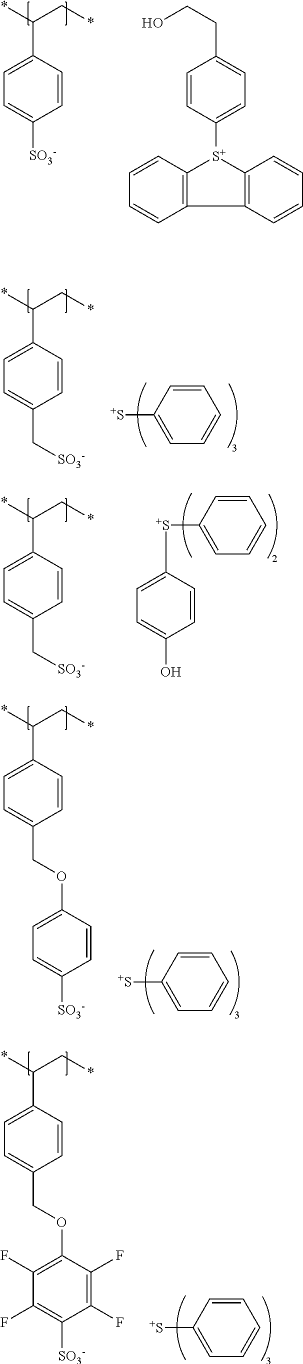

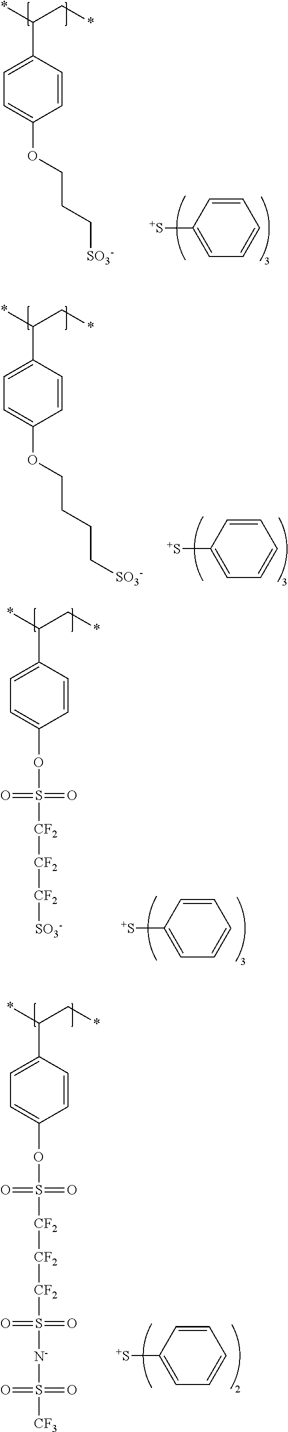

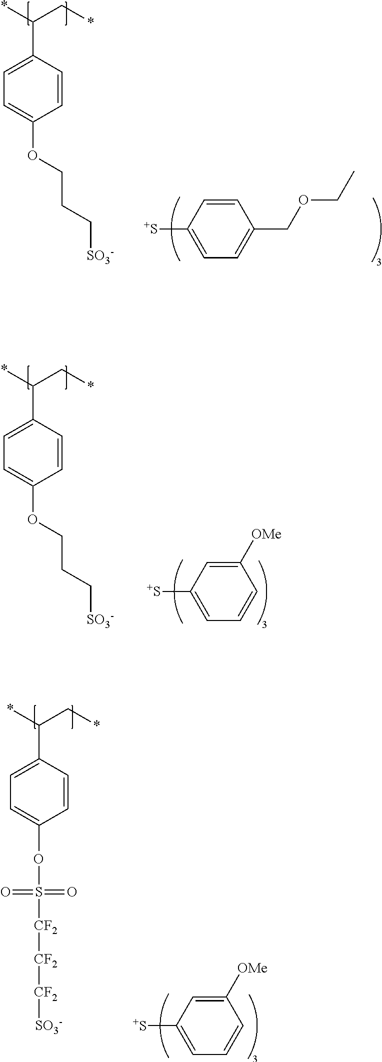

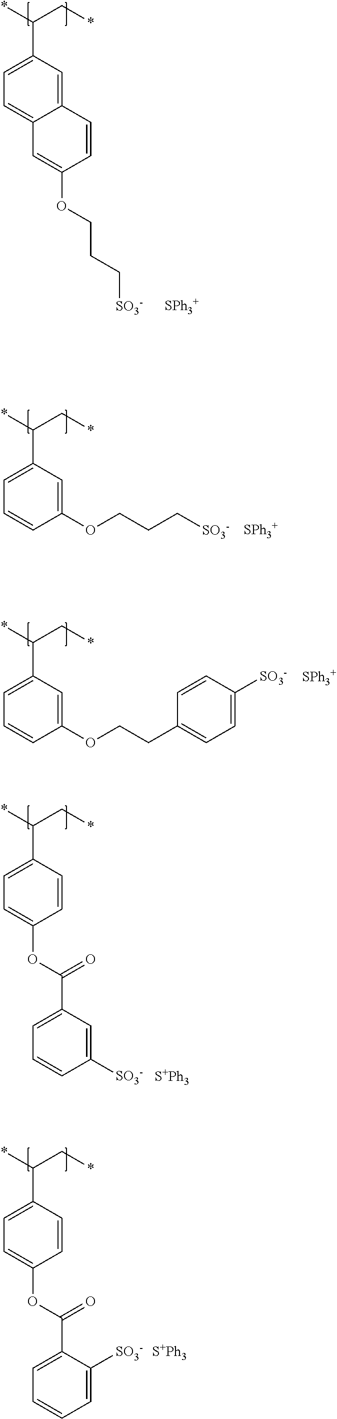

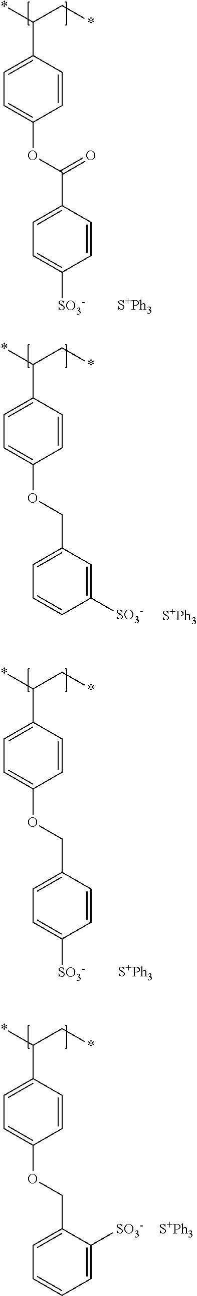

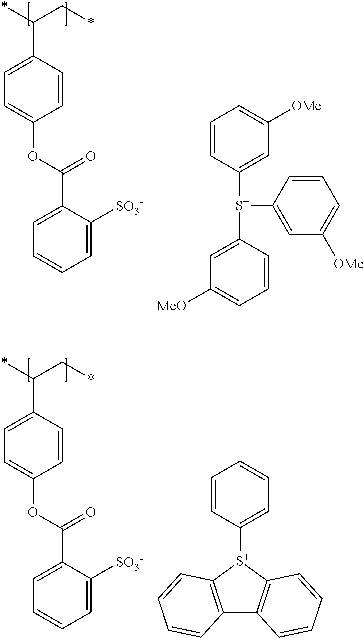

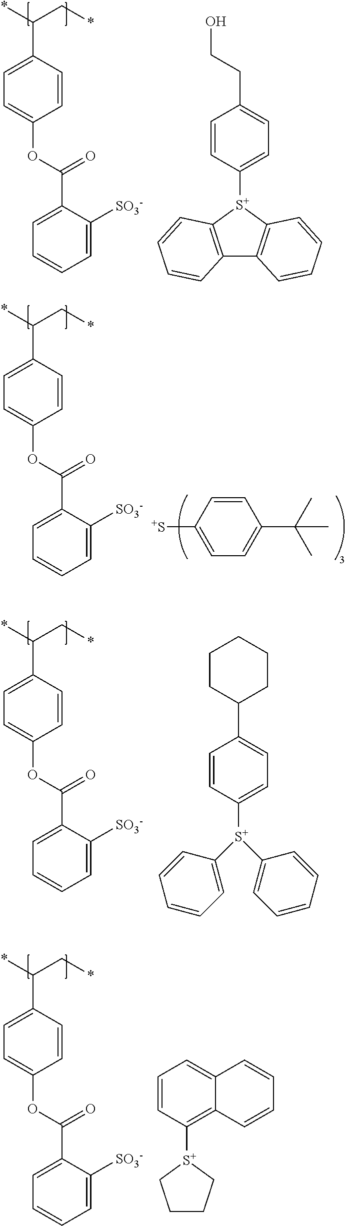

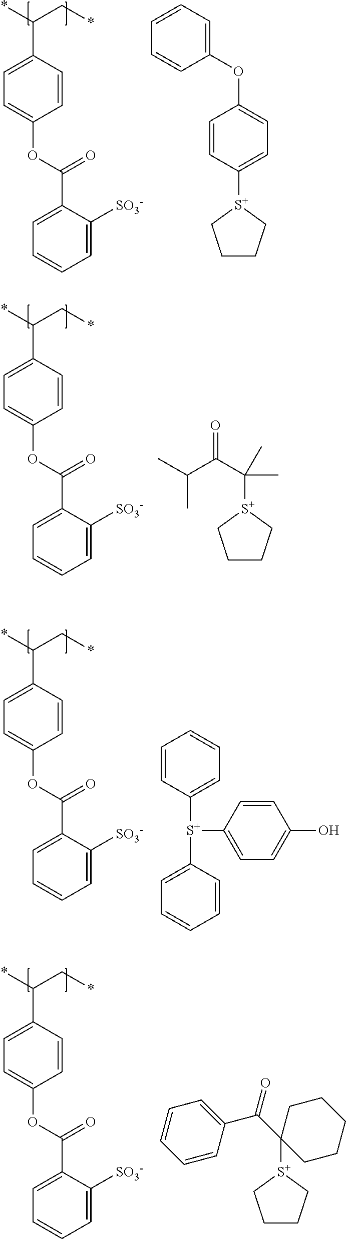

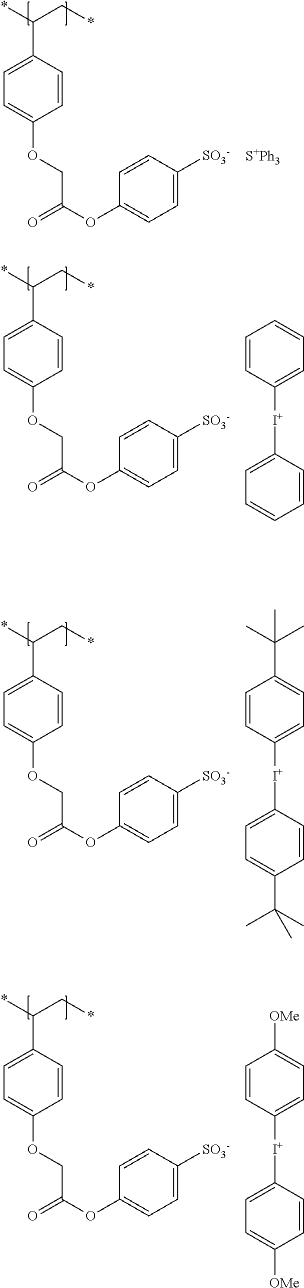

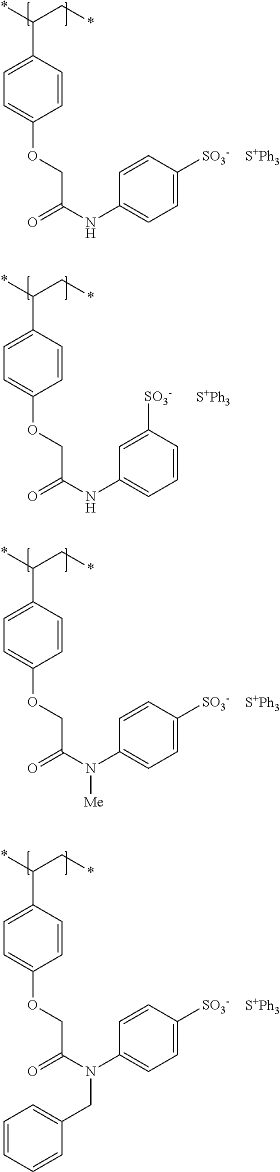

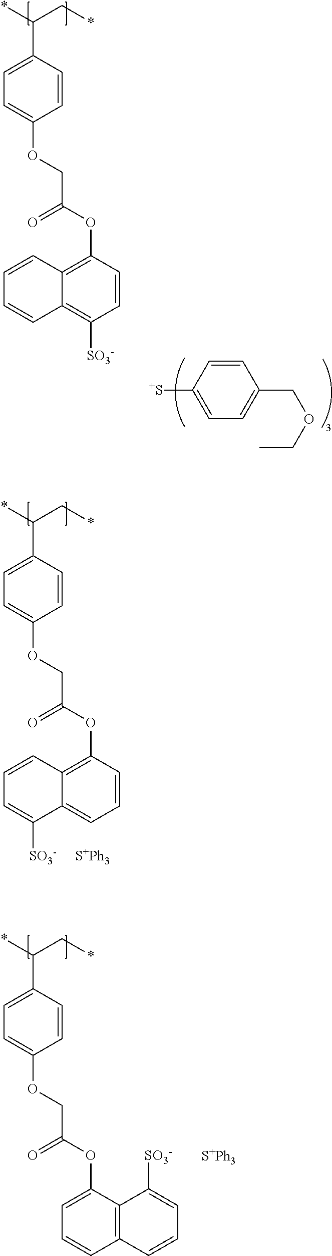

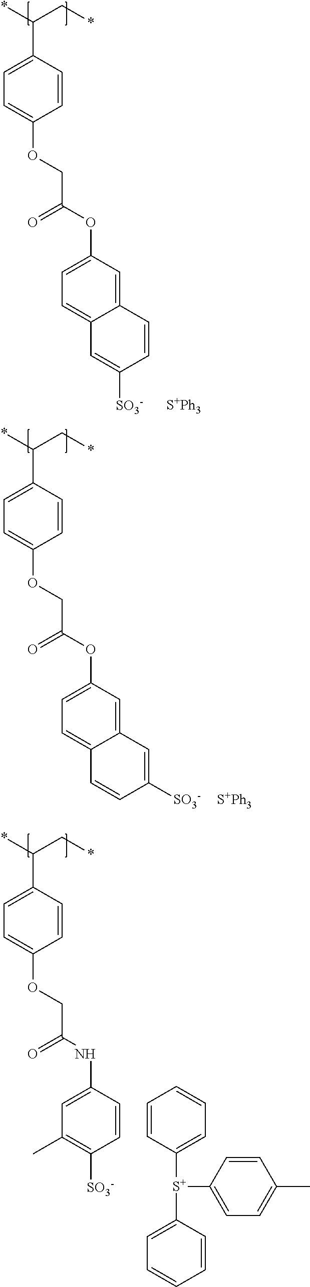

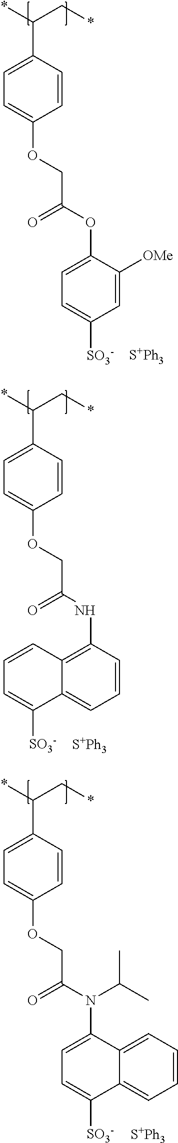

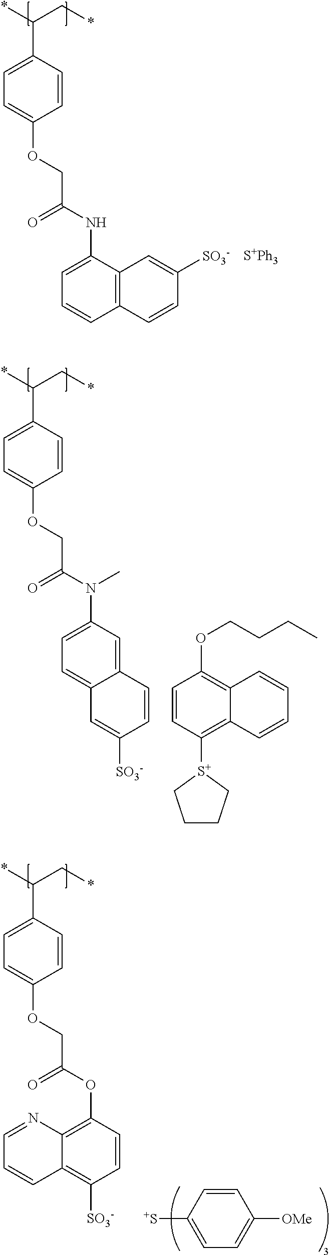

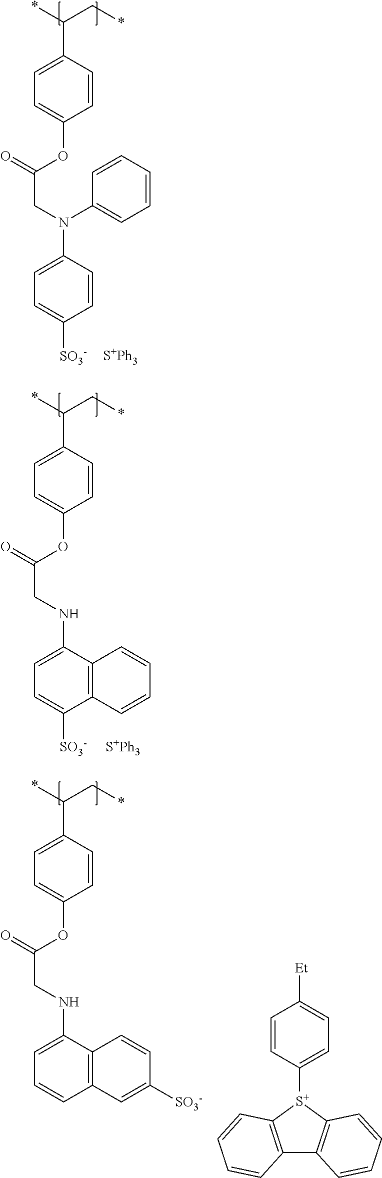

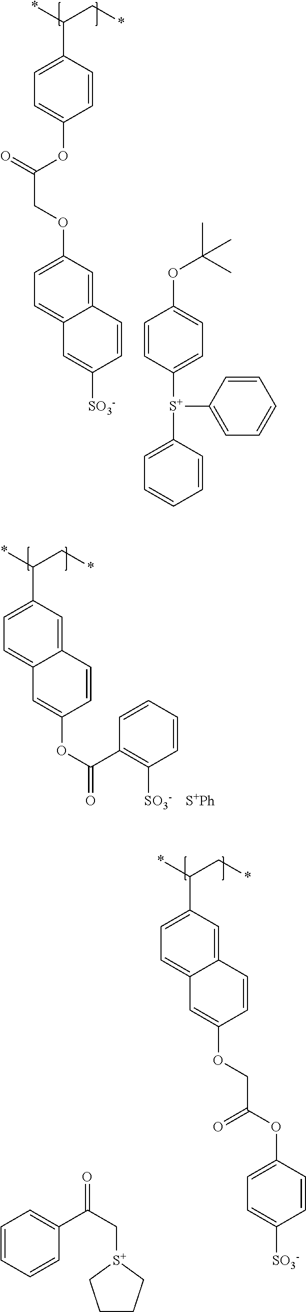

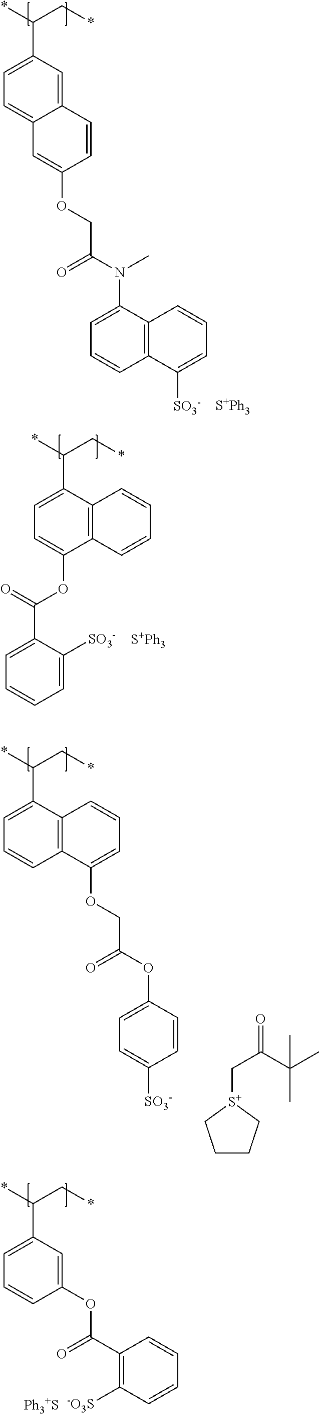

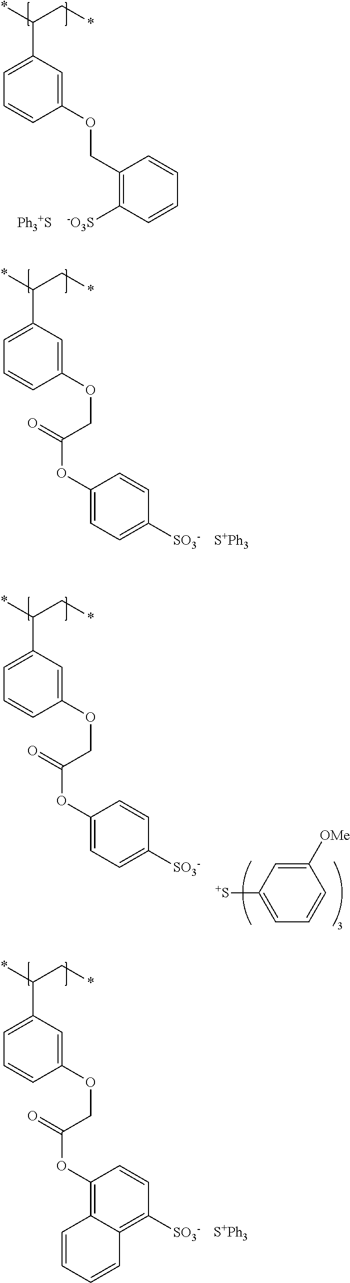

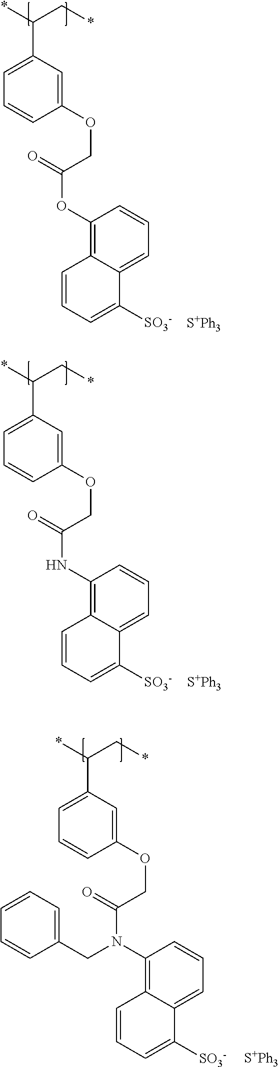

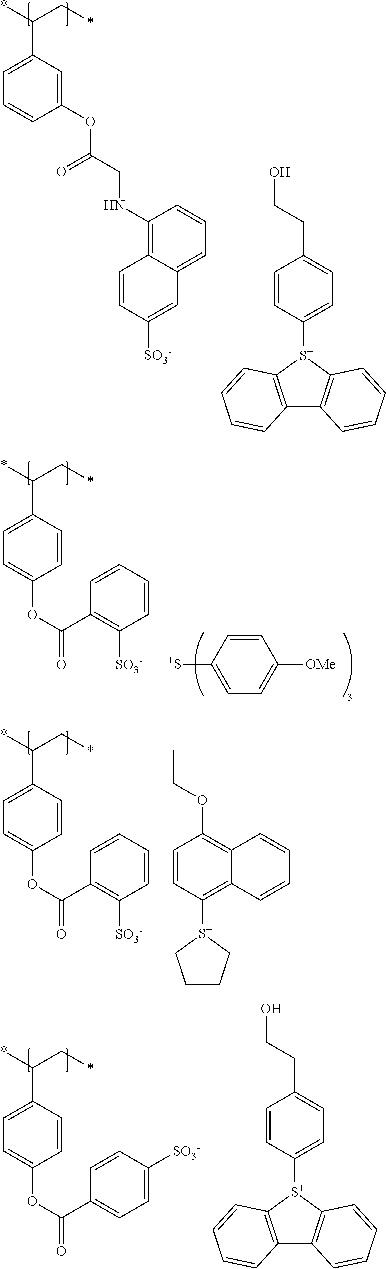

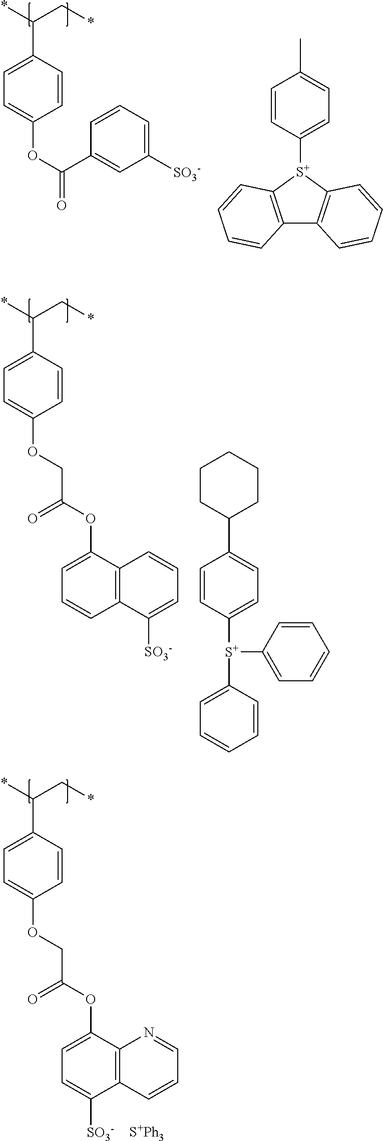

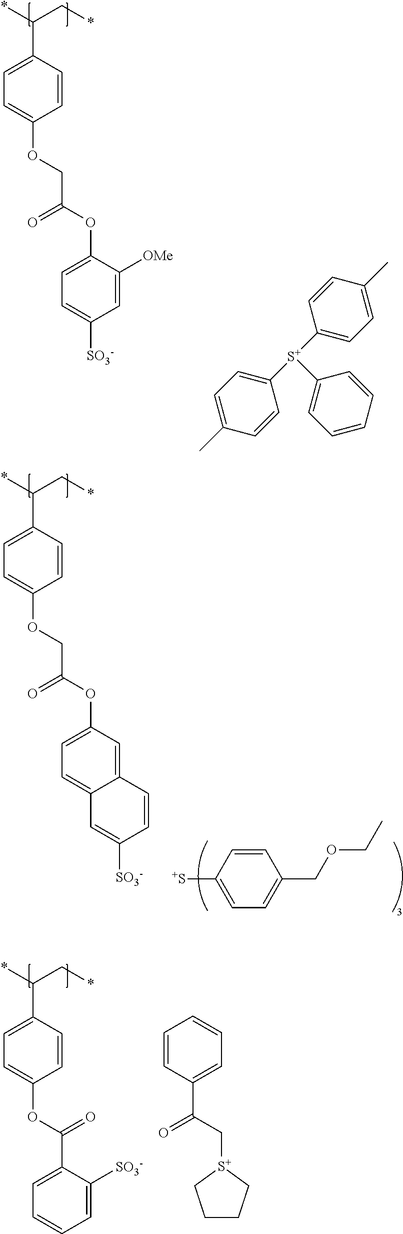

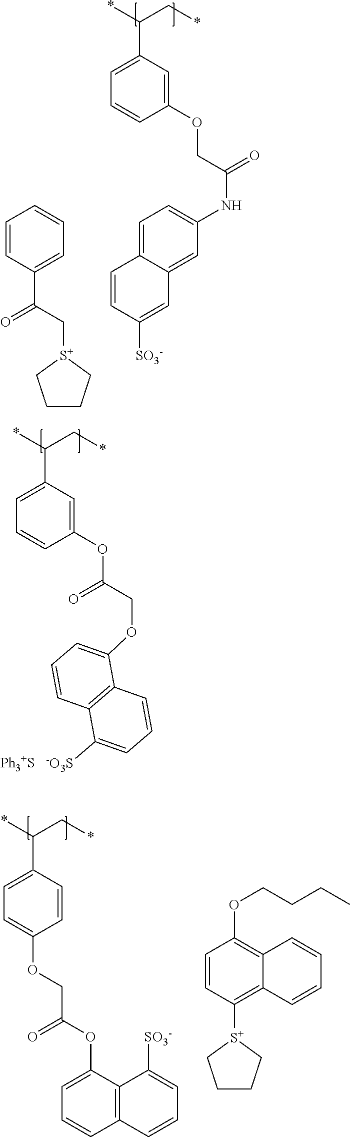

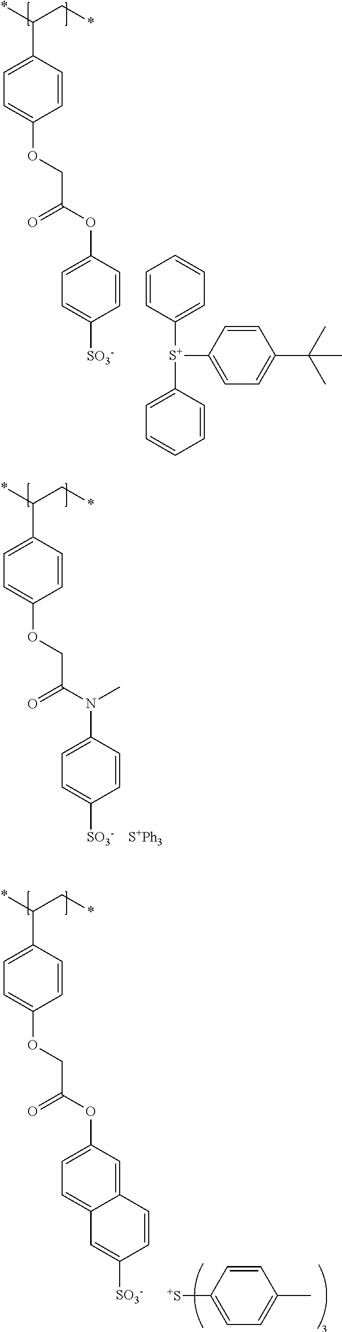

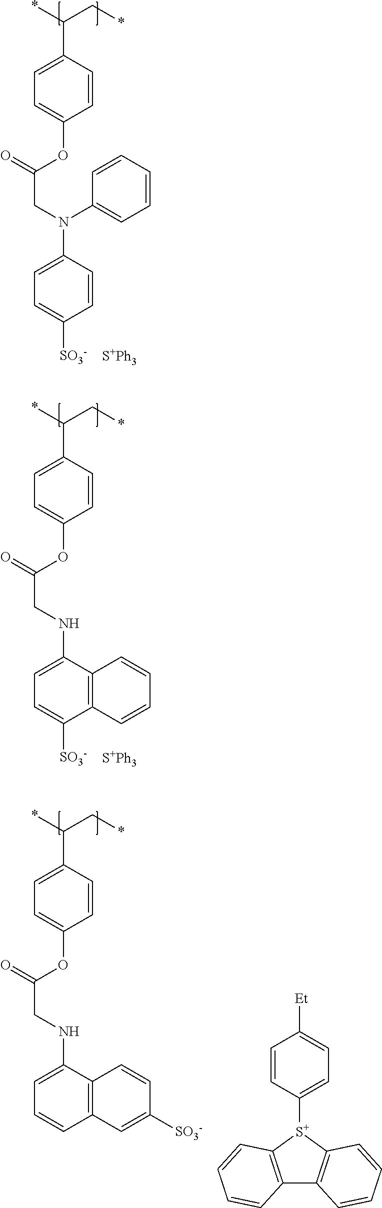

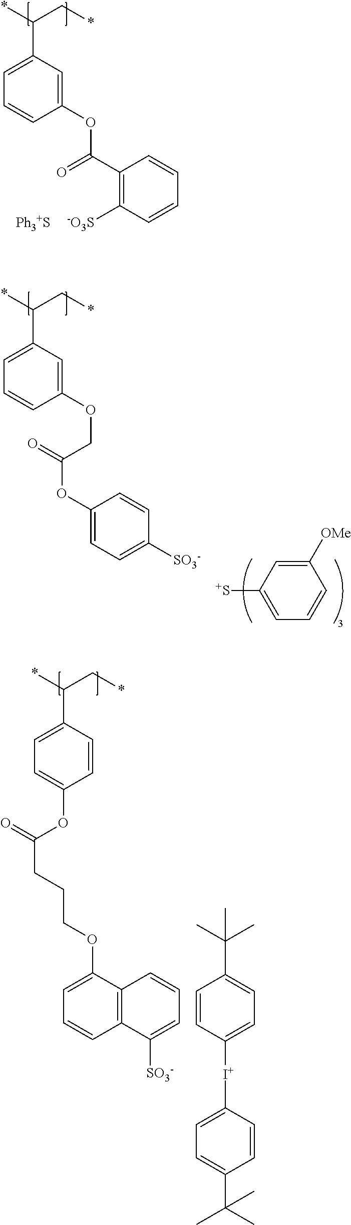

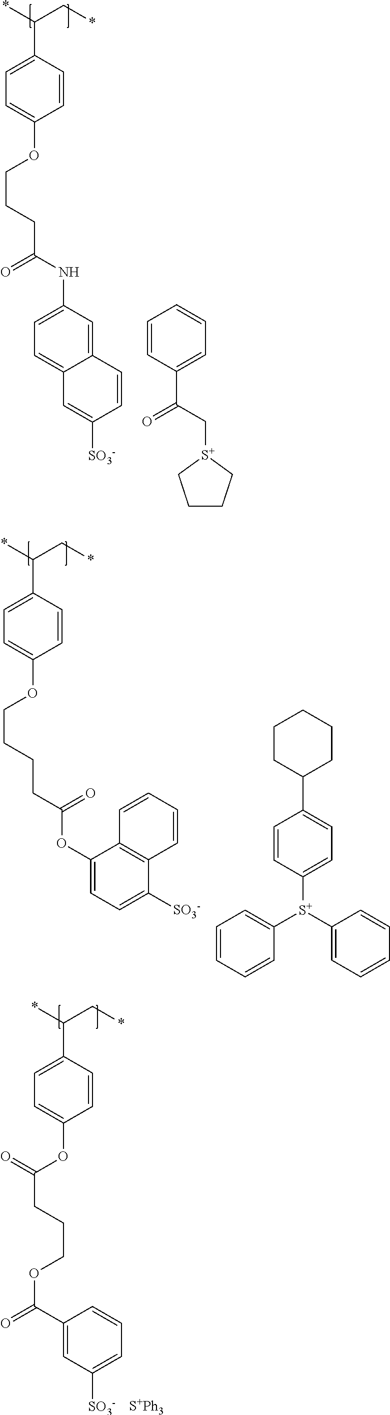

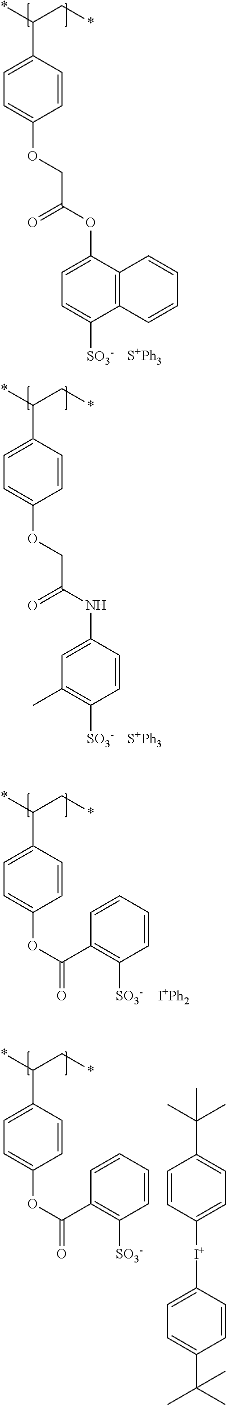

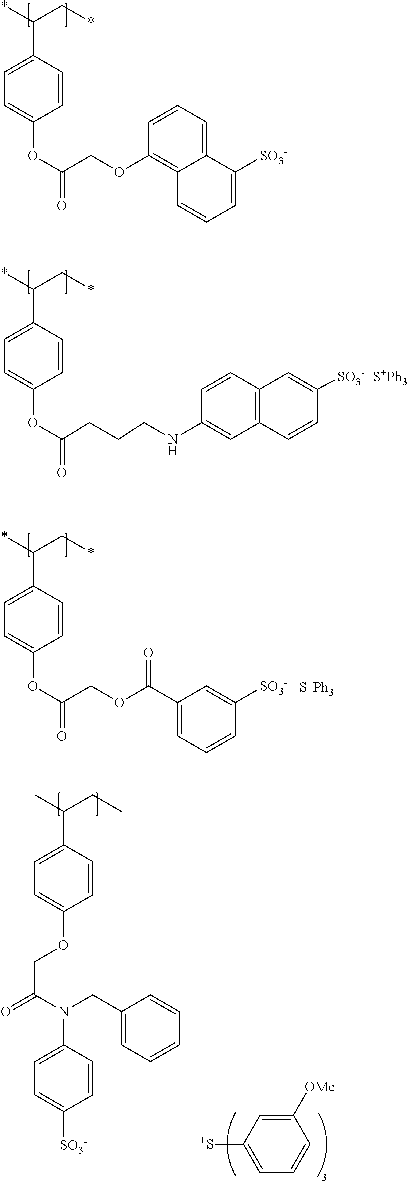

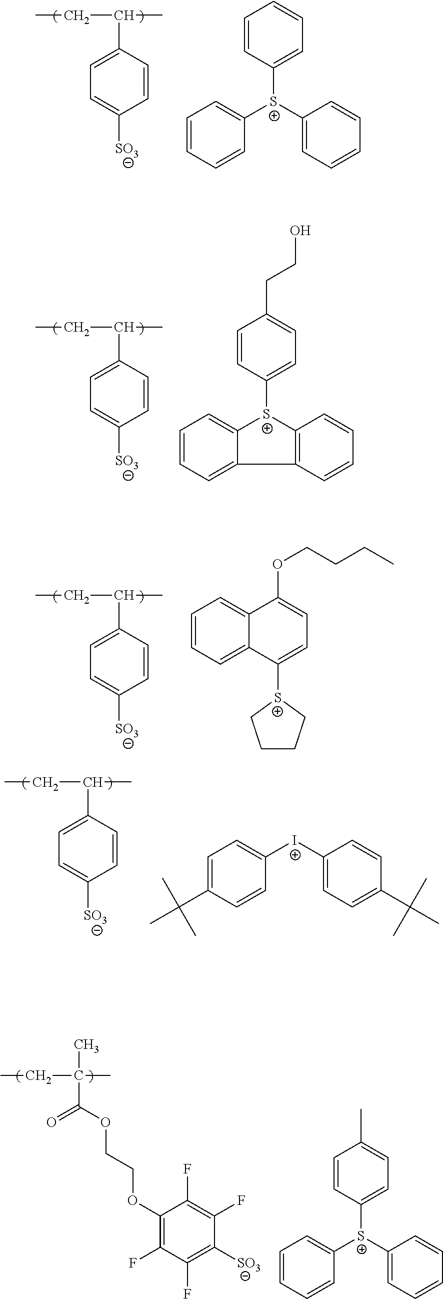

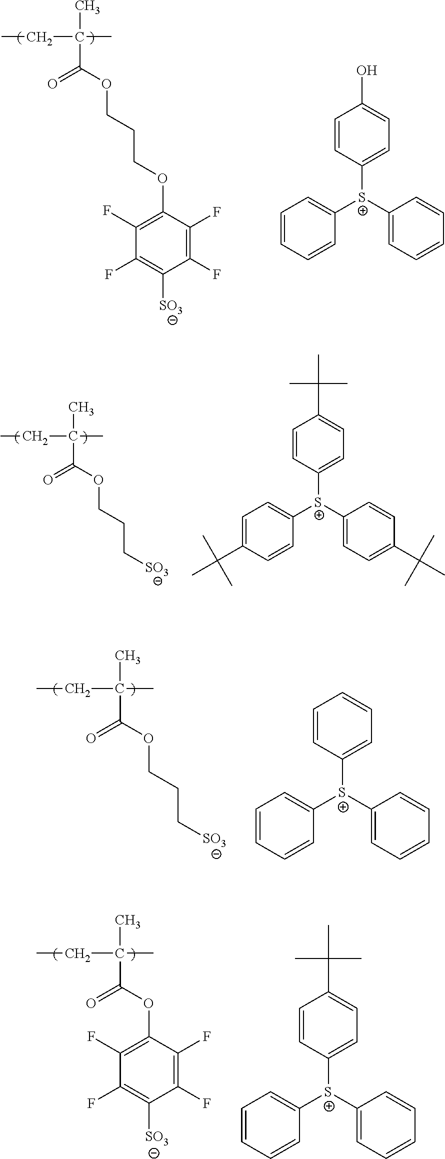

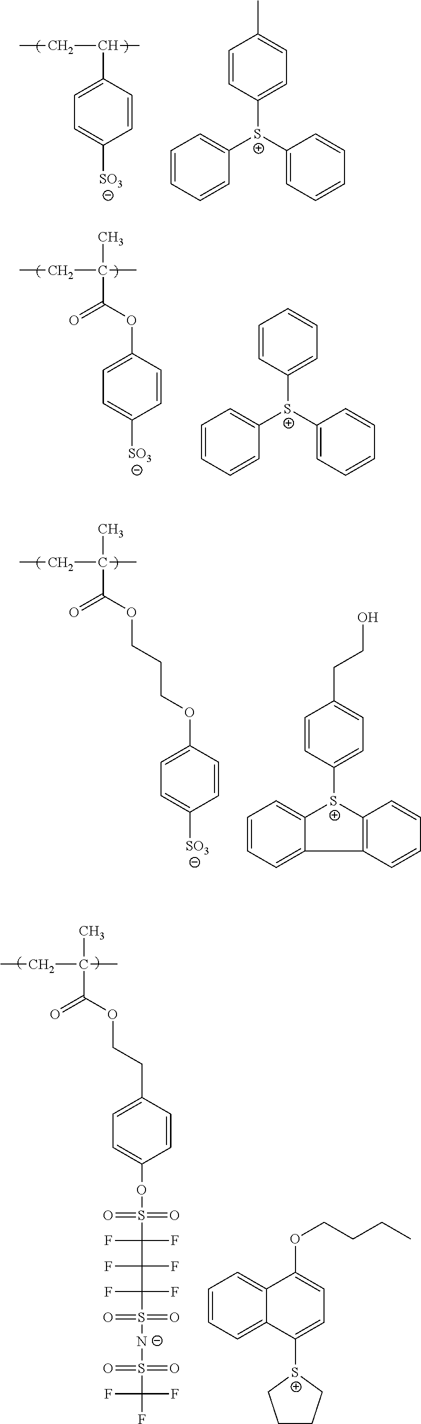

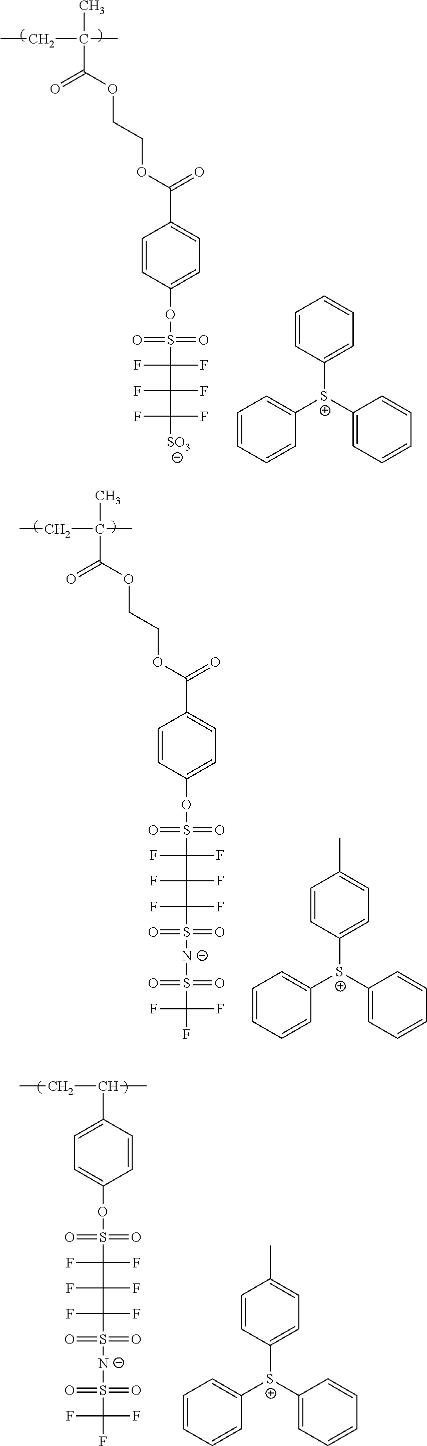

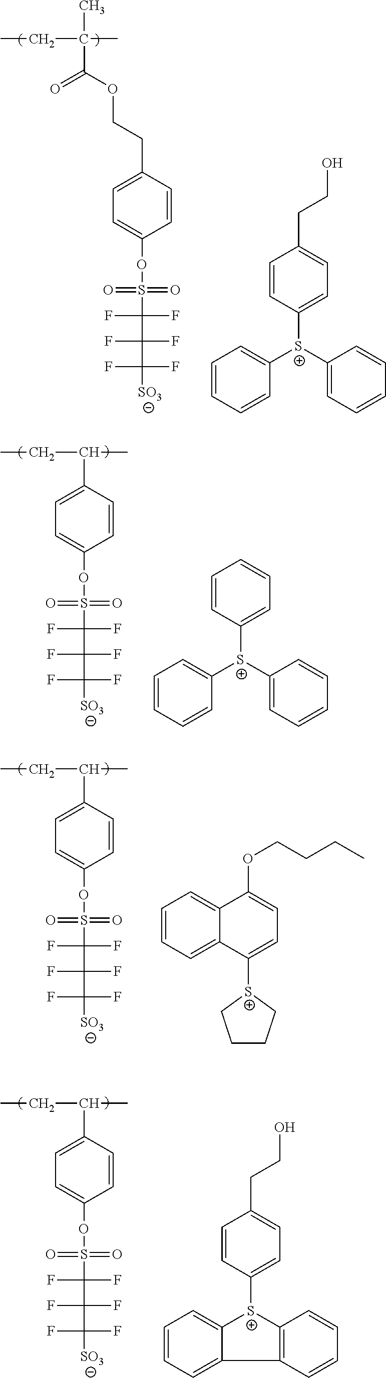

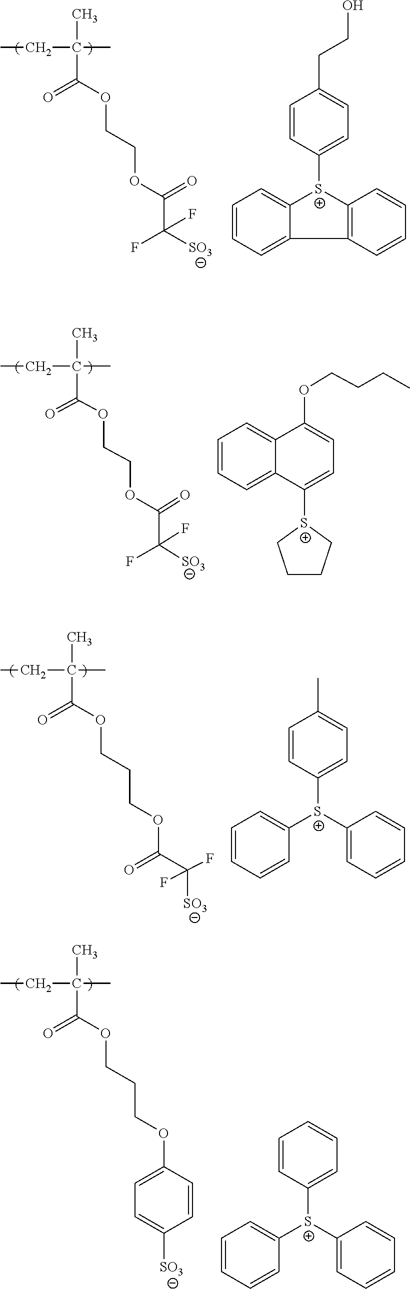

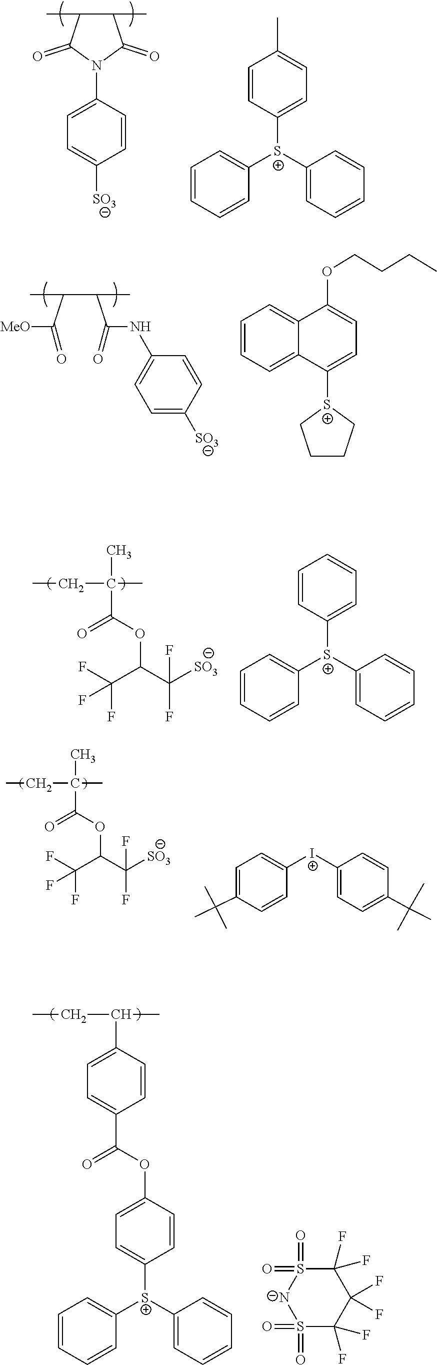

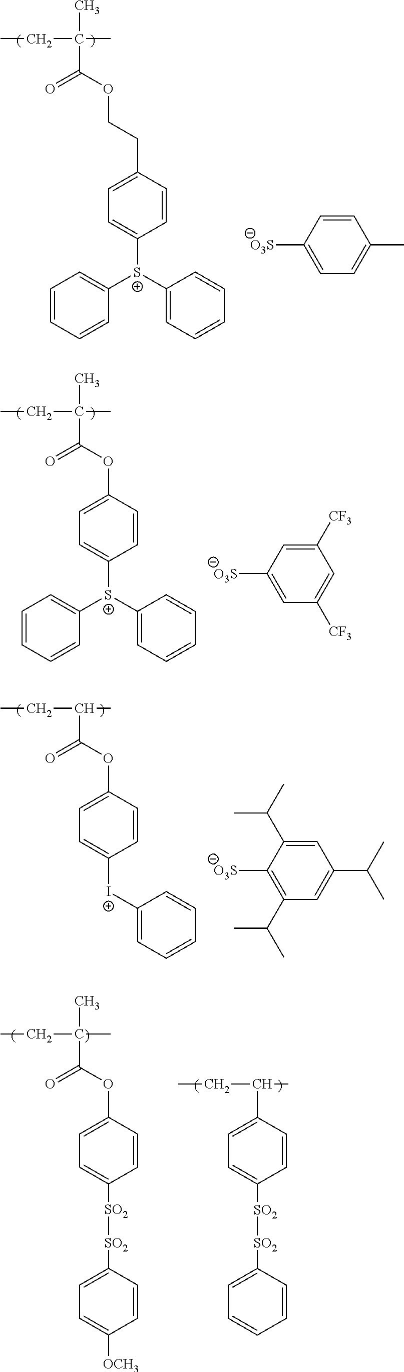

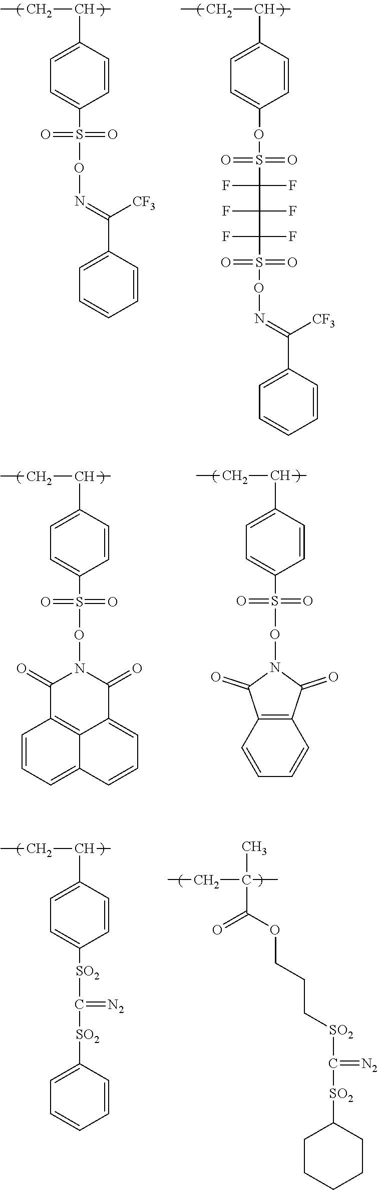

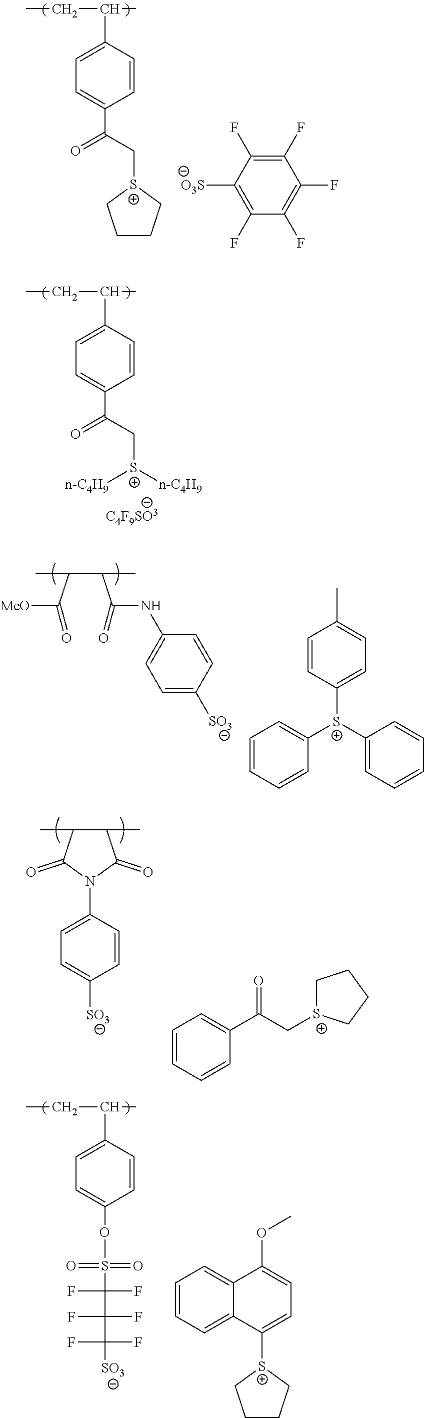

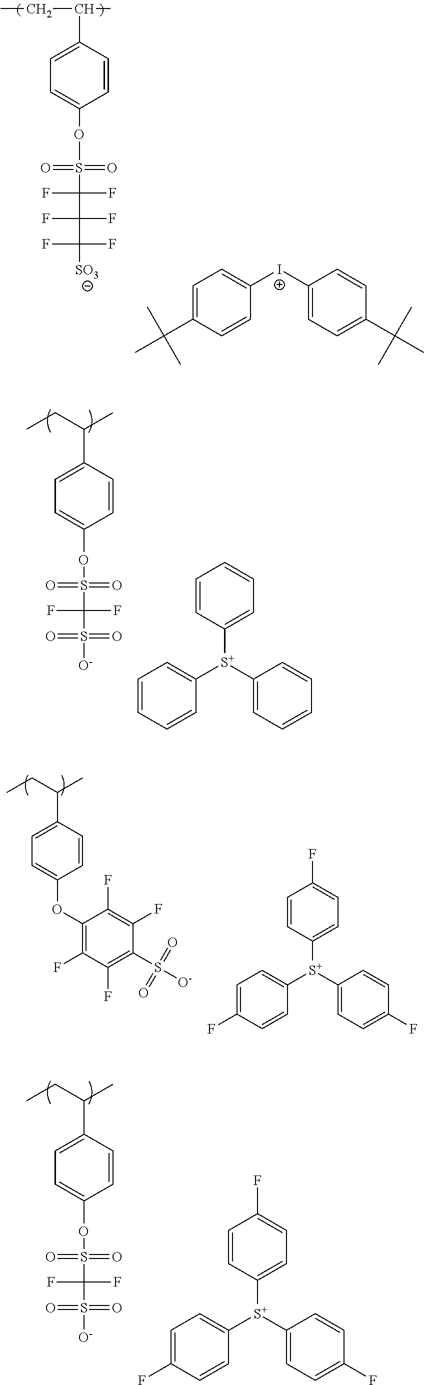

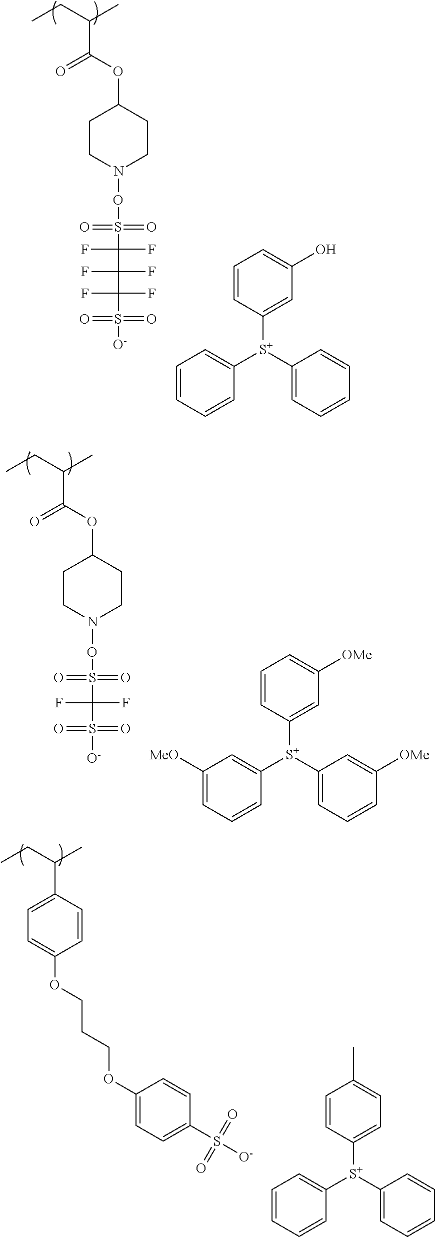

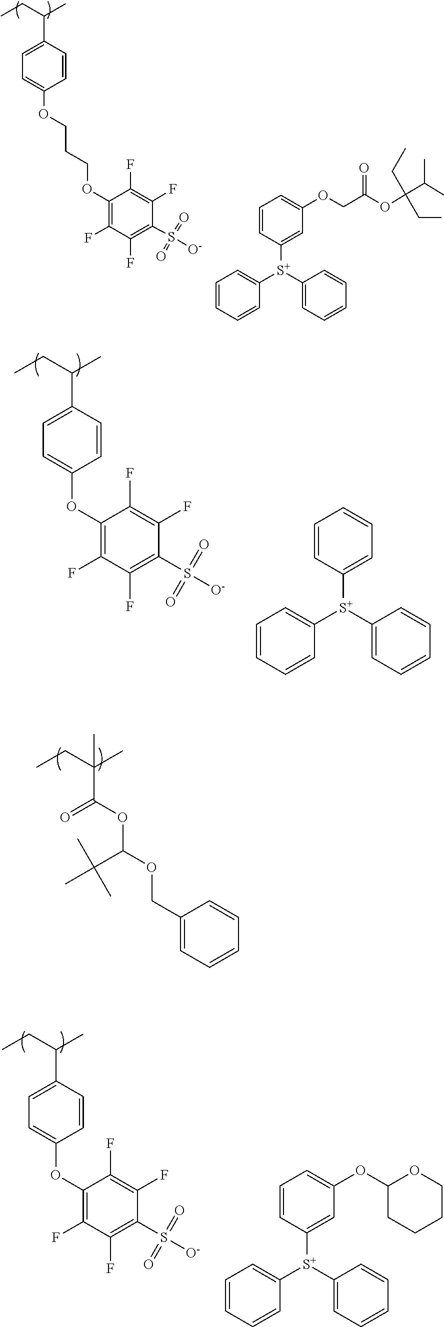

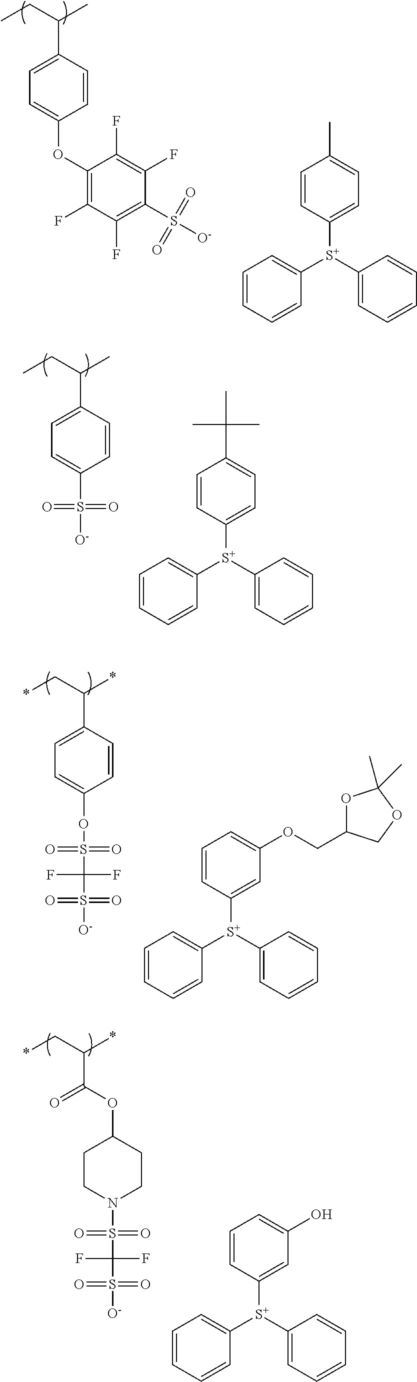

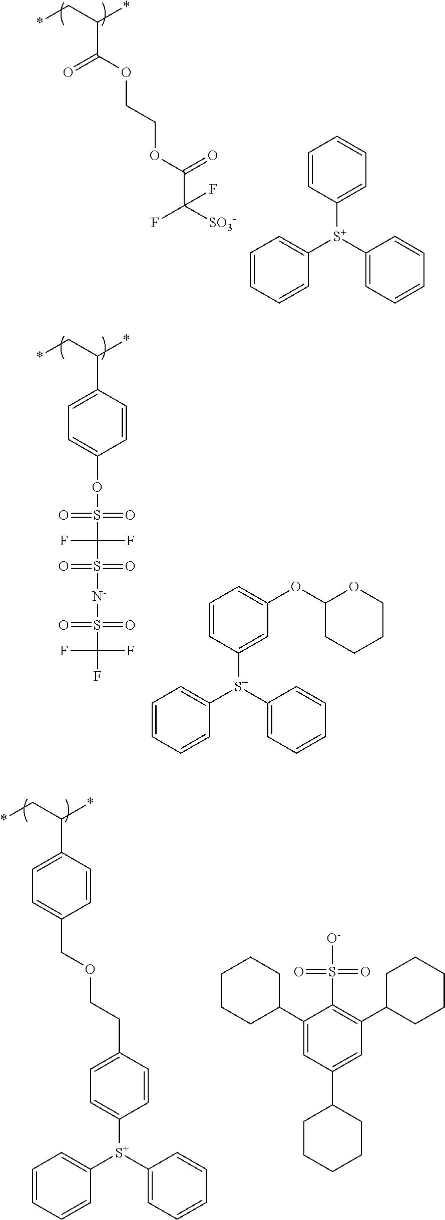

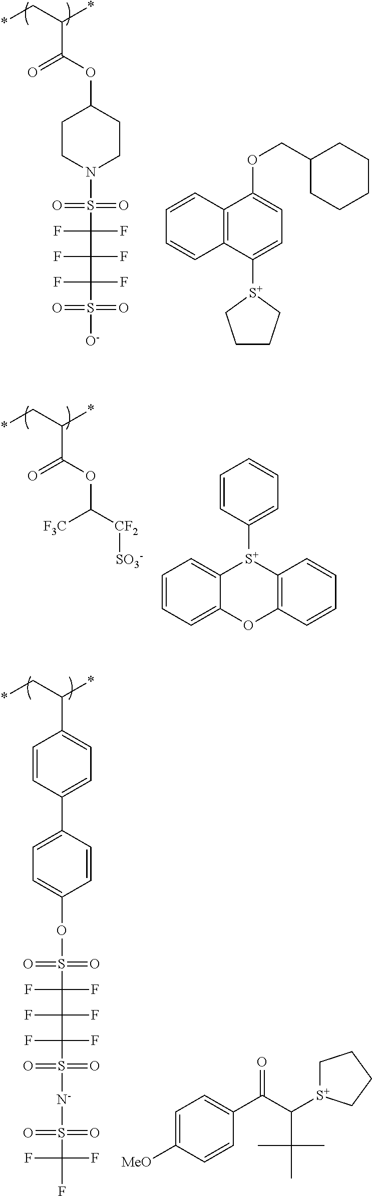

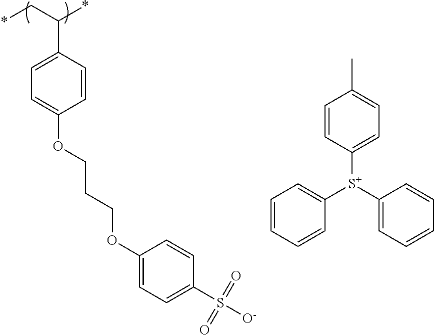

The content of the repeating unit represented by General Formula (4) in the resin (A) is preferably within a range of 1 mol % to 40 mol %, more preferably within a range of 2 mol % to 30 mol %, and particularly preferably within a range of 5 mol % to 25 mol %, with respect to the entirety of repeating units in the resin (A).

The resin (Ab) of the present invention may further have a repeating unit (b) represented by the following General Formula (A).

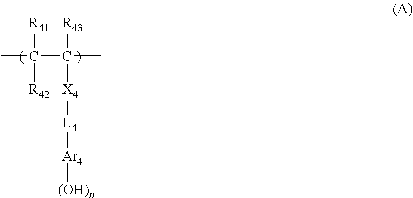

In General Formula (A), each of R₄₁, R₄₂, and R₄₃ independently represents a hydrogen atom, an alkyl group, a halogen atom, a cyano group, or an alkoxycarbonyl group. (Here, R₄₂ may be bonded to Ar₄ or X₄ to form a ring, and R₄₂ in this case represents a single bond or an alkylene group.)

X₄ represents a single bond, an alkylene group, —COO—, or —CONR₆₄—. (Here, R₆₄ represents a hydrogen atom or an alkyl group.)

L₄ represents a single bond, —COO—, or an alkylene group.

Ar₄ represents an (n+1) valent aromatic ring group, and, in the case of being bonded to R₄₂ to form a ring, Ar₄ represents an (n+2) valent aromatic ring group.

n represents an integer of 1 to 4.

Preferable examples of the alkyl group represented by each of R₄₁, R₄₂, and R₄₃ include an alkyl group having 20 or less carbon atoms such as a methyl group, an ethyl group, a propyl group, an isopropyl group, an n-butyl group, a sec-butyl group, a hexyl group, a 2-ethylhexyl group, an octyl group, or a dodecyl group, which may have a substituent, and an alkyl group having 8 or less carbon atoms is more preferable, and an alkyl group having 3 or less carbon atoms is particularly preferable.

Specific examples and preferable examples of the alkyl group included in the alkoxycarbonyl group represented by each of R₄₁, R₄₂, and R₄₃ include the same as those for the alkyl group represented by each of R₄₁, R₄₂, and R₄₃ described above.

Examples of the halogen atom represented by each of R₄₁, R₄₂, and R₄₃ include a fluorine atom, a chlorine atom, a bromine atom, and an iodine atom, and a fluorine atom is particularly preferable.

Ar₄ represents an (n+1) valent aromatic ring group. The bivalent aromatic ring group in a case where n is 1 may have a substituent, and preferable examples thereof include arylene groups having 6 to 18 carbon atoms such as a phenylene group, a tolylene group, a naphthylene group, and an anthracenylene group, and aromatic ring groups including a hetero ring, such as thiophene, furan, pyrrole, benzothiophene, benzofuran, benzopyrrole, triazine, imidazole, benzimidazole, triazole, thiadiazole, and thiazole.

Suitable specific examples of the (n+1) valent aromatic ring group in a case where n is an integer of 2 or greater can include a group obtained by excluding an arbitrary (n−1) hydrogen atoms from a specific example described above of the divalent aromatic ring group.

The (n+1) valent aromatic ring group may further have a substituent.

Examples of the alkylene group represented by L₄ include an alkylene group having 1 to 8 carbon atoms such as a methylene group, an ethylene group, a propylene group, a butylene group, a hexylene group, or an octylene group, which preferably may have a substituent.

The alkylene group represented by X₄ is the same as the alkylene group as the divalent connecting group represented by L in General Formula (Ab), and the preferable range thereof is also the same.

The alkylene group represented by R₄₂ in a case where R₄₂ and Ar₄ or X₄ are bonded to each other to form a ring may be linear or branched, and is preferably an alkylene group having 1 to 5 carbon atoms.

The alkylene group represented by X₄ in a case where R₄₂ and X₄ are bonded to each other to form a ring may be linear or branched, and is preferably an alkylene group having 1 to 5 carbon atoms.

Examples of the alkyl group represented by R₆₄ in —CONR₆₄— (R₆₄ represents a hydrogen atom or an alkyl group) represented by X₄ include the same as the alkyl group represented by each of R₄₁ to R₄₃.

X₄ is preferably a single bond, an alkylene group, —COO—, or —CONH—, and more preferably a single bond or —COO—.

Ar₄ is more preferably an aromatic ring group having 6 to 18 carbon atoms which may have a substituent, and particularly preferably a benzene ring group, a naphthalene ring group, or a biphenylene ring group

The repeating unit (b) preferably has a hydroxystyrene structure. That is, An₄ is preferably a benzene ring group.

Examples of the preferable substituent in each group described above can include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

The repeating unit represented by General Formula (A) is preferably a repeating unit represented by the following Formula (A1) or (A2), and more preferably the repeating unit represented by General Formula (A1). R″ represents a hydrogen atom or a methyl group.

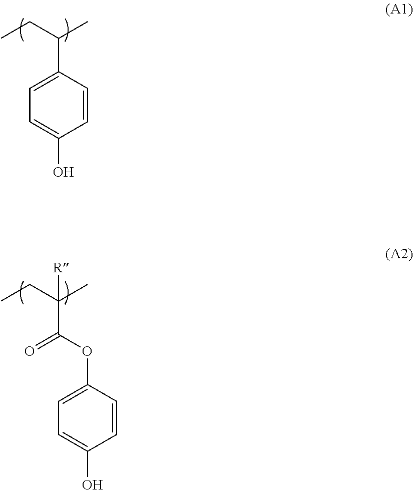

The content of the repeating unit represented by General Formula (A) is preferably 10 mol % to 80 mol %, more preferably 15 mol % to 65 mol %, and most preferably 20 mol % to 50 mol %, with respect to the entirety of repeating units in the resin (Ab).

Specific examples of the repeating unit (b) represented by General Formula (A) will be shown below, but the present invention is not limited thereto. In the formula, a represents an integer of 1 or 2.

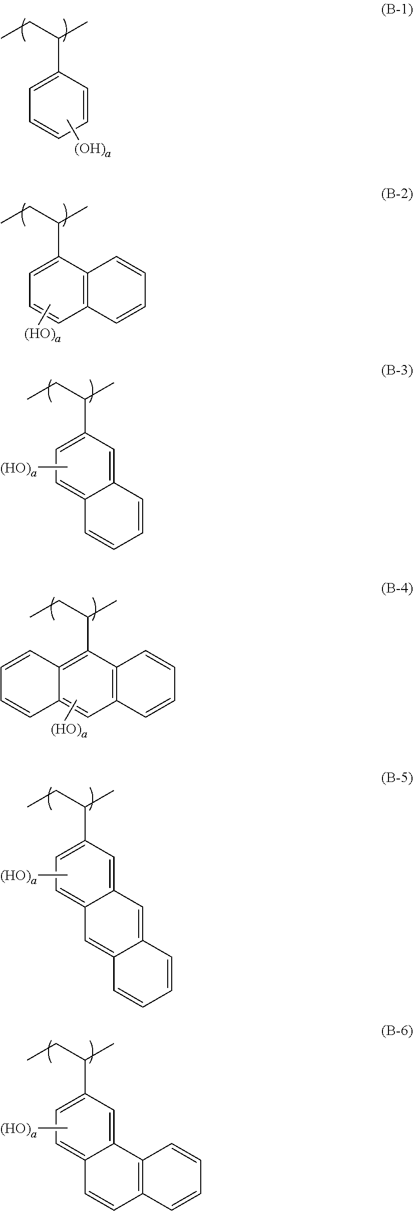

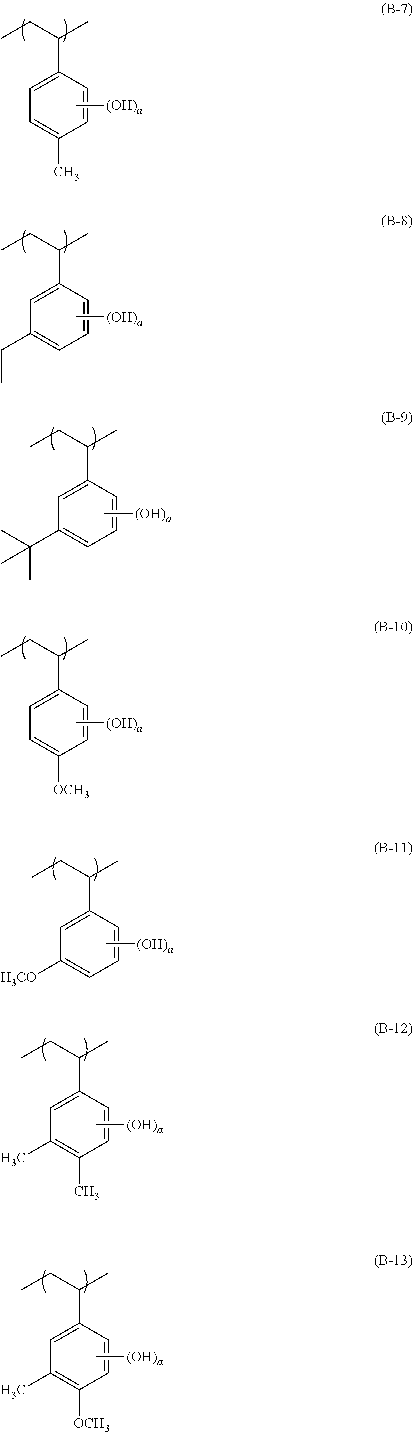

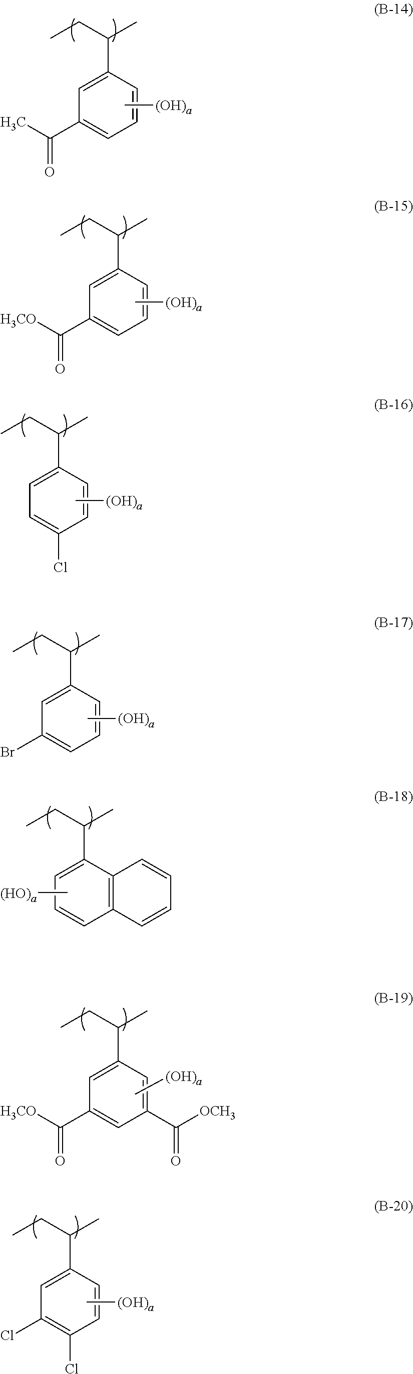

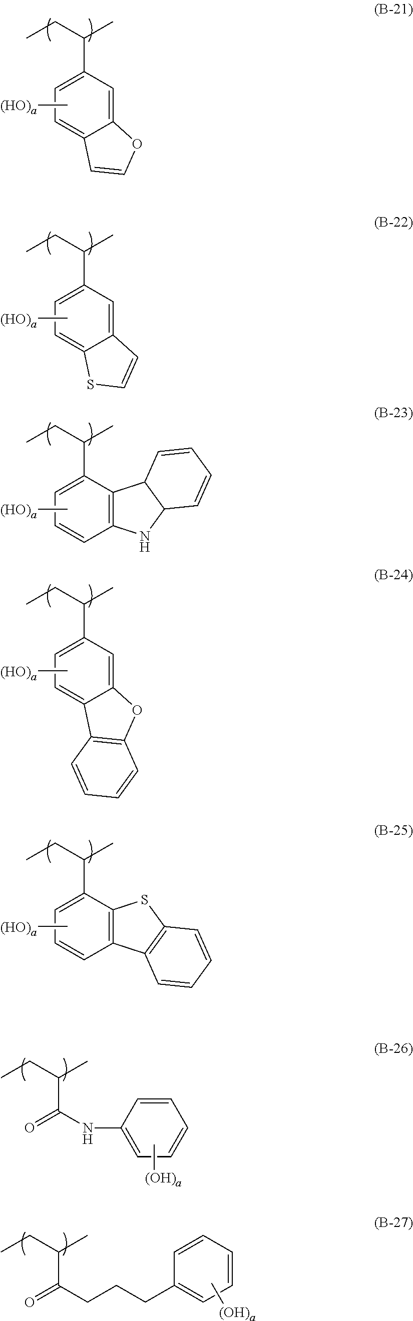

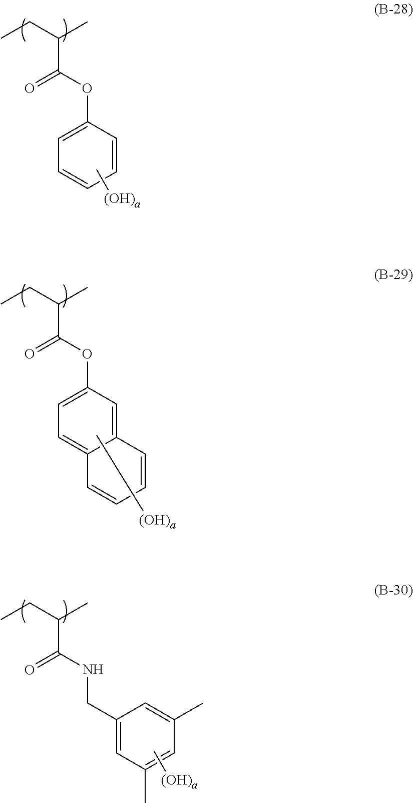

The resin (Ab) may include two or more types of the repeating unit represented by General Formula (A).

The content (in the case of containing plural types, the sum total content) of the repeating unit represented by General Formula (A) in the resin (Ab) is preferably 10 mol % to 70 mol %, more preferably 15 mol % to 55 mol %, and most preferably 20 mol % to 40 mol %, with respect to the entirety of repeating units in the resin (Ab), from the viewpoint of improving dissolution contrast with respect to a developer including an organic solvent, of a resist film.

The resin (Ab) preferably includes a repeating unit (b′) having a polar group different from the repeating unit represented by General Formula (A). When the resin (Ab) includes the repeating unit (b′), for example, the sensitivity of a composition including the resin can be improved. The repeating unit (b′) is preferably a non-acid-decomposable repeating unit (that is, a repeating unit which does not include an acid-decomposable group).

The polar group which can be included in the repeating unit (b′) is particularly preferably a group including an alcoholic hydroxyl group, a cyano group, a lactone group, a sultone group, or a cyano lactone structure.

When the resin further contains a repeating unit having an alcoholic hydroxyl group, the exposure latitude (EL) of a composition including the resin can be further improved.

When the resin further contains a repeating unit having a cyano group, the sensitivity of a composition including the resin can be further improved.

When the resin further contains a repeating unit having a lactone group, dissolution contrast with respect to a developer including an organic solvent can be further improved. In this manner, the dry etching resistance, the coating properties, and the adhesion to a substrate of a composition including the resin can also be further improved.

When the resin further contains a repeating unit having a group including a lactone structure having a cyano group, dissolution contrast with respect to a developer including an organic solvent can be further improved. In this manner, the sensitivity, the dry etching resistance, the coating properties, and the adhesion to a substrate of a composition including the resin can also be further improved. Additionally, in this manner, a function due to each of a cyano group and a lactone group can be carried by a single repeating unit, and thus, flexibility of design of the resin can be further increased.

In a case where the polar group which the repeating unit (b′) has is an alcoholic hydroxyl group, the polar group is preferably represented by at least one selected from the group consisting of the following General Formulas (I-1H) to (I-10H). In particular, the polar group is more preferably represented by at least one selected from the group consisting of the following General Formulas (I-1H) to (I-3H), and still more preferably represented by the following General Formula (I-1H).

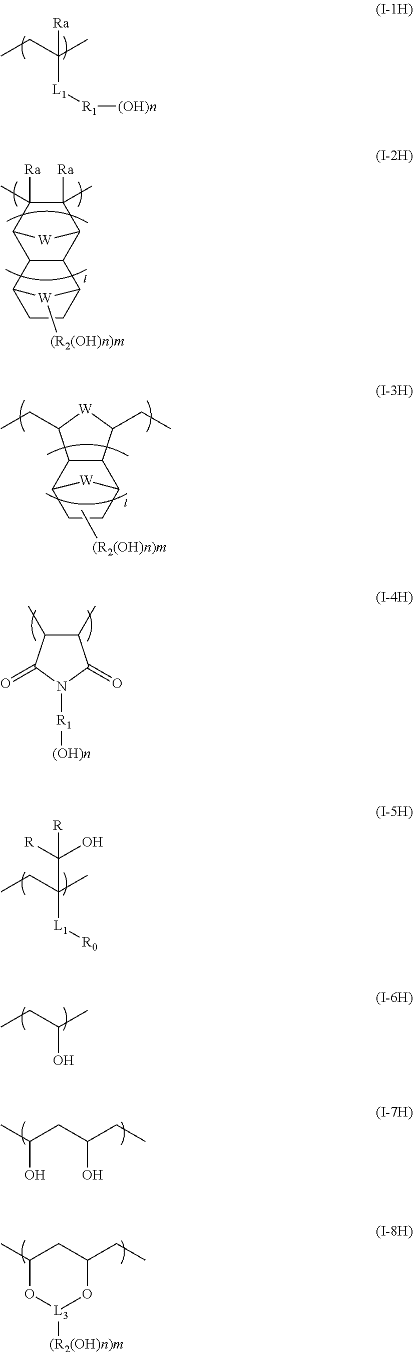

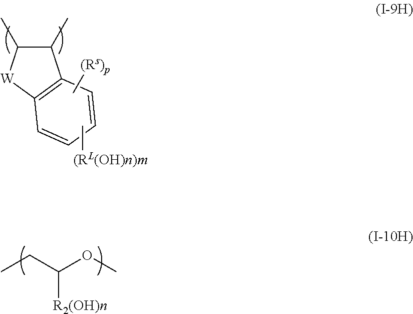

In the formula, each of Ra's independently represents a hydrogen atom, an alkyl group, or a group represented by —CH₂—O—Ra₂. Here, Ra₂ represents a hydrogen atom, an alkyl group, or an acyl group.

R₁ represents an (n+1) valent organic group.

In a case where m is 2 or greater, each of R₂'s independently represents a single bond or an (n+1) valent organic group.

Each of OP's independently represents the group which generates an alcoholic hydroxyl group by being decomposed due to the action of an acid. In a case where n is 2 or greater and/or m is 2 or greater, two or more OP's may be bonded to each other to form a ring.

W represents a methylene group, an oxygen atom, or a sulfur atom.

Each of n and m represents an integer of 1 or greater. In a case where R₂ in General Formula (1-2), (1-3), or (1-8) is a single bond, n is 1.

1 represents an integer of 0 or greater.

L₁ represents a connecting group represented by —COO—, —OCO—, —CONH—, —O—, —Ar—, —SO₃—, or —SO₂NH—. Here, Ar represents a divalent aromatic ring group.

Each of R's independently represents a hydrogen atom or an alkyl group.

R₀ represents a hydrogen atom or an organic group.

L₃ represents an (m+2) valent connecting group.

In a case where m is 2 or greater, each of R^{L}'s independently represents an (n+1) valent connecting group.

In a case where p is 2 or greater, each of R^{S}'s independently represents a substituent. In a case where p is 2 or greater, a plurality of R^{S}'s may be bonded to each other to form a ring.

p represents an integer of 0 to 3.

Ra represents a hydrogen atom, an alkyl group, or a group represented by —CH₂—O—Ra₂. Ra is preferably a hydrogen atom or an alkyl group having 1 to 10 carbon atoms, and more preferably a hydrogen atom or a methyl group.

W represents a methylene group, an oxygen atom, or a sulfur atom. W is preferably a methylene group or an oxygen atom.

R₁ represents an (n+1) valent organic group. R₁ is preferably a nonaromatic hydrocarbon group. In this case, R₁ may be a chain hydrocarbon group or may be an alicyclic hydrocarbon group. R₁ is more preferably an alicyclic hydrocarbon group.

R₂ represents a single bond or an (n+1) valent organic group. R₂ is preferably a single bond or a nonaromatic hydrocarbon group. In this case, R₂ may be a chain hydrocarbon group or may be an alicyclic hydrocarbon group.

In a case where R₁ and/or R₂ is a chain hydrocarbon group, the hydrocarbon group may be linear or may be branched. In addition, the chain hydrocarbon group preferably has 1 to 8 carbon atoms. For example, in a case where R₁ and/or R₂ is an alkylene group, R₁ and/or R₂ is preferably a methylene group, an ethylene group, an n-propylene group, an isopropylene group, an n-butylene group, an isobutylene group, or a sec-butylene group.

In a case where R₁ and/or R₂ is an alicyclic hydrocarbon group, the alicyclic hydrocarbon group may be monocyclic or may be polycyclic. The alicyclic hydrocarbon group has, for example, a monocyclic structure, a bicyclic structure, a tricyclic structure, or a tetracyclic structure. The alicyclic hydrocarbon group typical has 5 or more carbon atoms, preferably 6 to 30 carbon atoms, and more preferably 7 to 25 carbon atoms.

Examples of the alicyclic hydrocarbon group include an alicyclic hydrocarbon having one of substructures listed below. Each of these substructures may have a substituent. In addition, the methylene group (—CH₂—) in each of these substructures may be substituted with an oxygen atom (—O—), a sulfur atom (—S—), a carbonyl group [—C(═O)—], a sulfonyl group [—S(═O)₂—], a sulfinyl group [—S(═O)—], or an imino group [—N(R)—] (R is a hydrogen atom or an alkyl group).

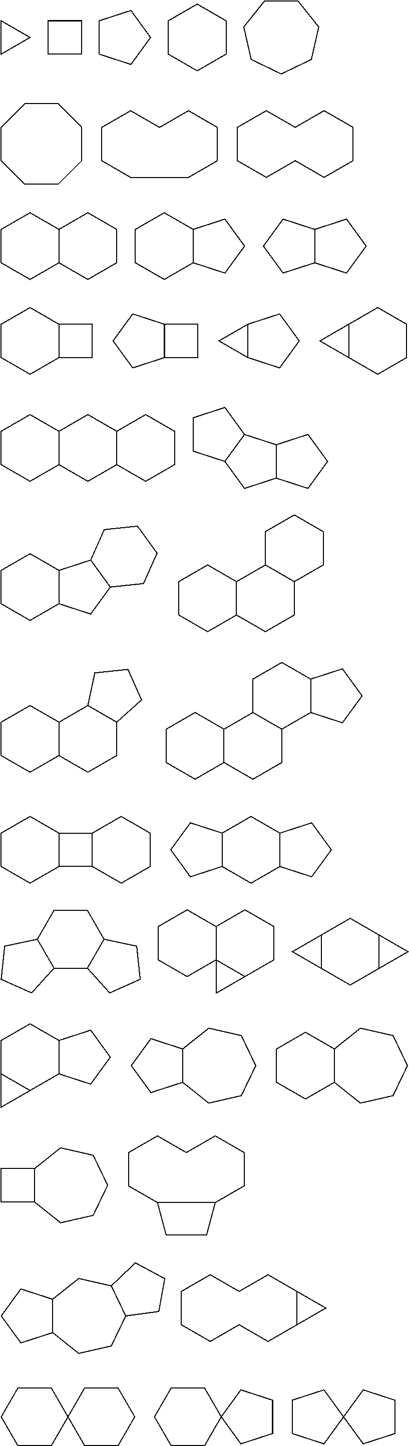

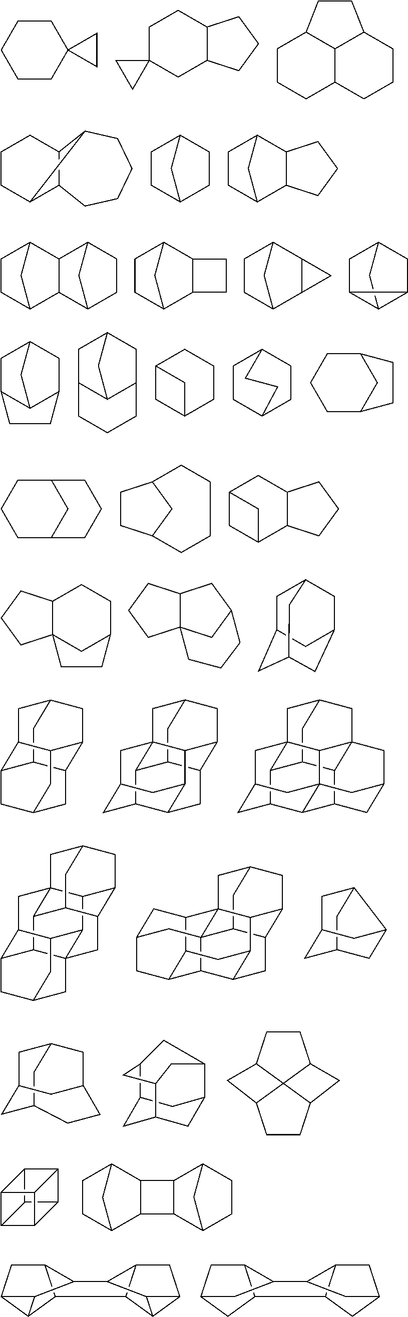

For example, in a case where R₁ and/or R₂ is a cycloalkylene group, R₁ and/or R₂ is preferably an adamantylene group, a noradamantylene group, a decahydronaphthylene group, a tricyclodecanylene group, a tetracyclododecanylene group, a norbornylene group, a cyclopentylene group, a cyclohexylene group, a cycloheptylene group, a cyclooctylene group, a cyclodecanylene group, or a cyclododecanylene group, and more preferably an adamantylene group, a norbornylene group, a cyclohexylene group, a cyclopentylene group, a tetracyclododecanylene group, or a tricyclodecanylene group.

The nonaromatic hydrocarbon group represented by R₁ and/or R₂ may have a substituent. Examples of the substituent include an alkyl group having 1 to 4 carbon atoms, a halogen atom, a hydroxy group, an alkoxy group having 1 to 4 carbon atoms, a carboxy group, and an alkoxycarbonyl group having 2 to 6 carbon atoms. The alkyl group, the alkoxy group, and the alkoxycarbonyl group described above may further have a substituent. Examples of the substituent include a hydroxy group, a halogen atom, and an alkoxy group.

L₁ represents a connecting group represented by —COO—, —OCO—, —CONH—, —O—, —Ar—, —SO₃—, or —SO₂NH—. Here, Ar represents a divalent aromatic ring group. L₁ is preferably a connecting group represented by —COO—, —CONH—, or —Ar—, and more preferably a connecting group represented by —COO— or —CONH—.

R represents a hydrogen atom or an alkyl group. The alkyl group may be linear, or may be branched. The alky group preferably has 1 to 6 carbon atoms, and more preferably 1 to 3 carbon atoms. R is preferably a hydrogen atom or a methyl group, and more preferably a hydrogen atom.

R₀ represents a hydrogen atom or an organic group. Examples of the organic group include an alkyl group, a cycloalkyl group, an aryl group, an alkynyl group, and an alkenyl group. R₀ is preferably a hydrogen atom or an alkyl group, and more preferably a hydrogen atom or a methyl group.

L₃ represents an (m+2) valent connecting group. That is, L₃ represents a tri- or higher valent connecting group. Examples of the connecting group include groups corresponding to specific examples listed below.

R^{L} represents an (n+1) valent connecting group. That is, R^{L} represents a di- or higher valent connecting group. Examples of the connecting group include an alkylene group, a cycloalkylene group, and groups corresponding to specific examples listed below. R^{L}'s may be bonded to each other to form a ring structure, or R^{L} may be bonded to R^{S} described below to form a ring structure.

R^{S} represents a substituent. Examples of the substituent include an alkyl group, an alkenyl group, an alkynyl group, an aryl group, an alkoxy group, an acyloxy group, an alkoxycarbonyl group, and a halogen atom.

n is an integer of 1 or greater. n is preferably an integer of 1 to 3, and more preferably 1 or 2. In addition, when n is 2 or greater, dissolution contrast with respect to a developer including an organic solvent can be further improved. Accordingly, by doing this, marginal resolving power and roughness characteristics can be further improved.

m is an integer of 1 or greater. m is preferably an integer of 1 to 3, and more preferably 1 or 2.

l is an integer of 0 or greater. l is preferably 0 or 1.

p is an integer of 0 to 3.

When a repeating unit having a group which generates an alcoholic hydroxyl group by being decomposed due to the action of an acid and a repeating unit represented by at least one selected from the group consisting of General Formulas (I-1H) to (I-10H) are used in combination, for example, by the suppression of acid diffusion by the alcoholic hydroxyl group and the increase in sensitivity due to a group which generates an alcoholic hydroxyl group by being decomposed due to the action of an acid, the exposure latitude (EL) can be improved without degrading other performances.

In the case of having an alcoholic hydroxyl group, the content of the repeating unit is preferably 1 mol % to 60 mol %, more preferably 3 mol % to 50 mol %, and still more preferably 5 mol % to 40 mol %, with respect to the entirety of repeating units in the resin (Ab).

Specific examples of the repeating unit represented by any one of General Formulas (I-1H) to (I-10H) are shown below. Moreover, Ra in specific examples has the same meaning as that in General Formulas (I-1H) to (I-10H).

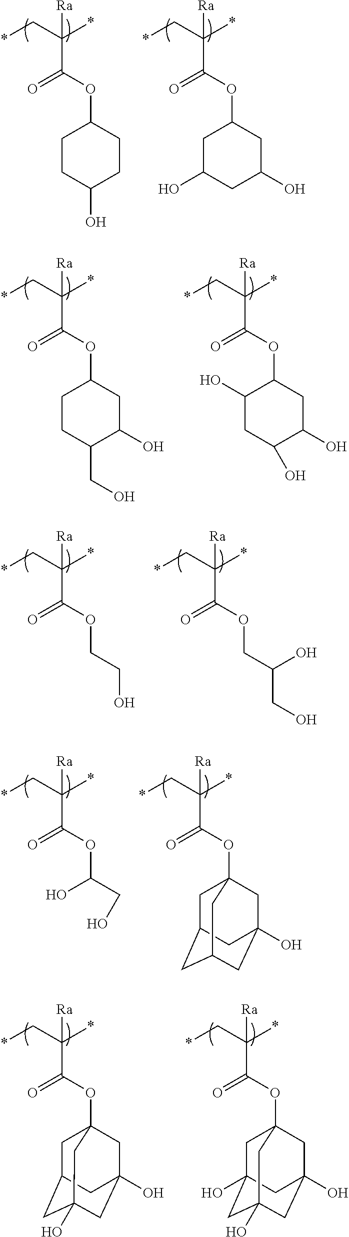

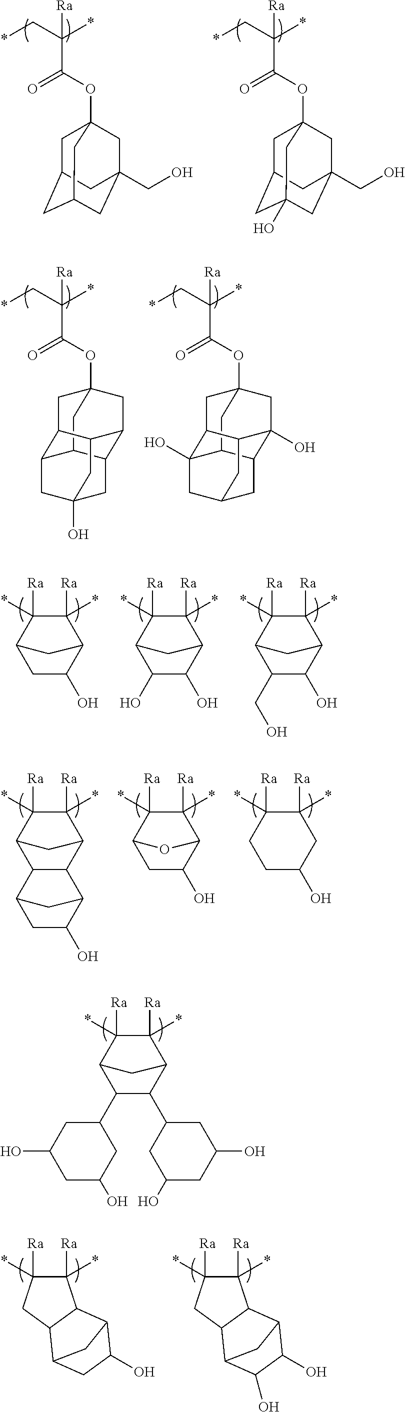

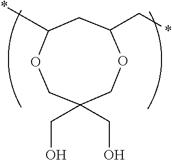

In a case where the polar group which the repeating unit (b′) has is an alcoholic hydroxyl group or a cyano group, as one aspect of a preferable repeating unit, a repeating unit having an alicyclic hydrocarbon structure substituted with a hydroxyl group or a cyano group is exemplified. At this time, an acid-decomposable group is not preferably included. As the alicyclic hydrocarbon structure in the alicyclic hydrocarbon structure substituted with a hydroxyl group or a cyano group, an adamantyl group, a diamantyl group, or a norbornane group is preferable. As a preferable alicyclic hydrocarbon structure substituted with a hydroxyl group or a cyano group, the substructures represented by the following General Formulas (VIIa) to (VIIc) are preferable. Thus, adhesion to a substrate and developer affinity are improved.

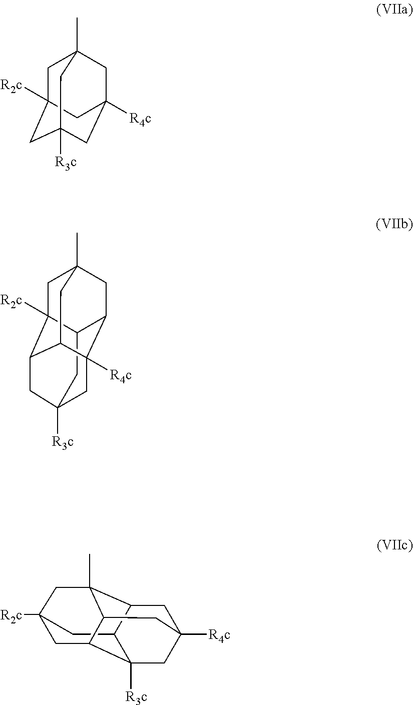

In General Formulas (VIIa) to (VIIc), each of R₂c to R₄c independently represents a hydrogen atom, a hydroxyl group, or a cyano group. Here, at least one of R₂c to R₄c is a hydroxyl group. Preferably, one or two of R₂c to R₄c are hydroxyl groups, and the other is a hydrogen atom. In General Formula (VIIa), more preferably, two of R₂c to R₄c are hydroxyl groups, and the other is a hydrogen atom.

As a repeating unit having a substructure represented by each of General Formulas (VIIa) to (VIIc), the repeating units represented by the following General Formulas (Alla) to (AIIc) can be exemplified.

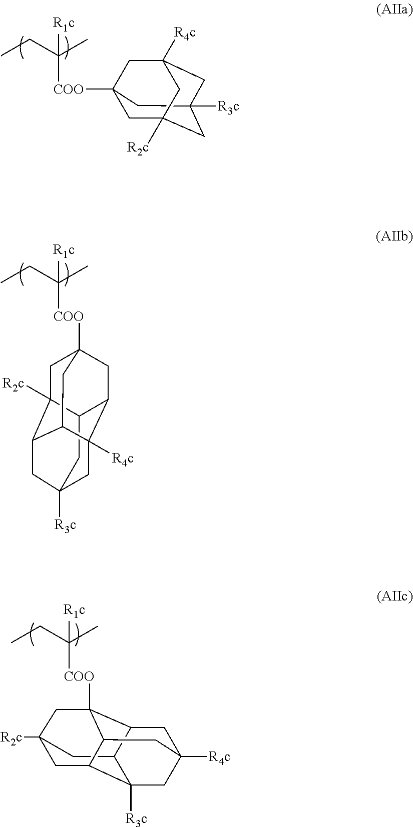

In General Formulas (Alla) to (AIIc), R₁c represents a hydrogen atom, a methyl group, a trifluoromethyl group, or a hydroxymethyl group.

R₂c to R₄c have the same meaning as R₂c to R₄c in General Formulas (VIIa) to (VIIc), respectively.

Although the resin (Ab) may contain or may not contain a repeating unit having a hydroxyl group or a cyano group, in a case where the resin (A) contains this repeating unit, the content of the repeating unit having a hydroxyl group or a cyano group is preferably 1 mol % to 60 mol %, more preferably 3 mol % to 50 mol %, and still more preferably 5 mol % to 40 mol %, with respect to the entirety of repeating units in the resin (Ab).

Specific examples of the repeating unit having a hydroxyl group or a cyano group are described below, but the present invention is not limited thereto.

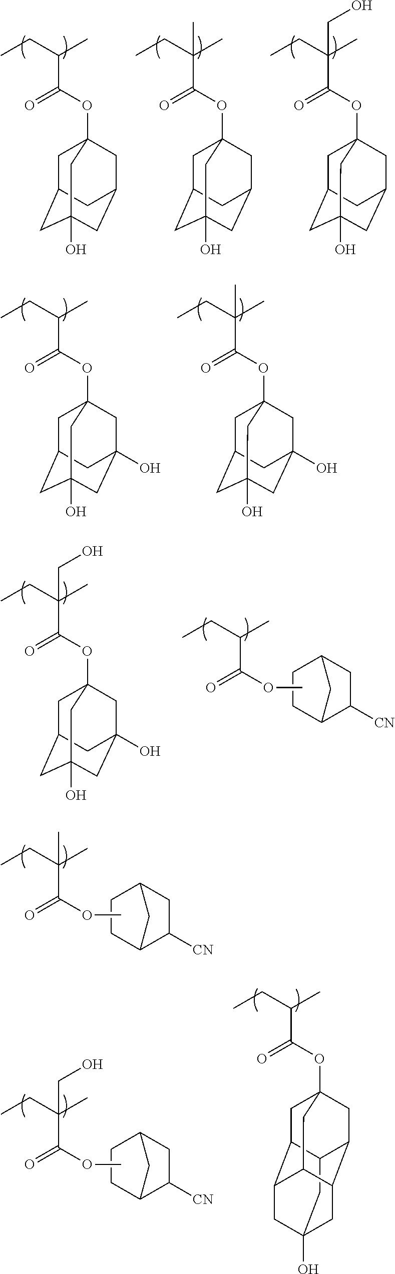

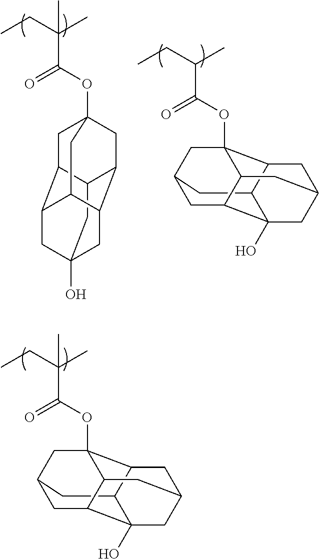

The repeating unit (b′) may be a repeating unit having a lactone structure as a polar group.

As the repeating unit having a lactone structure, a repeating unit represented by the following General Formula (AII) is more preferable.

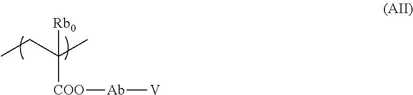

In General Formula (AII), Rb₀ represents a hydrogen atom, a halogen atom, or an alkyl group (preferably has 1 to 4 carbon atoms) which may have a substituent.

Preferable examples of the substituent which the alkyl group represented by Rb₀ may have include a hydroxyl group and a halogen atom. Examples of the halogen atom represented by Rb₀ include a fluorine atom, a chlorine atom, a bromine atom, and an iodine atom. Rb₀ is preferably a hydrogen atom, a methyl group, a hydroxymethyl group, or a trifluoromethyl group, and particularly preferably a hydrogen atom or a methyl group.

Ab represents a single bond, an alkylene group, a divalent connecting group having a monocyclic or polycyclic cycloalkyl structure, an ether bond, an ester bond, a carbonyl group, or a divalent connecting group obtained by combining these. Ab is preferably a single bond or a divalent connecting group represented by -Ab₁-CO₂—.

Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group having a lactone structure.

As the group having a lactone structure, any group can be used as long as the group has a lactone structure, but the group preferably has a 5- to 7-membered ring lactone structure. It is preferable that another ring structure be condensed with the 5- to 7-membered ring lactone structure while forming a bicyclo structure or a spiro structure. The group more preferably has a repeating unit having a lactone structure represented by any one of the following General Formulas (LC1-1) to (LC1-17). In addition, the lactone structure may be directly bonded to the main structure. A preferable structure is (LC1-1), (LC1-4), (LC1-5), (LC1-6), (LC1-8), (LC1-13), or (LC1-14).

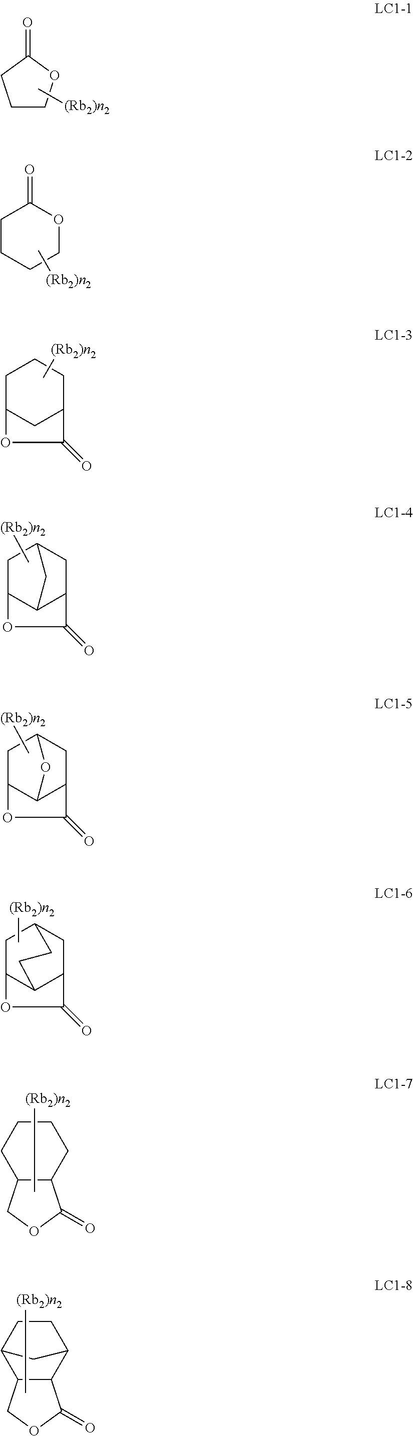

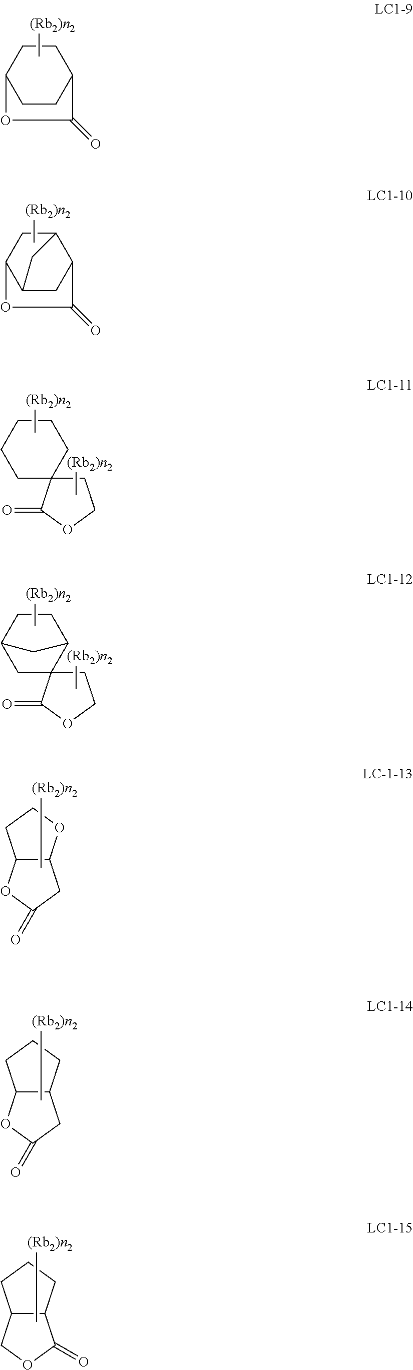

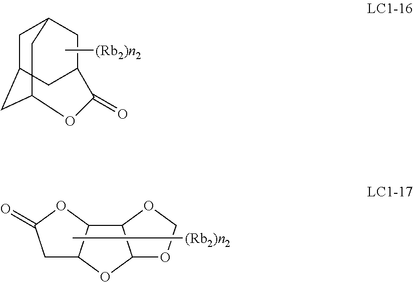

The lactone structural portion may or may not have a substituent (Rb₂). Preferable examples of the substituent (Rb₂) include an alkyl group having 1 to 8 carbon atoms, a monovalent cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. The substituent (Rb₂) is more preferably an alkyl group having 1 to 4 carbon atoms, a cyano group, or an acid-decomposable group. n₂ represents an integer of 0 to 4. When n₂ is 2 or greater, plural substituents (Rb₂) present in a molecule may be the same as or different from each other, and plural substituents (Rb₂) present in a molecule may be bonded to each other to form a ring.

The repeating unit having a lactone group typically has optical isomers, and any optical isomer may be used. In addition, one type of optical isomer may be used alone, or two or more types of optical isomers may be used in combination. In a case where one type of optical isomer is mainly used, the optical purity (ee) is preferably 90% or greater, and more preferably 95% or greater.

The resin (Ab) may contain or may not contain a repeating unit having a lactone structure, and in a case where the resin (Ab) contains the repeating unit having a lactone structure, the content of the repeating unit in the resin (Ab) is preferably within a range of 1 mol % to 70 mol %, more preferably within a range of 3 mol % to 65 mol %, and still more preferably within a range of 5 mol % to 60 mol %, with respect to the entirety of repeating units.

Specific examples of the repeating unit having a lactone structure in the resin (Ab) are shown below, but the present invention is not limited thereto. In the formula, Rx represents H, CH₃, CH₂OH, or CF₃.

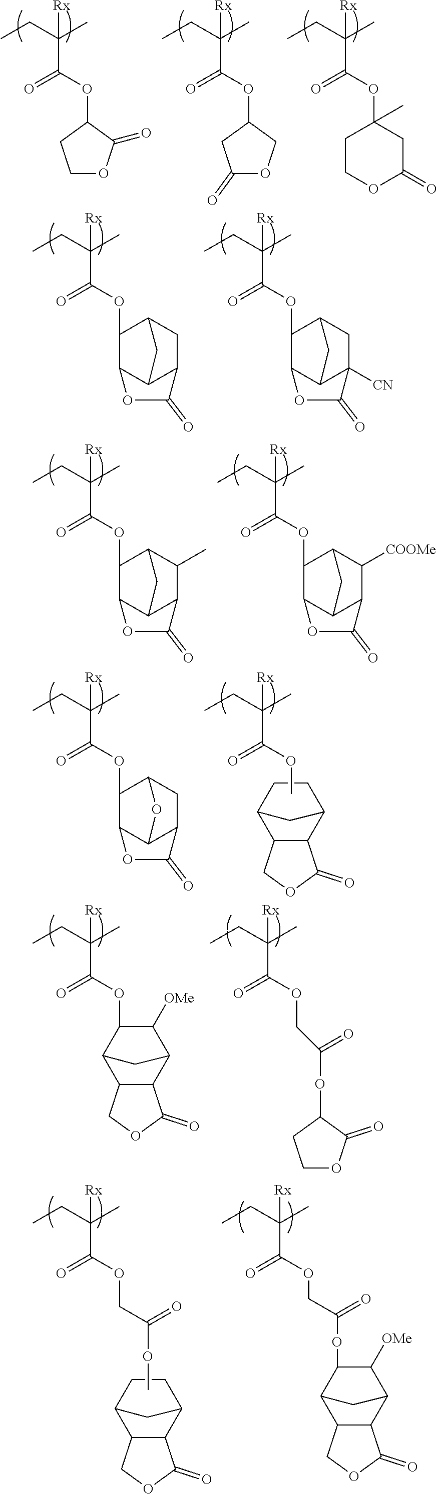

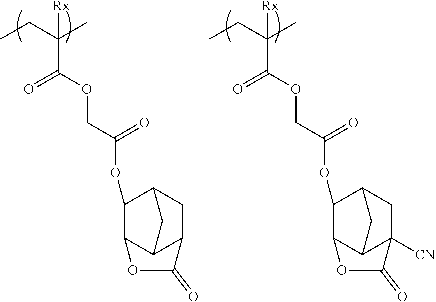

As a sultone group which the resin (Ab) has, the following General Formula (SL-1) or (SL-2) is preferable. Rb₂ and n₂ in the formula have the same definition as those in General Formulas (LC1-1) to (LC1-17), respectively.

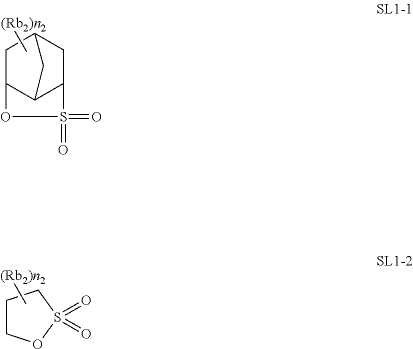

As the repeating unit including a sultone group which the resin (Ab) has, a repeating unit formed by substituting the lactone group in the repeating unit having a lactone group described above with a sultone group is preferable.

It is also a particularly preferable aspect that a polar group which the repeating unit (b′) can have is an acidic group. Preferable examples of the acidic group include a phenolic hydroxyl group, a carboxylic acid group, a sulfonic acid group, a fluorinated alcohol group (for example, a hexafluoroisopropanol group), a sulfonamide group, a sulfonyl imide group, a (alkylsulfonyl)(alkylcarbonyl)methylene group, a (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group. Among these, the repeating unit (b′) is more preferably a repeating unit having a carboxyl group. Due to a repeating unit having an acidic group being contained, resolution in contact hole use increases. Examples of the repeating unit having an acidic group preferably include any of a repeating unit of which an acidic group is directly bonded to the main chain of a resin as a repeating unit by acrylic acid or methacrylic acid, a repeating unit of which an acidic group is bonded to the main chain of a resin through a connecting group, and any repeating unit introduced to a terminal of a polymer chain using a polymerization initiator or a chain transfer agent having an acidic group at the time of polymerization. A repeating unit by acrylic acid or methacrylic acid is particularly preferable.

The polar group which the repeating unit (b′) can have may or may not include an aromatic ring. In a case where the repeating unit (b′) has an acidic group, the content of the repeating unit having an acidic group is preferably 30 mol % or less, and more preferably 20 mol % or less, with respect to the entirety of repeating units in the resin (Ab). In a case where the resin (Ab) contains a repeating unit having an acidic group, the content of the repeating unit having an acidic group in the resin (Ab) is typically 1 mol % or greater.

Specific examples of the repeating unit having an acidic group are shown below, but the present invention is not limited thereto.

In the specific examples, Rx represents H, CH₃, CH₂OH, or CF₃.

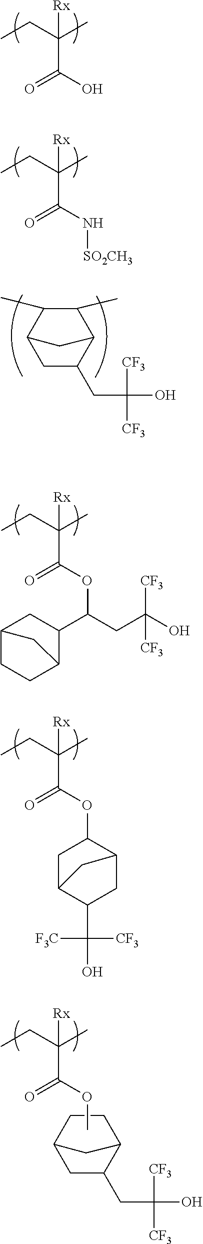

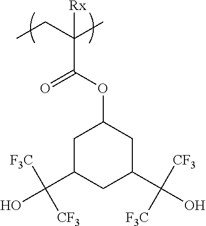

The resin (Ab) may have a repeating unit having a plurality of aromatic rings, and examples of the repeating unit having a plurality of aromatic rings include repeating units described in paragraphs “0200” to “0208” of JP2013-76991A.

The resin (Ab) in the present invention may suitably have a repeating unit other than the repeating units (a) to (c). One example of such a repeating unit is a repeating unit which has an alicyclic hydrocarbon structure without a polar group and does not exhibit acid-decomposability, described in paragraphs “0217” and “0218” of JP2013-76991A, or a repeating unit described in paragraphs “0219” and “0220” of JP2013-76991A.

The resin (Ab) may have a repeating unit having a cyclic carbonic acid ester structure.

The repeating unit having a cyclic carbonic acid ester structure is preferably the repeating unit represented by the following General Formula (A-1).

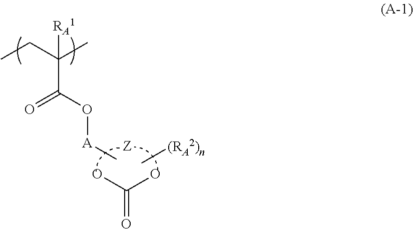

In General Formula (A-1), R_{A}¹ represents a hydrogen atom or an alkyl group.

In a case where R_{A}² is 2 or greater, each of R_{A}²'s independently represents a substituent.

A represents a single bond or a divalent connecting group.

Z represents an atomic group which forms a monocyclic or polycyclic structure together with a group represented by —O—C(═O)—O— in the formula.

n represents an integer of 0 or greater.

General Formula (A-1) will be described in detail.

The alkyl group represented by R_{A}¹ may have a substituent such as a fluorine atom. R_{A}¹ is preferably a hydrogen atom, a methyl group, or a trifluoromethyl group, and more preferably a methyl group.

The substituent represented by R_{A}², for example, is an alkyl group, a cycloalkyl group, a hydroxyl group, an alkoxy group, an amino group, or an alkoxycarbonylamino group. As the substituent, an alkyl group having 1 to 5 carbon atoms is preferable, and examples thereof can include a linear alkyl group having 1 to 5 carbon atoms such as a methyl group, an ethyl group, a propyl group, or a butyl group; and a branched alkyl group having 3 to 5 carbon atoms such as an isopropyl group, an isobutyl group, or a t-butyl group. The alkyl group may have a substituent such as a hydroxyl group.

n is an integer of 0 or greater, which represents the number of substituents. For example, n is preferably 0 to 4, and more preferably 0.

Examples of the divalent connecting group represented by A include an alkylene group, a cycloalkylene group, an ester bond, an amide bond, an ether bond, a urethane bond, a urea bond, and combinations thereof. The alkylene group is preferably an alkylene group having 1 to 10 carbon atoms, more preferably an alkylene group having 1 to 5 carbon atoms, and examples thereof include a methylene group, an ethylene group, and a propylene group.

In an aspect of the present invention, A is preferably a single bond or an alkylene group.

As a monocycle including —O—C(═O)—O—, represented by Z, a 5- to 7-membered ring having n_{A} of 2 to 4, in the cyclic carbonic acid ester represented by the following General Formula (a), is exemplified, and a 5-membered ring or a 6-membered ring (n_{A}=2 or 3) is preferable, and 5-membered ring (n_{A}=2) is more preferable.

As a polycycle including —O—C(═O)—O—, represented by Z, a structure in which a fused ring is formed by a cyclic carbonic acid ester represented by the following General Formula (a) together with a further one or two more ring structures or a structure in which a spiro ring is formed is exemplified. “Other ring structures” capable of forming a fused ring or a spiro ring may be an alicyclic hydrocarbon group, may be an aromatic hydrocarbon group, or may be a heterocycle.

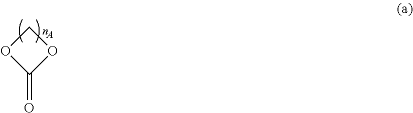

A monomer corresponding to the repeating unit represented by General Formula (A-1) can be synthesized by a method known in the related art, for example, those described in Tetrahedron Letters, Vol. 27, No. 32 p. 3741 (1986), or Organic Letters, Vol. 4, No. 15 p. 2561 (2002).

The resin (Ab) may include one type of repeating units represented by General Formula (A-1), or may include two or more types thereof.

Specific examples of the repeating unit having a cyclic carbonic acid ester structure are described below, but the present invention is not limited thereto.

Moreover, R_{A}¹ in the following specific examples has the same meaning as R_{A}¹ in General Formula (A-1).

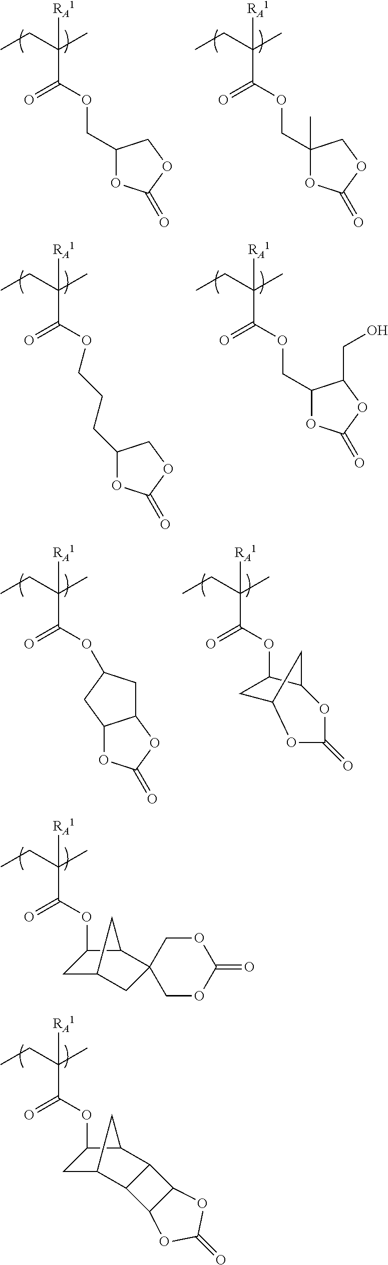

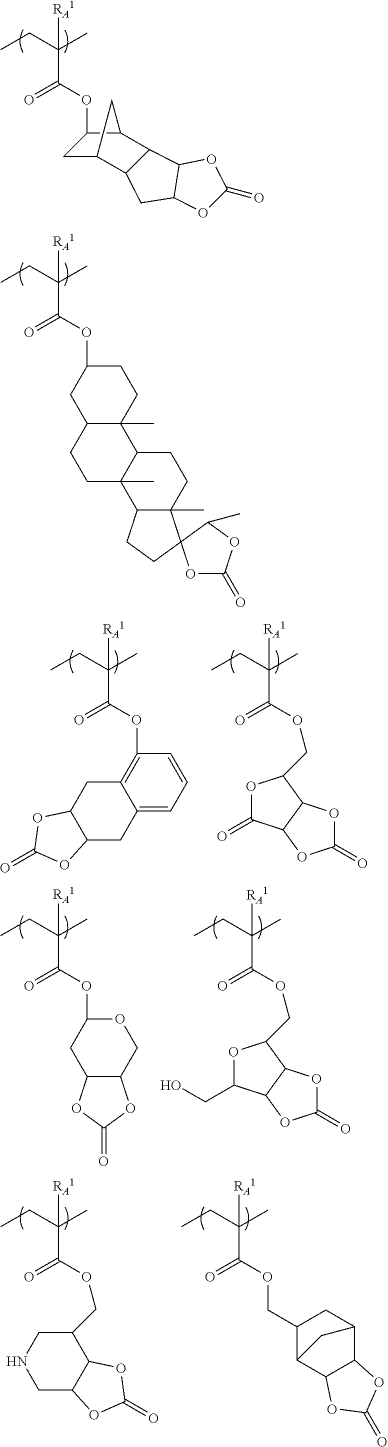

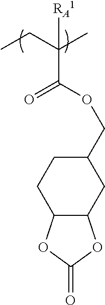

The resin (Ab) may include one type of repeating unit having a cyclic carbonic acid ester structure, or may include two or more types thereof.

In a case where the resin (Ab) contains a repeating unit having a cyclic carbonic acid ester structure, the content of the repeating unit having a cyclic carbonic acid ester structure is preferably 5 mol % to 60 mol %, more preferably 5 mol % to 55 mol %, and still more preferably 10 mol % to 50 mol %, with respect to the entirety of repeating units in the resin (Ab).

In the resin (Ab) used in the composition of the present invention, the content molar ratio of respective repeating structural units is suitably set to adjust dry etching resistance or standard developer suitability of a resist, adhesion to a substrate, a resist profile, and resolving power, heat resistance, and sensitivity which are properties generally required for a resist.

Hereinafter, specific examples of the resin (Ab) will be described, but the present invention is not limited thereto.

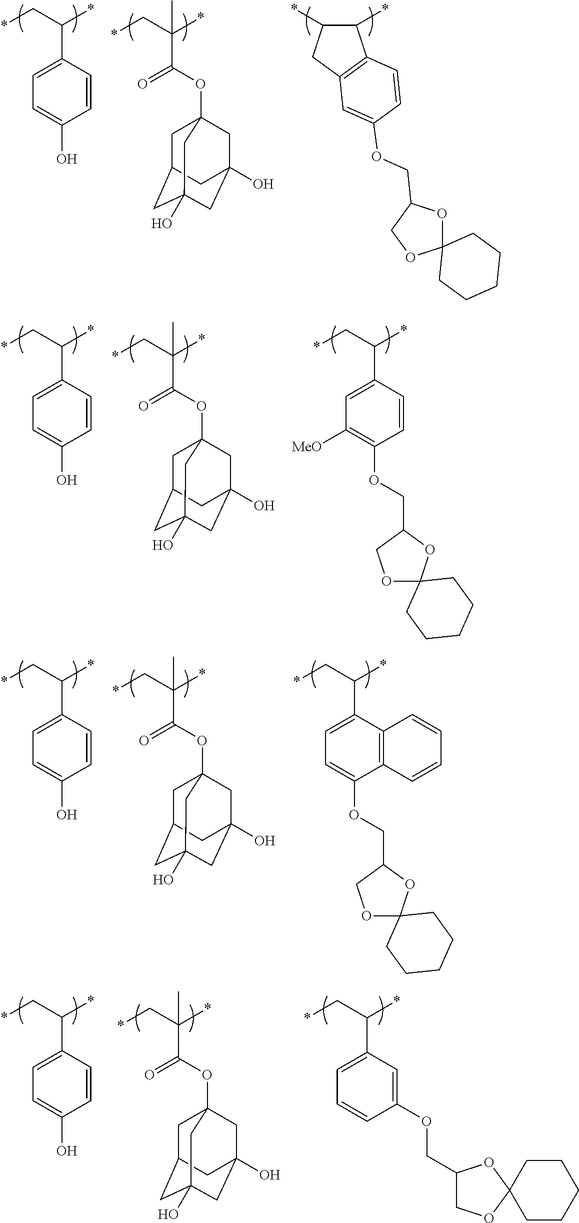

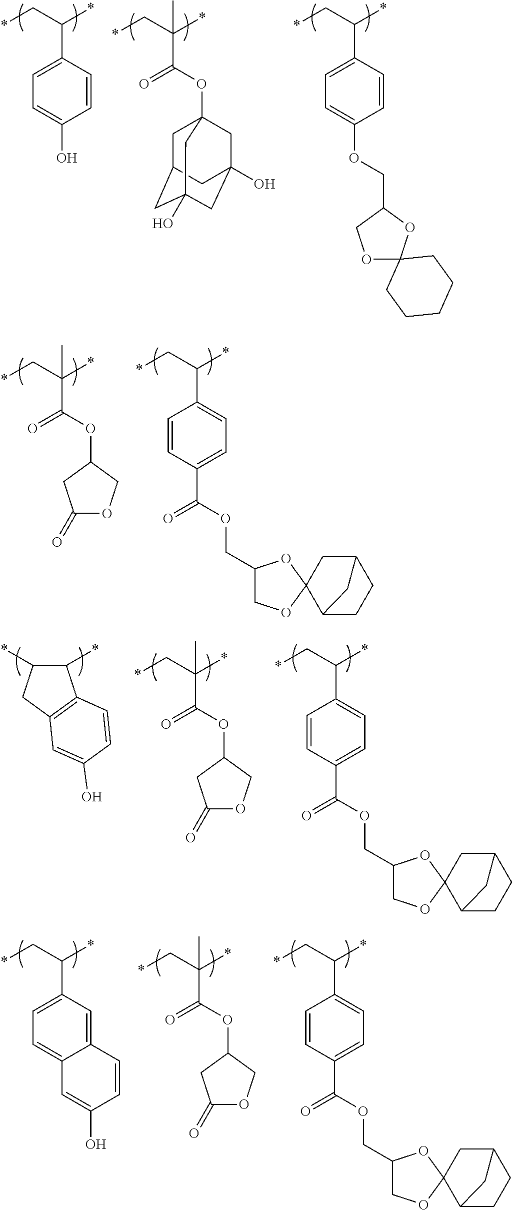

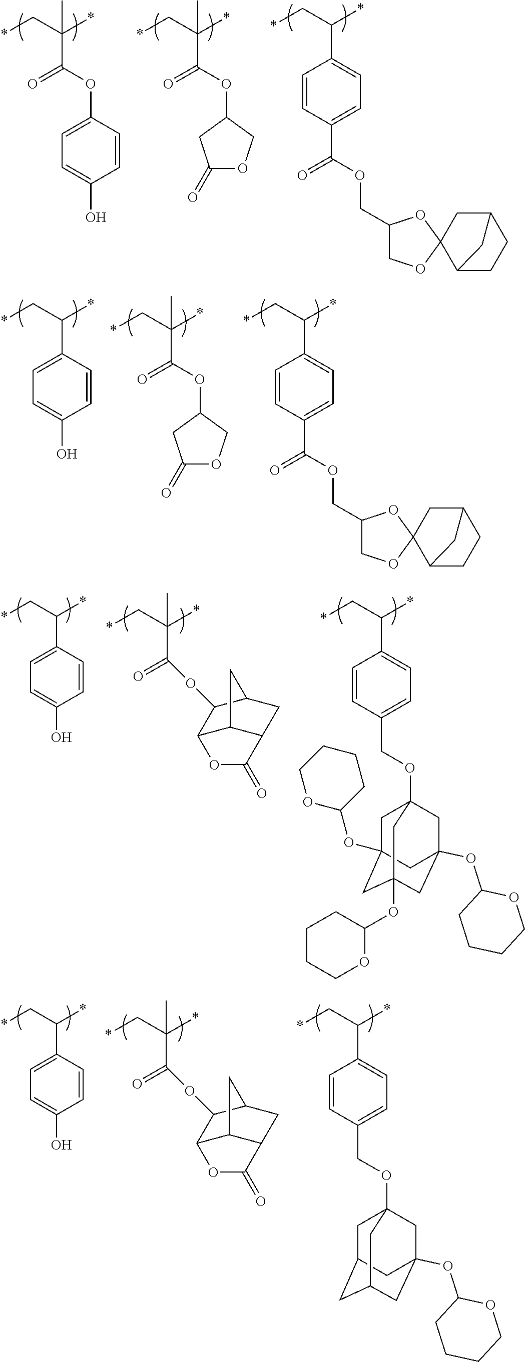

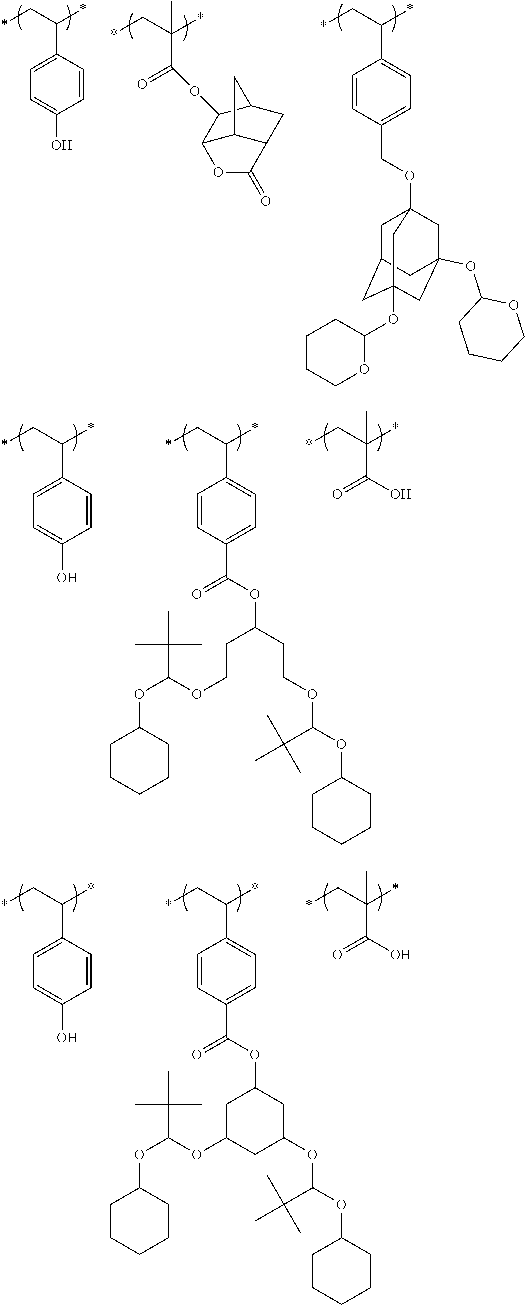

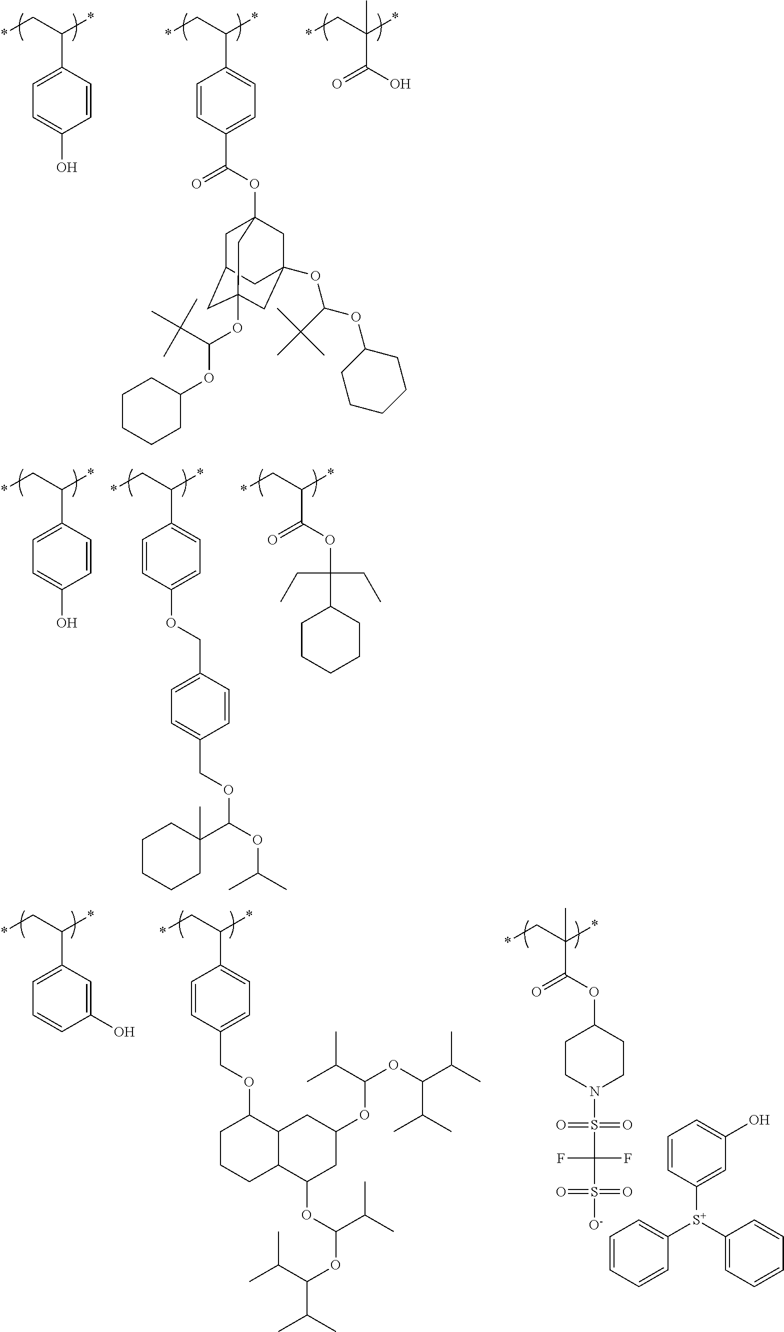

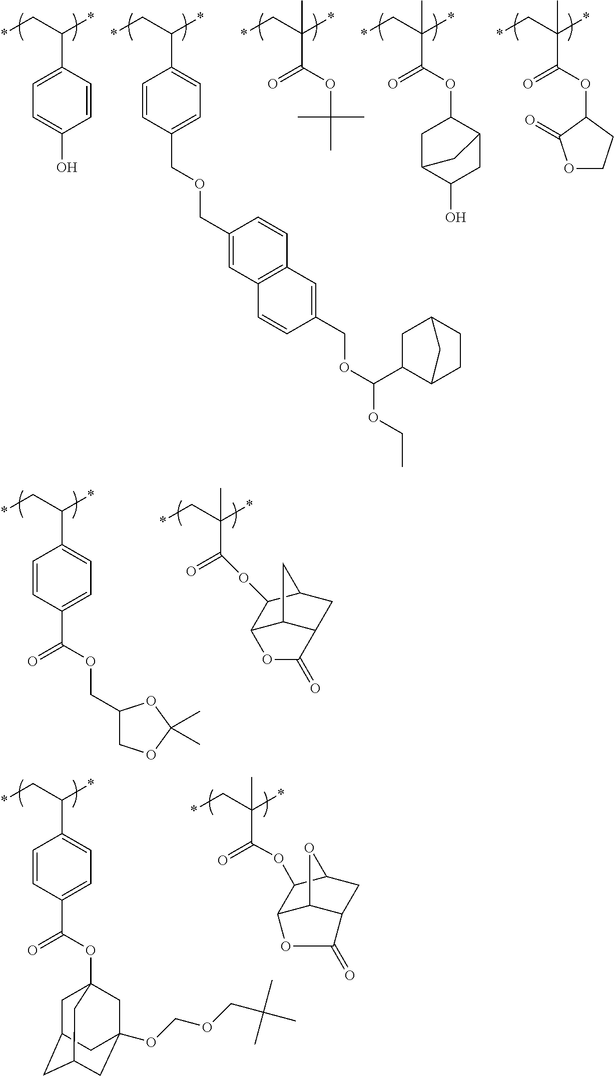

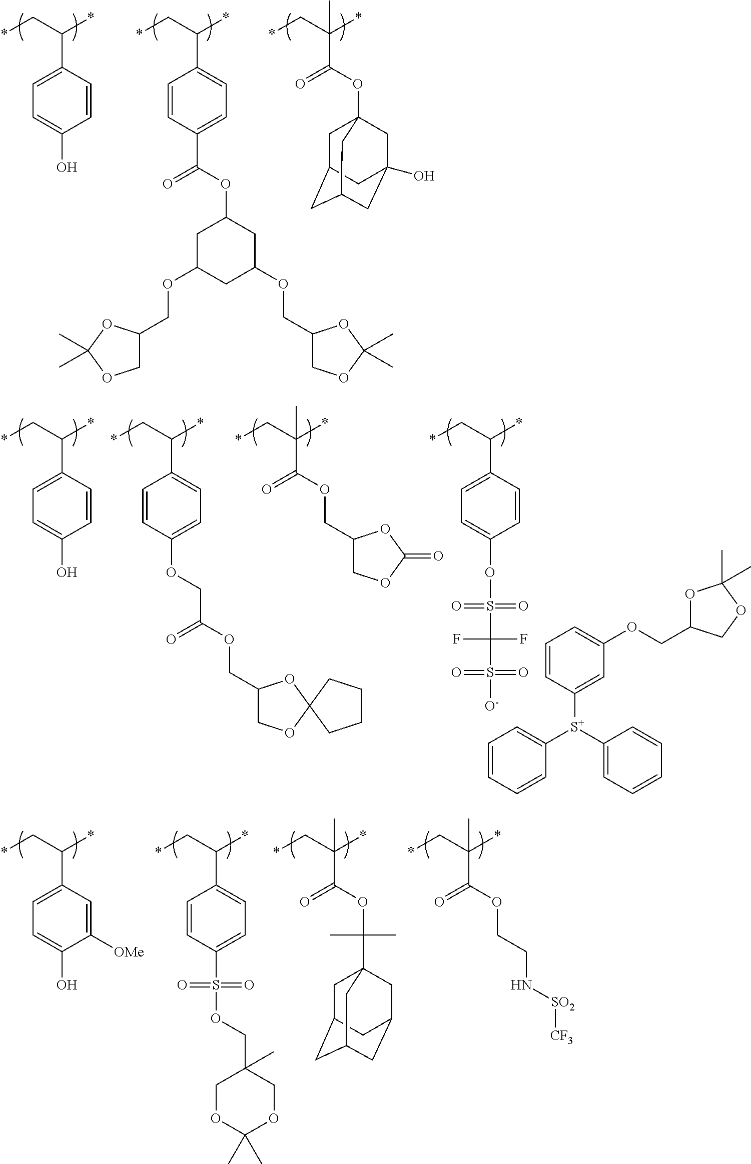

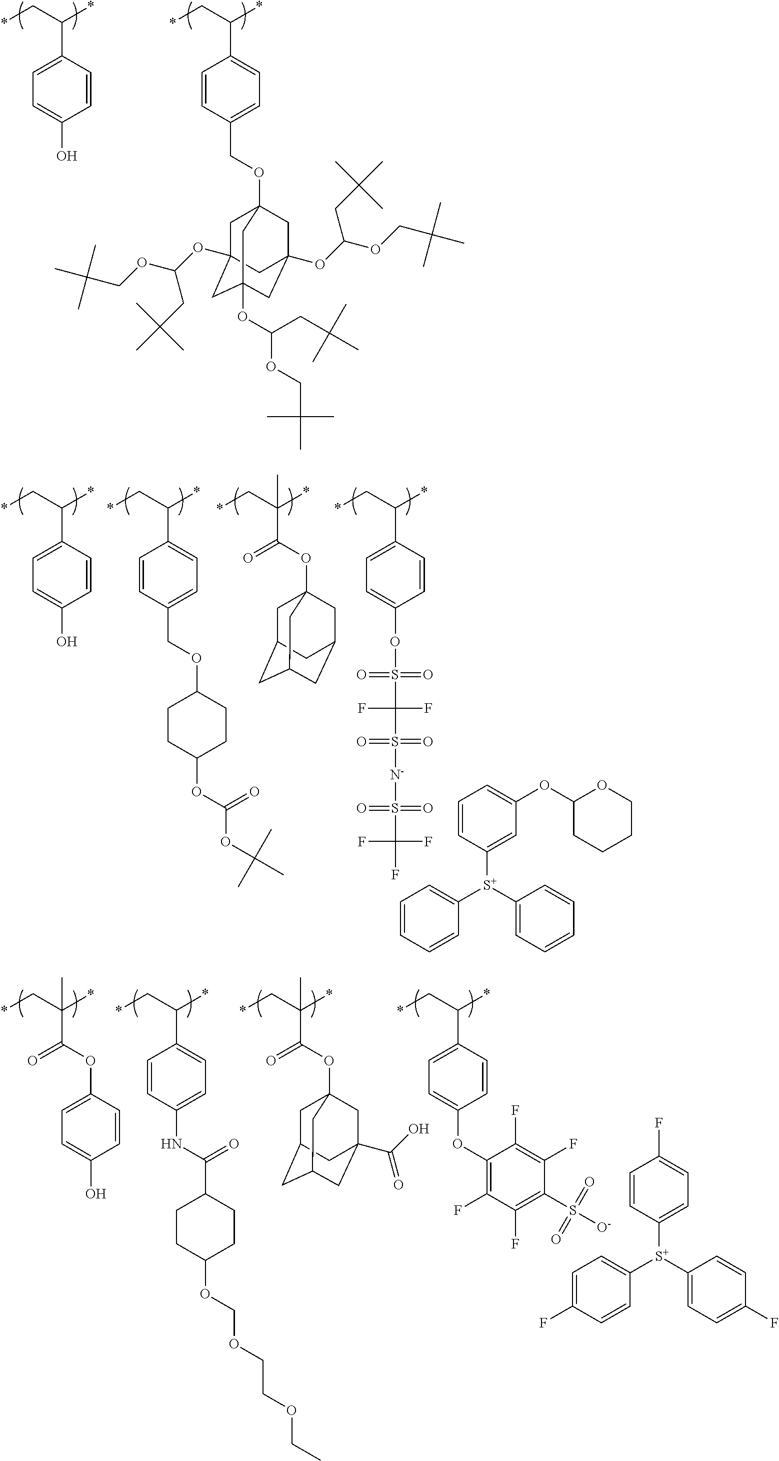

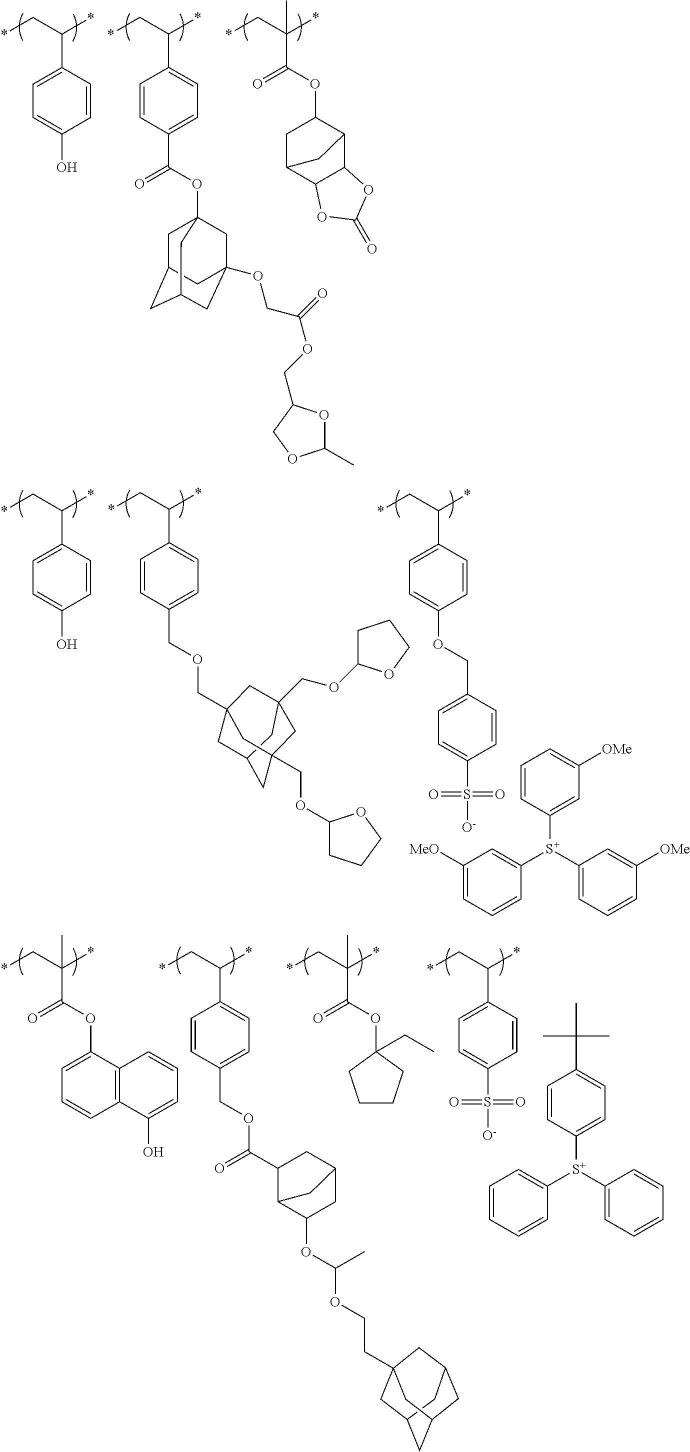

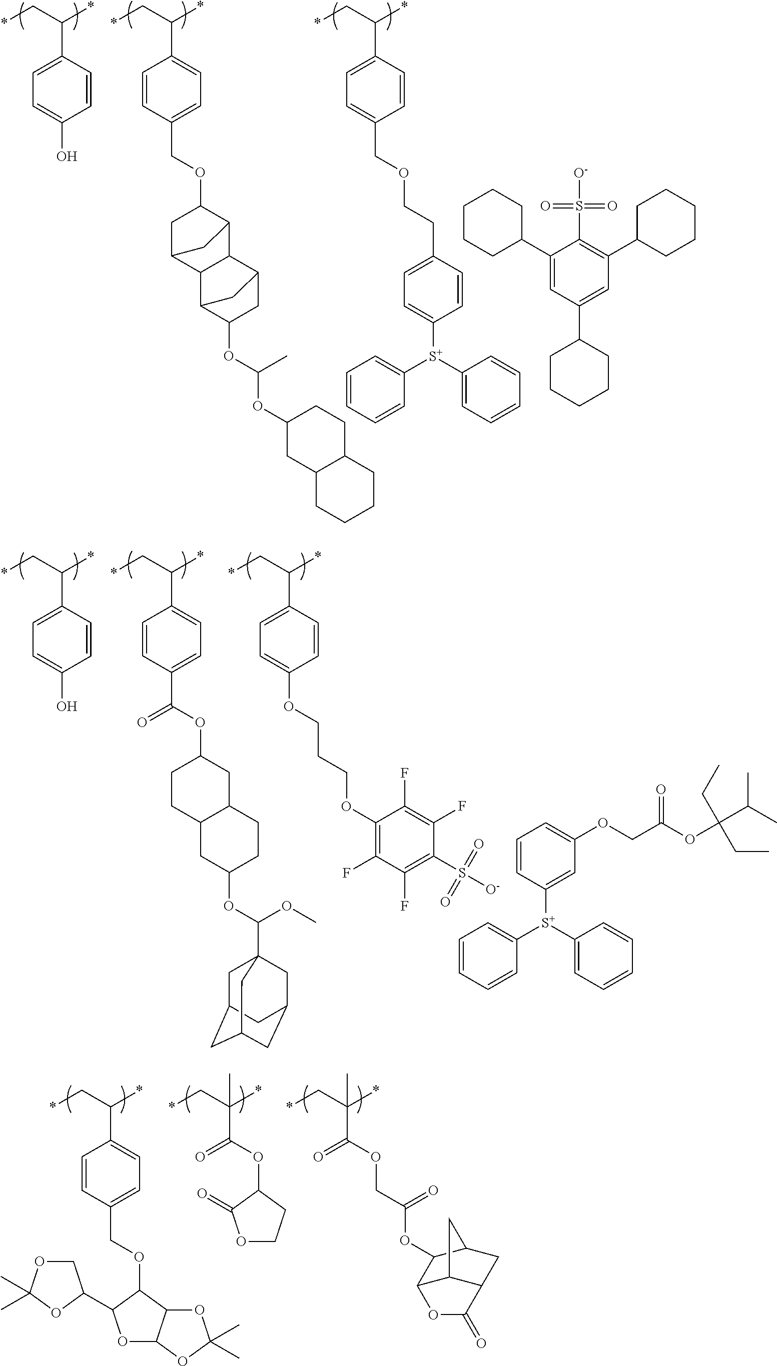

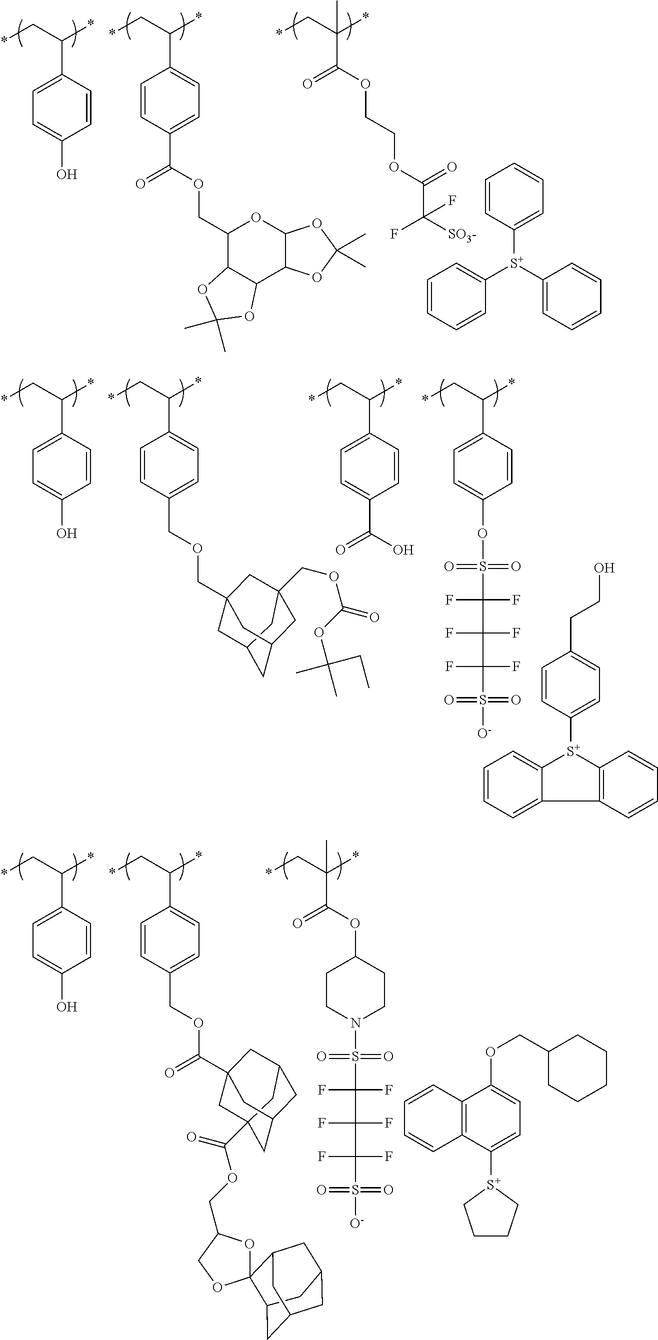

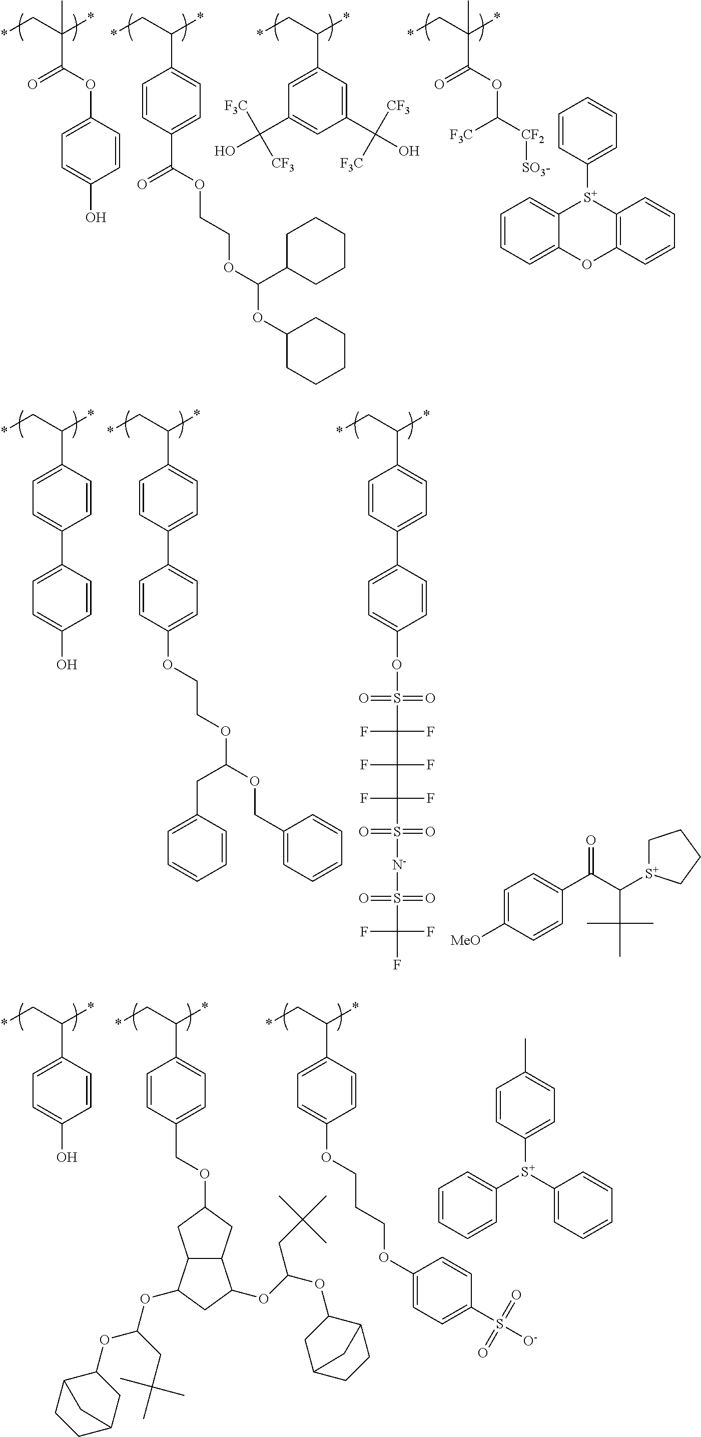

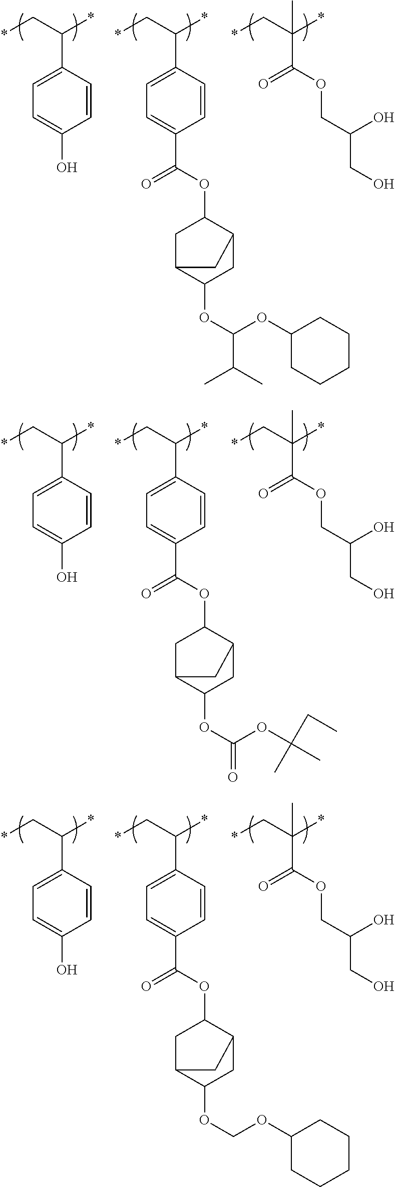

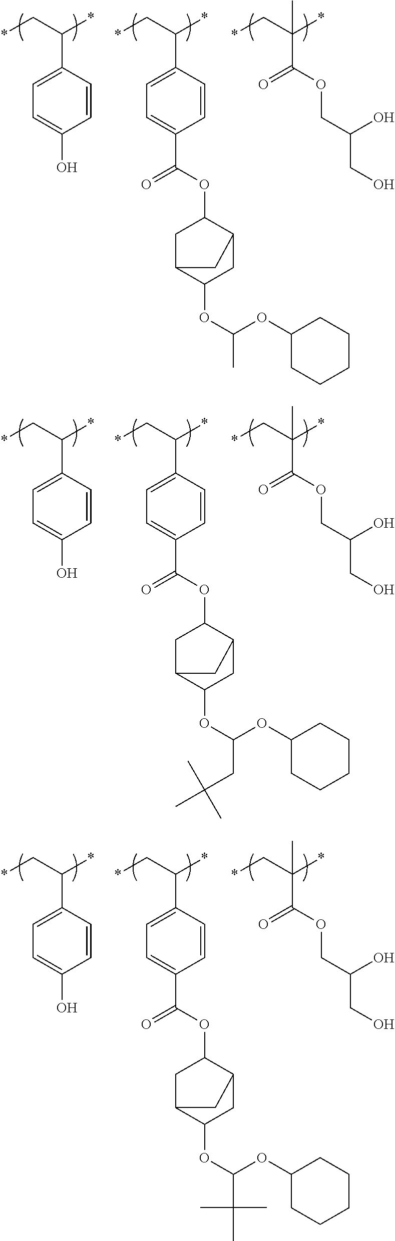

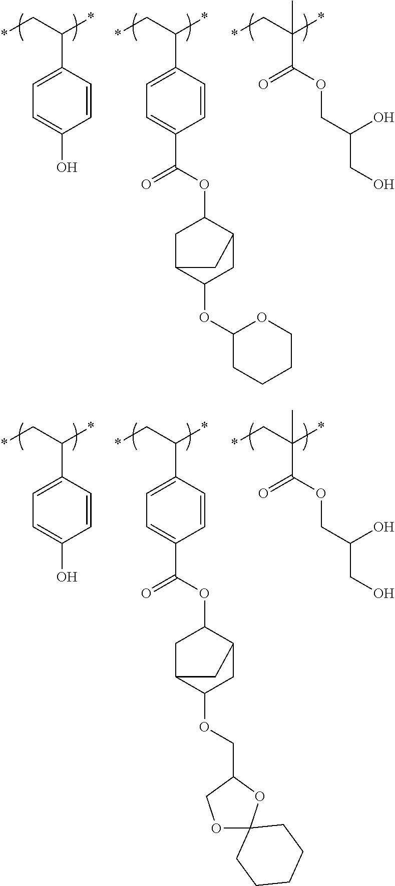

The form of the resin (Ab) of the present invention may be any form of a random form, a block form, a comb form, and a star form.

The resin (Ab) can be synthesized by, for example, polymerizing an unsaturated monomer corresponding to each structure through radical polymerization, cationic polymerization, or anionic polymerization. In addition, by performing a polymer reaction after polymerization is performed using an unsaturated monomer corresponding to a precursor of each structure, a target resin can also be obtained.

Examples of a general synthetic method include a collective polymerization method of performing polymerization by dissolving an unsaturated monomer and a polymerization initiator in a solvent and heating the resultant product and a dropping polymerization method of adding a solution containing an unsaturated monomer and a polymerization initiator dropwise to a heated solvent over a period of 1 hour to 10 hours, and the dropping polymerization method is preferable.

The resin (Ab) can be synthesized by the method described in JP2012-208477A.

Although the molecular weight of the resin (Ab) according to the present invention is not particularly limited, the weight average molecular weight is preferably within a range of 1000 to 100000, more preferably within a range of 1500 to 60000, and particularly preferably within a range of 2000 to 30000. When the weight average molecular weight is within a range of 1000 to 100000, degradation of heat resistance or dry etching resistance can be prevented, and degradation of developability or degradation of film-forming properties due to increase in viscosity can be prevented. Here, the weight average molecular weight of a resin is a molecular weight in terms of polystyrene measured by using GPC (carrier: THF or N-methyl-2-pyrrolidone (NMP)).

The weight average molecular weight and the dispersity (weight average molecular weight/number average molecular weight) of the resin (Ab) are defined as values that are measured by GPC and expressed in terms of polystyrene. In the specification, the weight average molecular weight and the dispersity can be obtained, for example, by using an HLC-8120 (manufactured by TOSOH CORPORATION), a TSK gel Multipore HXL-M (manufactured by TOSOH CORPORATION, 7.8 mm ID×30.0 cm) as a column, and tetrahydrofuran (THF) as an eluent.

The dispersity (Mw/Mn) is preferably 1.00 to 5.00, more preferably 1.03 to 3.50, and still more preferably 1.05 to 2.50. As the molecular weight distribution becomes lower, the resolution and the resist shape become better, and the side wall of the resist pattern becomes smoother, and thus, the roughness becomes excellent.

The resin (Ab) of the present invention can be used alone, or two or more types thereof can be used in combination. The content of the resin (Ab) is preferably 20% by mass to 99% by mass, more preferably 30% by mass to 89% by mass, and particularly preferably 40% by mass to 79% by mass, based on the total solid content of the actinic ray sensitive or radiation sensitive resin composition of the present invention.

[2] (B) Resin of which Solubility with Respect to Developer is Changed by being Decomposed Due to Action of Acid, Different from Resin (Ab)

The actinic ray sensitive or radiation sensitive resin composition of the present invention may further contain a resin (hereinafter, also referred to as “resin (B)”) of which the solubility with respect to a developer is changed by being decomposed due to the action of an acid, different from the resin (Ab).

In a case where the actinic ray sensitive or radiation sensitive resin composition of the present invention contains the resin (B), the content of the resin (B) is typically 0% by mass to 50% by mass, preferably 0% by mass to 30% by mass, and particularly preferably 0% by mass to 15% by mass, of the resin (B) with respect to the total solid content of the actinic ray sensitive or radiation sensitive resin composition.

Examples of the resin (B) include resins described in paragraphs “0059” to “0169” of JP2010-217884A or paragraphs “0214” to “0594” of JP2011-217048A.

[3] (B) Compound that Generates Acid by Irradiation with Actinic Ray or Radiation

The composition of the present invention preferably contains a compound that generates an acid by irradiation with actinic ray or radiation (hereinafter, also referred to as an “acid generator” or a “photoacid generator”).

Although the acid generator is not particularly limited as long as it is a known acid generator, the acid generator is preferably a compound that generates an organic acid, for example, at least any one of sulfonic acid, bis(alkylsulfonyl)imide, and tris(alkylsulfonyl)methide by irradiation with actinic ray or radiation.

The compound (B) that generates an acid by irradiation with active rays or radiation may have a form of a low molecular weight compound, or may have a form in which the compound (B) is incorporated into a part of a polymer. In addition, a form of a low molecular weight compound and a form in which the compound (B) is incorporated into a part of a polymer may be used in combination.

In a case where the compound (B) that generates an acid by irradiation with active rays or radiation has a form of a low molecular weight compound, the molecular weight of the compound (B) is preferably 3000 or less, more preferably 2000 or less, and still more preferably 1000 or less.

In a case where the compound (B) that generates an acid by irradiation with active rays or radiation has a form in which the compound (B) is incorporated into a part of a polymer, the compound (B) may be incorporated into a part of an acid decomposable resin described above, or may be incorporated into a resin different from the acid decomposable resin.

More preferably, the compounds represented by the following General Formula (ZI), (ZII), and (ZIII) can be exemplified.

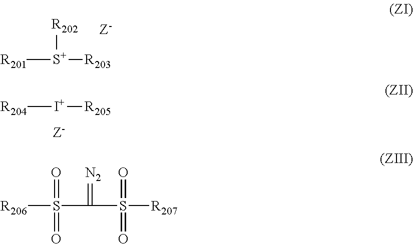

In General Formula (ZI), each of R₂₀₁, R₂₀₂, and R₂₀₃ independently represents an organic group.

The organic group represented by R₂₀₁, R₂₀₂, and R₂₀₃ generally has 1 to 30 carbon atoms, and preferably has 1 to 20 carbon atoms.

Two of R₂₀₁ to R₂₀₃ may be bonded to each other to form a ring structure, and an oxygen atom, a sulfur atom, an ester bond, an amide bond, or a carbonyl group may be included in the ring. Examples of the group that two of R₂₀₁ to R₂₀₃ form by bonding to each other include an alkylene group (for example, a butylene group, and a pentylene group).

Z⁻ represents a non-nucleophilic anion (anion which is significantly low in ability causing a nucleophilic reaction).

Examples of the non-nucleophilic anion include a sulfonate anion (an aliphatic sulfonate anion, an aromatic sulfonate anion, or a camphorsulfonate anion), a carboxylate anion (an aliphatic carboxylate anion, an aromatic carboxylate anion, or an aralkylcarboxylate anion), a sulfonylimide anion, a bis(alkylsulfonyl)imide anion, and a tris(alkylsulfonyl)methide anion.

The aliphatic portion in the aliphatic sulfonate anion and the aliphatic carboxylate anion, may be an alkyl group or a cycloalkyl group, and preferable examples thereof include a linear or branched alkyl group having 1 to 30 carbon atoms and a cycloalkyl group having 3 to 30 carbon atoms.

The aromatic group in the aromatic sulfonate anion and the aromatic carboxylate anion is preferably an aryl group having 6 to 14 carbon atoms, and examples thereof can include a phenyl group, a tolyl group, and a naphthyl group.

The alkyl group, the cycloalkyl group, and the aryl group described above may have a substituent. Specific examples thereof include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). Regarding the aryl group or a ring structure which each group has, as a substituent thereof, an alkyl group (which preferably has 1 to 15 carbon atoms) can be exemplified.

The aralkyl group in the aralkylcarboxylate anion is preferably an aralkyl group having 6 to 12 carbon atoms, and examples thereof can include a benzyl group, a phenethyl group, a naphthylmethyl group, a naphthylethyl group, and a naphthylbutyl group.

Examples of the sulfonylimide anion can include a saccharin anion.

The alkyl group in a bis(alkylsulfonyl)imide anion and a tris(alkylsulfonyl)methide anion is preferably an alkyl group having 1 to 5 carbon atoms. Examples of the substituent of the alkyl group can include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom or an alkyl group substituted with a fluorine atom is preferable.

In addition, the alkyl groups in bis(alkylsulfonyl)imide anion may be bonded to each other to form a ring structure. As a result, the acid strength increases.

Examples of other non-nucleophilic anions can include fluorophosphate (for example, PF₆⁻), fluoroborate (for example, BF₄⁻), and fluoroantimonate (for example, SbF₆⁻).

As the non-nucleophilic anion, an aliphatic sulfonate anion in which at least α position of sulfonic acid is substituted with a fluorine atom, an aromatic sulfonate anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom is preferable. The non-nucleophilic anion is more preferably a perfluoro aliphatic sulfonate anion (which more preferably has 4 to 8 carbon atoms) or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of acid strength, the pKa of the generated acid is preferably −1 or less for sensitivity enhancement.

In addition, as the non-nucleophilic anion, an anion represented by the following General Formula (AN1) is also exemplified as a preferable aspect.

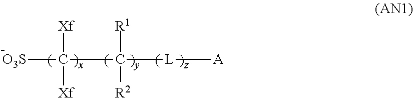

In the formula, each of Xf's independently represents a fluorine atom or an alkyl group substituted with at least one fluorine atom.

Each of R¹ and R² independently represents a hydrogen atom, a fluorine atom, or an alkyl group, and in a case where a plurality of R¹'s and R²'s are present, R¹'s and R²'s may be the same as or different from each other.

L represents a divalent connecting group, and in a case where a plurality of L's are present, L's may be the same as or different from each other.

A represents a cyclic organic group.

x represents an integer of 1 to 20, y represents an integer of 0 to 10, and z represents an integer of 0 to 10.

General Formula (AN1) will be described in more detail.

The alkyl group in the alkyl group substituted with a fluorine atom represented by Xf preferably has 1 to 10 carbon atoms, and more preferably 1 to 4 carbon atoms. In addition, the alkyl group substituted with a fluorine atom represented by Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, a fluorine atom or CF₃ is preferable. In particular, both of Xf's are preferably fluorine atoms.

The alkyl group represented by R¹ or R² may have a substituent (preferably a fluorine atom), and the alkyl group is preferably an alkyl group having 1 to 4 carbon atoms, and more preferably a perfluoroalkyl group having 1 to 4 carbon atoms. Specific examples of the alkyl group having a substituent, represented by R¹ or R², include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

Each of R¹ and R² is preferably a fluorine atom or CF₃.

x is preferably 1 to 10, and more preferably 1 to 5.

y is preferably 0 to 4, and more preferably 0.

z is preferably 0 to 5, and more preferably 0 to 3.

The divalent connecting group represented by L is not particularly limited, and examples thereof can include —COO—, —OCO—, —CO—, —O—, —S—, —SO—, —SO₂—, an alkylene group, a cycloalkylene group, an alkenylene group, and a connecting group obtained by connecting a plurality of these, and a connecting group having 12 or less carbon atoms in total is preferable. Among these, —COO—, —OCO—, —CO—, or —O— is preferable, and —COO— or —OCO— is more preferable.

The cyclic organic group represented by A is not particularly limited as long as it has a ring structure, and examples thereof include an alicyclic group, an aryl group, and a heterocyclic group (which includes not only a heterocyclic group having aromaticity but also a heterocyclic group having no aromaticity).

The alicyclic group may be monocyclic or polycyclic, and as the alicyclic group, a monocyclic cycloalkyl group such as a cyclopentyl group, a cyclohexyl group, or a cyclooctyl group, or polycyclic cycloalkyl groups such as a norbornyl group, a tricyclodecanyl group, a tetracyclodecanyl group, a tetracyclododecanyl group, or an adamantyl group is preferable. Among these, an alicyclic group with a bulky structure having 7 or more carbon atoms such as a norbornyl group, a tricyclodecanyl group, a tetracyclodecanyl group, a tetracyclododecanyl group, or an adamantyl group is preferable from the viewpoint of being capable of suppressing in-film diffusibility in a heating step after exposure and MEEF improvement.

Examples of the aryl group include a benzene ring, a naphthalene ring, a phenanthrene ring, and an anthracene ring.

Examples of the heterocyclic group include groups derived from a furan ring, a thiophene ring, a benzofuran ring, a benzothiophene ring, a dibenzofuran ring, a dibenzothiophene ring, and a pyridine ring. Among these, a group derived from a furan ring, a thiophene ring, or a pyridine ring is preferable.

In addition, as the cyclic organic group, a lactone structure can also be exemplified, and specific examples thereof can include the lactone structures represented by General Formulas (LC1-1) to (LC1-17), which the resin (Ab) may have.

Examples of the cyclic organic group may have a substituent, and examples of the substituent include an alkyl group (which may be linear, branched, or cyclic, and preferably has 1 to 12 carbon atoms), a cycloalkyl group (which may be a monocycle, a polycycle, or a spiro ring, and preferably has 3 to 20 carbon atoms), an aryl group (which preferably has 6 to 14 carbon atoms), a hydroxy group, an alkoxy group, an ester group, an amide group, a urethane group, a ureido group, a thioether group, a sulfonamide group, and a sulfonic acid ester group. Moreover, the carbon (carbon which contributes to formation of a ring) configuring the cyclic organic group may be a carbonyl carbon.

Examples of the organic group represented by R₂₀₁, R₂₀₂, or R₂₀₃ include an aryl group, an alkyl group, and a cycloalkyl group.

Preferably, at least one of R₂₀₁, R₂₀₂, and R₂₀₃ is an aryl group, and more preferably, all of three are aryl groups. Examples of the aryl group include heteroaryl groups such as a indole residue and a pyrrole residue, in addition to a phenyl group and a naphthyl group. Preferable examples of the alkyl group or the cycloalkyl group represented by each of R₂₀₁ to R₂₀₃ can include a linear or branched alkyl group having 1 to 10 carbon atoms and a cycloalkyl group having 3 to 10 carbon atoms. More preferable examples of the alkyl group can include a methyl group, an ethyl group, an n-propyl group, an i-propyl group, and an n-butyl group. More preferable examples of the cycloalkyl group can include a cyclopropyl group, a cyclobutyl group, a cyclopentyl group, a cyclohexyl group, and a cycloheptyl group. These groups may further contain a substituent. Examples of the substituent include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms), but the present invention is not limited thereto.

In addition, in a case where two of R₂₀₁ to R₂₀₃ are bonded to each other to form a ring structure, a structure represented by the following General Formula (A1) is preferable.

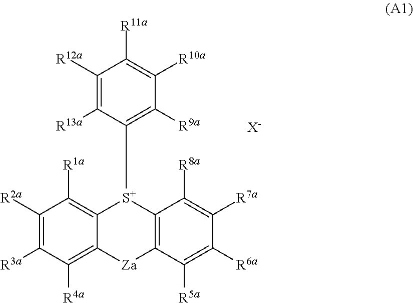

In General Formula (A1), each of R^{1a} to R^{13a} independently represents a hydrogen atom or a substituent.

One to three of R^{1a} to R^{13a} are preferably not hydrogen atoms, and any one of R^{9a} to R^{13a} is more preferably not a hydrogen atom.

Za represents a single bond or a divalent connecting group.

X⁻ has the same meaning as Z⁻ in General Formula (ZI).

Specific examples in a case where each of R^{1a} to R^{13a} is not a hydrogen atom include a halogen atom, a linear, branched, or cyclic alkyl group, an alkenyl group, an alkynyl group, aryl group, a heterocyclic group, a cyano group, a nitro group, carboxyl group, an alkoxy group, an aryl oxy group, a silyloxy group, a heterocyclic oxy group, an acyloxy group, a carbamoyloxy group, an alkoxycarbonyloxy group, an aryloxy carbonyloxy group, an amino group (including an anilino group), an ammonio group, an acylamino group, an aminocarbonyl amino group, an alkoxycarbonyl amino group, an aryloxy carbonyl amino group, a sulfamoyl amino group, an alkyl or arylsulfonyl amino group, a mercapto group, an alkylthio group, an arylthio group, a heterocyclic thio group, a sulfamoyl group, a sulfo group, an alkyl or aryl sulfinyl group, an alkyl or aryl sulfonyl group, an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

As a case where each of R^{1a} to R^{13a} is not a hydrogen atom, each of R^{1a} to R^{13a} is preferably a linear, branched, or cyclic alkyl group substituted with a hydroxyl group.

Examples of the divalent connecting group represented by Za include an alkylene group, an arylene group, a carbonyl group, a sulfonyl group, a carbonyloxy group, a carbonylamino group, sulfonylamide group, an ether bond, a thioether bond, an amino group, a disulfide group, —(CH₂)ₙ—CO—, —(CH₂)ₙ—SO₂—, —CH═CH—, an aminocarbonylamino group, and an aminosulfonylamino group (n is an integer of 1 to 3).

Moreover, when at least one of R₂₀₁, R₂₀₂, and R₂₀₃ is not an aryl group, examples of a preferable structure can include cationic structures of compounds exemplified in paragraphs “0047” and “0048” of JP2004-233661A, paragraphs “0040” to “0046” of JP2003-35948A, and exemplified as Formulas (I-1) to (I-70) in the specification of US2003/0224288A1, and compounds exemplified as Formulas (IA-1) to (IA-54), and Formulas (IB-1) to (IB-24) in the specification of US2003/0077540A1.

In General Formulas (ZII) and (ZIII), each of R₂₀₄ to R₂₀₇ independently represents an aryl group, an alkyl group, or a cycloalkyl group.

The aryl group, the alkyl group, and the cycloalkyl group represented by each of R₂₀₄ to R₂₀₇ are the same as the aryl group described as the aryl group, the alkyl group, and the cycloalkyl group represented by each of R₂₀₁ to R₂₀₃ in the compound (ZI).

The aryl group, the alkyl group, and the cycloalkyl group represented by each of R₂₀₄ to R₂₀₇ may have a substituent. Examples of the substituent include the substituents that the aryl group, the alkyl group, and the cycloalkyl group represented by each of R₂₀₁ to R₂₀₃ in the compound (ZI) may have.

Z⁻ represents a non-nucleophilic anion, and as Z⁻, the same as the non-nucleophilic anion in General Formula (ZI) can be exemplified.

As the acid generator, compounds represented by the following General Formula (ZIV), (ZV), or (ZVI) are also exemplified.

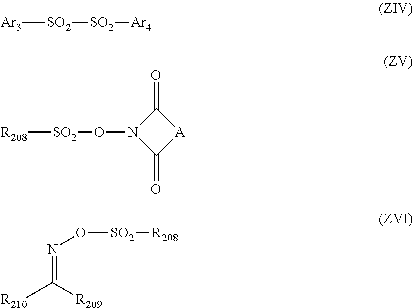

In General Formulas (ZIV) to (ZVI), each of Ar₃ and Ar₄ independently represents an aryl group.

Each of R₂₀₈, R₂₀₉, and R₂₁₀ independently represents an alkyl group, a cycloalkyl group, or an aryl group.

A represents an alkylene group, an alkenylene group, or an arylene group.

Specific examples of the aryl group represented by Ar₃, Ar₄, R₂₀₈, R₂₀₉, or R₂₁₀ include the same as the specific examples of the aryl group represented by R₂₀₁, R₂₀₂, or R₂₀₃ in General Formula (ZI).

Specific examples of the alkyl group and the cycloalkyl group represented by R₂₀₈, R₂₀₉, or R₂₁₀ include the same as the specific examples of the alkyl group and the cycloalkyl group represented by R₂₀₁, R₂₀₂, or R₂₀₃ in General Formula (ZI), respectively.

Examples of the alkylene group represented by A can include alkylene groups having 1 to 12 carbon atoms (for example, a methylene group, an ethylene group, a propylene group, an isopropylene group, a butylene group, and an isobutylene group), examples of the alkenylene group represented by A can include alkenylene groups having 2 to 12 carbon atoms (for example, an ethenylene group, a propenylene group, and a butenylene group), and examples of the arylene group represented by A can include arylene groups having 6 to 10 carbon atoms (for example, a phenylene group, a tolylene group, and a naphthylene group).

Particularly preferable examples of the acid generator will be described below.

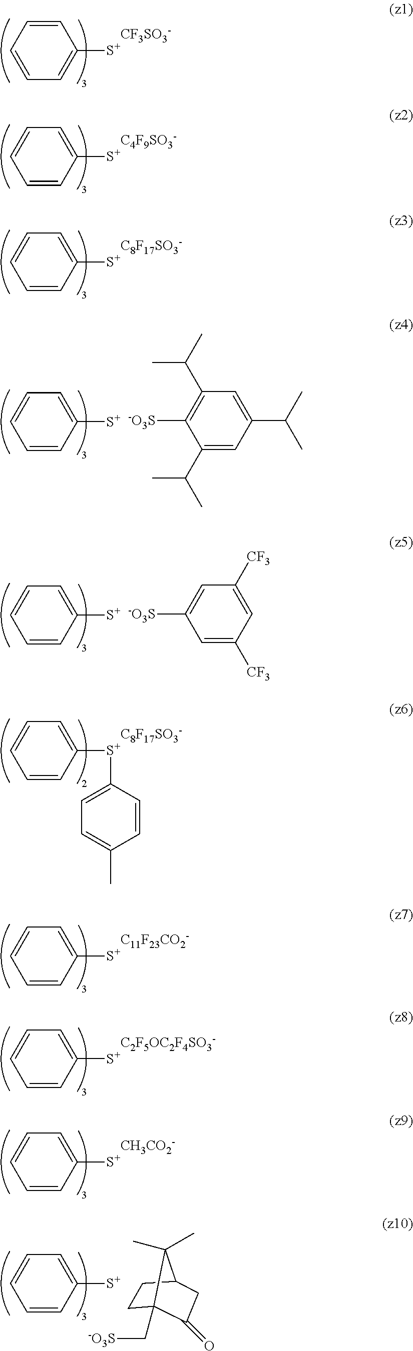

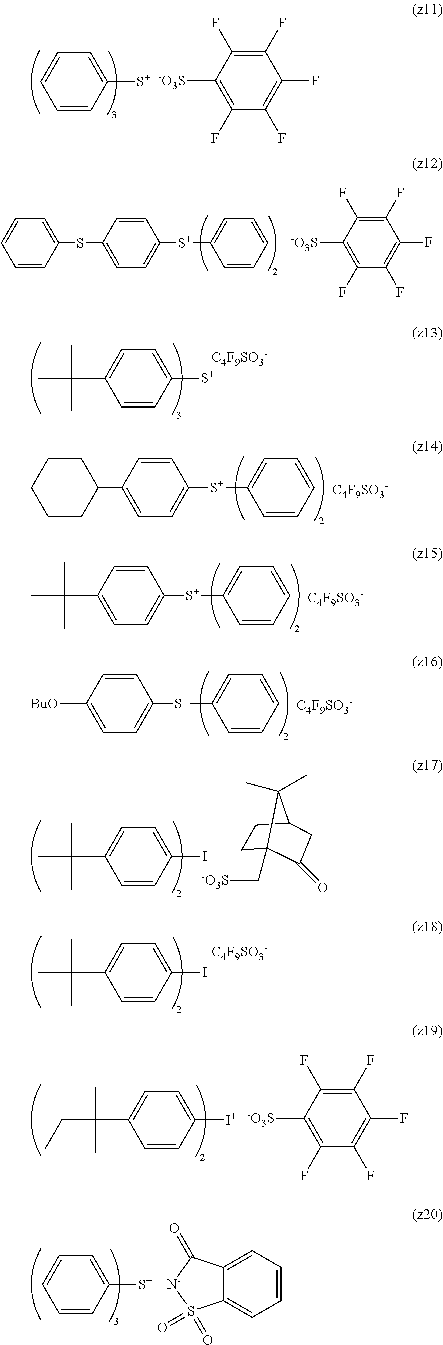

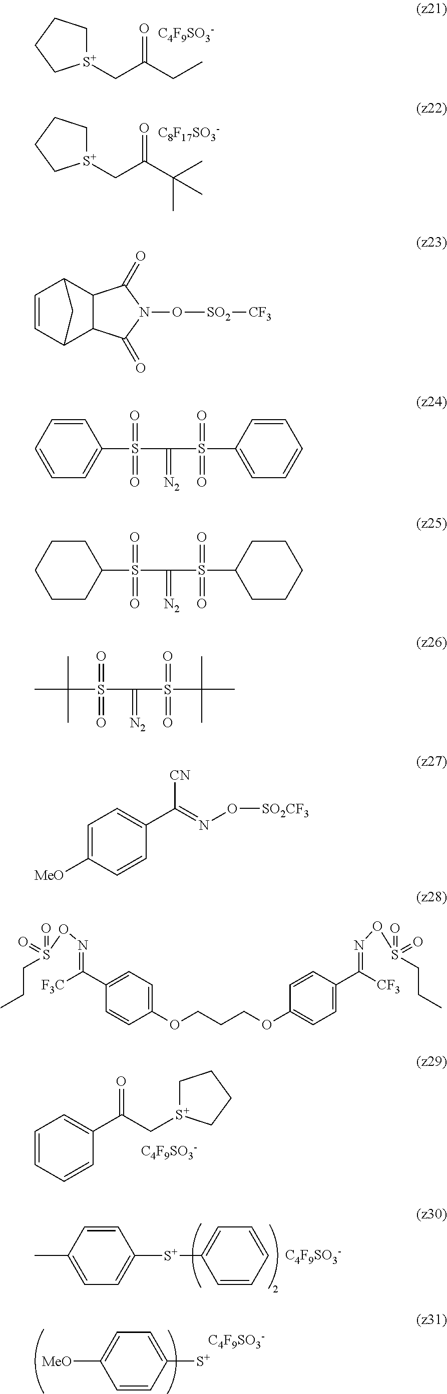

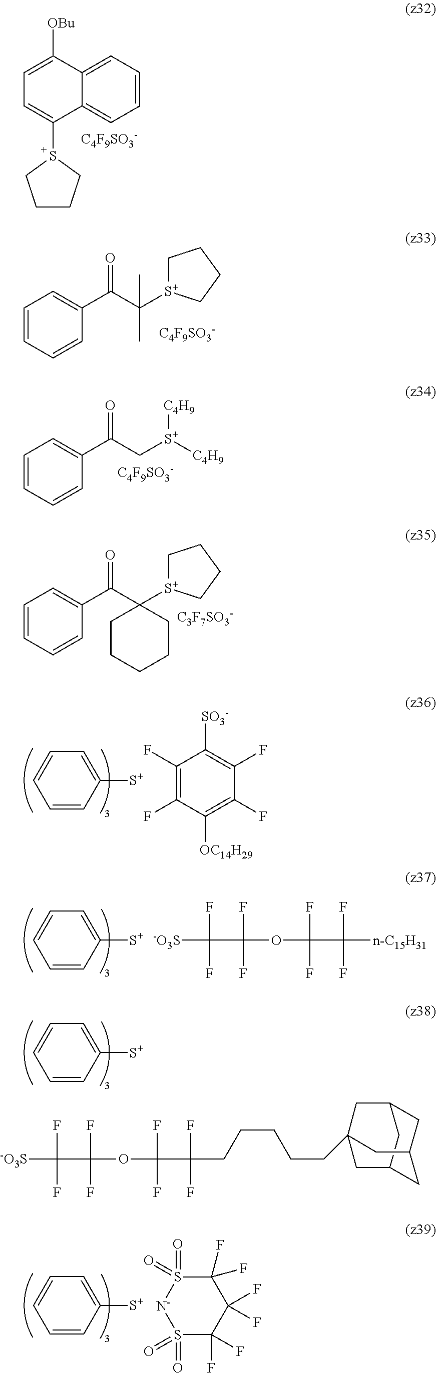

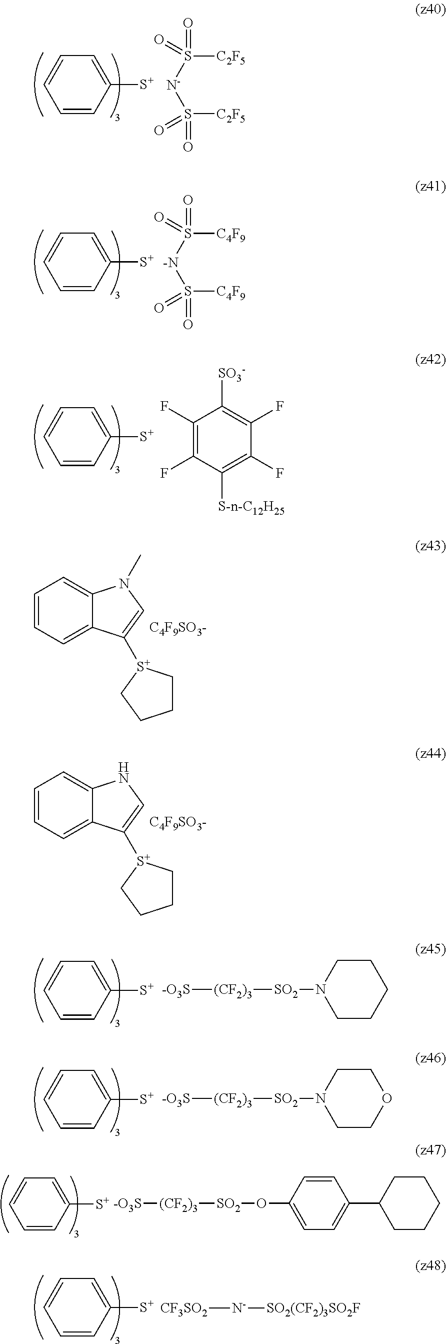

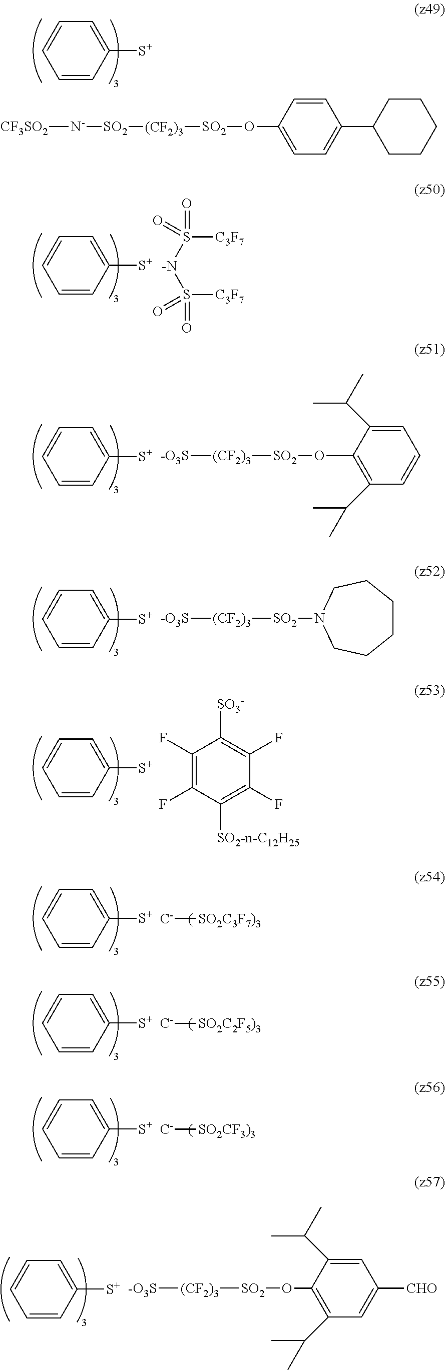

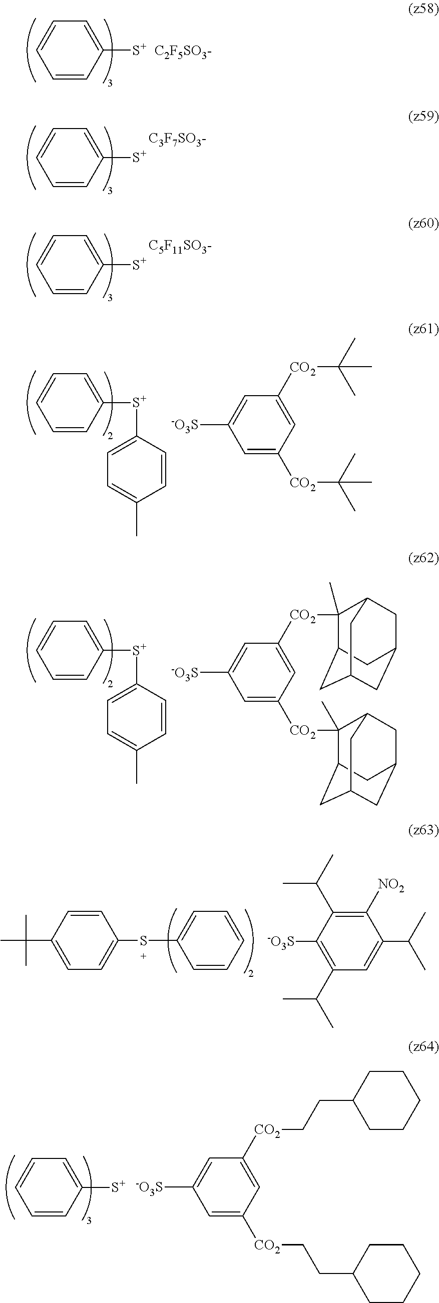

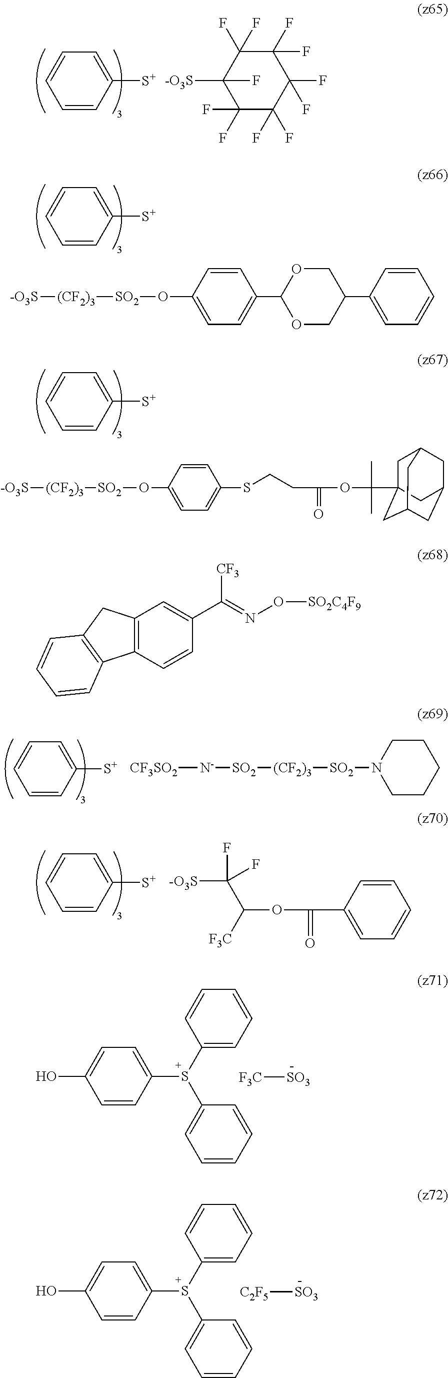

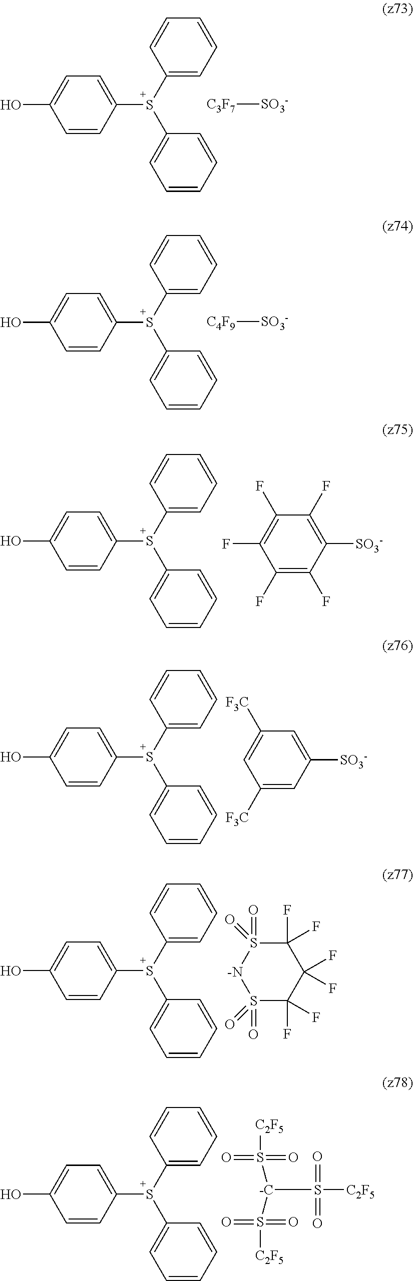

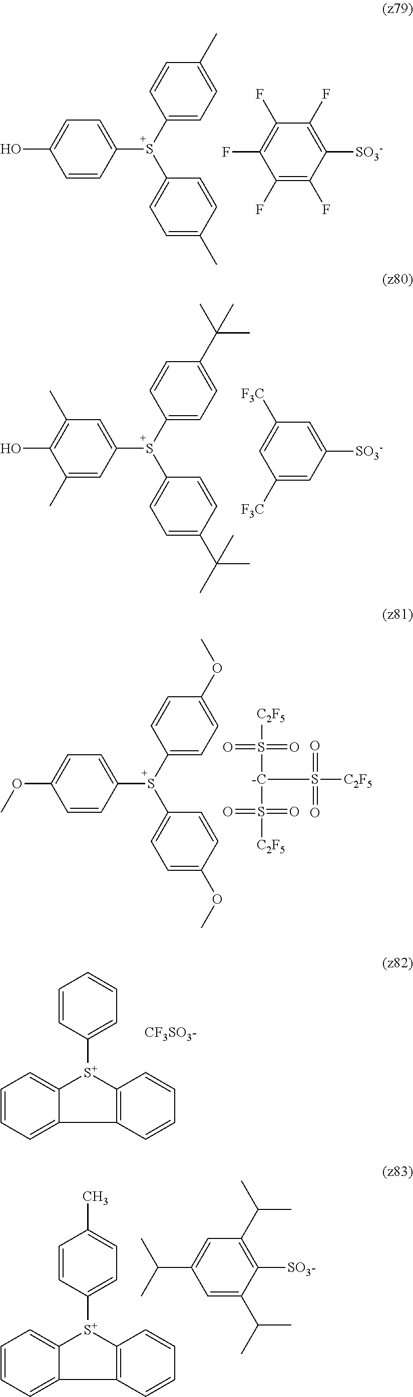

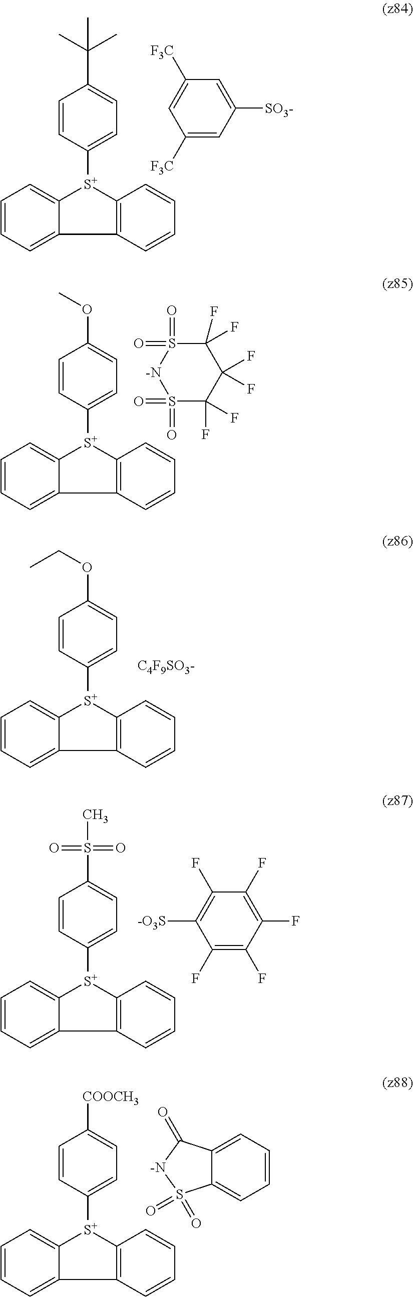

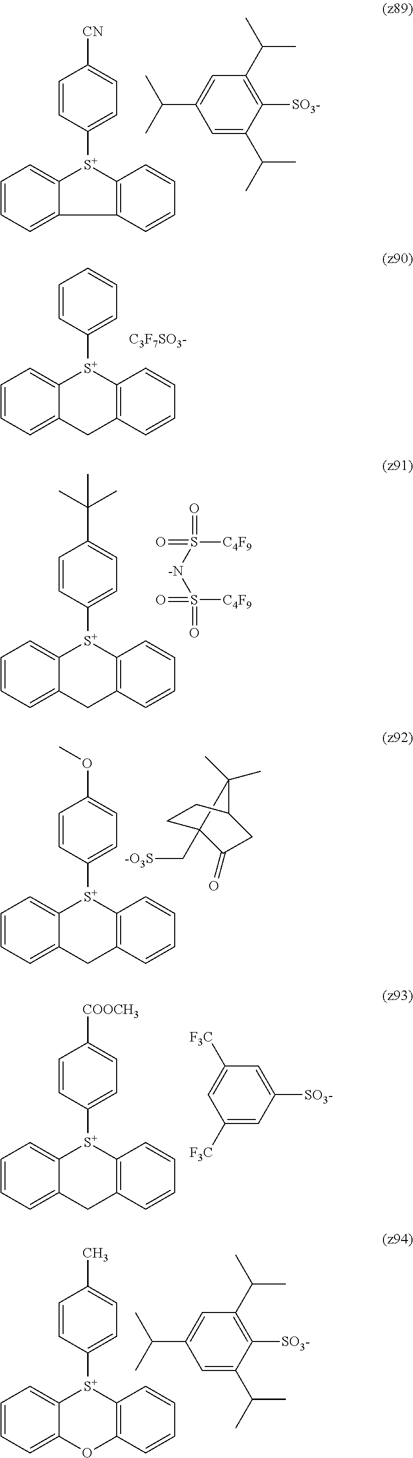

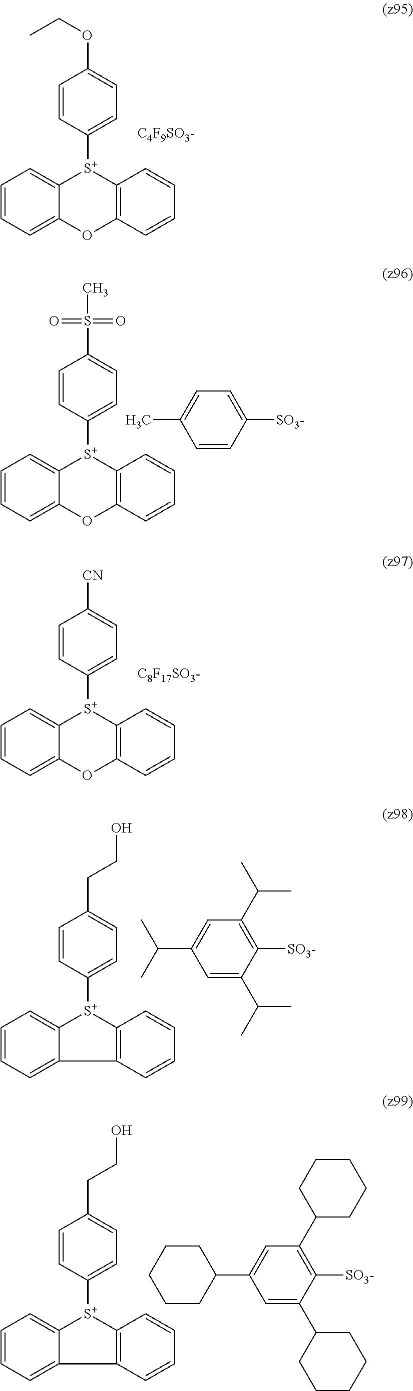

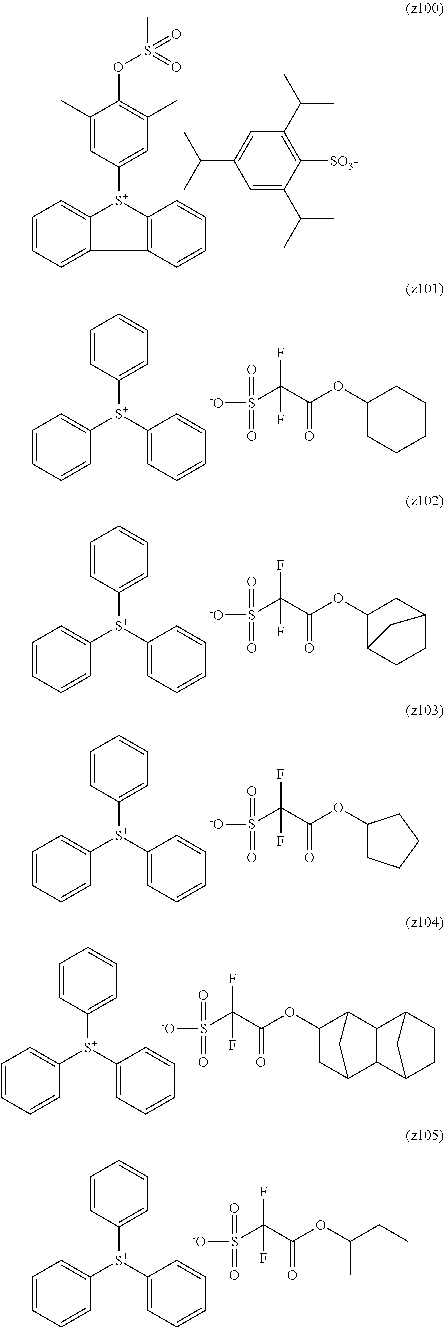

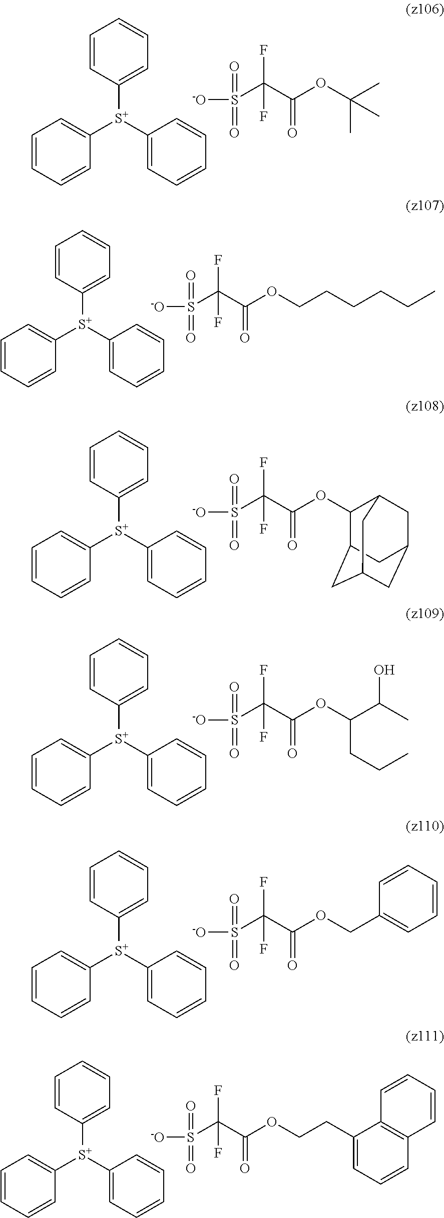

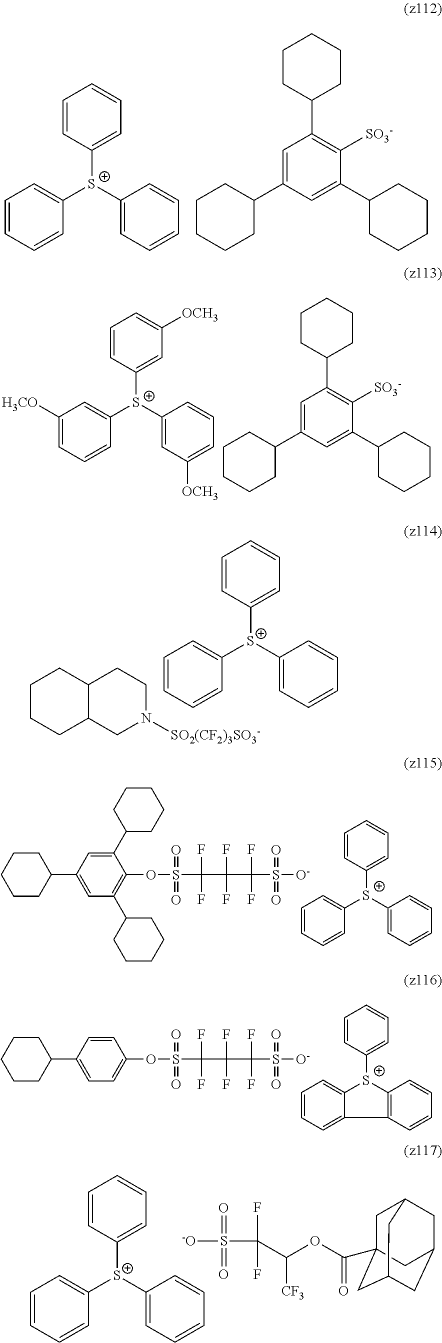

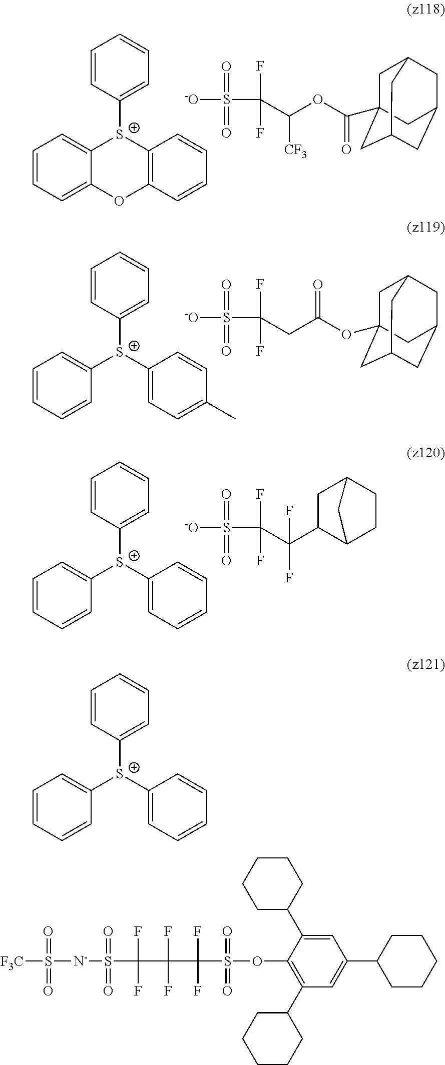

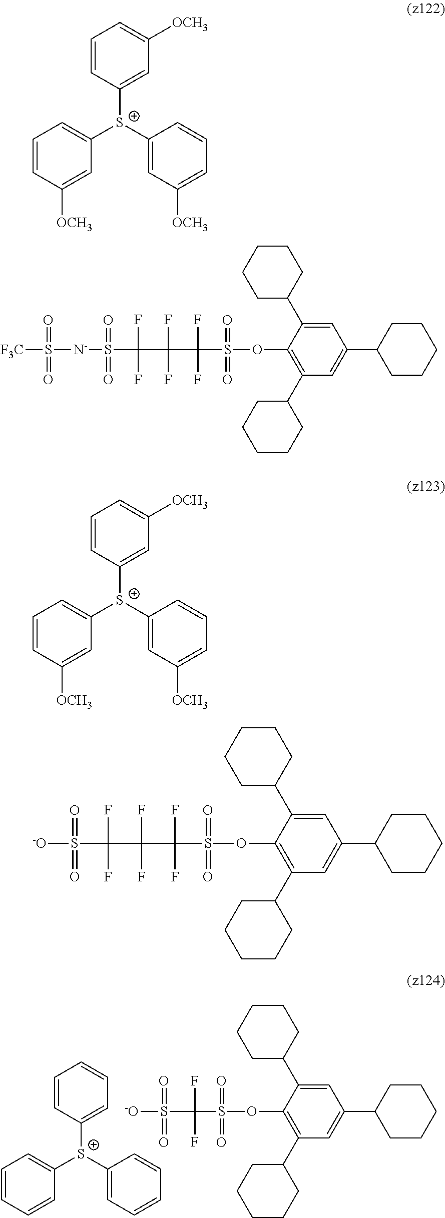

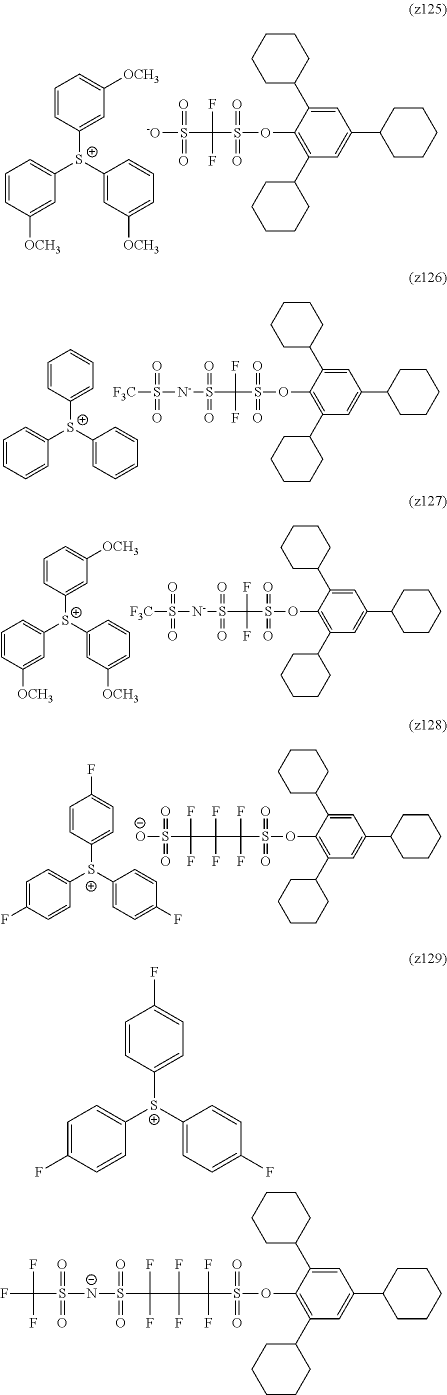

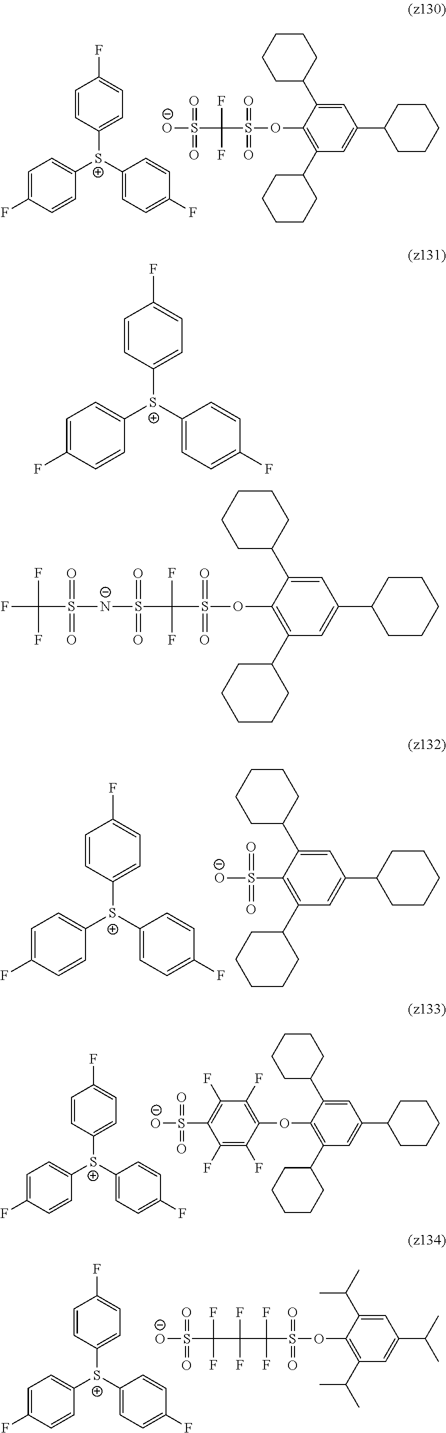

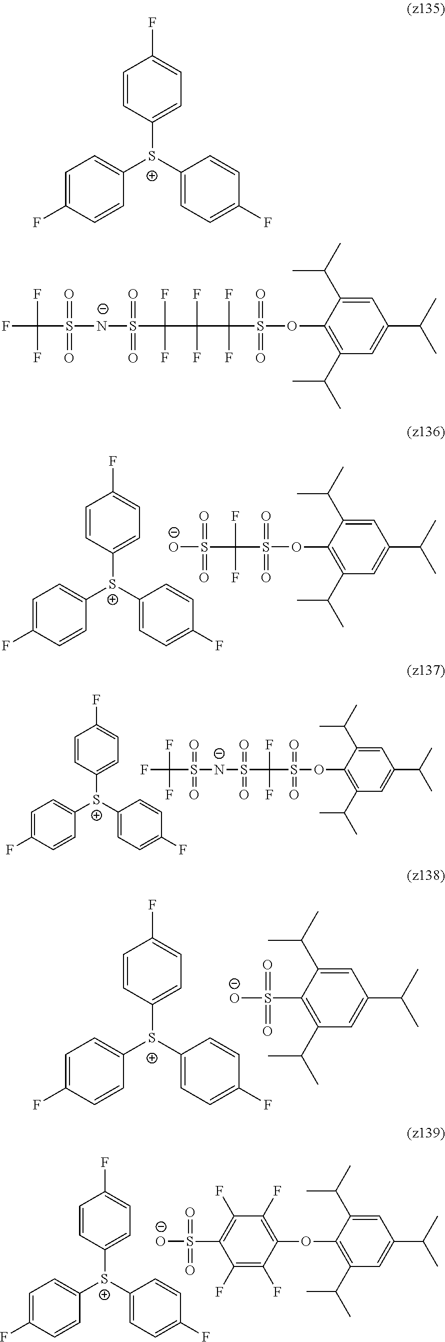

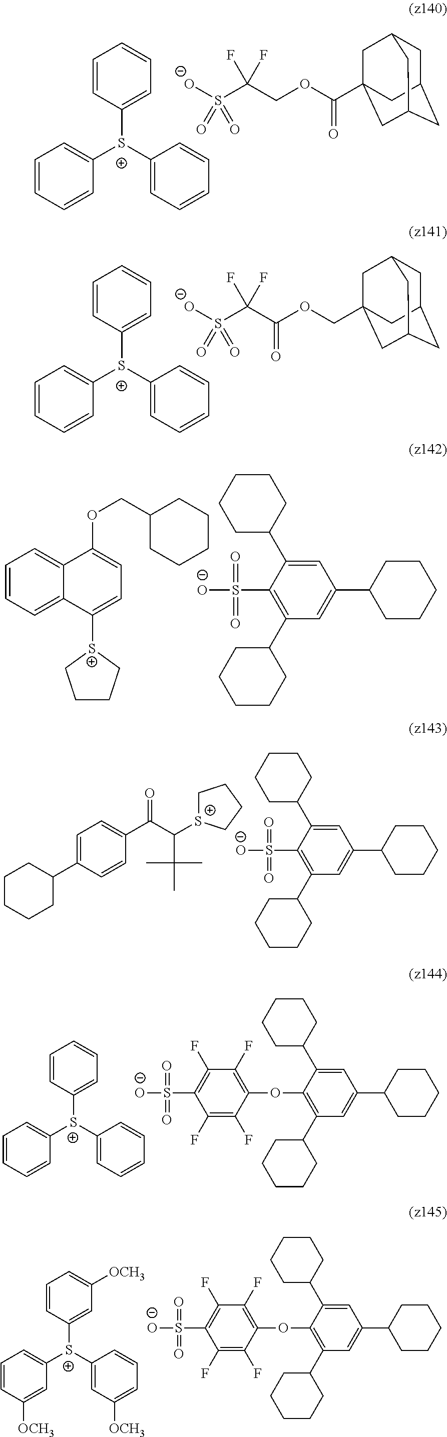

The acid generators can be used alone, or two or more types thereof can be used in combination.

The content of the acid generator is preferably 0.1% by mass to 50% by mass, more preferably 0.5% by mass to 45% by mass, and still more preferably 1% by mass to 40% by mass, based on the total solid content of the composition.

[4] Compound that Generates Acid by being Decomposed Due to Action of Acid

The actinic ray sensitive or radiation sensitive resin composition of the present invention may further include one or two or more types of compound that generates an acid by being decomposed due to the action of an acid. The acid generated by the compound that generates an acid by being decomposed due to the action of an acid is preferably sulfonic acid, methide acid, or imidic acid.

Examples of the compound that generates an acid by being decomposed due to the action of an acid which can be used in the present invention will be shown below, but the present invention is not limited thereto.

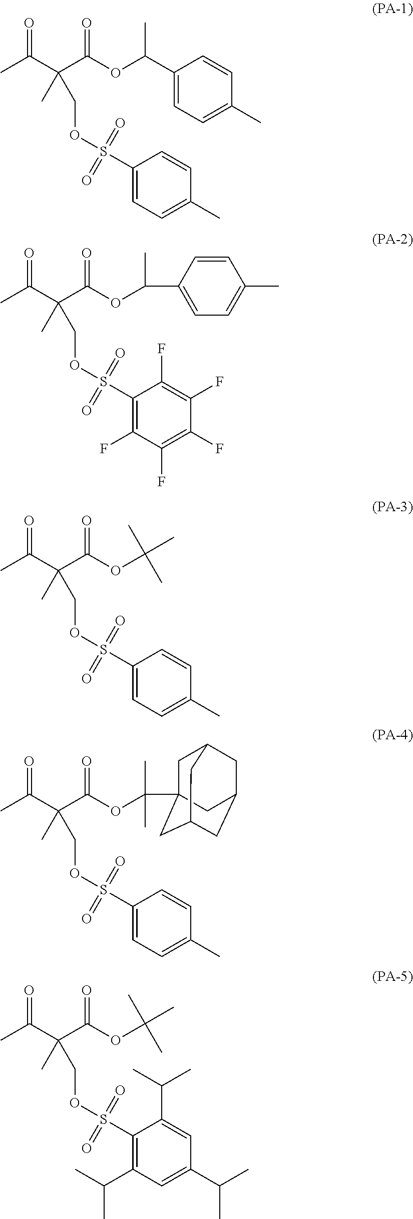

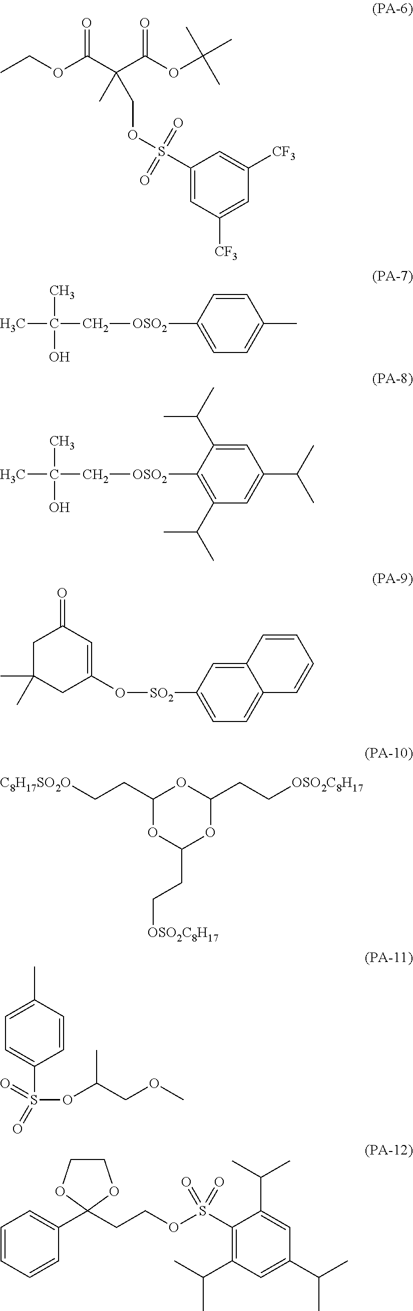

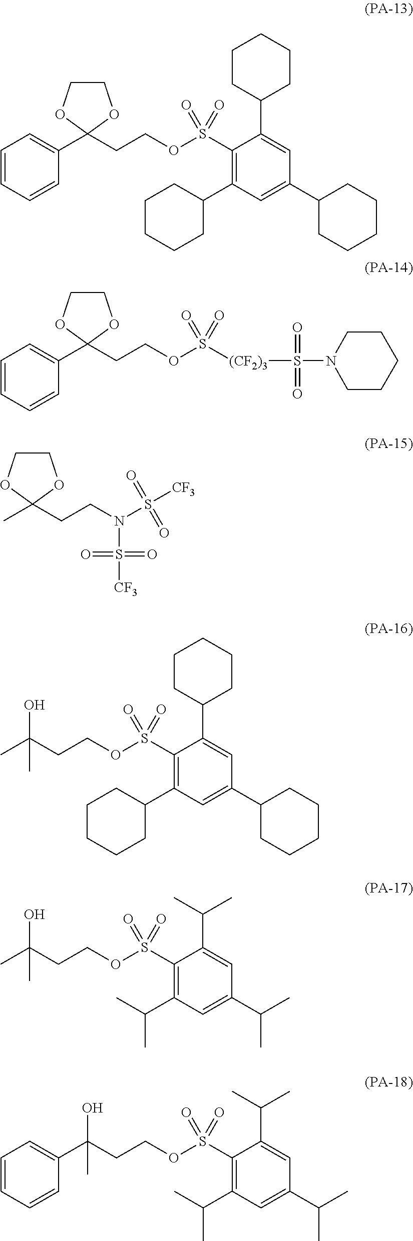

The compounds that generate an acid by being decomposed due to the action of an acid may be used alone or two or more types thereof can be used in combination.

The content of the compound that generates an acid by being decomposed due to the action of an acid is preferably 0.1% by mass to 40% by mass, more preferably 0.5% by mass to 30% by mass, and still more preferably 1.0% by mass to 20% by mass, based on the total solid content of the actinic ray sensitive or radiation sensitive resin composition.

[5] (C) Resist Solvent (Coating Solvent)

The solvent which can be used when preparing the composition is not particularly limited as long as each component is dissolved therein and examples thereof include an alkylene glycol monoalkyl ether carboxylate (propylene glycol monomethyl ether acetate (PGMEA; also referred to as 1-methoxy-2-acetoxypropane) and the like), an alkylene glycol monoalkyl ether (propylene glycol monomethyl ether (PGME; also referred to as 1-methoxy-2-propanol) and the like), an alkyl lactate ester (ethyl lactate, methyl lactate, and the like), a cyclic lactone (γ-butyrolactone and the like which preferably has 4 to 10 carbon atoms), a chain-like or a cyclic ketone (2-heptanone, cyclohexanone, and the like which preferably has 4 to 10 carbon atoms), an alkylene carbonate (ethylene carbonate, propylene carbonate, and the like), an alkyl carboxylate (an alkyl acetate such as butyl acetate is preferable), and an alkyl alkoxyacetate (ethyl ethoxypropionate). Other examples of the solvent which can be used include the solvents described in paragraphs “0244” and later of US2008/0248425A1.

Among these, an alkylene glycol monoalkyl ether carboxylate, or an alkylene glycol monoalkyl ether is preferable.

These solvents may be used alone or in a mixture of two or more types thereof. In a case where two or more types are mixed, it is preferable to mix a solvent having a hydroxyl group and a solvent not having a hydroxyl group. The mass ratio of the solvent having a hydroxyl group and the solvent not having a hydroxyl group is 1/99 to 99/1, preferably 10/90 to 90/10, and still more preferably 20/80 to 60/40.

The solvent having a hydroxyl group is preferably an alkylene glycol monoalkyl ether, and the solvent not having a hydroxyl group is preferably an alkylene glycol monoalkyl ether carboxylate.

[6] Basic Compound

The actinic ray sensitive or radiation sensitive resin composition according to the present invention may further include a basic compound. The basic compound is preferably a compound having a stronger basicity compared to phenol. In addition, the basic compound is preferably an organic basic compound, and more preferably a nitrogen-containing basic compound.

The nitrogen-containing basic compound which is able to be used is not particularly limited, but for example, the compounds which are classified into (1) to (7) below can be used.

(1) Compound Represented by General Formula (BS-1)

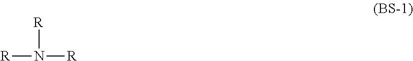

In General Formula (BS-1), each of R's independently represents a hydrogen atom or an organic group. Here, at least one of three R's is an organic group. This organic group is a linear or branched alkyl group, a monocyclic or polycyclic cycloalkyl group, an aryl group, or an aralkyl group.

The number of carbon atoms in the alkyl group represented by R is not particularly limited, but is typically 1 to 20, and preferably 1 to 12.

The number of carbon atoms in the cycloalkyl group represented by R is not particularly limited, but is typically 3 to 20, and preferably 5 to 15.

The number of carbon atoms in the aryl group represented by R is not particularly limited, but is typically 6 to 20, and preferably 6 to 10. Specific examples thereof include a phenyl group and a naphthyl group.

The number of carbon atoms in the aralkyl group represented by R is not particularly limited, but is normally 7 to 20, and preferably 7 to 11. Specifically, examples thereof include a benzyl group.

A hydrogen atom in the alkyl group, the cycloalkyl group, the aryl group, or the aralkyl group represented by R may be substituted with a substituent. Examples of the substituent include an alkyl group, a cycloalkyl group, an aryl group, an aralkyl group, a hydroxy group, a carboxy group, an alkoxy group, an aryloxy group, an alkylcarbonyloxy group, and an alkyloxycarbonyl group.

At least two of R's in the compound represented by General Formula (BS-1) are preferably organic groups.

Specific examples of the compound represented by General Formula (BS-1) include tri-n-butyl amine, tri-n-pentyl amine, tri-n-octyl amine, tri-n-decyl amine, triisodecyl amine, dicyclohexyl methyl amine, tetradecyl amine, pentadecyl amine, hexadecyl amine, octadecyl amine, didecyl amine, methyl octadecyl amine, dimethyl undecyl amine, N,N-dimethyl dodecyl amine, methyl dioctadecyl amine, N,N-dibutyl aniline, N,N-dihexyl aniline, 2,6-diisopropyl aniline, and 2,4,6-tri(t-butyl)aniline.

In addition, as the preferable basic compound represented by General Formula (BS-1), an alkyl group in which at least one R is substituted with a hydroxy group is exemplified. Specific examples thereof include triethanol amine and N,N-dihydroxyethyl aniline.

The alkyl group represented by R may have an oxygen atom in the alkyl chain. That is, an oxyalkylene chain may be formed. As the oxyalkylene chain, —CH₂CH₂O— is preferable. Specific examples thereof include tris(methoxyethoxyethyl)amine and a compound disclosed after line 60 of column 3 in the specification of U.S. Pat. No. 6,040,112A.

In particular, among basic compounds represented by General Formula (BS-1), examples of a compound having a hydroxyl group or an oxygen atom as described above include the following.

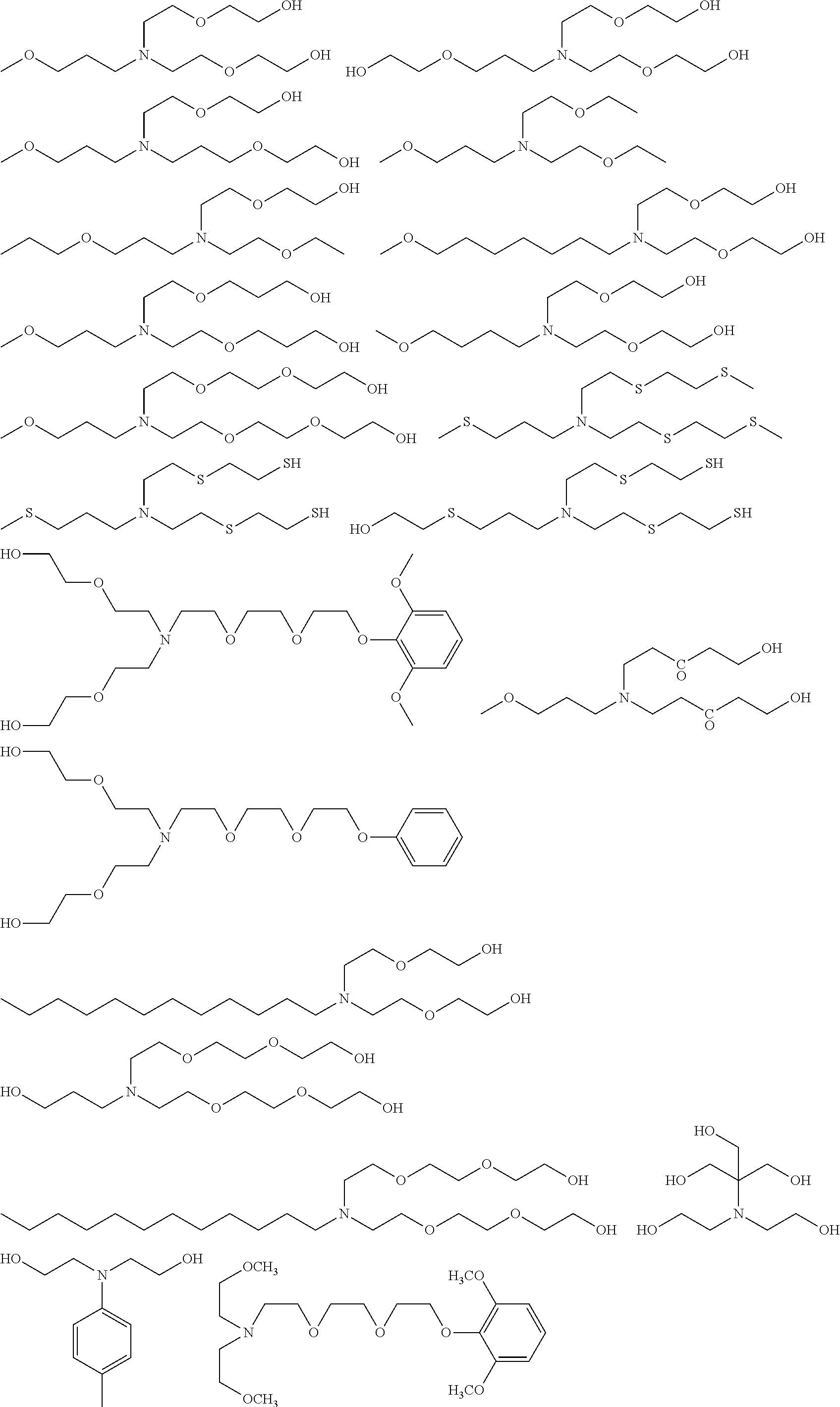

(2) Compound Having Nitrogen-Containing Heterocyclic Structure

The nitrogen-containing heterocycle may have aromatic properties, or may not have aromatic properties. The nitrogen-containing heterocycle may have a plurality of nitrogen atoms. Furthermore, the nitrogen-containing heterocycle may contain heteroatoms other than the nitrogen atom. Specific examples thereof include a compound having an imidazole structure (2-phenylbenzimidazole, 2,4,5-triphenylimidazole, and the like), a compound having a piperidine structure [N-hydroxyethylpiperidine, bis(1,2,2,6,6-pentamethyl-4-piperidyl)sebacate, and the like], a compound having a pyridine structure (4-dimethylaminopyridine and the like), and a compound having an antipyrine structure (antipyrine, hydroxyantipyrine, and the like).

Examples of the preferable compound having a nitrogen-containing heterocyclic structure include guanidine, aminopyridine, aminoalkyl pyridine, aminopyrrolidine, indazole, imidazole, pyrazole, pyrazine, pyrimidine, purine, imidazoline, pyrazoline, piperazine, aminomorpholine, and aminoalkyl morpholine. These may further have a substituent.

Examples of the preferable substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Examples of a particularly preferable basic compound include imidazole, 2-methylimidazole, 4-methylimidazole, N-methylimidazole, 2-phenylimidazole, 4,5-diphenyl midazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethyl yridine, 3-aminopyrrolidine, piperazine, N-(2-aminoethyl)piperazine, N-(2-aminoethyl) piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methyl pyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

A compound having two or more ring structures can also be suitably used. Specific examples thereof include 1,5-diazabicyclo[4.3.0]non-5-ene and 1,8-diazabicyclo[5.4.0]undec-7-ene.

(3) Amine Compound Having Phenoxy Group

An amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an acyloxy group, or an aryloxy group.

The compound more preferably has at least one oxyalkylene chain between the phenoxy group and the nitrogen atom. The number of oxyalkylene chains in one molecule is preferably 3 to 9, and more preferably 4 to 6. Among the oxyalkylene chains, —CH₂CH₂O— is particularly preferable.

Specific examples thereof include 2-[2-{2-(2,2-dimethoxyphenoxyethoxy)ethyl}-bis-(2-methoxy-ethyl)-amine and the compounds (C1-1) to (C3-3) exemplified in paragraph “0066” in the specification of US2007/0224539A1.

An amine compound having a phenoxy group is obtained by, for example, heating a mixture of a primary or secondary amine having a phenoxy group and a haloalkyl ether to be reacted, by adding an aqueous solution of a strong base such as sodium hydroxide, potassium hydroxide, or tetraalkylammonium thereto, and by extracting the resultant product with an organic solvent such as ethyl acetate or chloroform. In addition, an amine compound having a phenoxy group can also be obtained by heating a mixture of a primary or secondary amine and a haloalkyl ether having a phenoxy group at the terminal to be reacted, by adding an aqueous solution of a strong base such as sodium hydroxide, potassium hydroxide, or tetraalkylammonium thereto, and by extracting the resultant product with an organic solvent such as ethyl acetate or chloroform.

(4) Ammonium Salt

It is also possible to suitably use an ammonium salt as the basic compound.

As the cation of the ammonium salt, a tetraalkylammonium cation in which an alkyl group having 1 to 18 carbon atoms is substituted is preferable, a tetramethylammonium cation, a tetraethylammonium cation, a tetra(n-propyl)ammonium cation, a tetra(n-butyl)ammonium cation, a tetra(n-heptyl)ammonium cation, a tetra(n-octyl)ammonium cation, a dimethylhexadecylammonium cation, or a benzyltrimethyl cation is more preferable, and tetra(n-butyl)ammonium cation is most preferable.

Examples of the anion of the ammonium salt include halide, sulfonate, borate, phosphate, hydroxide, and carboxylate. Among these, hydroxide or carboxylate is particularly preferable.

As the halide, chloride, bromide, or iodide is particularly preferable.

As the sulfonate, an organic sulfonate having 1 to 20 carbon atoms is particularly preferable. Examples of the organic sulfonate include alkyl sulfonate and aryl sulfonate, having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzyl sulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, or a cyclohexyl group is preferable. Examples of other substituents include an alkoxy group having 1 to 6 carbon atoms, a halogen atom, a cyano group, a nitro group, an acyl group, and an acyloxy group.

The carboxylate may be an aliphatic carboxylate or an aromatic carboxylate, and examples thereof include acetate, lactate, pyruvate, trifluoroacetate, adamantane carboxylate, hydroxyadamantane carboxylate, benzoate, naphthoate, salicylate, phthalate, and phenolate, and, in particular, benzoate, naphthoate, or phenolate is preferable, and benzoate is most preferable.

In this case, as the ammonium salt, tetra(n-butyl)ammonium benzoate or tetra(n-butyl)ammonium phenolate is preferable.

In a case where the ammonium salt is hydroxide, the ammonium salt is particularly preferably tetraalkylammonium hydroxide (tetraalkylammonium hydroxide such as tetramethylammonium hydroxide, tetraethylammonium hydroxide, or tetra-(n-butyl)ammonium hydroxide) having 1 to 8 carbon atoms.

(5) Compound (PA) which has Proton-Accepting Functional Group and Generates Compound in which Proton-Acceptability is Reduced or Lost, or which is Changed from being Proton-Accepting to be Acidic, by being Decomposed by Irradiation with Actinic Ray or Radiation

The composition according to the present invention may further include a compound (hereinafter, referred to as “compound (PA)”) which has a proton-accepting functional group and generates a compound in which the proton-acceptability is reduced or lost, or which is changed from being proton-accepting to be acidic, by being decomposed due to irradiation with actinic ray or radiation, as a basic compound.

The proton-accepting functional group is a group which can electrostatically interact with a proton or a functional group having electrons, and, for example, means a functional group having a macrocyclic structure such as cyclic polyether or a functional group having a nitrogen atom having an unshared electron pair not contributing to n-conjugation. The nitrogen atom having an unshared electron pair not contributing to n-conjugation, for example, is a nitrogen atom having a substructure shown in the following general formula.

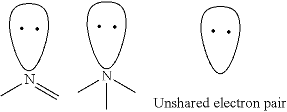

Examples of the compound (PA) include the compounds described in paragraphs “0294” to “0326” of JP2013-029751A.

(6) Guanidine Compound

The composition of the present invention may further contain a guanidine compound having a structure represented by the following formula.

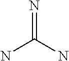

The guanidine compound exhibits strong basicity since the positive charge of the conjugate acid is dispersed and stabilized by the three nitrogen atoms.

For the basicity of the guanidine compound (A) of the present invention, the pKa of a conjugate acid is preferably 6.0 or greater, preferably 7.0 to 20.0 since neutralization reactivity with an acid is high and the roughness properties are excellent, and more preferably 8.0 to 16.0.

Examples of the guanidine compound include the compounds described in paragraphs “0535” to “0549” of JP2013-137537A.

(7) Low Molecular Weight Compound Having Nitrogen Atom and Group Leaving Due to Action of Acid

The composition of the present invention can contain a low molecular weight compound (hereinafter, also referred to as a “low molecular weight compound (D)” or “compound (D)”) having a nitrogen atom and a group leaving due to the action of an acid. The low molecular weight compound (D) preferably has basicity, after a group leaving due to the action of an acid leaves.

Although the group leaving due to the action of an acid is not particularly limited, an acetal group, a carbonate group, a carbamate group, a tertiary ester group, a tertiary hydroxyl group, or a hemiaminal ether group is preferable, and a carbamate group or a hemiaminal ether group is particularly preferable.

The molecular weight of the low molecular weight compound (D) having a group leaving due to the action of an acid is preferably 100 to 1000, more preferably 100 to 700, and particularly preferably 100 to 500.

The compound (D) is preferably an amine derivative having a group leaving due to the action of an acid on a nitrogen atom.

Examples of the compound (D) include the compounds described in paragraphs “0550” to “0573” of JP2013-137537A.

A compound represented by General Formula (A) can be synthesized according to JP2007-298569A or JP2009-199021A.

In the present invention, the low molecular weight compound (D) can be used alone or in a mixture of two or more types thereof.

Although the composition of the present invention may or may not contain the low molecular weight compound (D), in a case where the composition contains the compound (D), the content of the compound (D) is typically 0.001% by mass to 20% by mass, preferably 0.001% by mass to 10% by mass, and more preferably 0.01% by mass to 5% by mass, based on the total solid content of the composition combined with the basic compound described above.

In addition, in a case where the composition of the present invention contains an acid generator, the use ratio of the acid generator and the compound (D) in the composition has preferably acid generator/[compound (D)+following basic compound] (molar ratio) of 2.5 to 300. That is, a molar ratio of 2.5 or greater is preferable from the viewpoint of sensitivity and resolution, and a molar ratio of 300 or less is preferable from the viewpoint of suppressing the reduction of resolution due to the thickening of the resist pattern over time until a heat treatment after exposure. The acid generator/[compound (D)+the basic compound] (molar ratio) is more preferably 5.0 to 200 and still more preferably 7.0 to 150.

Other than this, examples of the compound which can be used in the composition according to the present invention include the compounds synthesized in Examples of JP2002-363146A and the compounds described in paragraph “0108” of JP2007-298569A.

As the basic compound, a photosensitive basic compound may be used. As the photosensitive basic compound, for example, the compounds described in JP2003-524799A, J. Photopolym. Sci. & Tech. Vol. 8, P. 543-553 (1995), and the like as can be used.

The molecular weight of the basic compound is typically 100 to 1500, preferably 150 to 1300, and more preferably 200 to 1000.

These basic compounds may be used alone or in combination of two or more types thereof.

In a case where the composition according to the present invention includes the basic compound, the content thereof is preferably 0.01% by mass to 8.0% by mass, more preferably 0.1% by mass to 5.0% by mass, and particularly preferably 0.2% by mass to 4.0% by mass, based on the total solid content of the composition.

The molar ratio of the basic compound with respect to the photoacid generator is preferably set to 0.01 to 10, more preferably set to 0.05 to 5, and still more preferably set to 0.1 to 3. When the molar ratio is excessively large, sensitivity and/or resolution is reduced in some cases. When the molar ratio is excessively small, there is a possibility that thinning of a pattern occurs, during exposure and heating (post-baking). The molar ratio is more preferably 0.05 to 5, and still more preferably 0.1 to 3. Moreover, the photoacid generator in the molar ratio is based on the total amount of the repeating unit (B) of the resin and the photoacid generator which the resin further may include.

[7] Hydrophobic Resin (HR)

The actinic ray sensitive or radiation sensitive resin composition of the present invention may have a hydrophobic resin (HR) separately from the resin (Ab).

The hydrophobic resin (HR) preferably contains a group having a fluorine atom, a group having a silicon atom, or a hydrocarbon group having 5 or more carbon atoms, in order to be unevenly distributed on a film surface. These groups may be contained in the main chain of the resin or may be substituted in the side chain. Specific examples of the hydrophobic resin (HR) will be shown below.

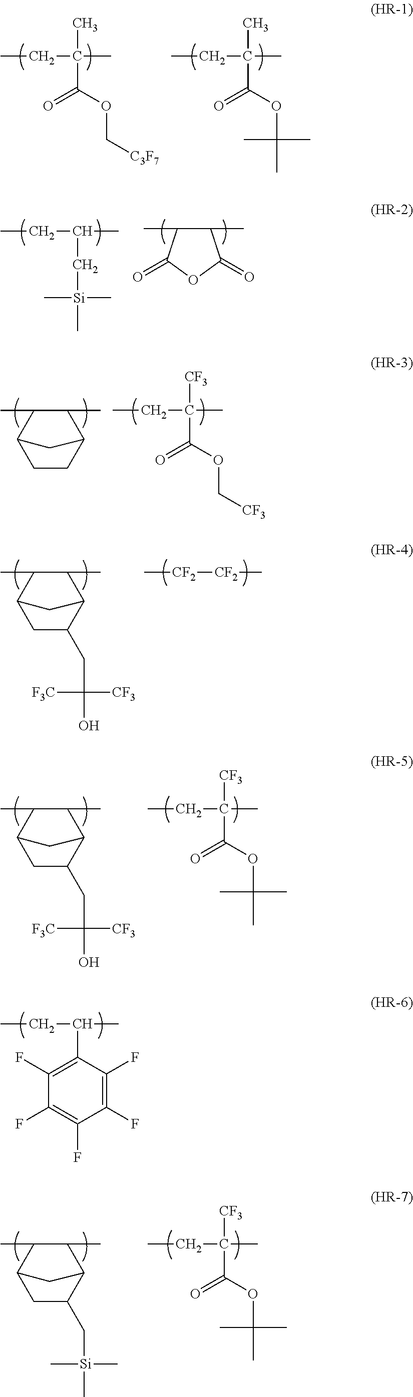

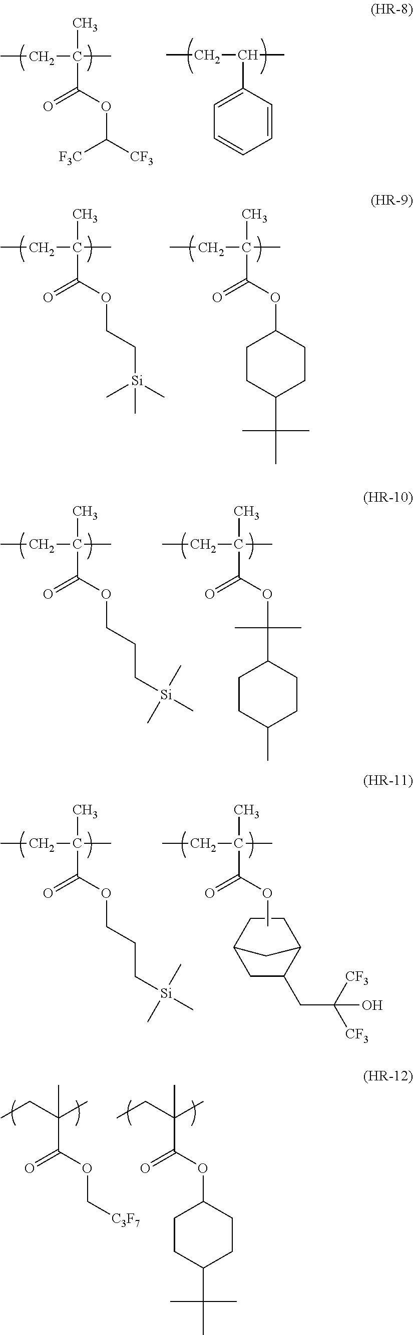

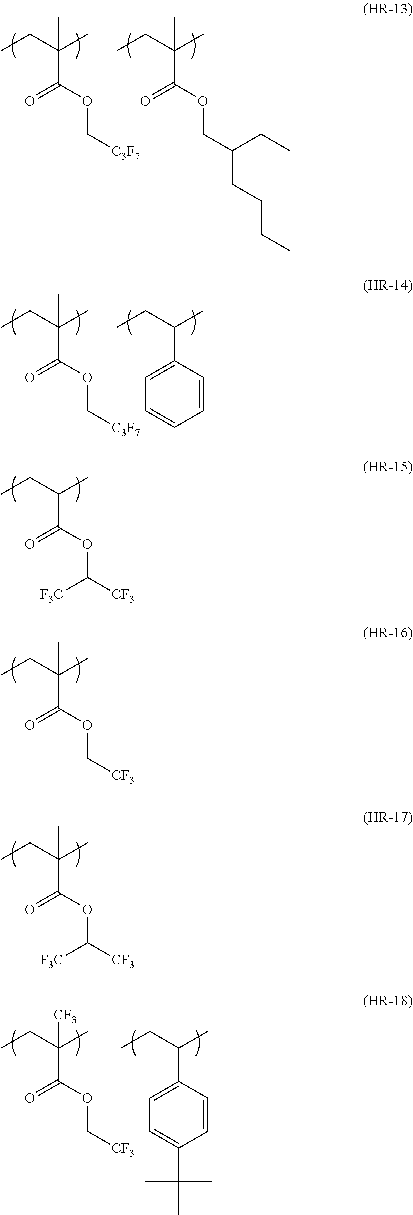

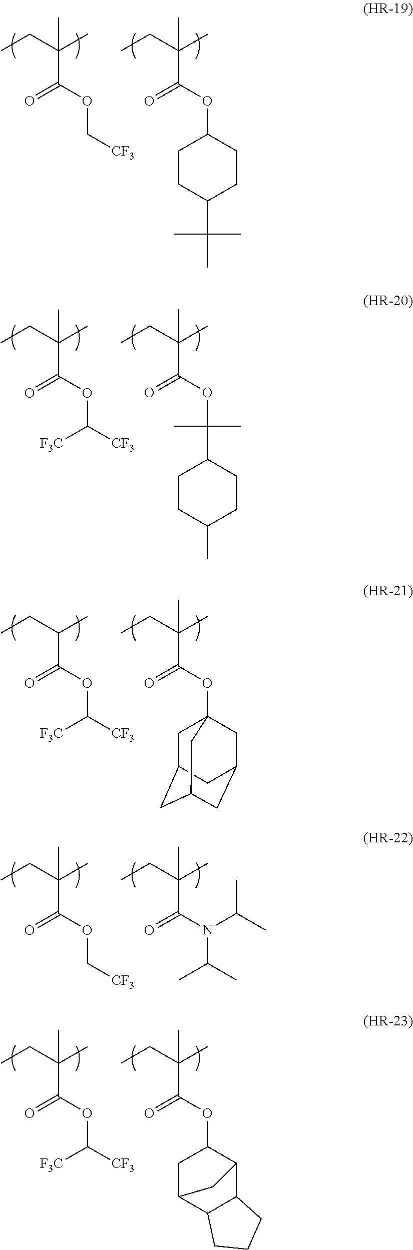

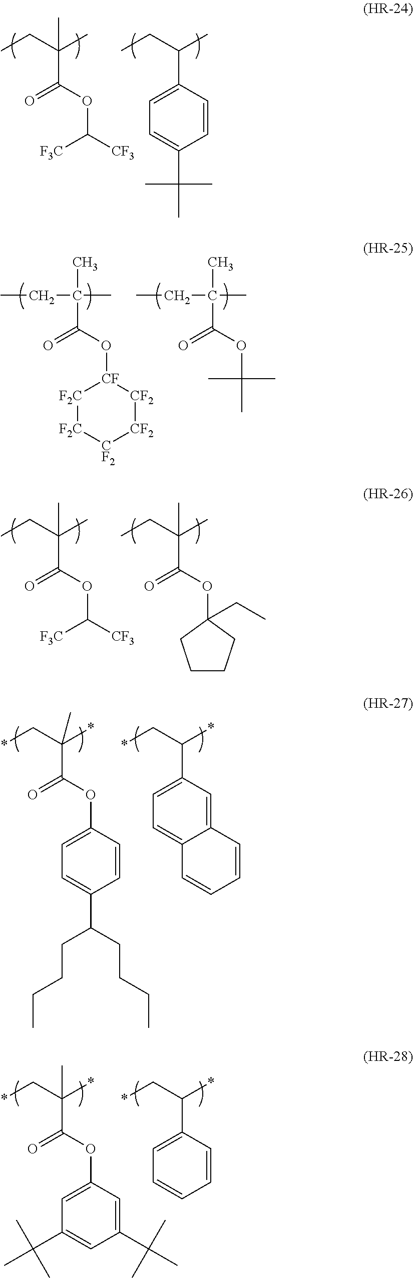

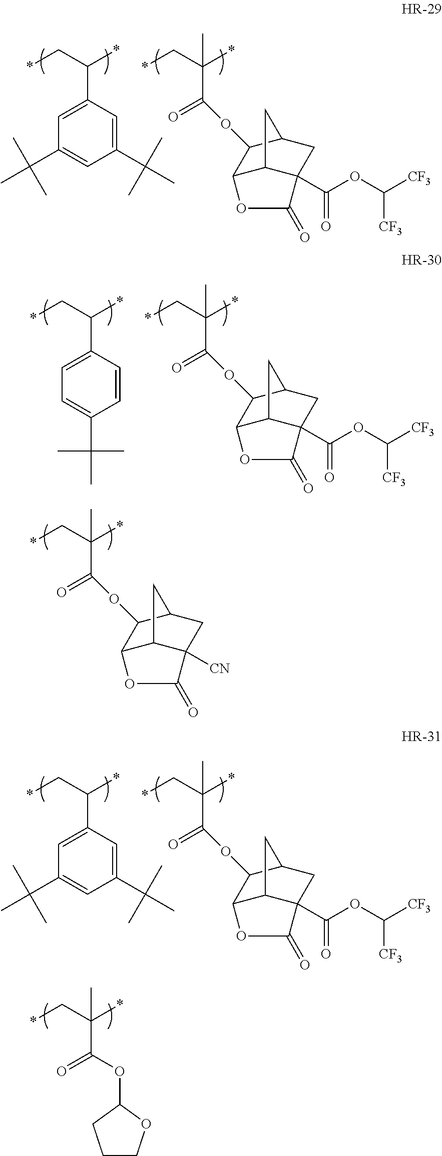

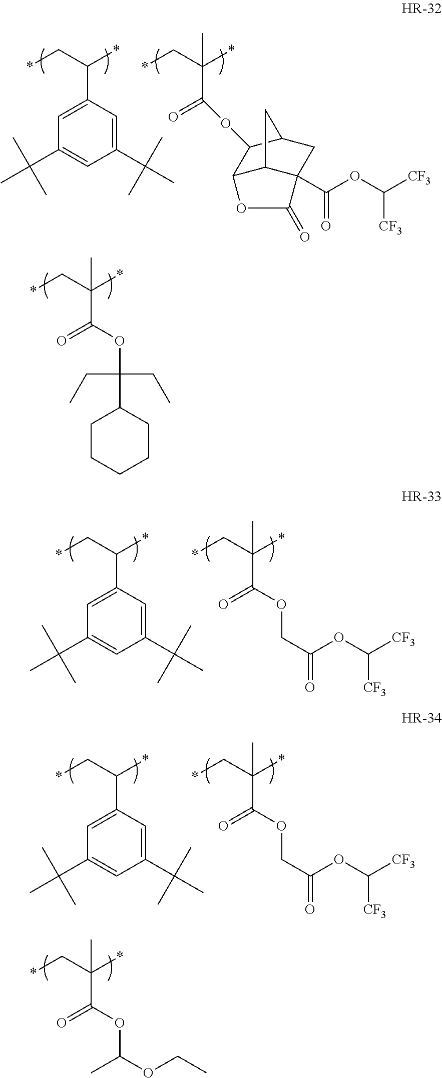

The weight average molecular weight of the hydrophobic resin (D) in terms of standard polystyrene is preferably 1,000 to 100,000, more preferably 1,000 to 50,000, and still more preferably 2,000 to 15,000.

In addition, the hydrophobic resin (D) may be used alone or in combination of a plurality of types thereof.

The content of the hydrophobic resin (D) in a composition is preferably 0.01% by mass to 10% by mass, more preferably 0.05% by mass to 8% by mass, and still more preferably 0.1% by mass to 7% by mass, with respect to the total solid content of the composition of the present invention.

In addition to the above hydrophobic resins, the hydrophobic resins described in JP2011-248019A, JP2010-175859A, or JP 2012-032544A can also be preferably used.

[8] Surfactant

The composition according to the present invention may further include a surfactant. Due to a surfactant being contained, in a case where an exposure light source having a wavelength of 250 nm or less is used, in particular, 220 nm or less, a pattern having less adhesion and development defect can be formed with a favorable sensitivity and resolution.

As the surfactant, a fluorine-based surfactant and/or a silicon-based surfactant is particularly preferably used.

Examples of the fluorine-based surfactant and/or the silicon-based surfactant include surfactants described in paragraph “0276” in the specification of US2008/0248425A. In addition, F Top EF301 or EF303 (manufactured by Shin-Akita Kasei Co., Ltd.); Fluorad FC430, 431, or 4430 (manufactured by Sumitomo 3M Ltd.); Megafac F171, F173, F176, F189, F113, F110, F177, F120, or R08 (manufactured by DIC Corporation); Surflon S-382, SC101, 102, 103, 104, 105, or 106 (manufactured by Asahi Glass Co., Ltd.); Troysol S-366 (manufactured by Troy Chemical Corp.); GF-300 or GF-150 (manufactured by Toagosei Chemical Industry Co., Ltd.), Surflon S-393 (manufactured by AGC Seimi Chemical Co., Ltd.); Eftop EF121, EF122A, EF122B, RF122C, EF125M, EF135M, EF351, EF352, EF801, EF802, or EF601 (manufactured by Jemco Co., Ltd); PF636, PF656, PF6320, or PF6520 (manufactured by OMNOVA Solutions Inc.); or FTX-204G, 208G, 218G, 230G, 204D, 208D, 212D, 218D, or 222D (manufactured by Neos Company Limited) may be used. Moreover, a polysiloxane polymer KP-341 (manufactured by Shin-Etsu Chemical Co., Ltd.) can also be used as a silicon-based surfactant.

In addition, in addition to the known surfactants as described above, the surfactant may be synthesized using a fluoroaliphatic compound prepared by a telomerization method (also referred to as a telomer method) or an oligomerization method (also referred to as an oligomer method). Specifically, a polymer having a fluoroaliphatic group derived from the fluoroaliphatic compound may be used as a surfactant. The fluoroaliphatic compound can be synthesized by the method described in JP2002-90991A.

As the polymer having a fluoroaliphatic group, a copolymer of a monomer having a fluoroaliphatic group and (poly(oxyalkylene))acrylate or methacrylate and/or (poly(oxyalkylene))methacrylate is preferable, and the polymer may be irregularly distributed, or may be a block copolymer.

Examples of the poly(oxyalkylene) group include a poly(oxyethylene) group, a poly(oxypropylene) group, and a poly(oxybutylene) group. In addition, the poly(oxyalkylene) group may be a unit having alkylenes having different chain lengths in the same chain, such as poly(block connector of oxyethylene oxypropylene and oxyethylene) and poly(block connector of oxyethylene and oxypropylene).

Furthermore, a copolymer of a monomer having a fluoroaliphatic group and (poly(oxyalkylene))acrylate or methacrylate may be a ternary or higher compound system copolymer formed by copolymerizing a monomer having two or more types of fluoroaliphatic group and two or more types of (poly(oxyalkylene))acrylate or methacrylate at the same time.

For example, examples of a commercially available surfactant include Megafac F178, F-470, F-473, F-475, F-476, and F-472 (manufactured by DIC Corporation). Furthermore, examples of a commercially available surfactant include a copolymer of an acrylate or methacrylate having a C₆F₁₃ group and (poly(oxyalkylene))acrylate or methacrylate, a copolymer of an acrylate or methacrylate having a C₆F₁₃ group, (poly(oxyethylene))acrylate or methacrylate, and (poly(oxypropylene))acrylate or methacrylate, a copolymer of an acrylate or methacrylate having a C₈F₁₇ group and (poly(oxyalkylene))acrylate or methacrylate, and a copolymer of an acrylate or methacrylate having a C₈F₁₇ group, (poly(oxyethylene))acrylate or methacrylate, and (poly(oxypropylene))acrylate or methacrylate.

In addition, surfactants other than a fluorine-based surfactant and/or a silicon-based surfactant described in paragraph “0280” in the specification of US2008/0248425A may be used.

These surfactants may be used alone or in combination of two or more types thereof.

In a case where the composition according to the present invention includes a surfactant, the content thereof is preferably 0% by mass to 2% by mass, more preferably 0.0001% by mass to 2% by mass, and still more preferably 0.0005% by mass to 1% by mass, based on the total solid content of the composition.

[9] Other Additives

The composition of the present invention can suitably contain a carboxylic acid, an onium carboxylate salt, a dissolution inhibiting compound having a molecular weight of 3000 or less described in Proceeding of SPIE, 2724, 355 (1996) or the like, a dye, a plasticizer, a photosensitizer, a light absorber, or an antioxidant, in addition to the components described above.

In particular, a carboxylic acid is suitably used to improve performance. As the carboxylic acid, an aromatic dicarboxylic acid such as benzoic acid or naphthoic acid is preferable.

The content of the carboxylic acid is preferably 0.01% by mass to 10% by mass, more preferably 0.01% by mass to 5% by mass, and still more preferably 0.01% by mass to 3% by mass, with respect to the total solid content concentration in the composition.

The actinic ray sensitive or radiation sensitive resin composition in the present invention is preferably used in a film thickness of 10 nm to 250 nm, more preferably used in a film thickness of 20 nm to 200 nm, and still more preferably used in a film thickness of 30 nm to 100 nm, form the viewpoint of resolution improvement. By setting the solid content concentration in the composition within a suitable range to obtain a suitable viscosity, coating properties and film-forming properties are improved, and as a result, such film thicknesses can be obtained.

The solid content concentration of the actinic ray sensitive or radiation sensitive resin composition in the present invention is typically 1.0% by mass to 10% by mass, preferably 2.0% by mass to 5.7% by mass, and still more preferably 2.0% by mass to 5.3% by mass. When the solid content concentration is within the above range, it is possible to evenly apply a resist solution to a substrate, and it is possible to form a resist pattern having excellent line width roughness. The reason for this is not clear, but, it is thought that, when the solid content concentration is 10% by mass or less, preferably 5.7% by mass or less, aggregation of the material, in particular, the photoacid generator in the resist solution is suppressed, and as a result, an even resist film can be formed.

The solid content concentration is a percentage in terms of weight of the weight of the resist components excluding the solvent with respect to the total weight of the actinic ray sensitive or radiation sensitive resin composition.

For the actinic ray sensitive or radiation sensitive resin composition in the present invention, the components described above are dissolved in a predetermined organic solvent, preferably, dissolved in the mixed solvent described above, then, the resultant product is filtered using a filter, and is applied to a predetermined support (substrate), and used. As the filter used in filtration, a filter made of polytetrafluoroethylene, made of polyethylene, or made of nylon, and preferably having a pore size of 0.1 μm or less, more preferably having a pore size of 0.05 μm or less, and still more preferably having a pore size of 0.03 μm or less is preferable. In the filtration using a filter, for example, as in JP2002-62667A, circulation filtration may be performed, or filtration may be performed in a state of connecting a plurality of filters in series or in parallel. The composition may be filtered multiple times. Furthermore, before and after the filtration using a filter, the composition may be subjected to a deaeration treatment.

[Applications]

The pattern forming method of the present invention is suitably used in production of a fine semiconductor circuit such as manufacture of an ultra LSI or a high-capacity microchip. Moreover, when producing a fine semiconductor circuit, after a resist film on which a pattern has been formed is subjected to circuit formation or etching, the remaining resist film portion is ultimately removed by a solvent or the like, and thus, unlike a so-called permanent resist used for a printed circuit board or the like, in a final product such as a microchip, a resist film derived from the actinic ray sensitive or radiation sensitive resin composition described in the present invention does not remain.

### EXAMPLES

Hereinafter, the present invention will be described in further detail using examples, but the content of the invention is not limited by this.

### Synthesis Example 1

### Synthesis of Resin (P-13)

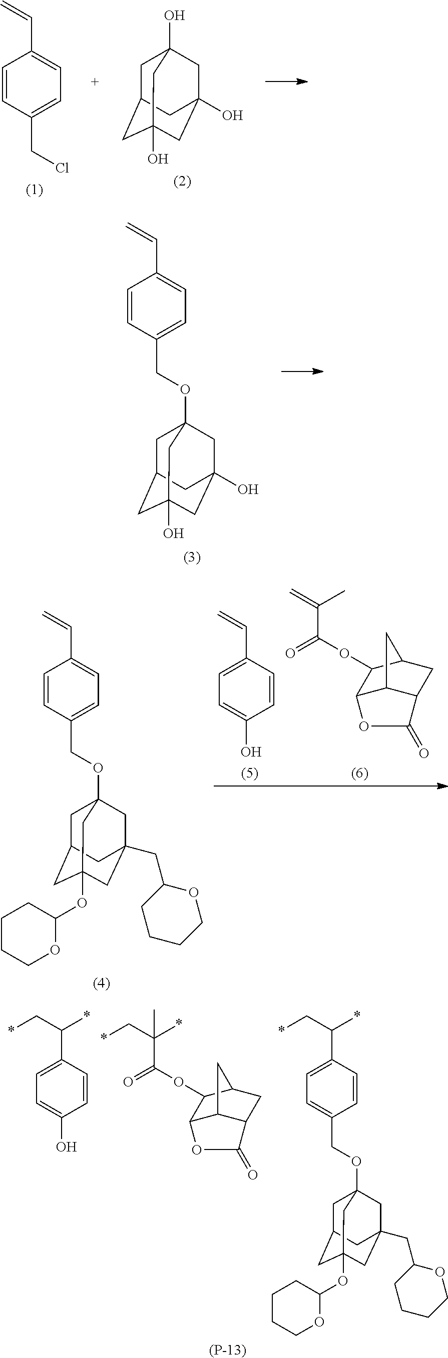

8.60 g of sodium hydride (about 60% by mass oil dispersion) was dissolved in 360.00 g of dehydrated N,N-dimethylformamide at 0° C. in a nitrogen gas atmosphere, 40.00 g of a compound (1) was added thereto, followed by stirring for 30 minutes, and 33.20 g of a compound (2) was added dropwise thereto at 0° C., followed by stirring at 50° C. for 4 hours. Thereafter, 400 g of ion exchange water was added dropwise at 20° C., and 600 g of ethyl acetate was added thereto. The organic layer was washed with 400 g of ion exchange water three times and dried over anhydrous magnesium sulfate, and then, the solvent was distilled off. The resultant product was isolated and purified by column chromatography, whereby 19.60 g of a compound (3) was obtained. 10.00 g of the compound (3) was dissolved in 60.00 g of dehydrated tetrahydrofuran, 14.00 g of 3,4-dihydro-2H-pyran was added thereto, followed by stirring at room temperature (20° C.), and 0.15 g of camphorsulfonic acid was added thereto, followed by stirring for 5 hours. After 0.34 g of triethylamine was added thereto, followed by stirring for 10 minutes, the solvent was distilled off, 200 g of ethyl acetate was added thereto, then, the organic layer was washed with 100 g of a saturated sodium hydrogencarbonate aqueous solution and 100 g of saturated sodium chloride and dried over anhydrous magnesium sulfate, and the solvent was distilled off. The resultant product was isolated and purified by column chromatography, whereby 14.80 g of a compound (4) was obtained.

1.42 g of a compound (5) (40.54% by mass cyclohexanone solution), 0.36 g of a compound (6), 4.50 g of the compound (4), and 0.15 g of a polymerization initiator V-601 (manufactured by Wako Pure Chemical Industries, Ltd.) were dissolved in 17.46 g of cyclohexanone. 9.86 g of cyclohexanone was put into a reaction vessel, and dropping into the system at 85° C. was performed over a period of 4 hours in a nitrogen gas atmosphere. The reaction solution was heated and stirred for 2 hours, and cooled to room temperature.

The reaction solution was added dropwise into 330 g of a mixed solution (heptane/ethy acetate=9/1 (mass ratio)) of heptane and ethyl acetate to precipitate a polymer, and the polymer was filtered off. Washing of the filtered solid was performed using 100 g of a mixed solution (heptane/ethy acetate=9/1 (mass ratio)) of heptane and ethyl acetate. Thereafter, the solid after washing was dried under reduced pressure, whereby 4.02 g of a resin (P-13) was obtained.

In the same manner, resins (P-1) to (P-12) and (P-14) to (P-47) were synthesized. The structure, the composition ratio (molar ratio) of repeating units, the mass average molecular weight (Mw), and the dispersity (Mw/Mn) of each of the synthesized resins are shown below.

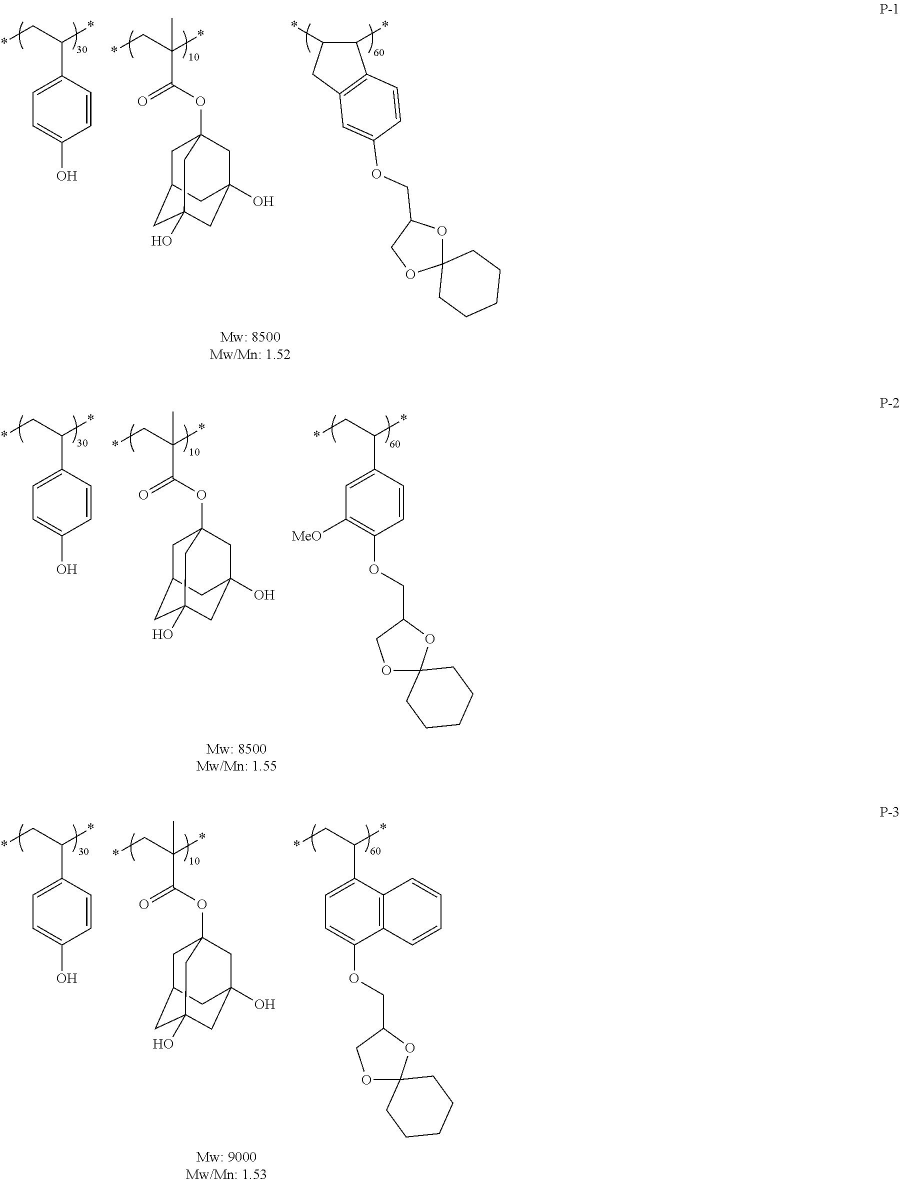

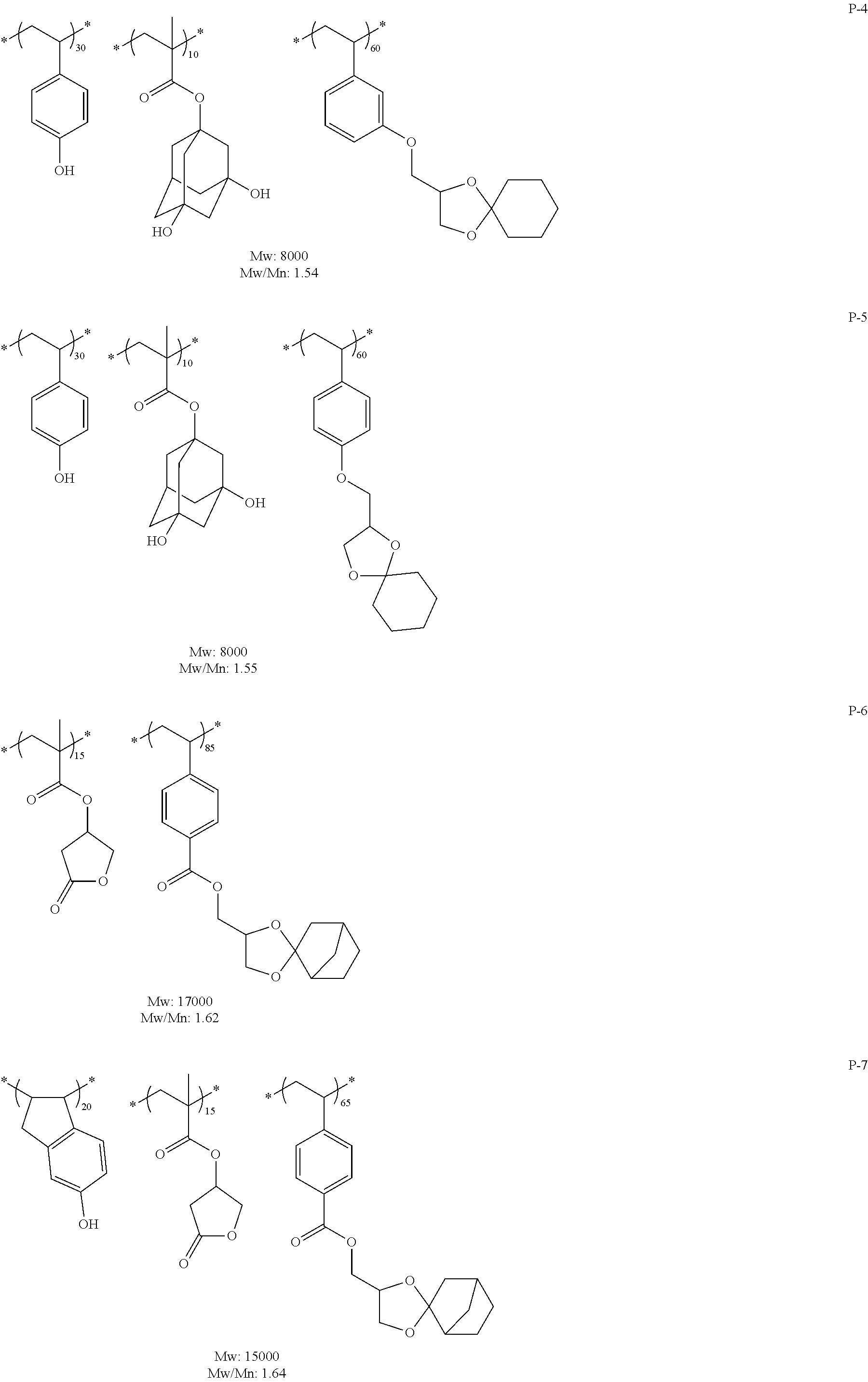

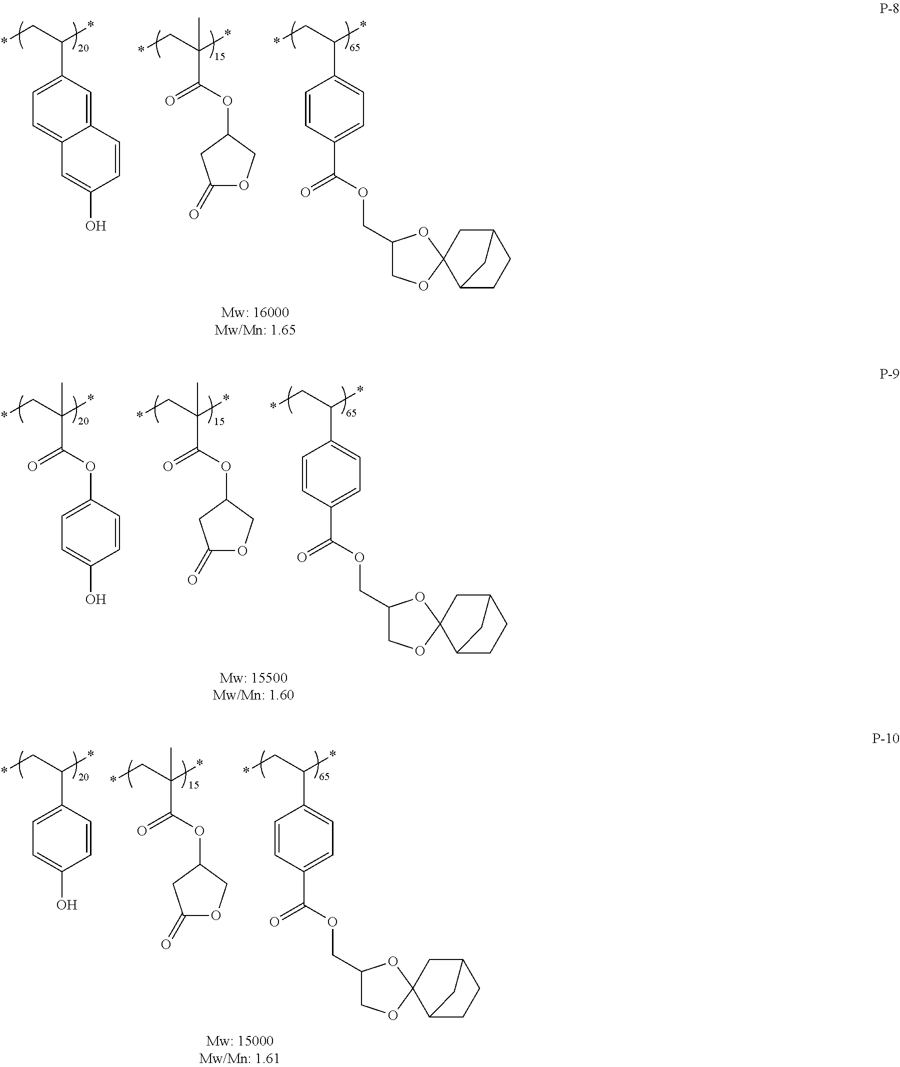

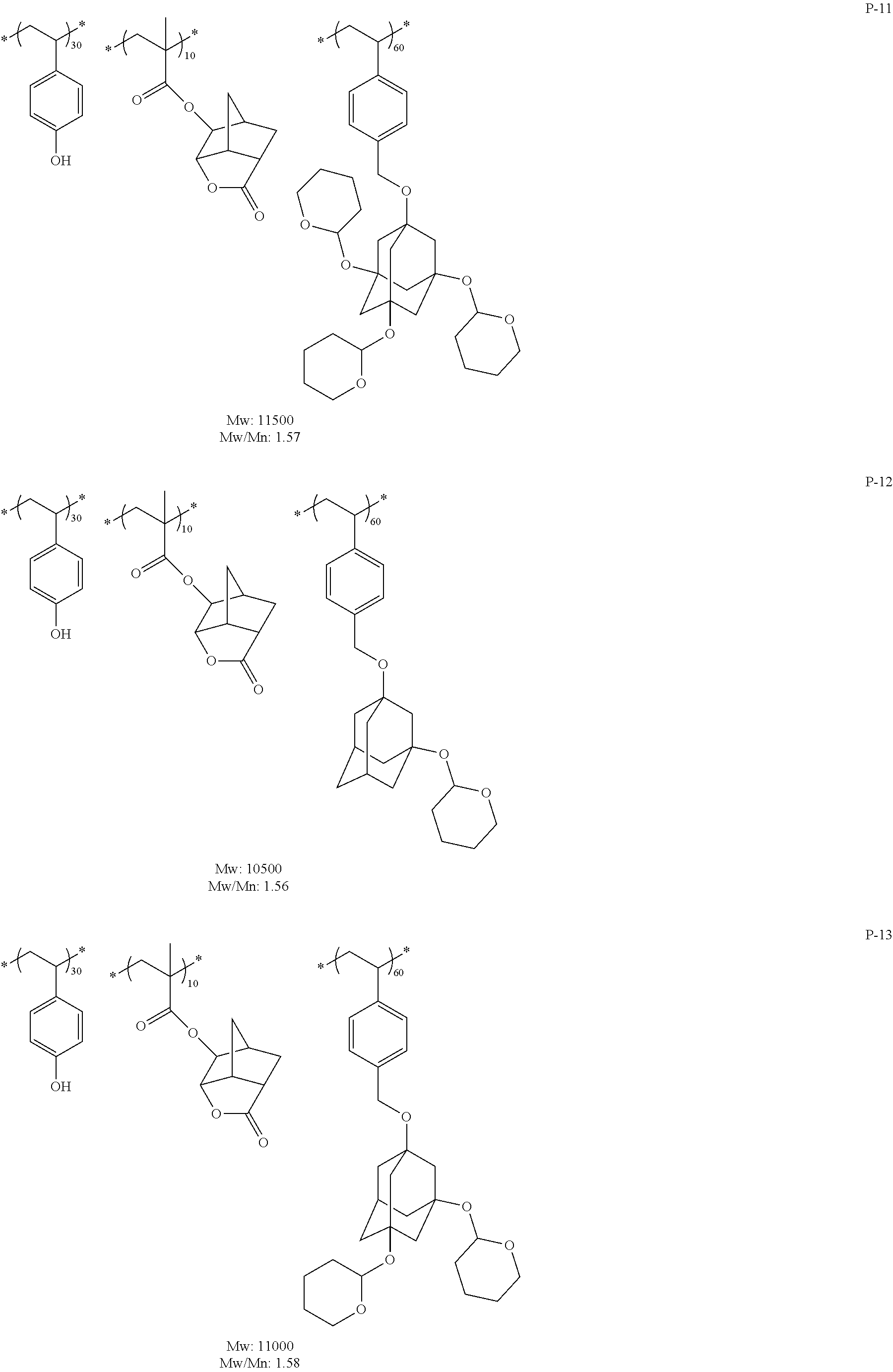

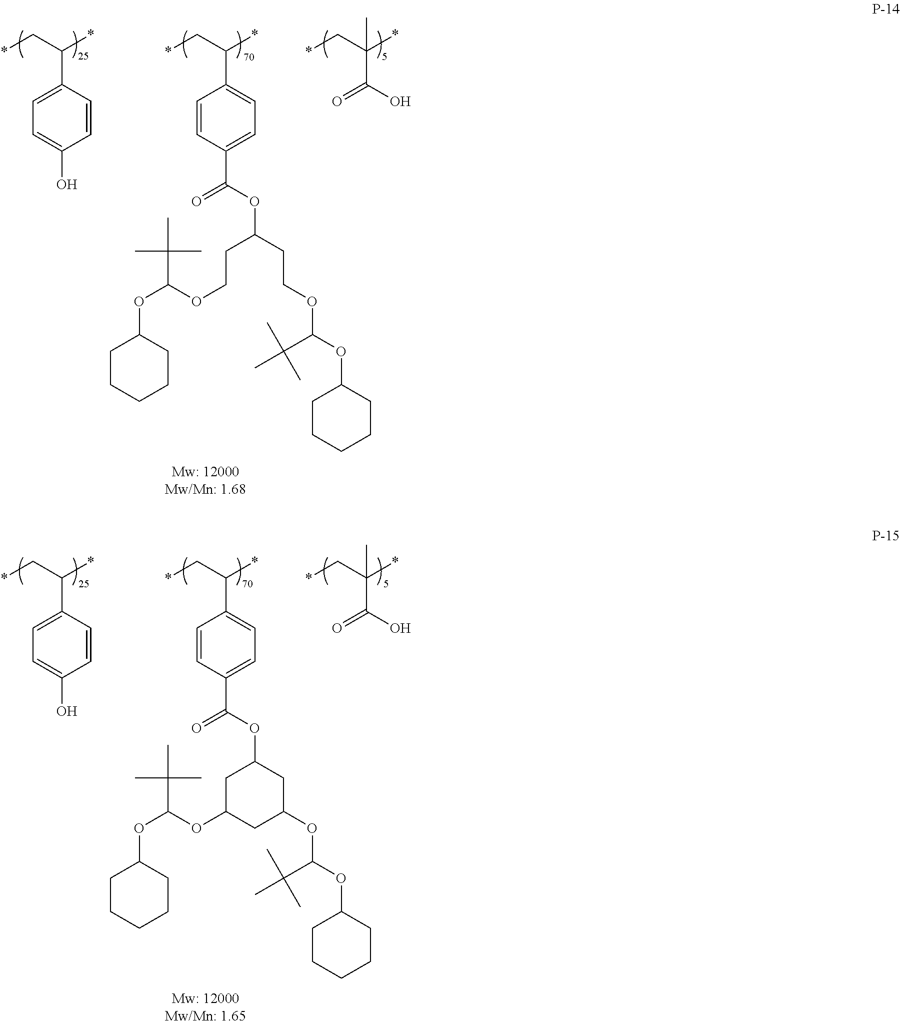

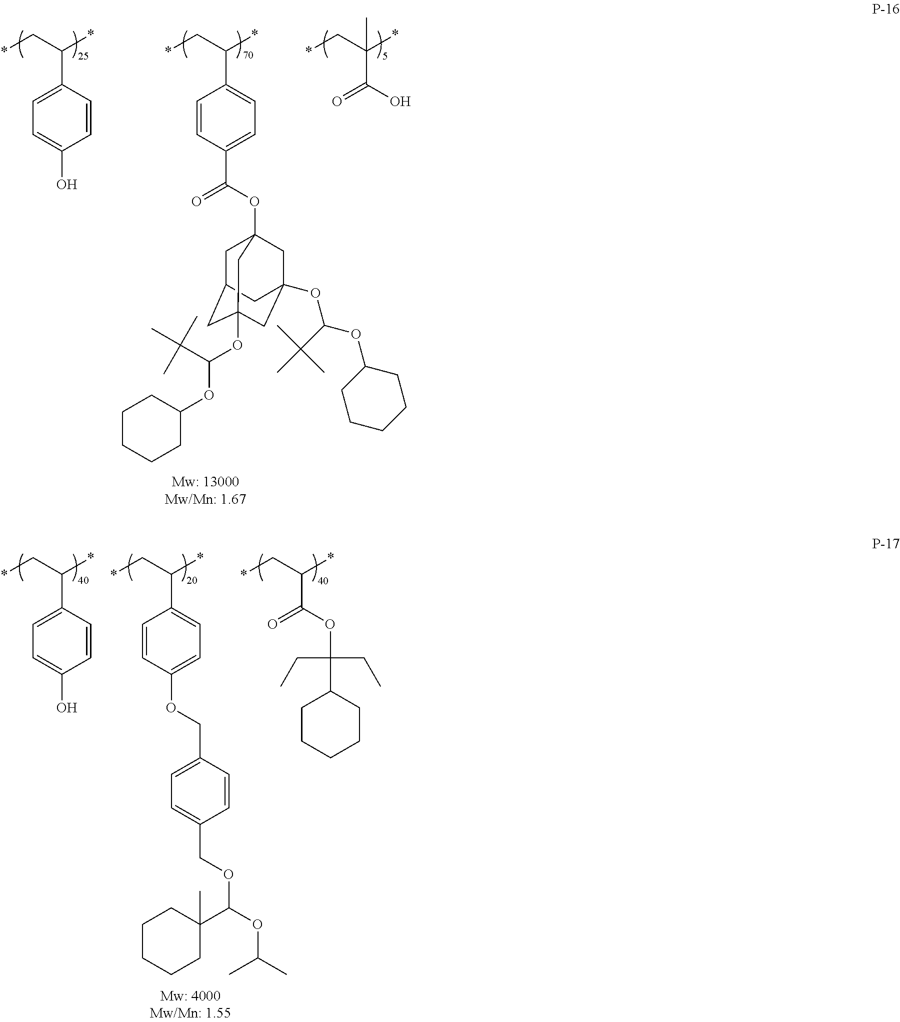

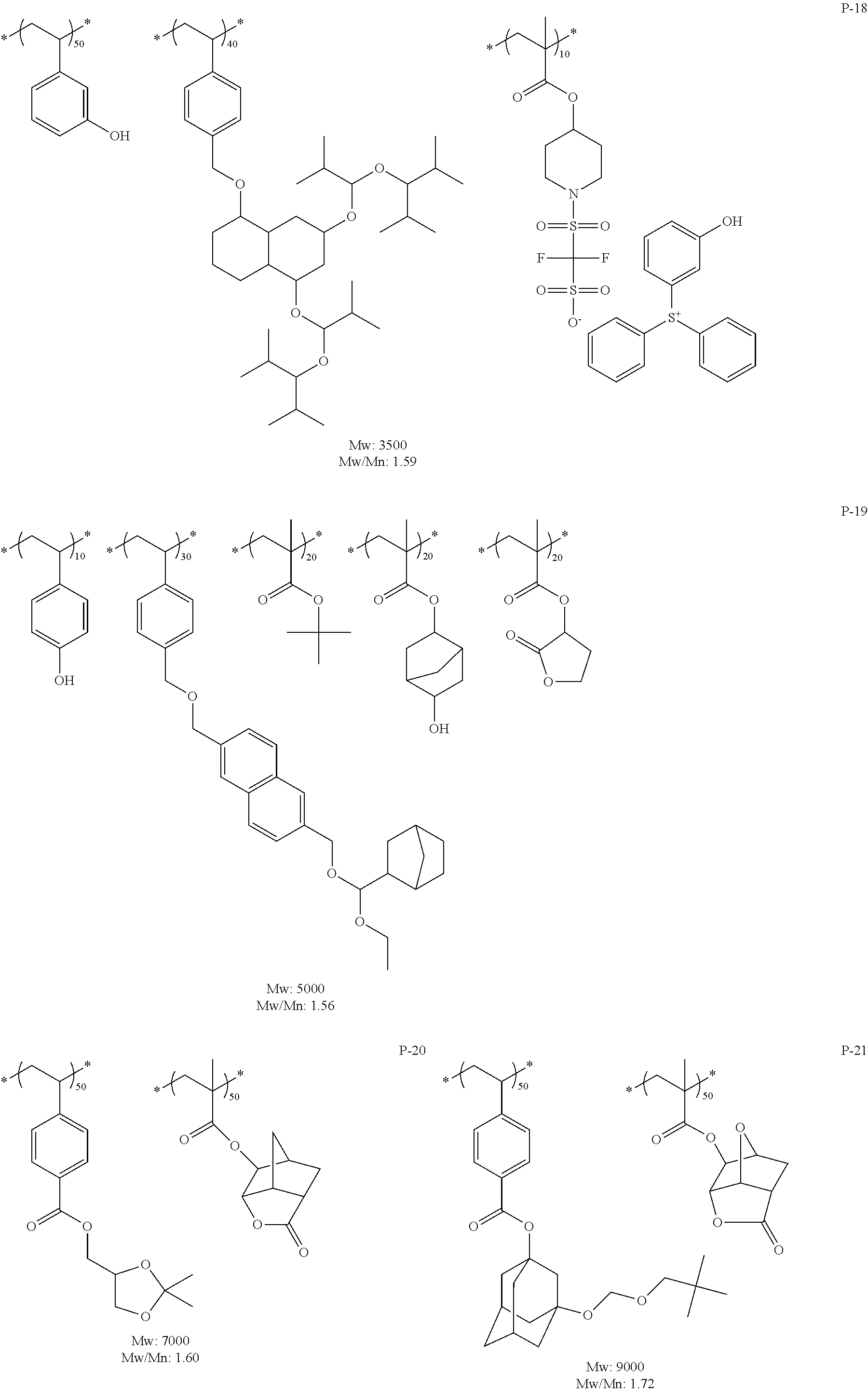

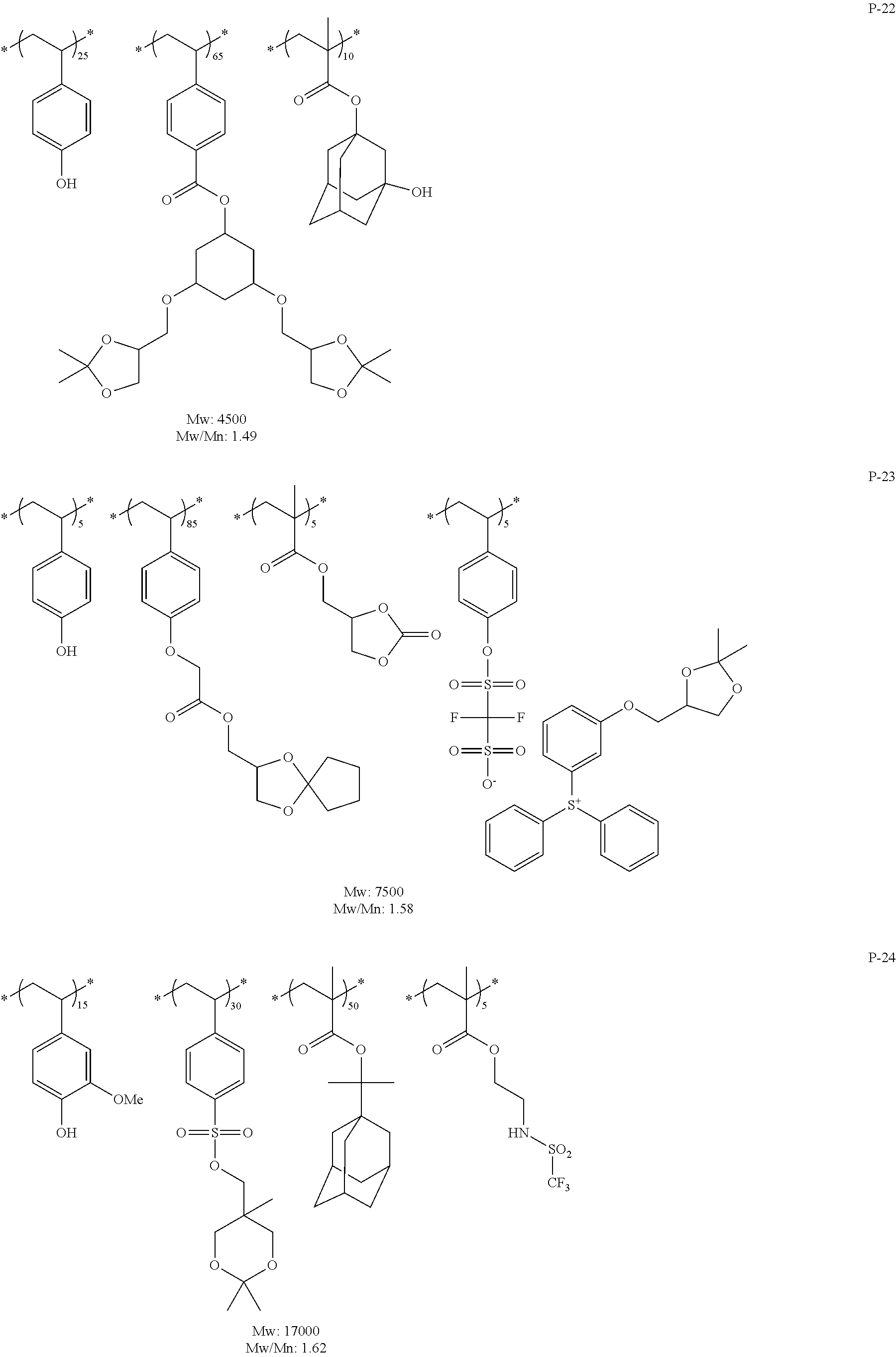

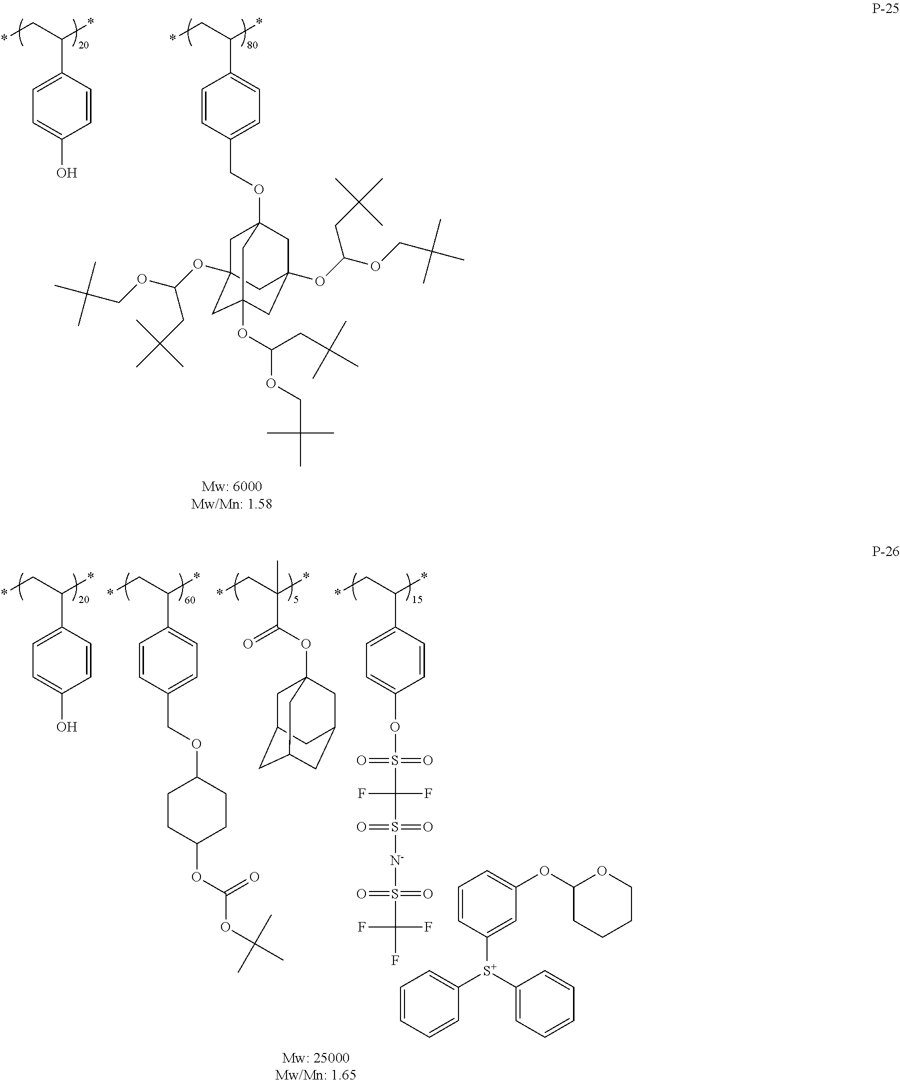

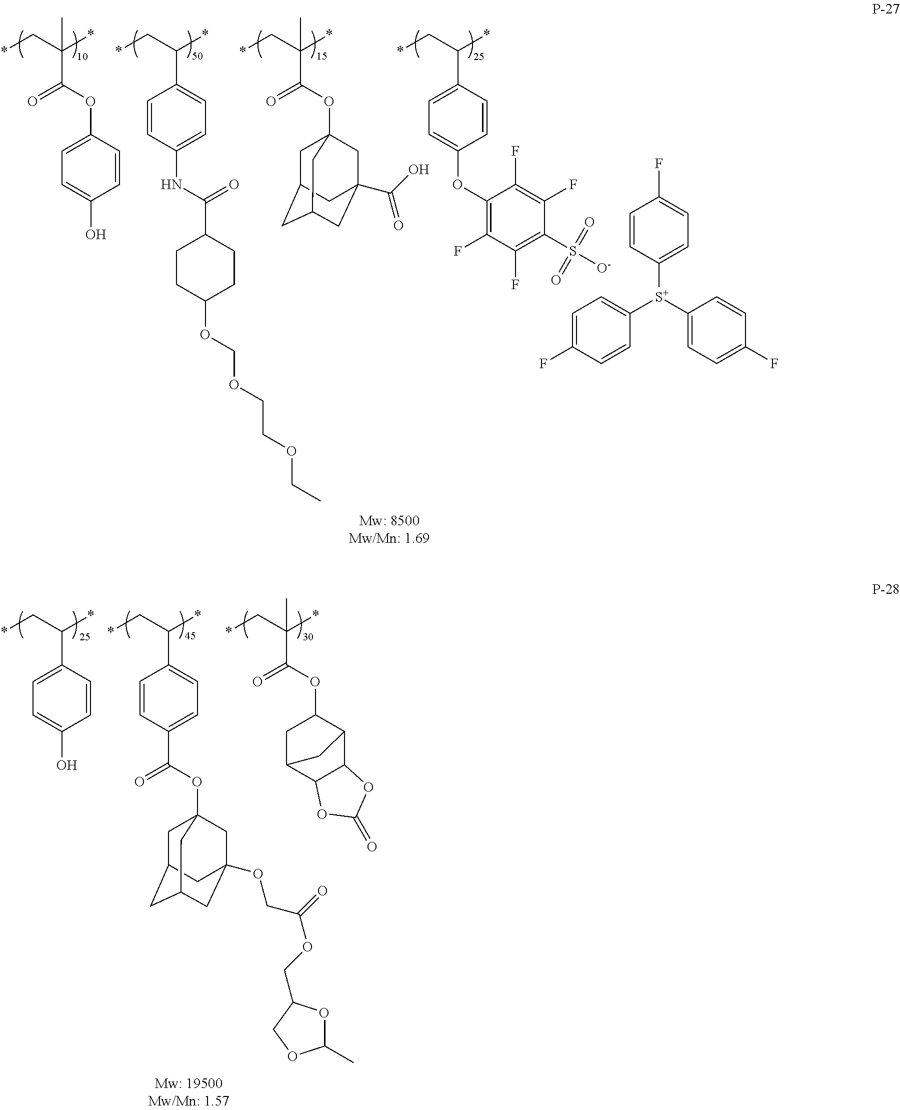

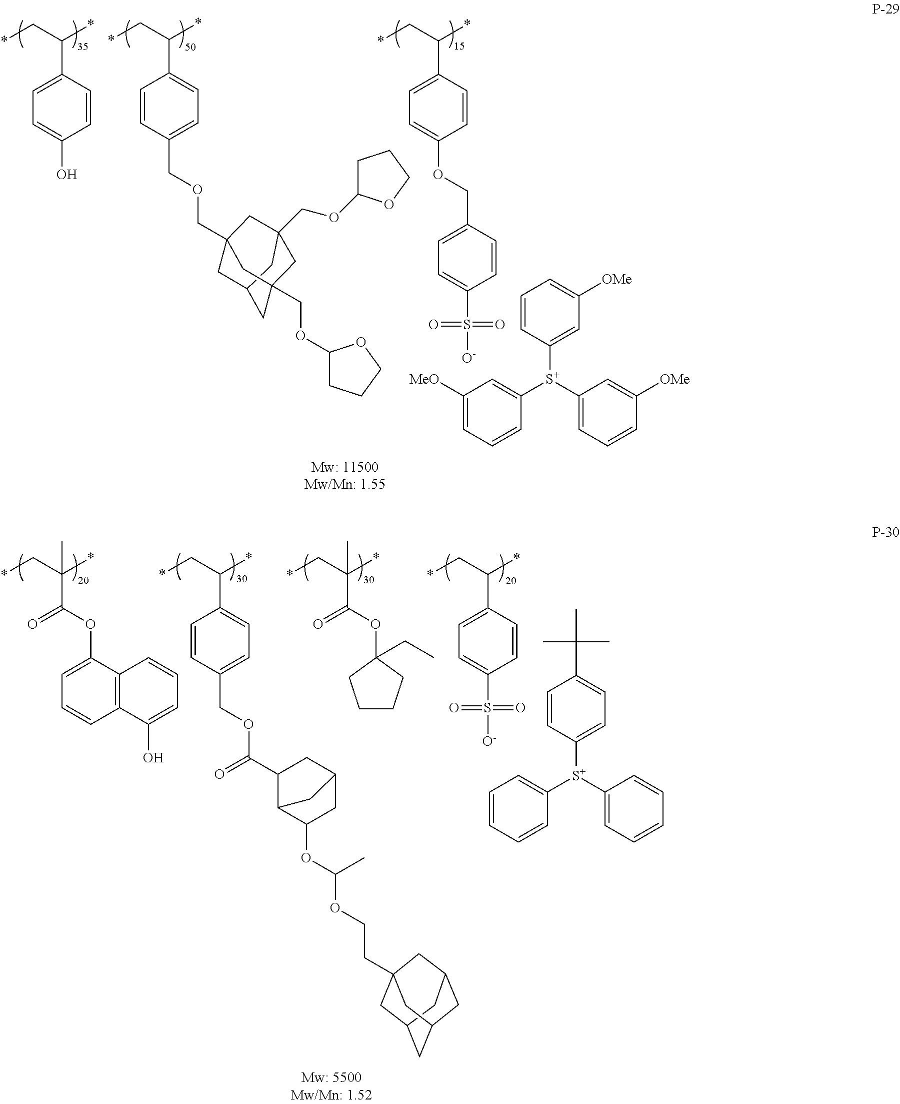

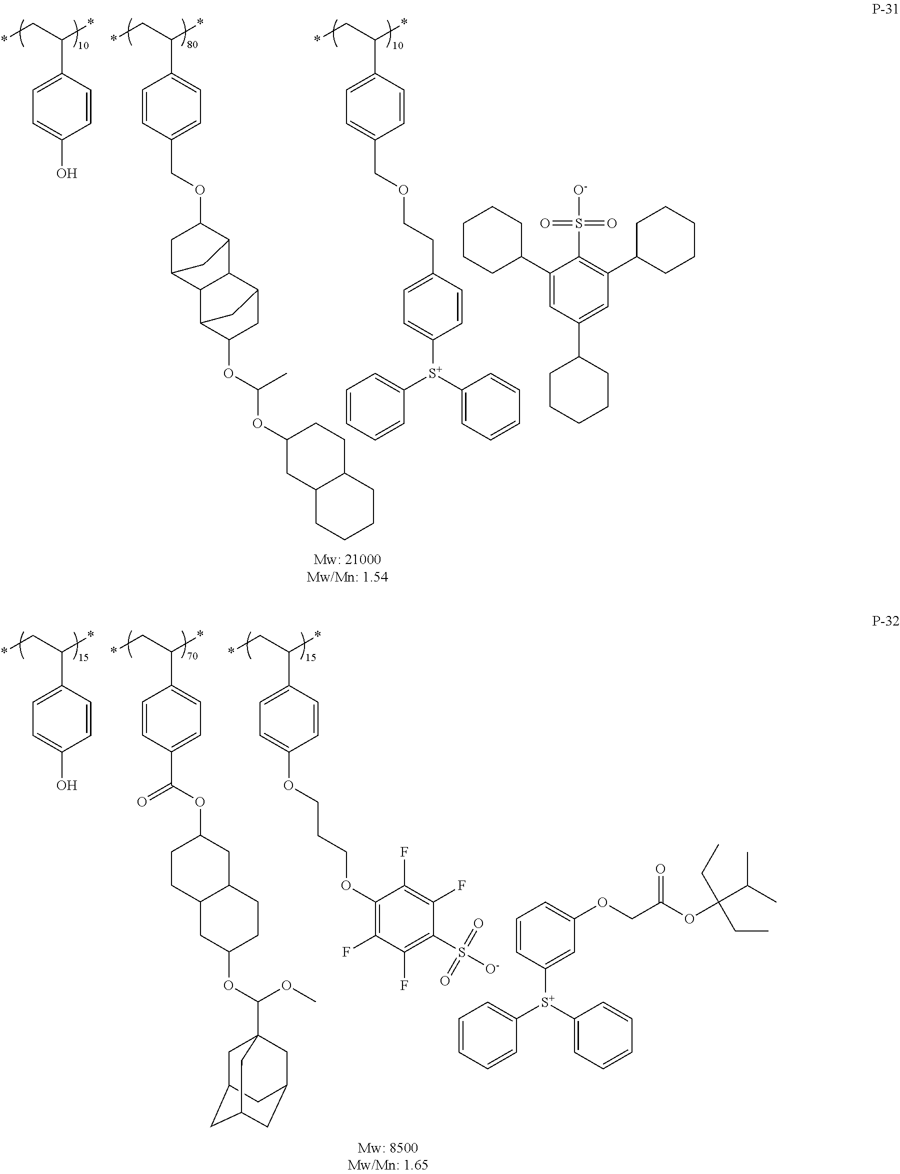

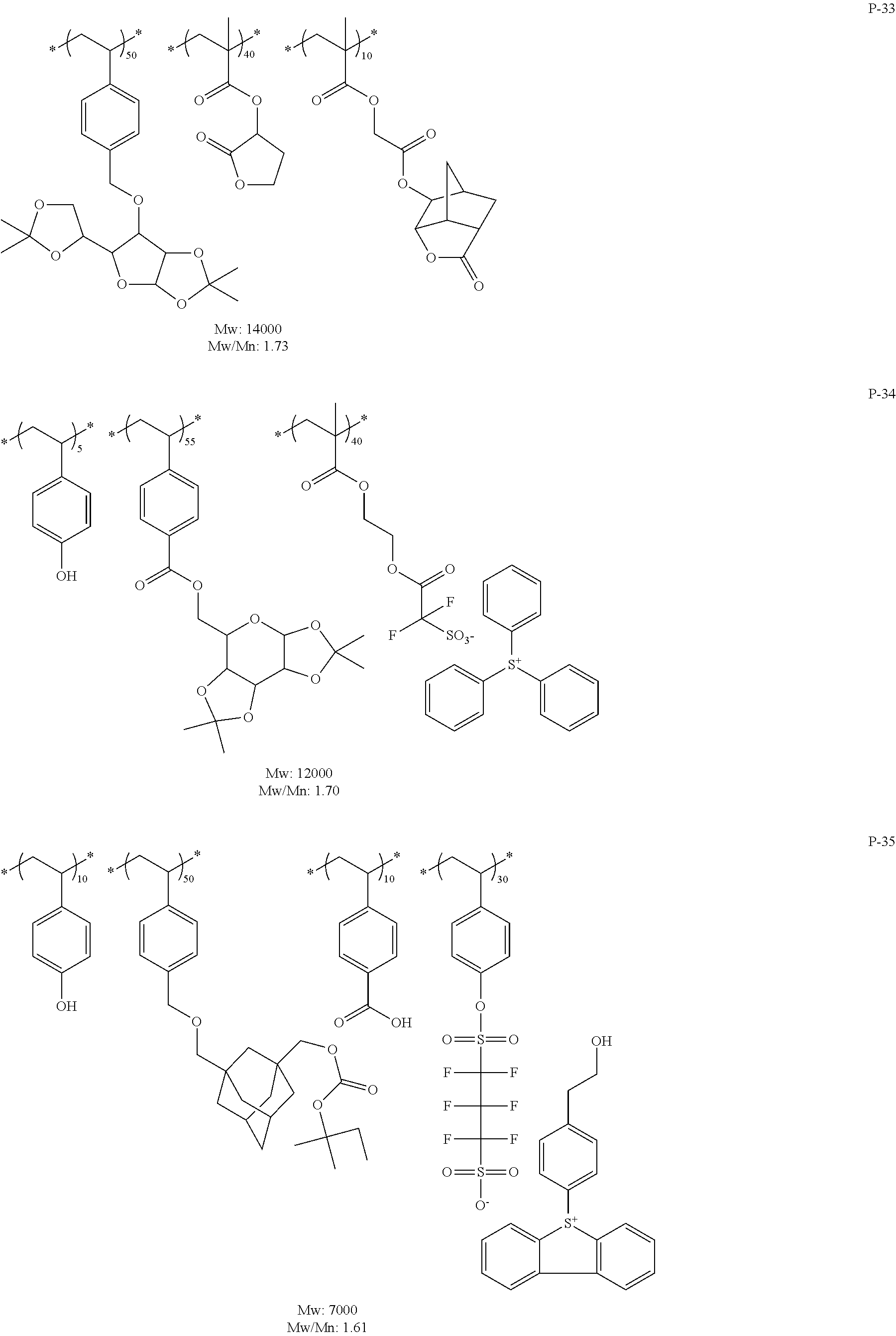

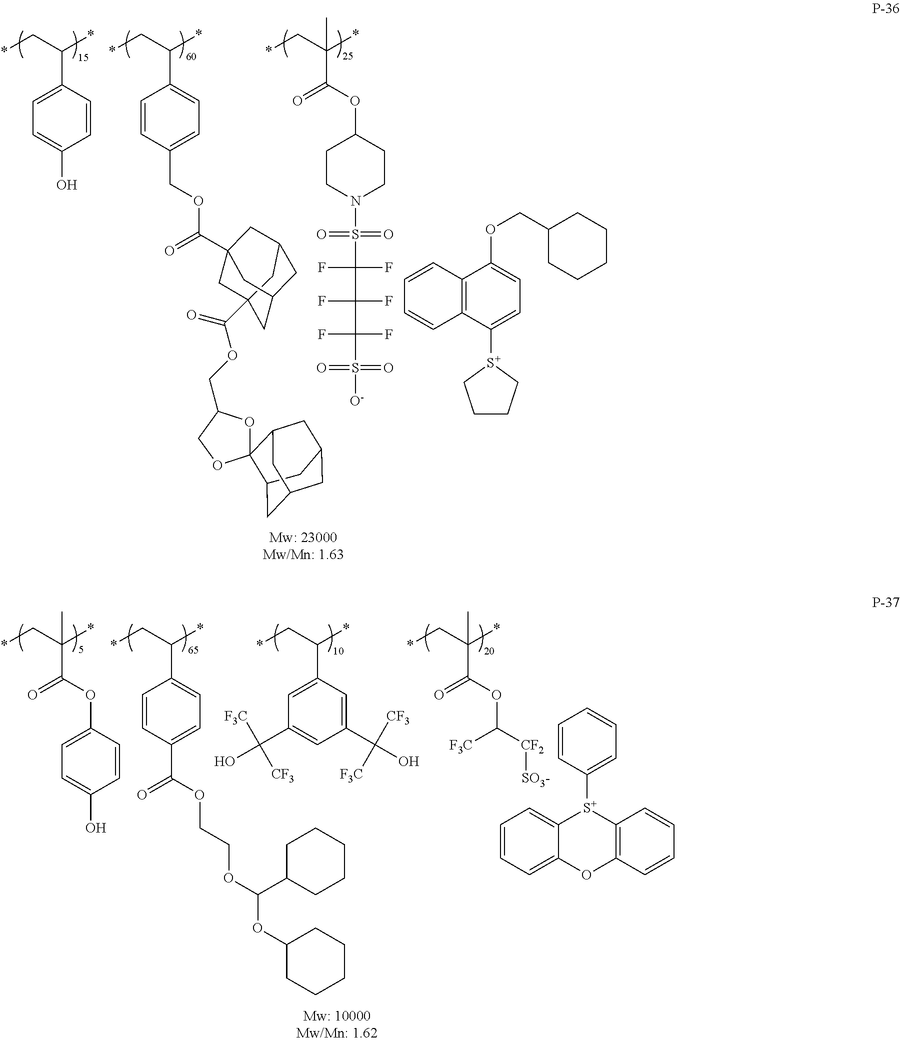

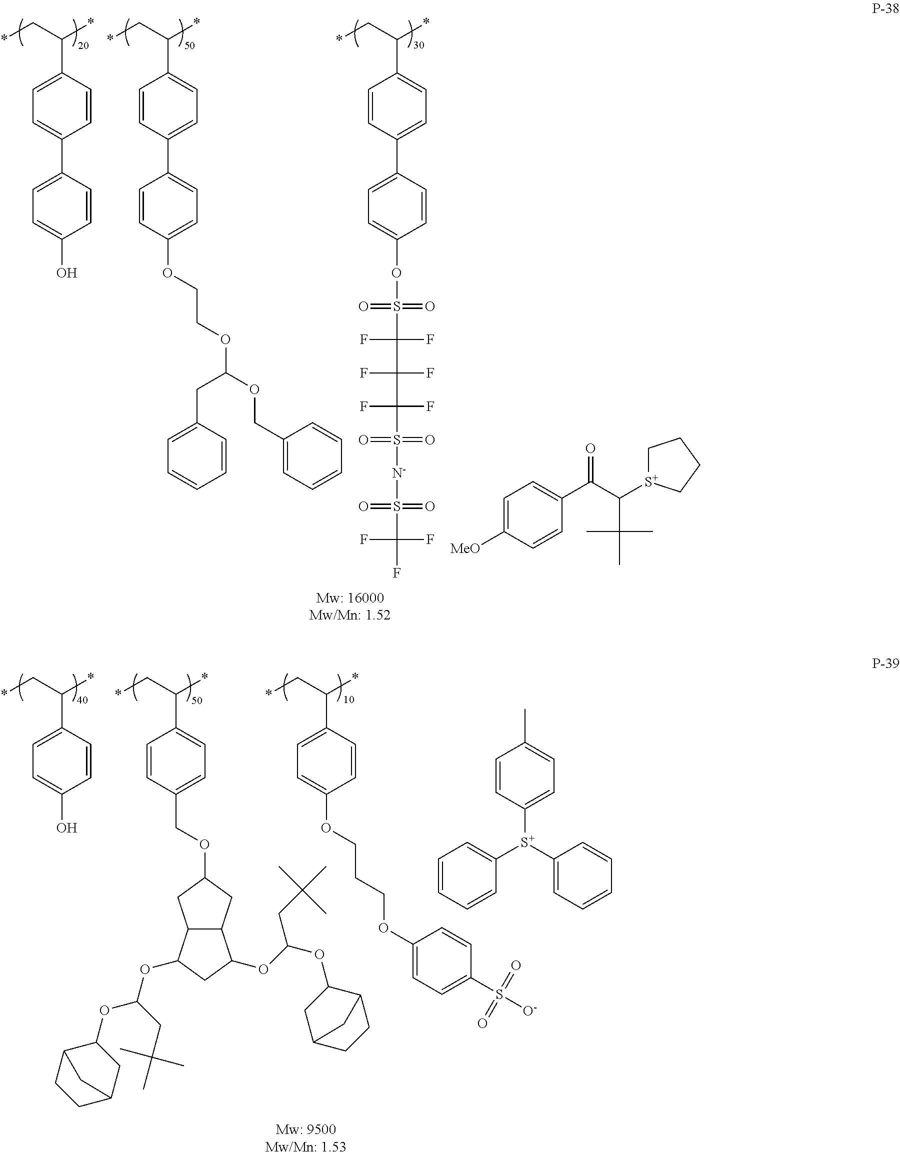

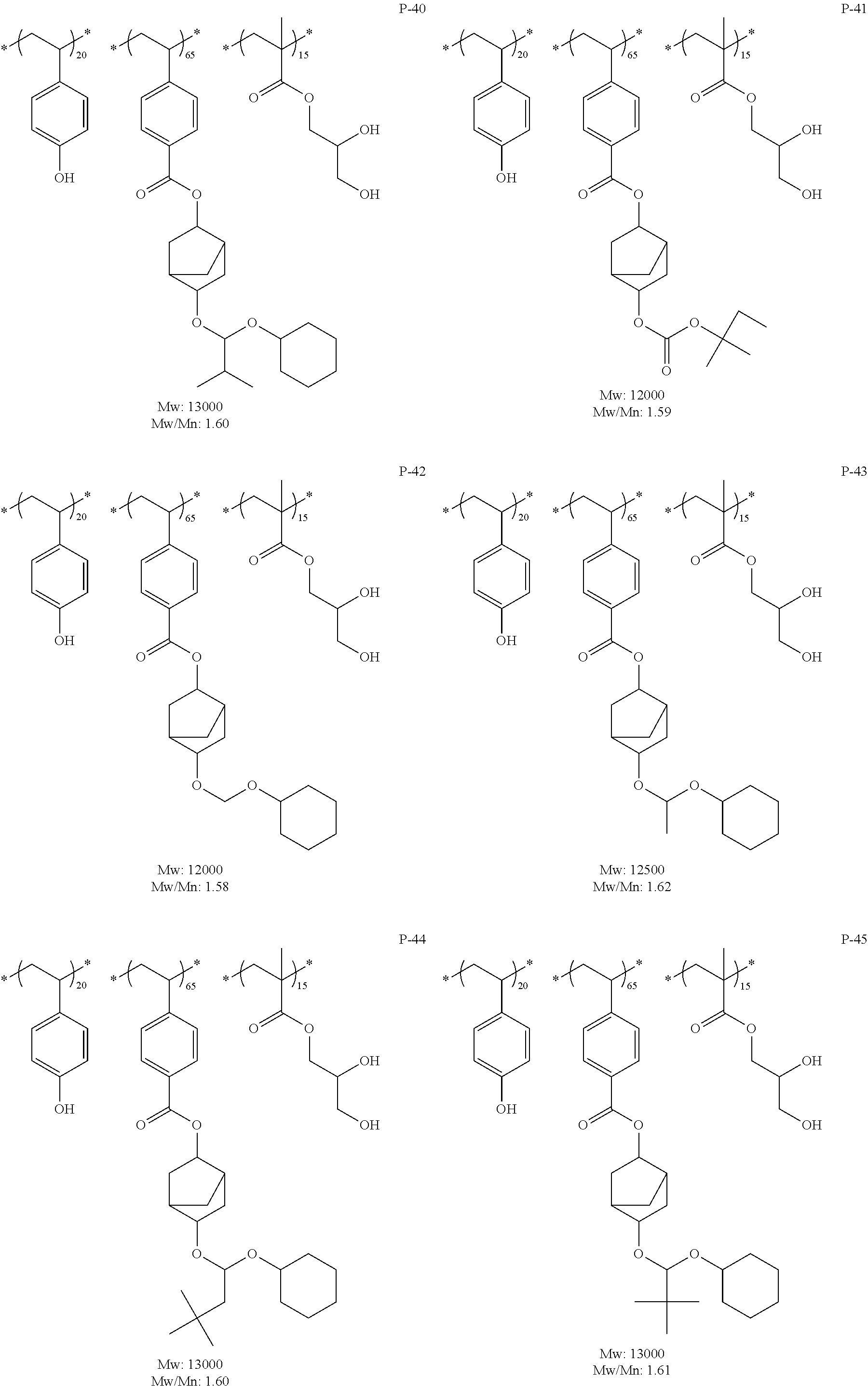

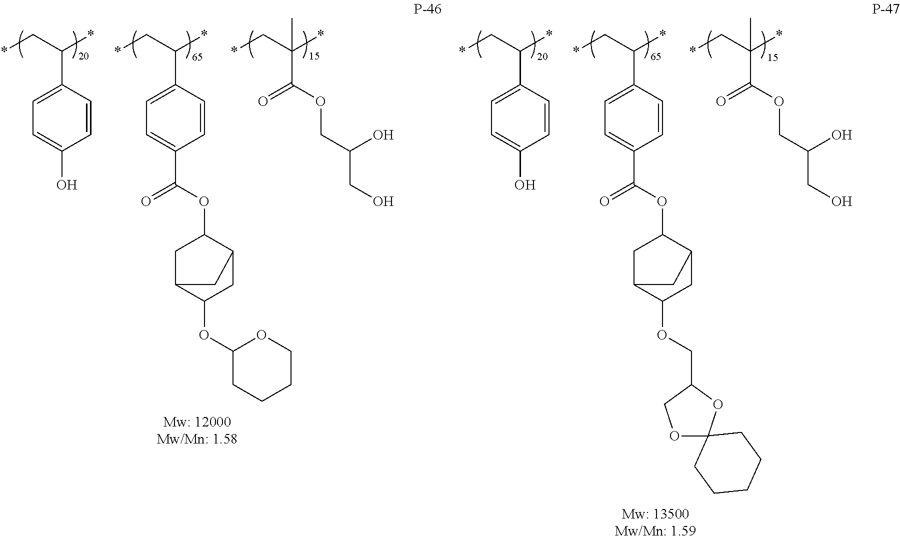

The structure, the composition ratio (molar ratio) of repeating units, the mass average molecular weight (Mw), and the dispersity (Mw/Mn) of each of the resins used in the comparative examples are shown below.

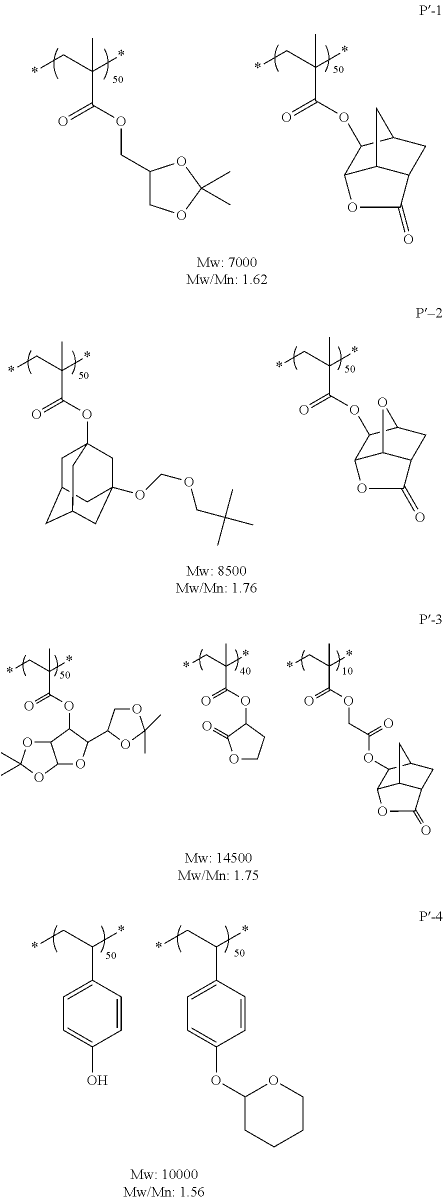

Hereinafter, the acid generator, the basic compound, the surfactant, the solvent, the hydrophobic resin, the developer, and the rinse liquid used in each of the examples and the comparative examples will be shown.

[Acid Generator]

As the acid generator, an acid generator suitably selected from the above-described acid generators z1 to z145 was used.

[Basic Compound]

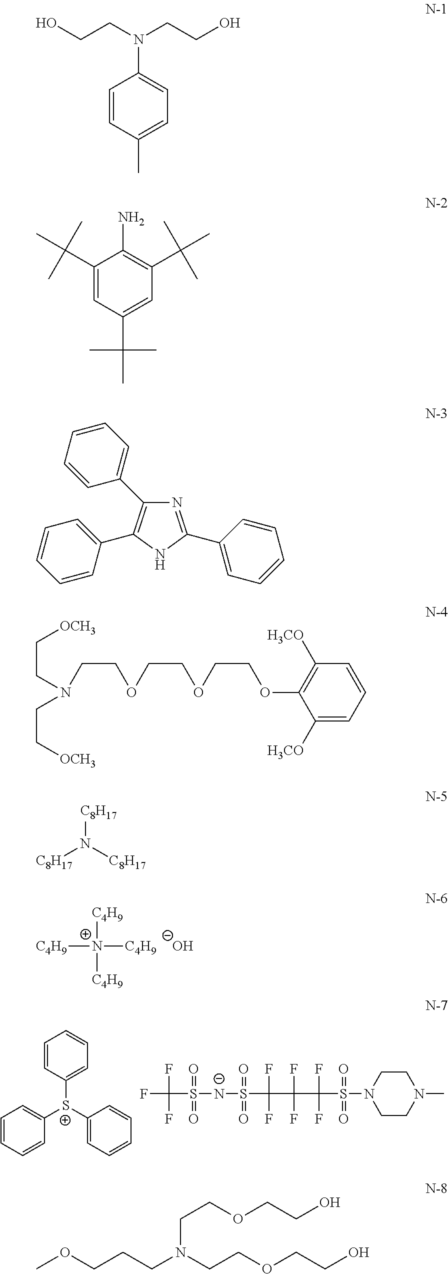

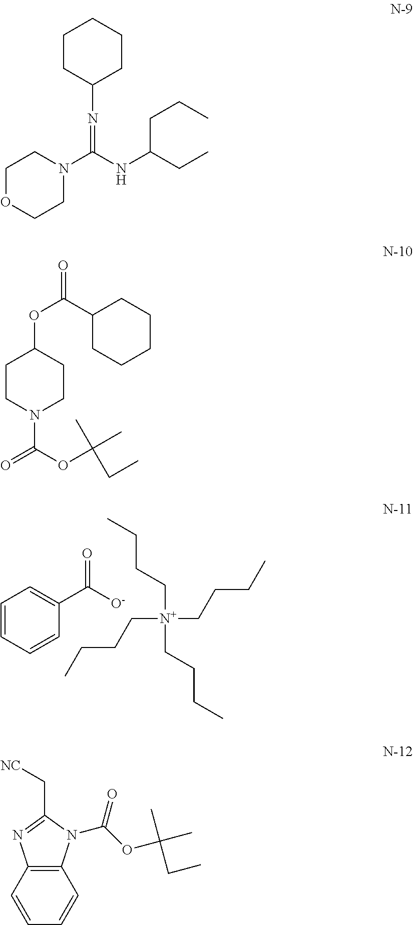

[Hydrophobic Resin]

The structure, the composition ratio (molar ratio) of repeating units, the mass average molecular weight (Mw), and the dispersity (Mw/Mn) of the hydrophobic resin are shown below.

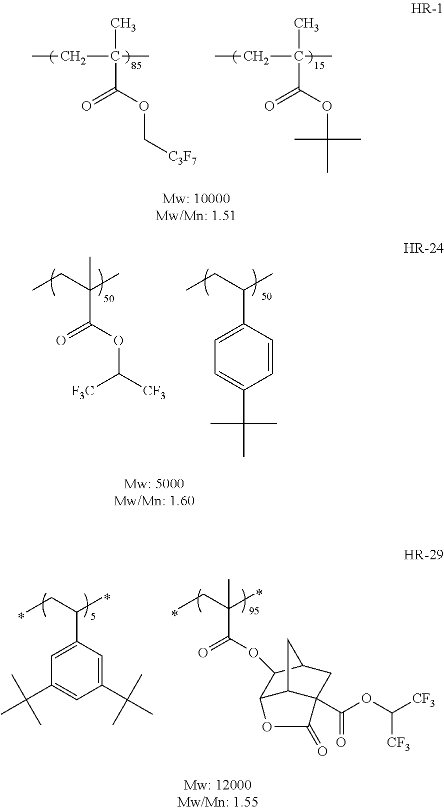

[Solvent]

S-1: propylene glycol monomethyl ether acetate (PGMEA) (b.p.=146° C.)

S-2: propylene glycol monomethyl ether (PGME) (b.p.=120° C.)

S-3: methyl lactate (b.p.=145° C.)

S-4: cyclohexanone (b.p.=157° C.)

[Surfactant]

W-1: Megafac R08 (manufactured by DIC Corporation; fluorine-based surfactant or silicon-based surfactant)

W-2: Polysiloxane polymer KP-341 (manufactured by Shin-Etsu Chemical Co., Ltd.; silicon-based surfactant)

W-3: Troysol S-366 (manufactured by Troy Chemical Corp.; fluorine-based surfactant)

W-4: PF6320 (manufactured by OMNOVA Solutions Inc.; fluorine-base surfactant)

[Developer and Rinse Liquid]

G-1: butyl acetate

G-2: 2-heptanone

G-3: anisole

G-4: 4-methyl-2-pentanol

G-5: 1-hexanol

G-6: decane

### Examples 1A to 47A and Comparative Examples 1A to 4A

(1) Coating Liquid Preparation and Application of Actinic Ray Sensitive or Radiation Sensitive Resin Composition

The components shown in the following Table 1 were dissolved in each of the solvents shown in the same table at a solid content of 3.0% by mass, and each of the resultant products was microfiltered using a membrane filter having a pore size of 0.1 μm, whereby actinic ray sensitive or radiation sensitive resin composition (resist composition) solutions were obtained. (the content of a surfactant is a proportion with respect to the total solid content in the resist composition)

This actinic ray sensitive or radiation sensitive resin composition solution was applied to a 6-inch Si wafer subjected to a hexamethyldisilazane (HMDS) treatment in advance using a spin coater Mark 8 manufactured by Tokyo Electron Limited, and dried on a hot plate at 100° C. for 60 seconds, whereby a resist film having a thickness of 100 nm was obtained.

(2) EB Exposure and Development

Pattern irradiation was performed on the wafer to which the resist film obtained in the above (1) had been applied using an electron beam lithography device (HL 750 manufactured by Hitachi, Ltd., acceleration voltage of 50 KeV). At this time, lithography was performed such that a line and a space were formed in a ratio of 1:1. After the electron beam lithography, the wafer was heated on a hot plate at 100° C. for 90 seconds, developed by paddling the organic-based developer described in the following table for 30 seconds, rinsed by using the rinse liquid described in the following table, rotated for 30 seconds at a rotation speed of 4000 rpm, and heated at 95° C. for 60 seconds, whereby a resist pattern of a line and space pattern in a ratio of 1:1 having a line width of 100 nm was obtained.

(3) Evaluation of Resist Pattern

The sensitivity, the pattern shape, and the resolution of an isolated line pattern and an isolated space pattern of the obtained resist pattern were evaluated by the following method using a scanning electron microscope (S-9220 manufactured by Hitachi, Ltd.).

[Sensitivity]

The irradiation energy when the line and space pattern in a ratio of 1:1 having a line width of 100 nm was resolved was taken as a sensitivity.

[Pattern Shape Evaluation]

The cross-sectional shape of the line and space pattern in a ratio of 1:1 having a line width of 100 nm in the irradiation amount at which the sensitivity above was exhibited was observed using a scanning electron microscope (S-4300 manufactured by Hitachi, Ltd.), and a three stage evaluation of a rectangle, a reverse taper, and a taper was performed.

[Resolution of Isolated Line Pattern; Resolving Power]

The marginal resolving power (a minimum line width at which a line and a space are separately resolved) of an isolated line pattern (line:space=1:>100) in the irradiation amount at which the above sensitivity was exhibited was determined. This value was taken as “resolving power (nm)”.

[Dry Etching Resistance]

In the (1) coating liquid preparation and application of the actinic ray sensitive or radiation sensitive resin composition, a resist film having a film thickness of 200 nm was formed, and plasma etching was performed on the resist film at a temperature of 23° C. for 30 seconds using a mixed gas of C₄F₆ (20 mL/min) and O₂ (40 mL/min). Thereafter, the remaining film amount was determined, and the etching rate was calculated. On the basis of the following evaluation criteria, the etching resistance was evaluated.

(Evaluation Criteria)

A: a case where the etching rate was less than 15 Angstroms/sec.

B: a case where the etching rate was 15 Angstroms/sec or greater.

TABLE 1
[EB]

| | Resist composition | | | | | | | | Evaluation results | | | |
|---|---|---|---|---|---|---|---|---|---|---|---|---|
| | | | | Photo- | | | | | | | | |
| | Hydro- | | | acid | Basic | Surfac- | | | | | Isolated | |
| | phobic | Resin | Sol- | gener- | com- | tant | Devel- | Rinse | | | line | |
| | resin | (Ab) | vent | ator | pound | (0.01% | oper | Liquid | Sensi- | | pattern | Dry |
| | (% by | (% by | (mass | (% by | (% by | by | (mass | (mass | tivity | Pattern | resolution | etching |
| Rinse | mass) | mass) | ratio) | mass) | mass) | mass) | ratio) | ratio) | (μC/cm²) | shape | (nm) | resistance |
| Example 1A | — | P-1 | S-1/S-2 | z125 | N-3 | W-3 | G-1 | — | 32 | Rectangle | 100.0 | A |
| | 0 | 68 | 80/20 | 30 | 2 | | | | | | | |
| Example 2A | — | P-2 | S-1/S-2 | z125 | N-3 | W-3 | G-1 | — | 29 | Rectangle | 87.5 | A |
| | 0 | 68 | 80/20 | 30 | 2 | | | | | | | |
| Example 3A | — | P-3 | S-1/S-2 | z125 | N-3 | W-3 | G-1 | — | 27 | Rectangle | 75.0 | A |
| | 0 | 68 | 80/20 | 30 | 2 | | | | | | | |
| Example 4A | — | P-4 | S-1/S-2 | z125 | N-3 | W-3 | G-1 | — | 25 | Rectangle | 62.5 | A |
| | 0 | 68 | 80/20 | 30 | 2 | | | | | | | |
| Example 5A | — | P-5 | S-1/S-2 | z125 | N-3 | W-3 | G-1 | — | 22 | Rectangle | 50.0 | A |
| | 0 | 68 | 80/20 | 30 | 2 | | | | | | | |
| Example 6A | — | P-6 | S-1/S-2 | z130 | N-6 | W-4 | G-1 | — | 30 | Rectangle | 100.0 | A |
| | 0 | 79 | 60/40 | 20 | 1 | | | | | | | |
| Example 7A | — | P-7 | S-1/S-2 | z130 | N-6 | W-4 | G-1 | — | 28 | Rectangle | 87.5 | A |
| | 0 | 79 | 60/40 | 20 | 1 | | | | | | | |
| Example 8A | — | P-8 | S-1/S-2 | z130 | N-6 | W-4 | G-1 | — | 24 | Rectangle | 75.0 | A |
| | 0 | 79 | 60/40 | 20 | 1 | | | | | | | |
| Example 9A | — | P-9 | S-1/S-2 | z130 | N-6 | W-4 | G-1 | — | 21 | Rectangle | 62.5 | A |
| | 0 | 79 | 60/40 | 20 | 1 | | | | | | | |
| Example 10A | — | P-10 | S-1/S-2 | z130 | N-6 | W-4 | G-1 | — | 18 | Rectangle | 50.0 | A |
| | 0 | 79 | 60/40 | 20 | 1 | | | | | | | |
| Example 11A | — | P-11 | S-1/S-2 | z115 | N-11 | W-4 | G-1 | — | 25 | Rectangle | 87.5 | A |
| | 0 | 73 | 70/30 | 25 | 2 | | | | | | | |
| Example 12A | — | P-12 | S-1/S-2 | z115 | N-11 | W-4 | G-1 | — | 23 | Rectangle | 62.5 | A |
| | 0 | 73 | 70/30 | 25 | 2 | | | | | | | |
| Example 13A | — | P-13 | S-1/S-2 | z115 | N-11 | W-4 | G-1 | — | 22 | Rectangle | 50.0 | A |
| | 0 | 73 | 70/30 | 25 | 2 | | | | | | | |
| Example 14A | — | P-14 | S-1/S-2 | z127 | N-11 | W-3 | G-1 | — | 28 | Rectangle | 75.0 | A |
| | 0 | 83 | 50/50 | 15 | 2 | | | | | | | |
| Example 15A | — | P-15 | S-1/S-2 | z127 | N-11 | W-3 | G-1 | — | 26 | Rectangle | 62.5 | A |
| | 0 | 83 | 50/50 | 15 | 2 | | | | | | | |
| Example 16A | — | P-16 | S-1/S-2 | z127 | N-11 | W-3 | G-1 | — | 24 | Rectangle | 50.0 | A |
| | 0 | 83 | 50/50 | 15 | 2 | | | | | | | |
| Example 17A | — | P-17 | S-1/S-3 | z76 | N-7 | W-4 | G-1 | — | 23 | Rectangle | 50.0 | A |
| | 0 | 62 | 70/30 | 35 | 3 | | | | | | | |
| Example 18A | — | P-18 | S-2 | — | N-5 | W-4 | G-3 | G-4 | 26 | Rectangle | 87.5 | A |
| | 0 | 99 | 100 | 0 | 1 | | | | | | | |
| Example 19A | — | P-19 | S-4/S-2 | z121 | N-10 | W-3 | G-1 | — | 27 | Rectangle | 50.0 | A |
| | 0 | 55 | 90/10 | 40 | 5 | | | | | | | |
| Example 20A | — | P-20 | S-1/S-2 | z140 | N-3 | W-1 | G-1 | — | 28 | Rectangle | 87.5 | A |
| | 0 | 88 | 90/10 | 10 | 2 | | | | | | | |
| Example 21A | — | P-21 | S-4/S-2 | z118 | N-8 | W-2 | G-2 | — | 27 | Rectangle | 100.0 | A |
| | 0 | 94 | 80/20 | 5 | 1 | | | | | | | |
| Example 22A | HR-24 | P-22 | S-1/S-3 | z145 | N-3 | W-4 | G-1 | — | 25 | Rectangle | 87.5 | A |
| | 10 | 79 | 60/40 | 10 | 1 | | | | | | | |
| Example 23A | — | P-23 | S-2/S-1 | — | N-1 | W-1 | G-2 | G-4 | 26 | Rectangle | 100.0 | A |
| | 0 | 99 | 80/20 | 0 | 1 | | | | | | | |
| Example 24A | — | P-24 | S-1/S-4 | z67 | N-9 | W-4 | G-1 | G-4 | 24 | Rectangle | 75.0 | A |
| | 0 | 83 | 90/10 | 15 | 2 | | | | | | | |
| Example 25A | — | P-13/P-25 | S-1 | z113 | N-5 | W-3 | G-1 | — | 21 | Rectangle | 62.5 | A |
| | 0 | 39/39 | 100 | 20 | 2 | | | | | | | |
| Example 26A | — | P-26 | S-2/S-1 | — | N-2 | W-2 | G-1 | — | 30 | Rectangle | 87.5 | A |
| | 0 | 97 | 90/10 | 0 | 3 | | | | | | | |
| Example 27A | — | P-27 | S-3/S-4 | — | N-4 | W-1 | G-1 | G-5 | 25 | Rectangle | 62.5 | A |
| | 0 | 97 | 50/50 | 0 | 3 | | | | | | | |
| Example 28A | HR-29 | P-28 | S-2/S-1 | z114 | N-12 | W-4 | G-1 | — | 23 | Rectangle | 87.5 | A |
| | 5 | 84 | 60/40 | 10 | 1 | | | | | | | |
| Example 29A | HR-1 | P-29 | S-2/S-1 | — | N-5 | W-2 | G-3 | — | 26 | Rectangle | 87.5 | A |
| | 3 | 95 | 70/30 | 0 | 2 | | | | | | | |
| Example 30A | — | P-30 | S-2/S-3 | — | N-11 | W-1 | G-3 | G-5 | 20 | Rectangle | 75.0 | A |
| | 0 | 99 | 70/30 | 0 | 1 | | | | | | | |
| Example 31A | — | P-31 | S-3 | — | N-6 | W-3 | G-1/G-3 | — | 31 | Rectangle | 87.5 | A |
| | 0 | 98 | 100 | 0 | 2 | | 80/20 | | | | | |
| Example 32A | — | P-32 | S-2/S-3 | — | N-6 | W-2 | G-1 | — | 22 | Rectangle | 87.5 | A |
| | 0 | 98 | 80/20 | 0 | 2 | | | | | | | |
| Example 33A | — | P-33 | S-1/S-3 | z141 | N-2 | W-3 | G-1 | G-6 | 23 | Rectangle | 75.0 | A |
| | 0 | 83 | 80/20 | 15 | 2 | | | | | | | |
| Example 34A | — | P-34 | S-3/S-1 | — | N-3 | W-2 | G-1 | G-4/G-5 | 21 | Rectangle | 50.0 | A |
| | 0 | 97 | 50/50 | 0 | 3 | | | 50/50 | | | | |
| Example 35A | — | P-35 | S-2/S-3 | — | N-12 | W-2 | G-2 | G-5 | 28 | Rectangle | 62.5 | A |
| | 0 | 97 | 50/50 | 0 | 3 | | | | | | | |
| Example 36A | — | P-36 | S-3/S-1 | z143 | N-11 | W-2 | G-2 | G-6 | 24 | Rectangle | 50.0 | A |
| | 0 | 93 | 60/40 | 5 | 2 | | | | | | | |
| Example 37A | — | P-37 | S-3/S-4 | — | N-6 | W-1 | G-1 | — | 24 | Rectangle | 75.0 | A |
| | 0 | 98 | 80/20 | 0 | 2 | | | | | | | |
| Example 38A | — | P-38 | S-3/S-4 | — | N-10 | W-1 | G-1 | — | 26 | Rectangle | 62.5 | A |
| | 0 | 97 | 70/30 | 0 | 3 | | | | | | | |
| Example 39A | — | P-39 | S-2/S-4 | z142 | N-9 | W-3 | G-3 | G-6 | 28 | Rectangle | 50.0 | A |
| | 0 | 88 | 90/10 | 10 | 2 | | | | | | | |
| Example 40A | — | P-40 | S-1/S-4 | z136/z130 | N-5 | W-1 | G-1 | — | 29 | Rectangle | 75.0 | A |
| | 0 | 68 | 80/20 | 15/15 | 2 | | | | | | | |
| Example 41A | — | P-41 | S-1/S-4 | z136/z130 | N-5 | W-1 | G-1 | — | 30 | Rectangle | 75.0 | A |
| | 0 | 68 | 80/20 | 15/15 | 2 | | | | | | | |
| Example 42A | — | P-42 | S-1/S-4 | z136/z130 | N-5 | W-1 | G-1 | — | 25 | Rectangle | 62.5 | A |
| | 0 | 68 | 80/20 | 15/15 | 2 | | | | | | | |
| Example 43A | — | P-43 | S-1/S-4 | z136/z130 | N-5 | W-1 | G-1 | — | 24 | Rectangle | 62.5 | A |
| | 0 | 68 | 80/20 | 15/15 | 2 | | | | | | | |
| Example 44A | — | P-44 | S-1/S-4 | z136/z130 | N-5 | W-1 | G-1 | — | 20 | Rectangle | 50.0 | A |
| | 0 | 68 | 80/20 | 15/15 | 2 | | | | | | | |
| Example 45A | — | P-45 | S-1/S-4 | z136/z130 | N-5 | W-1 | G-1 | — | 22 | Rectangle | 50.0 | A |
| | 0 | 68 | 80/20 | 15/15 | 2 | | | | | | | |
| Example 46A | — | P-46 | S-1/S-4 | z136/z130 | N-5 | W-1 | G-1 | — | 21 | Rectangle | 50.0 | A |
| | 0 | 68 | 80/20 | 15/15 | 2 | | | | | | | |
| Example 47A | — | P-47 | S-1/S-4 | z136/z130 | N-5 | W-1 | G-1 | — | 21 | Rectangle | 50.0 | A |
| | 0 | 68 | 80/20 | 15/15 | 2 | | | | | | | |
| Comparative | — | P-1 | S-1/S-2 | z140 | N-3 | W-1 | G-1 | — | 38 | Reverse | 125.0 | B |
| Example 1A | 0 | 88 | 90/10 | 10 | 2 | | | | | taper | | |
| Comparative | — | P-2 | S-4/S-2 | z118 | N-8 | W-2 | G-2 | — | 39 | Reverse | 150.0 | B |
| Example 2A | 0 | 94 | 80/20 | 5 | 1 | | | | | taper | | |
| Comparative | — | P-3 | S-1/S-3 | z141 | N-2 | W-3 | G-1 | G-6 | 38 | Reverse | 125.0 | B |
| Example 3A | 0 | 83 | 80/20 | 15 | 2 | | | | | taper | | |

| | | | | | | | | | | |
|---|---|---|---|---|---|---|---|---|---|---|
| Comparative | — | P-4 | S-1/S-3 | z5 | N-1 | W-4 | G-1 | — | Pattern formation is not possible | A |
| Example 4A | 0 | 88 | 90/10 | 10 | 2 | | | | | |

As apparent from the results shown in the above tables, it was found that Examples 1A to 47A using the pattern forming method according to the present invention satisfies high sensitivity, high resolving power at the time of isolated line pattern formation, a good pattern shape, and high dry etching resistance at the same time, in contrast to Comparative Examples 1A to 4A.

### Examples 1B to 47B and Comparative Examples 1B to 4B

### Exposure Conditions 2: EUV Exposure

(4) Coating Liquid Preparation and Application of Actinic Ray Sensitive or Radiation-Sensitive Resin Composition

The components shown in the following Table 2 were dissolved in each of the solvents shown in the same table at a solid content of 1.5% by mass, and each of the resultant products was microfiltered using a membrane filter having a pore size of 0.05 μm, whereby actinic ray sensitive or radiation sensitive resin composition (resist composition) solutions were obtained (the content of a surfactant is a proportion with respect to the total solid content in the resist composition).

This actinic ray sensitive or radiation sensitive resin composition solution was applied to a 6-inch Si wafer subjected to a hexamethyldisilazane (HMDS) treatment in advance using a spin coater Mark 8 manufactured by Tokyo Electron Limited, and dried on a hot plate at 100° C. for 60 seconds, whereby a resist film having a thickness of 50 nm was obtained.

(5) EUV Exposure and Development

Using an EUV exposure device (Micro Exposure Tool manufactured by Exitech Corporation, NA0.3, Quadrupole, outer sigma of 0.68, inner sigma of 0.36), pattern exposure was performed on the wafer to which the resist film obtained in the above (4) had been applied using an exposure mask (line/space=1/1). After exposure, the wafer was heated on a hot plate at 100° C. for 90 seconds, developed by paddling the organic-based developer described in the following table for 30 seconds, rinsed by using the rinse liquid described in the following table, rotated for 30 seconds at a rotation speed of 4000 rpm, and baked at 95° C. for 60 seconds, whereby a resist pattern of a line and space pattern in a ratio of 1:1 having a line width of 50 nm was obtained.

(6) Evaluation of Resist Pattern

The sensitivity, the pattern shape, and the resolution of an isolated line pattern and an isolated space pattern of the obtained resist pattern were evaluated by the following method using a scanning electron microscope (S-938011 manufactured by Hitachi, Ltd.). The results are shown in the following table.

[Sensitivity]

The exposure amount when the line and space pattern in a ratio of 1:1 having a line width of 50 nm was resolved was taken as a sensitivity.

[Pattern Shape Evaluation]

The cross-sectional shape of the line and space pattern in a ratio of 1:1 having a line width of 50 nm in the exposure amount at which the sensitivity above was exhibited was observed using a scanning electron microscope (S-4300 manufactured by Hitachi, Ltd.), and a three stage evaluation of a rectangle, a reverse taper, and a taper was performed.

[Resolution of Isolated Line Pattern; Resolving Power]

The marginal resolving power (a minimum line width at which a line and a space are separately resolved) of an isolated line pattern (line:space=1:5) through a mask of line:space=5:1, in the exposure amount at which the above sensitivity was exhibited was determined. This value was taken as “resolving power (nm)”.

[Dry Etching Resistance]

In the (4) coating liquid preparation and application of the actinic ray sensitive or radiation sensitive resin composition, a resist film having a film thickness of 200 nm was formed, and plasma etching was performed on the resist film at a temperature of 23° C. for 30 seconds using a mixed gas of C₄F₆ (20 mL/min) and O₂ (40 mL/min). Thereafter, the remaining film amount was determined, and the etching rate was calculated. On the basis of the following evaluation criteria, the etching resistance was evaluated.

(Evaluation Criteria)

A: a case where the etching rate was less than 15 Angstroms/sec.

B: a case where the etching rate was 15 Angstroms/sec or greater.

TABLE 2
[EUV]

| | Resist Composition | | | | | | | | | | | |
|---|---|---|---|---|---|---|---|---|---|---|---|---|
| | | | | Photo- | | | | | Evaluation results | | | |
| | Hydro- | | | acid | Basic | Surfac- | | | | | Isolated | |
| | phobic | Resin | Sol- | gener- | com- | tant | Devel- | Rinse | | | line | |
| | resin | (Ab) | vent | ator | pound | (0.01% | oper | Liquid | Sensi- | | pattern | Dry |
| | (% by | (% by | (mass | (% by | (% by | by | (mass | (mass | tivity | Pattern | resolution | etching |
| Rinse | mass) | mass) | ratio) | mass) | mass) | mass) | ratio) | ratio) | (μC/cm²) | shape | (nm) | resistance |
| Example 1B | — | P-1 | S-1/S-2 | z125 | N-3 | W-3 | G-1 | — | 28 | Rectangle | 38.0 | A |
| | 0 | 68 | 80/20 | 30 | 2 | | | | | | | |
| Example 2B | — | P-2 | S-1/S-2 | z125 | N-3 | W-3 | G-1 | — | 25 | Rectangle | 36.0 | A |
| | 0 | 68 | 80/20 | 30 | 2 | | | | | | | |
| Example 3B | — | P-3 | S-1/S-2 | z125 | N-3 | W-3 | G-1 | — | 22 | Rectangle | 34.0 | A |
| | 0 | 68 | 80/20 | 30 | 2 | | | | | | | |
| Example 4B | — | P-4 | S-1/S-2 | z125 | N-3 | W-3 | G-1 | — | 20 | Rectangle | 32.0 | A |
| | 0 | 68 | 80/20 | 30 | 2 | | | | | | | |
| Example 5B | — | P-5 | S-1/S-2 | z125 | N-3 | W-3 | G-1 | — | 16 | Rectangle | 30.0 | A |
| | 0 | 68 | 80/20 | 30 | 2 | | | | | | | |
| Example 6B | — | P-6 | S-1/S-2 | z130 | N-6 | W-4 | G-1 | — | 29 | Rectangle | 38.0 | A |
| | 0 | 79 | 60/40 | 20 | 1 | | | | | | | |
| Example 7B | — | P-7 | S-1/S-2 | z130 | N-6 | W-4 | G-1 | — | 26 | Rectangle | 36.0 | A |
| | 0 | 79 | 60/40 | 20 | 1 | | | | | | | |
| Example 8B | — | P-8 | S-1/S-2 | z130 | N-6 | W-4 | G-1 | — | 22 | Rectangle | 34.0 | A |
| | 0 | 79 | 60/40 | 20 | 1 | | | | | | | |
| Example 9B | — | P-9 | S-1/S-2 | z130 | N-6 | W-4 | G-1 | — | 20 | Rectangle | 32.0 | A |
| | 0 | 79 | 60/40 | 20 | 1 | | | | | | | |
| Example 10B | — | P-10 | S-1/S-2 | z130 | N-6 | W-4 | G-1 | — | 17 | Rectangle | 30.0 | A |
| | 0 | 79 | 60/40 | 20 | 1 | | | | | | | |
| Example 11B | — | P-11 | S-1/S-2 | z115 | N-11 | W-4 | G-1 | — | 26 | Rectangle | 36.0 | A |
| | 0 | 73 | 70/30 | 25 | 2 | | | | | | | |
| Example 12B | — | P-12 | S-1/S-2 | z115 | N-11 | W-4 | G-1 | — | 21 | Rectangle | 32.0 | A |
| | 0 | 73 | 70/30 | 25 | 2 | | | | | | | |
| Example 13B | — | P-13 | S-1/S-2 | z115 | N-11 | W-4 | G-1 | — | 20 | Rectangle | 30.0 | A |
| | 0 | 73 | 70/30 | 25 | 2 | | | | | | | |
| Example 14B | — | P-14 | S-1/S-2 | z127 | N-11 | W-3 | G-1 | — | 28 | Rectangle | 38.0 | A |
| | 0 | 83 | 50/50 | 15 | 2 | | | | | | | |
| Example 15B | — | P-15 | S-1/S-2 | z127 | N-11 | W-3 | G-1 | — | 25 | Rectangle | 36.0 | A |
| | 0 | 83 | 50/50 | 15 | 2 | | | | | | | |
| Example 16B | — | P-16 | S-1/S-2 | z127 | N-11 | W-3 | G-1 | — | 21 | Rectangle | 32.0 | A |
| | 0 | 83 | 50/50 | 15 | 2 | | | | | | | |
| Example 17B | — | P-17 | S-1/S-3 | z76 | N-7 | W-4 | G-1 | — | 24 | Rectangle | 32.0 | A |
| | 0 | 62 | 70/30 | 35 | 3 | | | | | | | |
| Example 18B | — | P-18 | S-2 | — | N-5 | W-4 | G-3 | G-4 | 25 | Rectangle | 36.0 | A |
| | 0 | 99 | 100 | 0 | 1 | | | | | | | |
| Example 19B | — | P-19 | S-4/S-2 | z121 | N-10 | W-3 | G-1 | — | 26 | Rectangle | 30.0 | A |
| | 0 | 55 | 90/10 | 40 | 5 | | | | | | | |
| Example 20B | — | P-20 | S-1/S-2 | z140 | N-3 | W-1 | G-1 | — | 29 | Rectangle | 36.0 | A |
| | 0 | 88 | 90/10 | 10 | 2 | | | | | | | |
| Example 21B | — | P-21 | S-4/S-2 | z118 | N-8 | W-2 | G-2 | — | 28 | Rectangle | 38.0 | A |
| | 0 | 94 | 80/20 | 5 | 1 | | | | | | | |
| Example 22B | HR-24 | P-22 | S-1/S-3 | z145 | N-3 | W-4 | G-1 | — | 24 | Rectangle | 36.0 | A |
| | 10 | 79 | 60/40 | 10 | 1 | | | | | | | |
| Example 23B | — | P-23 | S-2/S-1 | — | N-1 | W-1 | G-2 | G-4 | 26 | Rectangle | 38.0 | A |
| | 0 | 99 | 80/20 | 0 | 1 | | | | | | | |
| Example 24B | — | P-24 | S-1/S-4 | z67 | N-9 | W-4 | G-1 | G-4 | 22 | Rectangle | 34.0 | A |
| | 0 | 83 | 90/10 | 15 | 2 | | | | | | | |
| Example 25B | — | P-13/P-25 | S-1 | z113 | N-5 | W-3 | G-1 | — | 20 | Rectangle | 32.0 | A |
| | 0 | 39/39 | 100 | 20 | 2 | | | | | | | |
| Example 26B | — | P-26 | S-2/S-1 | — | N-2 | W-2 | G-1 | — | 29 | Rectangle | 34.0 | A |
| | 0 | 97 | 90/10 | 0 | 3 | | | | | | | |
| Example 27B | — | P-27 | S-3/S-4 | — | N-4 | W-1 | G-1 | G-5 | 25 | Rectangle | 32.0 | A |
| | 0 | 97 | 50/50 | 0 | 3 | | | | | | | |
| Example 28B | HR-29 | P-28 | S-2/S-1 | z114 | N-12 | W-4 | G-1 | — | 23 | Rectangle | 36.0 | A |
| | 5 | 84 | 60/40 | 10 | 1 | | | | | | | |
| Example 29B | HR-1 | P-29 | S-2/S-1 | — | N-5 | W-2 | G-3 | — | 26 | Rectangle | 36.0 | A |
| | 3 | 95 | 70/30 | 0 | 2 | | | | | | | |
| Example 30B | — | P-30 | S-2/S-3 | — | N-11 | W-1 | G-3 | G-5 | 21 | Rectangle | 32.0 | A |
| | 0 | 99 | 70/30 | 0 | 1 | | | | | | | |
| Example 31B | — | P-31 | S-3 | — | N-6 | W-3 | G-1/G-3 | — | 30 | Rectangle | 34.0 | A |
| | 0 | 98 | 100 | 0 | 2 | | 80/20 | | | | | |
| Example 32B | — | P-32 | S-2/S-3 | — | N-6 | W-2 | G-1 | — | 21 | Rectangle | 34.0 | A |
| | 0 | 98 | 80/20 | 0 | 2 | | | | | | | |
| Example 33B | — | P-33 | S-1/S-3 | z141 | N-2 | W-3 | G-1 | G-6 | 22 | Rectangle | 34.0 | A |
| | 0 | 83 | 80/20 | 15 | 2 | | | | | | | |
| Example 34B | — | P-34 | S-3/S-1 | — | N-3 | W-2 | G-1 | G-4/G-5 | 20 | Rectangle | 30.0 | A |
| | 0 | 97 | 50/50 | 0 | 3 | | | 50/50 | | | | |
| Example 35B | — | P-35 | S-2/S-3 | — | N-12 | W-2 | G-2 | G-5 | 27 | Rectangle | 30.0 | A |
| | 0 | 97 | 50/50 | 0 | 3 | | | | | | | |
| Example 36B | — | P-36 | S-3/S-1 | z143 | N-11 | W-2 | G-2 | G-6 | 24 | Rectangle | 32.0 | A |
| | 0 | 93 | 60/40 | 5 | 2 | | | | | | | |
| Example 37B | — | P-37 | S-3/S-4 | — | N-6 | W-1 | G-1 | — | 25 | Rectangle | 36.0 | A |
| | 0 | 98 | 80/20 | 0 | 2 | | | | | | | |
| Example 38B | — | P-38 | S-3/S-4 | — | N-10 | W-1 | G-1 | — | 25 | Rectangle | 32.0 | A |
| | 0 | 97 | 70/30 | 0 | 3 | | | | | | | |
| Example 39B | — | P-39 | S-2/S-4 | z142 | N-9 | W-3 | G-3 | G-6 | 27 | Rectangle | 30.0 | A |
| | 0 | 88 | 90/10 | 10 | 2 | | | | | | | |
| Example 40B | — | P-40 | S-1/S-4 | z136/z130 | N-5 | W-1 | G-1 | — | 29 | Rectangle | 36.0 | A |
| | 0 | 68 | 80/20 | 15/15 | 2 | | | | | | | |
| Example 41B | — | P-41 | S-1/S-4 | z136/z130 | N-5 | W-1 | G-1 | — | 30 | Rectangle | 36.0 | A |
| | 0 | 68 | 80/20 | 15/15 | 2 | | | | | | | |
| Example 42B | — | P-42 | S-1/S-4 | z136/z130 | N-5 | W-1 | G-1 | — | 27 | Rectangle | 34.0 | A |
| | 0 | 68 | 80/20 | 15/15 | 2 | | | | | | | |
| Example 43B | — | P-43 | S-1/S-4 | z136/z130 | N-5 | W-1 | G-1 | — | 26 | Rectangle | 34.0 | A |
| | 0 | 68 | 80/20 | 15/15 | 2 | | | | | | | |
| Example 44B | — | P-44 | S-1/S-4 | z136/z130 | N-5 | W-1 | G-1 | — | 22 | Rectangle | 32.0 | A |
| | 0 | 68 | 80/20 | 15/15 | 2 | | | | | | | |
| Example 45B | — | P-45 | S-1/S-4 | z136/z130 | N-5 | W-1 | G-1 | — | 24 | Rectangle | 30.0 | A |
| | 0 | 68 | 80/20 | 15/15 | 2 | | | | | | | |
| Example 46B | — | P-46 | S-1/S-4 | z136/z130 | N-5 | W-1 | G-1 | — | 23 | Rectangle | 30.0 | A |
| | 0 | 68 | 80/20 | 15/15 | 2 | | | | | | | |
| Example 47B | — | P-47 | S-1/S-4 | z136/z130 | N-5 | W-1 | G-1 | — | 23 | Rectangle | 30.0 | A |
| | 0 | 68 | 80/20 | 15/15 | 2 | | | | | | | |
| Comparative | — | P-1 | S-1/S-2 | z140 | N-3 | W-1 | G-1 | — | 35 | Reverse | 46.0 | B |
| Example 1B | 0 | 88 | 90/10 | 10 | 2 | | | | | taper | | |
| Comparative | — | P-2 | S-4/S-2 | z118 | N-8 | W-2 | G-2 | — | 36 | Reverse | 42.0 | B |
| Example 2B | 0 | 94 | 80/20 | 5 | 1 | | | | | taper | | |
| Comparative | — | P-3 | S-1/S-3 | z141 | N-2 | W-3 | G-1 | G-6 | 37 | Reverse | 44.0 | B |
| Example 3B | 0 | 83 | 80/20 | 15 | 2 | | | | | taper | | |

| | | | | | | | | | | |
|---|---|---|---|---|---|---|---|---|---|---|
| Comparative | — | P-4 | S-1/S-3 | z5 | N-1 | W-4 | G-1 | — | Pattern formation is not possible | A |
| Example 4B | 0 | 88 | 90/10 | 10 | 2 | | | | | |

As apparent from the results shown in the above tables, it was found that Examples 1B to 47B using the pattern forming method according to the present invention satisfies high sensitivity, high resolving power at the time of isolated line pattern formation, a good pattern shape, and high dry etching resistance at the same time, in contrast to Comparative Examples 1B to 4B.

According to the present invention, a pattern forming method which satisfies high sensitivity, high resolving power at the time of isolated line pattern formation, a good pattern shape, and high dry etching resistance at the same time, an actinic ray sensitive or radiation sensitive resin composition, a resist film, a method for manufacturing an electronic device using these, and an electronic device can be provided.

The present invention has been described in detail and with reference to specific embodiments, and it is apparent to those skilled in the art that various modifications and changes are possible without departing from the spirit and the scope of the invention.

This application is based on Japanese Patent Application (JP2013-161903) filed on Friday, Aug. 2, 2013, and the contents thereof are incorporated herein by reference.

What is claimed is:

1. A pattern forming method, comprising:
step (1) of forming a film using an actinic ray sensitive or radiation sensitive resin composition containing a resin (Ab) having a repeating unit represented by the following General Formula (Ab1);
step (2) of exposing the film; and
step (4) of performing development using a developer including an organic solvent after exposing and of forming a negative type pattern, in this order: 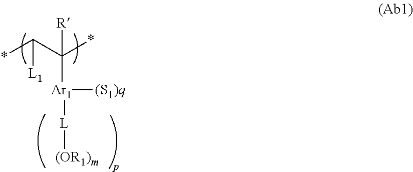
wherein, in General Formula (Ab1),
R′ represents a hydrogen atom, an alkyl group, or a halogen atom;
L₁ represents a hydrogen atom or an alkyl group, L₁ and Ar₁ may be connected to each other to form a ring, and in this case, L₁ represents an alkylene group;
Ar₁ represents a (p+q+1) valent aromatic ring group;
L represents an (m+1) valent connecting group;
S₁ represents an organic group;
OR₁ represents a group which generates an alcoholic hydroxyl group by being decomposed due to the action of an acid;
in a case where a plurality of S₁'s, L's, and R₁'s are present, the plurality of S₁'s, the plurality of L's, or the plurality of R₁'s may be the same or different, respectively, and the plurality of R₁'s may be bonded to each other to form a ring;
m represents an integer of 1 or greater;
and p represents an integer of 1 or greater, and
q represents an integer of 0 or greater.

2. The pattern forming method according to claim 1,
wherein the repeating unit represented by General Formula (Ab1) is a repeating unit represented by the following General Formula (Ab1-1): 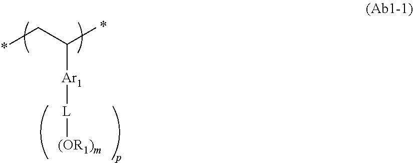
wherein, in General Formula (Ab1-1),
Ar₁ represents a (p+1) valent aromatic ring group;
L represents an (m+1) valent connecting group;
OR₁ represents a group which generates an alcoholic hydroxyl group by being decomposed due to the action of an acid;
in a case where a plurality of L's and R₁'s are present, the plurality of L's and the plurality of R₁'s may be the same or different, respectively, and the plurality of R₁'s may be bonded to each other to form a ring;
m represents an integer of 1 or greater; and
p represents an integer of 1 or greater.

3. The pattern forming method according to claim 2,
wherein the repeating unit represented by General Formula (Ab1-1) is a repeating unit represented by the following General Formula (Ab1-1-1): 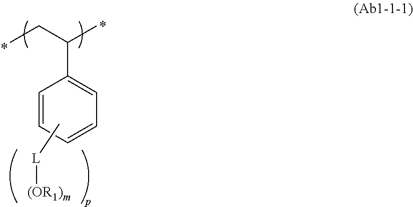
wherein, in General Formula (Ab1-1-1),
L represents an (m+1) valent connecting group;
OR₁ represents a group which generates an alcoholic hydroxyl group by being decomposed due to the action of an acid;
in a case where a plurality of L's and R₁'s are present, the plurality of L's and the plurality of R₁'s may be the same or different, respectively, and the plurality of R₁'s may be bonded to each other to form a ring;
m represents an integer of 1 or greater; and
p represents an integer of 1 or greater.

4. The pattern forming method according to claim 1,
wherein the resin (Ab) further has a repeating unit represented by the following General Formula (A): 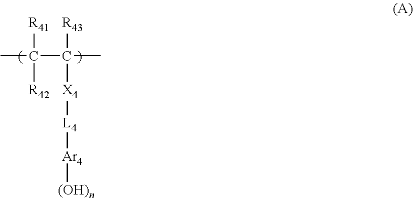
wherein, in General Formula (A),
each of R₄₁, R₄₂, and R₄₃ independently represents a hydrogen atom, an alkyl group, a halogen atom, a cyano group, or an alkoxycarbonyl group;
here, R₄₂ may be bonded to Ar₄ or X₄ to form a ring, and R₄₂ in this case represents a single bond or an alkylene group;
X₄ represents a single bond, an alkylene group, —COO—, or —CONR₆₄—; here, R₆₄ represents a hydrogen atom or an alkyl group;
L₄ represents a single bond, —COO—, or an alkylene group;
Ar₄ represents an (n+1) valent aromatic ring group, and, in the case of being bonded to R₄₂ to form a ring, Ar₄ represents an (n+2) valent aromatic ring group; and
n represents an integer of 1 to 4.

5. The pattern forming method according to claim 4,
wherein the repeating unit represented by General Formula (A) is a repeating unit represented by the following General Formula (A1) or (A2): 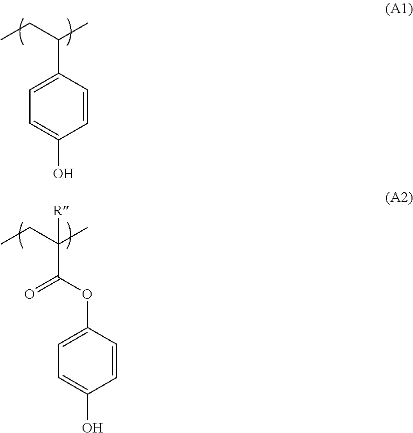
wherein, in General Formula (A2),
R″ represents a hydrogen atom or a methyl group.

6. The pattern forming method according to claim 1,
wherein the exposure in the step (2) is exposure by an electron beam or extreme ultraviolet rays.

7. The pattern forming method according to claim 1,
wherein the actinic ray sensitive or radiation sensitive resin composition further includes a compound that generates an acid by irradiation with actinic ray or radiation.

8. The pattern forming method according to claim 1,
wherein the resin (Ab) is a resin having a repeating unit represented by the following General Formula (4): 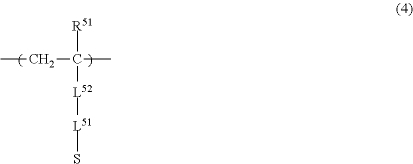
wherein, in General Formula (4),
R⁵¹ represents a hydrogen atom or a methyl group;
L⁵¹ represents a single bond or a divalent connecting group;
L⁵² represents a divalent connecting group; and
S represents a structural portion that generates an acid on a side chain by being decomposed by irradiation with actinic ray or radiation.

9. An actinic ray sensitive or radiation sensitive resin composition which is supplied to the pattern forming method according to claim 1.

10. A resist film which is formed of the actinic ray sensitive or radiation sensitive resin composition according to claim 9.

11. A method for manufacturing an electronic device, comprising:
the pattern forming method according to claim 1.

12. An electronic device manufactured by the method for manufacturing an electronic device according to claim 11.
